(19) United States
(12) Patent Application Publication
(10) Pub. No.: US 2023/0240129 A1
(43) Pub. Date: Jul. 27, 2023

(54) ORGANIC ELECTROLUMINESCENT MATERIAL AND DEVICE THEREOF

(71) Applicant: BEIJING SUMMER SPROUT TECHNOLOGY CO., LTD., Beijing (CN)

(72) Inventors: Ming SANG, Beijing (CN); Zheng WANG, Beijing (CN); Hongbo LI, Beijing (CN); Chi Yuen Raymond KWONG, Beijing (CN); Chuanjun Xia, Beijing (CN)

(21) Appl. No.: 18/157,225

(22) Filed: Jan. 20, 2023

(30) Foreign Application Priority Data
Jan. 25, 2022 (CN) 202210078763.2
Nov. 23, 2022 (CN) 202211472133.X

(51) Int. Cl. H10K 85/30; H10K 50/12

(52) U.S. Cl. CPC H10K 85/342; H10K 50/12

(57) ABSTRACT

Provided are an organic electroluminescent material and device. The organic electroluminescent material is a metal complex comprising a ligand Lₐ having a structure of Formula 1. When applied to organic electroluminescent devices, these metal complexes can provide very good device performance, especially an extended device lifetime and improved device efficiency and have a huge application prospect in aspects of white and low blue light sources. Further provided are an organic electroluminescent device comprising the metal complex and a compound composition comprising the metal complex.

### CROSS-REFERENCE TO RELATED APPLICATION(S)

This application claims priority to Chinese Patent Application No. 202210078763.2 filed on Jan. 25, 2022 and Chinese Patent Application No. 202211472133.X filed on Nov. 23, 2022, the disclosures of both applications being incorporated herein by reference in their entireties.

### TECHNICAL FIELD

The present disclosure relates to compounds for organic electronic devices, for example, organic electroluminescent devices. More particularly, the present disclosure relates to a metal complex comprising a ligand Lₐ having a structure of Formula 1 and an organic electroluminescent device and compound composition comprising the metal complex.

### BACKGROUND

Organic electronic devices include, but are not limited to, the following types: organic light-emitting diodes (OLEDs), organic field-effect transistors (O-FETs), organic light-emitting transistors (OLETs), organic photovoltaic devices (OPVs), dye-sensitized solar cells (DSSCs), organic optical detectors, organic photoreceptors, organic field-quench devices (OFQDs), light-emitting electrochemical cells (LECs), organic laser diodes and organic plasmon emitting devices.

In 1987, Tang and Van Slyke of Eastman Kodak reported a bilayer organic electroluminescent device, which includes an arylamine hole transporting layer and a tris-8-hydroxyquinolato-aluminum layer as the electron and emitting layer (Applied Physics Letters, 1987, 51 (12): 913-915). Once a bias is applied to the device, green light was emitted from the device. This device laid the foundation for the development of modern organic light-emitting diodes (OLEDs). State-of-the-art OLEDs may include multiple layers such as charge injection and transporting layers, charge and exciton blocking layers, and one or multiple emissive layers between the cathode and anode. Since the OLED is a self-emitting solid state device, it offers tremendous potential for display and lighting applications. In addition, the inherent properties of organic materials, such as their flexibility, may make them well suited for particular applications such as fabrication on flexible substrates.

The OLED can be categorized as three different types according to its emitting mechanism. The OLED invented by Tang and van Slyke is a fluorescent OLED. It only utilizes singlet emission. The triplets generated in the device are wasted through nonradiative decay channels. Therefore, the internal quantum efficiency (IQE) of the fluorescent OLED is only 25%. This limitation hindered the commercialization of OLED. In 1997, Forrest and Thompson reported phosphorescent OLED, which uses triplet emission from heavy metal containing complexes as the emitter. As a result, both singlet and triplets can be harvested, achieving 100% IQE. The discovery and development of phosphorescent OLED contributed directly to the commercialization of active-matrix OLED (AMOLED) due to its high efficiency. Recently, Adachi achieved high efficiency through thermally activated delayed fluorescence (TADF) of organic compounds. These emitters have small singlet-triplet gap that makes the transition from triplet back to singlet possible. In the TADF device, the triplet excitons can go through reverse intersystem crossing to generate singlet excitons, resulting in high IQE.

OLEDs can also be classified as small molecule and polymer OLEDs according to the forms of the materials used. A small molecule refers to any organic or organometallic material that is not a polymer. The molecular weight of the small molecule can be large as long as it has well defined structure. Dendrimers with well-defined structures are considered as small molecules. Polymer OLEDs include conjugated polymers and non-conjugated polymers with pendant emitting groups. Small molecule OLED can become the polymer OLED if post polymerization occurred during the fabrication process.

There are various methods for OLED fabrication. Small molecule OLEDs are generally fabricated by vacuum thermal evaporation. Polymer OLEDs are fabricated by solution process such as spin-coating, inkjet printing, and slit printing. If the material can be dissolved or dispersed in a solvent, the small molecule OLED can also be produced by solution process.

The emitting color of the OLED can be achieved by emitter structural design. An OLED may include one emitting layer or a plurality of emitting layers to achieve desired spectrum. In the case of green, yellow, and red OLEDs, phosphorescent emitters have successfully reached commercialization. Blue phosphorescent device still suffers from non-saturated blue color, short device lifetime, and high operating voltage. Commercial full-color OLED displays normally adopt a hybrid strategy, using fluorescent blue and phosphorescent yellow, or red and green. At present, efficiency roll-off of phosphorescent OLEDs at high brightness remains a problem. In addition, it is desirable to have more saturated emitting color, higher efficiency, and longer device lifetime.

US2014021447A1 discloses a metal complex having the following structure:

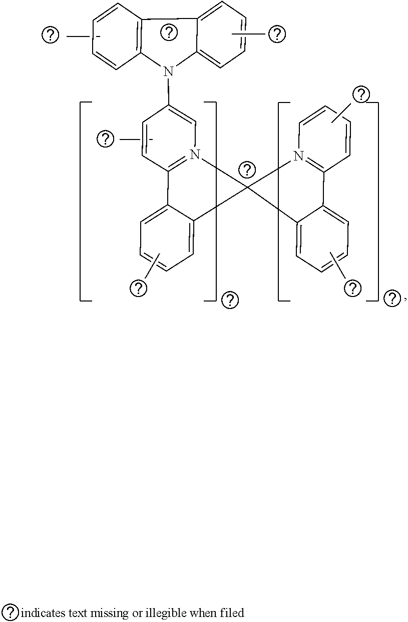

wherein Z is a single bond or is absent, and further discloses the following iridium complex:

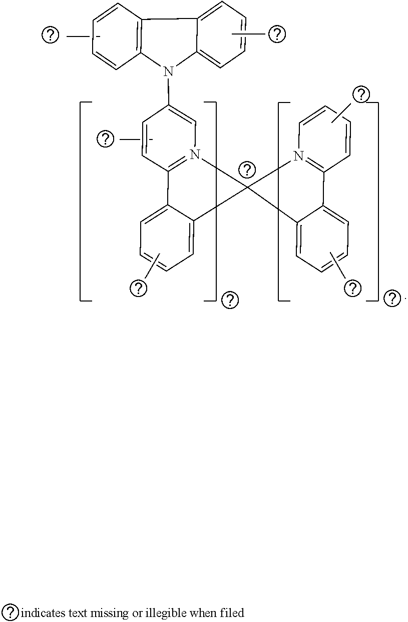

This application discloses a metal complex in which a carbazole group is joined at position 5 of pyridine in a phenyl-pyridine ligand. However, this application has neither disclosed nor taught a metal complex in which a particular substituent is joined at position 4 of pyridine in a fused six-five-six member ring-pyridine ligand and an effect of the metal complex on device performance.

U.S. Pat. No. 7,816,016B1 discloses a metal complex having the following structure:

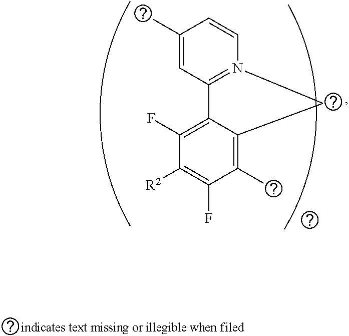

wherein R¹ is selected from a structure such as indole, indoline, carbazole, tetrahydrocarbazole, phenanthroline, phenazine, phenanthridine, quinoxaline, pyrrole or CHAr₂, and further discloses a metal complex comprising a fluorine-substituted phenylpyridine ligand where a carbazole is substituted at position 4 of the pyridine. This application discloses a metal complex, wherein in the phenyl-pyridine ligand, a heteroaryl group such as carbazole is joined at position 4 of the pyridine and a fluorine substitution exists on the phenyl. However, this application has not disclosed the data of an organic electroluminescent device and has neither disclosed nor taught a metal complex in which a particular substituent is joined at position 4 of pyridine in a ligand with another structure, such as a fused six-five-six member ring-pyridine ligand, and an effect of the metal complex on device performance.

### SUMMARY

The present disclosure aims to provide a series of metal complexes each comprising a ligand Lₐ having a structure of Formula 1 to solve at least part of the above-mentioned problems. These metal complexes may be used as light-emitting materials in electroluminescent devices. When applied to the electroluminescent devices, these novel compounds can provide better device performance such as improved device efficiency and an extended device lifetime and significantly improve the overall performance of the devices.

According to an embodiment of the present disclosure, disclosed is a metal complex comprising a metal M and a ligand Lₐ coordinated to the metal M, wherein Lₐ has a structure represented by Formula 1:

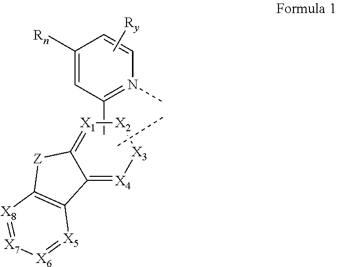

wherein

the metal M is selected from a metal with a relative atomic mass greater than 40;

Z is selected from the group consisting of O, S, Se, NR′, CR′R′ and SiR′R′; when two R′ are present at the same time, the two R′ are the same or different;

the substituent R_{y} represents mono-substitution, multiple substitutions or non-substitution;

X₁ to X₈ are, at each occurrence identically or differently, selected from C, CRₓ or N, and at least one of X₁ to X₄ is selected from C and joined to pyridine in Formula 1;

the substituent Rₙ has a structure represented by Formula 2:

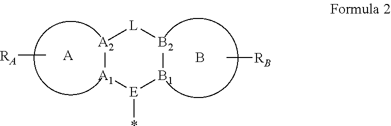

wherein in Formula 2,

the substituents RA and RB represent, at each occurrence identically or differently, mono-substitution, multiple substitutions or non-substitution;

the ring A and the ring B are identically or differently selected from a carbocyclic ring having 3 to 30 ring atoms or a heterocyclic ring having 3 to 30 ring atoms;

A₁, A₂, B₁, B₂ and E are, at each occurrence identically or differently, selected from C, N, B, P, CR′″, SiR′″ or GeR′″;

L is selected from a single bond, O, S, SO₂, Se, NR″, CR″R″, SiR″R″, GeR″R″, BR″, PR″, P(O)R″, R″C═CR″, substituted or unsubstituted alkylene having 1 to 20 carbon atoms, substituted or unsubstituted heteroalkylene having 1 to 20 carbon atoms, substituted or unsubstituted cycloalkylene having 3 to 20 carbon atoms, substituted or unsubstituted heterocyclylene having 3 to 20 ring atoms, substituted or unsubstituted arylene having 6 to 30 carbon atoms, substituted or unsubstituted heteroarylene having 3 to 30 carbon atoms or a combination thereof;

the substituents R′, R″, R′″, Rₓ, R_{y}, R_{A} and R_{B} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof;

“*” represents a position where Formula 2 is joined; and

adjacent substituents R′, Rₓ, R″, R′″, R_{A}, R_{B}, R_{y} can be optionally joined to form a ring.

According to another embodiment of the present disclosure, further disclosed is an electroluminescent device comprising an anode, a cathode and an organic layer disposed between the anode and the cathode, wherein at least one layer of the organic layer comprises the metal complex in the preceding embodiment.

According to another embodiment of the present disclosure, further disclosed is a compound composition comprising the metal complex in the preceding embodiment.

The present disclosure discloses a series of metal complexes each comprising a ligand Lₐ having a structure of Formula 1. These novel metal complexes may be used as light-emitting materials in electroluminescent devices. When applied to the electroluminescent devices, these metal complexes can achieve very good device performance such as improved device efficiency and an extended device lifetime and significantly improve the overall performance of the devices. These metal complexes have a huge application prospect in aspects of white and low blue light sources.

### BRIEF DESCRIPTION OF DRAWINGS

FIG. 1 is a schematic diagram of an organic light-emitting apparatus that may comprise a metal complex and a compound composition disclosed herein.

FIG. 2 is a schematic diagram of another organic light-emitting apparatus that may comprise a metal complex and a compound composition disclosed herein.

### DETAILED DESCRIPTION

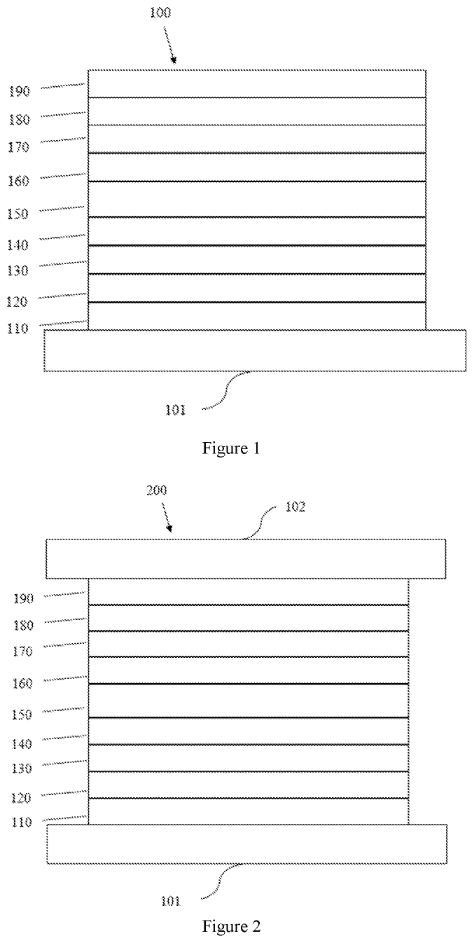

OLEDs can be fabricated on various types of substrates such as glass, plastic, and metal foil. FIG. 1 schematically shows an organic light-emitting device 100 without limitation. The figures are not necessarily drawn to scale. Some of the layers in the figures can also be omitted as needed. Device 100 may include a substrate 101, an anode 110, a hole injection layer 120, a hole transport layer 130, an electron blocking layer 140, an emissive layer 150, a hole blocking layer 160, an electron transport layer 170, an electron injection layer 180 and a cathode 190. Device 100 may be fabricated by depositing the layers described in order. The properties and functions of these various layers, as well as example materials, are described in more detail in U.S. Pat. No. 7,279,704 at cols. 6-10, the contents of which are incorporated by reference herein in its entirety.

More examples for each of these layers are available. For example, a flexible and transparent substrate-anode combination is disclosed in U.S. Pat. No. 5,844,363, which is incorporated by reference herein in its entirety. An example of a p-doped hole transport layer is m-MTDATA doped with F4-TCNQ at a molar ratio of 50:1, as disclosed in U.S. Patent Application Publication No. 2003/0230980, which is incorporated by reference herein in its entirety. Examples of host materials are disclosed in U.S. Pat. No. 6,303,238 to Thompson et al., which is incorporated by reference herein in its entirety. An example of an n-doped electron transport layer is BPhen doped with Li at a molar ratio of 1:1, as disclosed in U.S. Patent Application Publication No. 2003/0230980, which is incorporated by reference herein in its entirety. U.S. Pat. Nos. 5,703,436 and 5,707,745, which are incorporated by reference herein in their entireties, disclose examples of cathodes including composite cathodes having a thin layer of metal such as Mg:Ag with an overlying transparent, electrically-conductive, sputter-deposited ITO layer. The theory and use of blocking layers are described in more detail in U.S. Pat. No. 6,097,147 and U.S. Patent Application Publication No. 2003/0230980, which are incorporated by reference herein in their entireties. Examples of injection layers are provided in U.S. Patent Application Publication No. 2004/0174116, which is incorporated by reference herein in its entirety. A description of protective layers may be found in U.S. Patent Application Publication No. 2004/0174116, which is incorporated by reference herein in its entirety.

The layered structure described above is provided by way of non-limiting examples. Functional OLEDs may be achieved by combining the various layers described in different ways, or layers may be omitted entirely. It may also include other layers not specifically described. Within each layer, a single material or a mixture of multiple materials can be used to achieve optimum performance. Any functional layer may include several sublayers. For example, the emissive layer may have two layers of different emitting materials to achieve desired emission spectrum.

In one embodiment, an OLED may be described as having an “organic layer” disposed between a cathode and an anode. This organic layer may include a single layer or multiple layers.

An OLED can be encapsulated by a barrier layer. FIG. 2 schematically shows an organic light emitting device 200 without limitation. FIG. 2 differs from FIG. 1 in that the organic light emitting device include a barrier layer 102, which is above the cathode 190, to protect it from harmful species from the environment such as moisture and oxygen. Any material that can provide the barrier function can be used as the barrier layer such as glass or organic-inorganic hybrid layers. The barrier layer should be placed directly or indirectly outside of the OLED device. Multilayer thin film encapsulation was described in U.S. Pat. No. 7,968,146, which is incorporated by reference herein in its entirety.

Devices fabricated in accordance with embodiments of the present disclosure can be incorporated into a wide variety of consumer products that have one or more of the electronic component modules (or units) incorporated therein. Some examples of such consumer products include flat panel displays, monitors, medical monitors, televisions, billboards, lights for interior or exterior illumination and/or signaling, heads-up displays, fully or partially transparent displays, flexible displays, smart phones, tablets, phablets, wearable devices, smart watches, laptop computers, digital cameras, camcorders, viewfinders, micro-displays, 3-D displays, vehicles displays, and vehicle tail lights.

The materials and structures described herein may be used in other organic electronic devices listed above.

As used herein, “top” means furthest away from the substrate, while “bottom” means closest to the substrate. Where a first layer is described as “disposed over” a second layer, the first layer is disposed further away from the substrate. There may be other layers between the first and second layers, unless it is specified that the first layer is “in contact with” the second layer. For example, a cathode may be described as “disposed over” an anode, even though there are various organic layers in between.

As used herein, “solution processible” means capable of being dissolved, dispersed, or transported in and/or deposited from a liquid medium, either in solution or suspension form.

A ligand may be referred to as “photoactive” when it is believed that the ligand directly contributes to the photoactive properties of an emissive material. A ligand may be referred to as “ancillary” when it is believed that the ligand does not contribute to the photoactive properties of an emissive material, although an ancillary ligand may alter the properties of a photoactive ligand.

It is believed that the internal quantum efficiency (IQE) of fluorescent OLEDs can exceed the 25% spin statistics limit through delayed fluorescence. As used herein, there are two types of delayed fluorescence, i.e. P-type delayed fluorescence and E-type delayed fluorescence. P-type delayed fluorescence is generated from triplet-triplet annihilation (TTA).

On the other hand, E-type delayed fluorescence does not rely on the collision of two triplets, but rather on the transition between the triplet states and the singlet excited states. Compounds that are capable of generating E-type delayed fluorescence are required to have very small singlet-triplet gaps to convert between energy states. Thermal energy can activate the transition from the triplet state back to the singlet state. This type of delayed fluorescence is also known as thermally activated delayed fluorescence (TADF). A distinctive feature of TADF is that the delayed component increases as temperature rises. If the reverse intersystem crossing (RISC) rate is fast enough to minimize the non-radiative decay from the triplet state, the fraction of back populated singlet excited states can potentially reach 75%. The total singlet fraction can be 100%, far exceeding 25% of the spin statistics limit for electrically generated excitons.

E-type delayed fluorescence characteristics can be found in an exciplex system or in a single compound. Without being bound by theory, it is believed that E-type delayed fluorescence requires the luminescent material to have a small singlet-triplet energy gap (ΔE_{S-T}). Organic, non-metal containing, donor-acceptor luminescent materials may be able to achieve this. The emission in these materials is generally characterized as a donor-acceptor charge-transfer (CT) type emission. The spatial separation of the HOMO and LUMO in these donor-acceptor type compounds generally results in small ΔE_{S-T}. These states may involve CT states. Generally, donor-acceptor luminescent materials are constructed by connecting an electron donor moiety such as amino- or carbazole-derivatives and an electron acceptor moiety such as N-containing six-membered aromatic rings.

### Definition of Terms of Substituents

Halogen or halide—as used herein includes fluorine, chlorine, bromine, and iodine.

Alkyl—as used herein includes both straight and branched chain alkyl groups. Alkyl may be alkyl having 1 to 20 carbon atoms, preferably alkyl having 1 to 12 carbon atoms, and more preferably alkyl having 1 to 6 carbon atoms. Examples of alkyl groups include a methyl group, an ethyl group, a propyl group, an isopropyl group, an n-butyl group, an s-butyl group, an isobutyl group, a t-butyl group, an n-pentyl group, an n-hexyl group, an n-heptyl group, an n-octyl group, an n-nonyl group, an n-decyl group, an n-undecyl group, an n-dodecyl group, an n-tridecyl group, an n-tetradecyl group, an n-pentadecyl group, an n-hexadecyl group, an n-heptadecyl group, an n-octadecyl group, a neopentyl group, a 1-methylpentyl group, a 2-methylpentyl group, a 1-pentylhexyl group, a 1-butylpentyl group, a 1-heptyloctyl group, and a 3-methylpentyl group. Of the above, preferred are a methyl group, an ethyl group, a propyl group, an isopropyl group, a n-butyl group, an s-butyl group, an isobutyl group, a t-butyl group, an n-pentyl group, a neopentyl group, and an n-hexyl group. Additionally, the alkyl group may be optionally substituted.

Cycloalkyl—as used herein includes cyclic alkyl groups. The cycloalkyl groups may be those having 3 to 20 ring carbon atoms, preferably those having 4 to 10 carbon atoms. Examples of cycloalkyl include cyclobutyl, cyclopentyl, cyclohexyl, 4-methylcyclohexyl, 4,4-dimethylcylcohexyl, 1-adamantyl, 2-adamantyl, 1-norbornyl, 2-norbornyl, and the like. Of the above, preferred are cyclopentyl, cyclohexyl, 4-methylcyclohexyl, and 4,4-dimethylcylcohexyl. Additionally, the cycloalkyl group may be optionally substituted.

Heteroalkyl—as used herein, includes a group formed by replacing one or more carbons in an alkyl chain with a hetero-atom(s) selected from the group consisting of a nitrogen atom, an oxygen atom, a sulfur atom, a selenium atom, a phosphorus atom, a silicon atom, a germanium atom, and a boron atom. Heteroalkyl may be those having 1 to 20 carbon atoms, preferably those having 1 to 10 carbon atoms, and more preferably those having 1 to 6 carbon atoms. Examples of heteroalkyl include methoxymethyl, ethoxymethyl, ethoxyethyl, methylthiomethyl, ethylthiomethyl, ethylthioethyl, methoxymethoxymethyl, ethoxymethoxymethyl, ethoxyethoxyethyl, hydroxymethyl, hydroxyethyl, hydroxypropyl, mercaptomethyl, mercaptoethyl, mercaptopropyl, aminomethyl, aminoethyl, aminopropyl, dimethylaminomethyl, trimethylgermanylmethyl, trimethylgermanylethyl, trimethylgermanylisopropyl, dimethylethylgermanylmethyl, dimethylisopropylgermanylmethyl, tert-butylmethylgermanylmethyl, triethylgermanylmethyl, triethylgermanylethyl, triisopropylgermanylmethyl, triisopropylgermanylethyl, trimethylsilylmethyl, trimethylsilylethyl, and trimethylsilylisopropyl, triisopropylsilylmethyl, triisopropylsilylethyl. Additionally, the heteroalkyl group may be optionally substituted.

Alkenyl—as used herein includes straight chain, branched chain, and cyclic alkene groups. Alkenyl may be those having 2 to 20 carbon atoms, preferably those having 2 to 10 carbon atoms. Examples of alkenyl include vinyl, 1-propenyl group, 1-butenyl, 2-butenyl, 3-butenyl, 1,3-butandienyl, 1-methylvinyl, styryl, 2,2-diphenylvinyl, 1,2-diphenylvinyl, 1-methylallyl, 1,1-dimethylallyl, 2-methylallyl, 1-phenylallyl, 2-phenylallyl, 3-phenylallyl, 3,3-diphenylallyl, 1,2-dimethylallyl, 1-phenyl-1-butenyl, 3-phenyl-1-butenyl, cyclopentenyl, cyclopentadienyl, cyclohexenyl, cycloheptenyl, cycloheptatrienyl, cyclooctenyl, cyclooctatetraenyl, and norbornenyl. Additionally, the alkenyl group may be optionally substituted.

Alkynyl—as used herein includes straight chain alkynyl groups. Alkynyl may be those having 2 to 20 carbon atoms, preferably those having 2 to 10 carbon atoms. Examples of alkynyl groups include ethynyl, propynyl, propargyl, 1-butynyl, 2-butynyl, 3-butynyl, 1-pentynyl, 2-pentynyl, 3,3-dimethyl-1-butynyl, 3-ethyl-3-methyl-1-pentynyl, 3,3-diisopropyl-1-pentynyl, phenylethynyl, phenylpropynyl, etc. Of the above, preferred are ethynyl, propynyl, propargyl, 1-butynyl, 2-butynyl, 3-butynyl, 1-pentynyl, and phenylethynyl. Additionally, the alkynyl group may be optionally substituted.

Aryl or an aromatic group—as used herein includes non-condensed and condensed systems. Aryl may be those having 6 to 30 carbon atoms, preferably those having 6 to 20 carbon atoms, and more preferably those having 6 to 12 carbon atoms. Examples of aryl groups include phenyl, biphenyl, terphenyl, triphenylene, tetraphenylene, naphthalene, anthracene, phenalene, phenanthrene, fluorene, pyrene, chrysene, perylene, and azulene, preferably phenyl, biphenyl, terphenyl, triphenylene, fluorene, and naphthalene. Examples of non-condensed aryl groups include phenyl, biphenyl-2-yl, biphenyl-3-yl, biphenyl-4-yl, p-terphenyl-4-yl, p-terphenyl-3-yl, p-terphenyl-2-yl, m-terphenyl-4-yl, m-terphenyl-3-yl, m-terphenyl-2-yl, o-tolyl, m-tolyl, p-tolyl, p-(2-phenylpropyl)phenyl, 4′-methylbiphenylyl, 4″-t-butyl-p-terphenyl-4-yl, o-cumenyl, m-cumenyl, p-cumenyl, 2,3-xylyl, 3,4-xylyl, 2,5-xylyl, mesityl, and m-quarterphenyl. Additionally, the aryl group may be optionally substituted.

Heterocyclic groups or heterocycle—as used herein include non-aromatic cyclic groups. Non-aromatic heterocyclic groups include saturated heterocyclic groups having 3 to 20 ring atoms and unsaturated non-aromatic heterocyclic groups having 3 to 20 ring atoms, where at least one ring atom is selected from the group consisting of a nitrogen atom, an oxygen atom, a sulfur atom, a selenium atom, a silicon atom, a phosphorus atom, a germanium atom, and a boron atom. Preferred non-aromatic heterocyclic groups are those having 3 to 7 ring atoms, each of which includes at least one hetero-atom such as nitrogen, oxygen, silicon, or sulfur. Examples of non-aromatic heterocyclic groups include oxiranyl, oxetanyl, tetrahydrofuranyl, tetrahydropyranyl, dioxolanyl, dioxanyl, aziridinyl, dihydropyrrolyl, tetrahydropyrrolyl, piperidinyl, oxazolidinyl, morpholinyl, piperazinyl, oxepinyl, thiepinyl, azepinyl, and tetrahydrosilolyl. Additionally, the heterocyclic group may be optionally substituted.

Heteroaryl—as used herein, includes non-condensed and condensed hetero-aromatic groups having 1 to 5 hetero-atoms, where at least one hetero-atom is selected from the group consisting of a nitrogen atom, an oxygen atom, a sulfur atom, a selenium atom, a silicon atom, a phosphorus atom, a germanium atom, and a boron atom. A hetero-aromatic group is also referred to as heteroaryl. Heteroaryl may be those having 3 to 30 carbon atoms, preferably those having 3 to 20 carbon atoms, and more preferably those having 3 to 12 carbon atoms. Suitable heteroaryl groups include dibenzothiophene, dibenzofuran, dibenzoselenophene, furan, thiophene, benzofuran, benzothiophene, benzoselenophene, carbazole, indolocarbazole, pyridoindole, pyrrolodipyridine, pyrazole, imidazole, triazole, oxazole, thiazole, oxadiazole, oxatriazole, dioxazole, thiadiazole, pyridine, pyridazine, pyrimidine, pyrazine, triazine, oxazine, oxathiazine, oxadiazine, indole, benzimidazole, indazole, indoxazine, benzoxazole, benzisoxazole, benzothiazole, quinoline, isoquinoline, cinnoline, quinazoline, quinoxaline, naphthyridine, phthalazine, pteridine, xanthene, acridine, phenazine, phenothiazine, benzofuropyridine, furodipyridine, benzothienopyridine, thienodipyridine, benzoselenophenopyridine, and selenophenodipyridine, preferably dibenzothiophene, dibenzofuran, dibenzoselenophene, carbazole, indolocarbazole, imidazole, pyridine, triazine, benzimidazole, 1,2-azaborine, 1,3-azaborine, 1,4-azaborine, borazine, and aza-analogs thereof. Additionally, the heteroaryl group may be optionally substituted.

Alkoxy—as used herein, is represented by —O-alkyl, —O-cycloalkyl, —O-heteroalkyl, or —O-heterocyclic group. Examples and preferred examples of alkyl, cycloalkyl, heteroalkyl, and heterocyclic groups are the same as those described above. Alkoxy groups may be those having 1 to 20 carbon atoms, preferably those having 1 to 6 carbon atoms. Examples of alkoxy groups include methoxy, ethoxy, propoxy, butoxy, pentyloxy, hexyloxy, cyclopropyloxy, cyclobutyloxy, cyclopentyloxy, cyclohexyloxy, tetrahydrofuranyloxy, tetrahydropyranyloxy, methoxypropyloxy, ethoxyethyloxy, methoxymethyloxy, and ethoxymethyloxy. Additionally, the alkoxy group may be optionally substituted.

Aryloxy—as used herein, is represented by —O-aryl or —O-heteroaryl. Examples and preferred examples of aryl and heteroaryl are the same as those described above. Aryloxy groups may be those having 6 to 30 carbon atoms, preferably those having 6 to 20 carbon atoms. Examples of aryloxy groups include phenoxy and biphenyloxy. Additionally, the aryloxy group may be optionally substituted.

Arylalkyl—as used herein, contemplates alkyl substituted with an aryl group. Arylalkyl may be those having 7 to 30 carbon atoms, preferably those having 7 to 20 carbon atoms, and more preferably those having 7 to 13 carbon atoms. Examples of arylalkyl groups include benzyl, 1-phenylethyl, 2-phenylethyl, 1-phenylisopropyl, 2-phenylisopropyl, phenyl-t-butyl, alpha-naphthylmethyl, 1-alpha-naphthylethyl, 2-alpha-naphthylethyl, 1-alpha-naphthylisopropyl, 2-alpha-naphthylisopropyl, beta-naphthylmethyl, 1-beta-naphthylethyl, 2-beta-naphthylethyl, 1-beta-naphthylisopropyl, 2-beta-naphthylisopropyl, p-methylbenzyl, m-methylbenzyl, o-methylbenzyl, p-chlorobenzyl, m-chlorobenzyl, o-chlorobenzyl, p-bromobenzyl, m-bromobenzyl, o-bromobenzyl, p-iodobenzyl, m-iodobenzyl, o-iodobenzyl, p-hydroxybenzyl, m-hydroxybenzyl, o-hydroxybenzyl, p-aminobenzyl, m-aminobenzyl, o-aminobenzyl, p-nitrobenzyl, m-nitrobenzyl, o-nitrobenzyl, p-cyanobenzyl, m-cyanobenzyl, o-cyanobenzyl, 1-hydroxy-2-phenylisopropyl, and 1-chloro-2-phenylisopropyl. Of the above, preferred are benzyl, p-cyanobenzyl, m-cyanobenzyl, o-cyanobenzyl, 1-phenylethyl, 2-phenylethyl, 1-phenylisopropyl, and 2-phenylisopropyl. Additionally, the arylalkyl group may be optionally substituted.

Alkylsilyl—as used herein, contemplates a silyl group substituted with an alkyl group. Alkylsilyl groups may be those having 3 to 20 carbon atoms, preferably those having 3 to 10 carbon atoms. Examples of alkylsilyl groups include trimethylsilyl, triethylsilyl, methyldiethylsilyl, ethyldimethylsilyl, tripropylsilyl, tributylsilyl, triisopropylsilyl, methyldiisopropylsilyl, dimethylisopropylsilyl, tri-t-butylsilyl, triisobutylsilyl, dimethyl t-butylsilyl, and methyldi-t-butylsilyl. Additionally, the alkylsilyl group may be optionally substituted.

Arylsilyl—as used herein, contemplates a silyl group substituted with an aryl group. Arylsilyl groups may be those having 6 to 30 carbon atoms, preferably those having 8 to 20 carbon atoms. Examples of arylsilyl groups include triphenylsilyl, phenyldibiphenylylsilyl, diphenylbiphenylsilyl, phenyldiethylsilyl, diphenylethylsilyl, phenyldimethylsilyl, diphenylmethylsilyl, phenyldiisopropylsilyl, diphenylisopropylsilyl, diphenylbutylsilyl, diphenylisobutylsilyl, diphenyl t-butylsilyl. Additionally, the arylsilyl group may be optionally substituted.

Alkylgermanyl—as used herein contemplates germanyl substituted with an alkyl group. The alkylgermanyl may be those having 3 to 20 carbon atoms, preferably those having 3 to 10 carbon atoms. Examples of alkylgermanyl include trimethylgermanyl, triethylgermanyl, methyldiethylgermanyl, ethyldimethylgermanyl, tripropylgermanyl, tributylgermanyl, triisopropylgermanyl, methyldiisopropylgermanyl, dimethylisopropylgermanyl, tri-t-butylgermanyl, triisobutylgermanyl, dimethyl-t-butylgermanyl, and methyldi-t-butylgermanyl. Additionally, the alkylgermanyl may be optionally substituted.

Arylgermanyl—as used herein contemplates a germanyl substituted with at least one aryl group or heteroaryl group. Arylgermanyl may be those having 6 to 30 carbon atoms, preferably those having 8 to 20 carbon atoms. Examples of arylgermanyl include triphenylgermanyl, phenyldibiphenylylgermanyl, diphenylbiphenylgermanyl, phenyldiethylgermanyl, diphenylethylgermanyl, phenyldimethylgermanyl, diphenylmethylgermanyl, phenyldiisopropylgermanyl, diphenylisopropylgermanyl, diphenylbutylgermanyl, diphenylisobutylgermanyl, and diphenyl-t-butylgermanyl. Additionally, the arylgermanyl may be optionally substituted.

The term “aza” in azadibenzofuran, azadibenzothiophene, etc. means that one or more of C—H groups in the respective aromatic fragment are replaced by a nitrogen atom. For example, azatriphenylene encompasses dibenzo[f,h]quinoxaline, dibenzo[f,h]quinoline and other analogs with two or more nitrogens in the ring system. One of ordinary skill in the art can readily envision other nitrogen analogs of the aza-derivatives described above, and all such analogs are intended to be encompassed by the terms as set forth herein.

In the present disclosure, unless otherwise defined, when any term of the group consisting of substituted alkyl, substituted cycloalkyl, substituted heteroalkyl, substituted heterocyclic group, substituted arylalkyl, substituted alkoxy, substituted aryloxy, substituted alkenyl, substituted alkynyl, substituted aryl, substituted heteroaryl, substituted alkylsilyl, substituted arylsilyl, substituted alkylgermanyl, substituted arylgermanyl, substituted amino, substituted acyl, substituted carbonyl, a substituted carboxylic acid group, a substituted ester group, substituted sulfinyl, substituted sulfonyl, and substituted phosphino is used, it means that any group of alkyl, cycloalkyl, heteroalkyl, heterocyclic group, arylalkyl, alkoxy, aryloxy, alkenyl, alkynyl, aryl, heteroaryl, alkylsilyl, arylsilyl, alkylgermanyl, arylgermanyl, amino, acyl, carbonyl, a carboxylic acid group, an ester group, sulfinyl, sulfonyl, and phosphino may be substituted with one or more moieties selected from the group consisting of deuterium, halogen, unsubstituted alkyl having 1 to 20 carbon atoms, unsubstituted cycloalkyl having 3 to 20 ring carbon atoms, unsubstituted heteroalkyl having 1 to 20 carbon atoms, an unsubstituted heterocyclic group having 3 to 20 ring atoms, unsubstituted arylalkyl having 7 to 30 carbon atoms, unsubstituted alkoxy having 1 to 20 carbon atoms, unsubstituted aryloxy having 6 to 30 carbon atoms, unsubstituted alkenyl having 2 to 20 carbon atoms, unsubstituted alkynyl having 2 to 20 carbon atoms, unsubstituted aryl having 6 to 30 carbon atoms, unsubstituted heteroaryl having 3 to 30 carbon atoms, unsubstituted alkylsilyl having 3 to 20 carbon atoms, unsubstituted arylsilyl having 6 to 20 carbon atoms, unsubstituted alkylgermanyl having 3 to 20 carbon atoms, unsubstituted arylgermanyl group having 6 to 20 carbon atoms, unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof.

It is to be understood that when a molecular fragment is described as being a substituent or otherwise attached to another moiety, its name may be written as if it were a fragment (e.g. phenyl, phenylene, naphthyl, dibenzofuryl) or as if it were the whole molecule (e.g. benzene, naphthalene, dibenzofuran). As used herein, these different ways of designating a substituent or an attached fragment are considered to be equivalent.

In the compounds mentioned in the present disclosure, hydrogen atoms may be partially or fully replaced by deuterium. Other atoms such as carbon and nitrogen can also be replaced by their other stable isotopes. The replacement by other stable isotopes in the compounds may be preferred due to its enhancements of device efficiency and stability.

In the compounds mentioned in the present disclosure, multiple substitution refers to a range that includes a di-substitution, up to the maximum available substitution. When substitution in the compounds mentioned in the present disclosure represents multiple substitution (including di-, tri-, and tetra-substitutions, etc.), that means the substituent may exist at a plurality of available substitution positions on its linking structure, the substituents present at a plurality of available substitution positions may be the same structure or different structures.

In the compounds mentioned in the present disclosure, adjacent substituents in the compounds cannot be joined to form a ring unless otherwise explicitly defined, for example, adjacent substituents can be optionally joined to form a ring. In the compounds mentioned in the present disclosure, the expression that adjacent substituents can be optionally joined to form a ring includes a case where adjacent substituents may be joined to form a ring and a case where adjacent substituents are not joined to form a ring. When adjacent substituents can be optionally joined to form a ring, the ring formed may be monocyclic or polycyclic (including spirocyclic, endocyclic, fusedcyclic, and etc.), as well as alicyclic, heteroalicyclic, aromatic, or heteroaromatic. In such expression, adjacent substituents may refer to substituents bonded to the same atom, substituents bonded to carbon atoms which are directly bonded to each other, or substituents bonded to carbon atoms which are more distant from each other. Preferably, adjacent substituents refer to substituents bonded to the same carbon atom and substituents bonded to carbon atoms which are directly bonded to each other.

The expression that adjacent substituents can be optionally joined to form a ring is also intended to mean that two substituents bonded to the same carbon atom are joined to each other via a chemical bond to form a ring, which can be exemplified by the following formula:

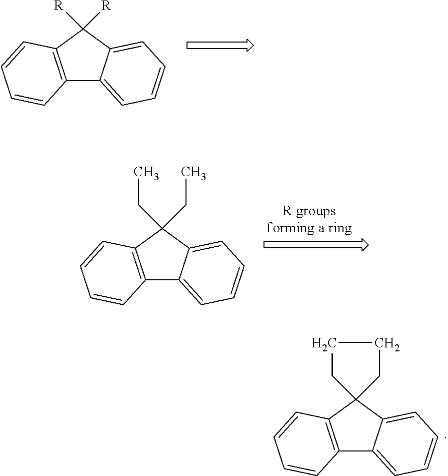

The expression that adjacent substituents can be optionally joined to form a ring is also intended to mean that two substituents bonded to carbon atoms which are directly bonded to each other are joined to each other via a chemical bond to form a ring, which can be exemplified by the following formula:

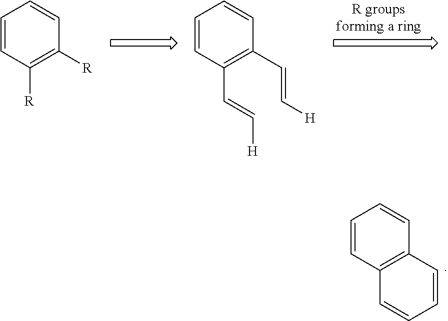

The expression that adjacent substituents can be optionally joined to form a ring is also intended to mean that two substituents bonded to a further distant carbon atom are joined to each other via a chemical bond to form a ring, which can be exemplified by the following formula:

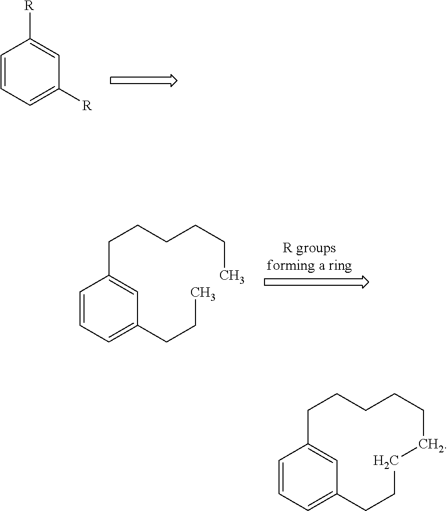

Furthermore, the expression that adjacent substituents can be optionally joined to form a ring is also intended to mean that, in the case where one of the two substituents bonded to carbon atoms which are directly bonded to each other represents hydrogen, the second substituent is bonded at a position at which the hydrogen atom is bonded, thereby forming a ring. This is exemplified by the following formula:

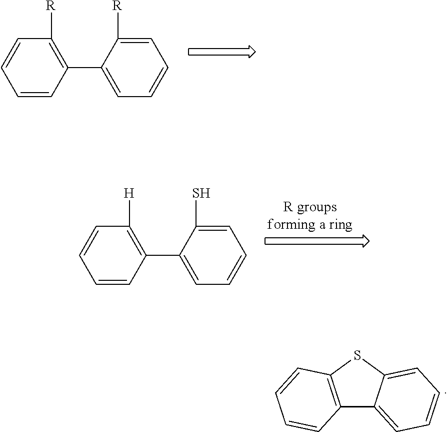

According to an embodiment of the present disclosure, disclosed is a metal complex comprising a metal M and a ligand Lₐ coordinated to the metal M, wherein Lₐ has a structure represented by Formula 1:

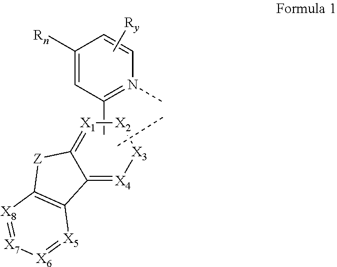

wherein

the metal M is selected from a metal with a relative atomic mass greater than 40;

Z is selected from the group consisting of O, S, Se, NR′, CR′R′ and SiR′R′; when two R′ are present at the same time, the two R′ are the same or different;

the substituent R_{y} represents mono-substitution, multiple substitutions or non-substitution;

X₁ to X₈ are, at each occurrence identically or differently, selected from C, CRₓ or N; and two of X₁ to X₄ are selected from C, one C is joined to pyridine in Formula 1, and the other C is coordinated to the metal to form a metal-carbon bond;

the substituent Rₐ has a structure represented by Formula 2:

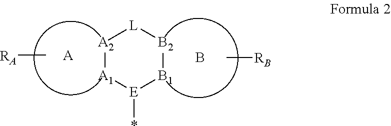

wherein in Formula 2,

the substituents R_{A} and R_{B} represent, at each occurrence identically or differently, mono-substitution, multiple substitutions or non-substitution;

the ring A and the ring B are identically or differently selected from a carbocyclic ring having 3 to 30 ring atoms or a heterocyclic ring having 3 to 30 ring atoms;

A₁, A₂, B₁, B₂ and E are, at each occurrence identically or differently, selected from C, N, B, P, CR′″, SiR′″ or GeR′″;

L is selected from a single bond, O, S, SO₂, Se, NR″, CR″R″, SiR″R″, GeR″R″, BR″, PR″, P(O)R″, R″C═CR″, substituted or unsubstituted alkylene having 1 to 20 carbon atoms, substituted or unsubstituted heteroalkylene having 1 to 20 carbon atoms, substituted or unsubstituted cycloalkylene having 3 to 20 carbon atoms, substituted or unsubstituted heterocyclylene having 3 to 20 ring atoms, substituted or unsubstituted arylene having 6 to 30 carbon atoms, substituted or unsubstituted heteroarylene having 3 to 30 carbon atoms or a combination thereof;

the substituents R′, R″, R′″, Rₓ, R_{y}, R_{A} and R_{B} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof,

“*” represents a position where Formula 2 is joined; and

adjacent substituents R′, Rₓ, R″, R′″, R_{A}, R_{B}, R_{y} can be optionally joined to form a ring.

In the present disclosure, the expression that “L is selected from a single bond” is intended to mean that Formula 2 has the following structure:

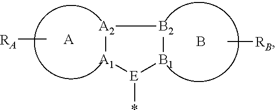

wherein A₁, A₂, B₁, B₂, E, the ring A, the ring B, R_{A} and R_{B} are defined as described herein.

In the present disclosure, the expression that “adjacent substituents R′, Rₓ, R″, R′″, R_{A}, R_{B}, R_{y} can be optionally joined to form a ring” is intended to mean that any one or more of groups of adjacent substituents, such as two substituents R′, two substituents Rₓ, two substituents R_{A}, two substituents R_{B}, two substituents R_{y}, substituents R′ and Rₓ, substituents R′ and R_{y}, substituents R_{A} and R_{B}, substituents R_{A} and R″, substituents R″ and R_{B}, substituents R_{A} and R_{y} and substituents R_{y} and R_{B}, can be joined to form a ring. Obviously, it is also possible that none of these substituents are joined to form a ring.

According to an embodiment of the present disclosure, the ligand Lₐ is, at each occurrence identically or differently, selected from any one of the group consisting of the following structures:

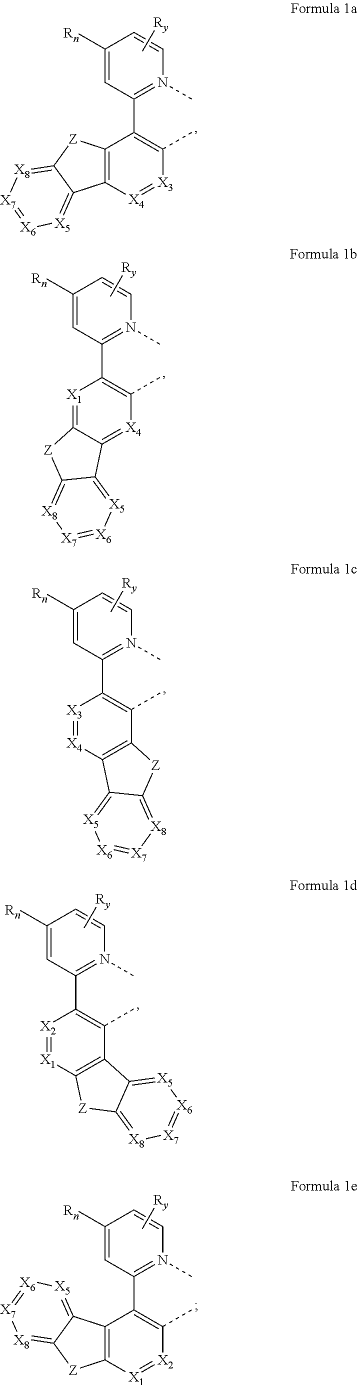

wherein

Z is selected from the group consisting of O, S, Se, NR′, CR′R′ and SiR′R′; when two R′ are present at the same time, the two R′ are the same or different;

the substituent R_{y} represents mono-substitution, multiple substitutions or non-substitution; in Formula 1a and Formula 1c, X₃ to X₅ are, at each occurrence identically or differently, selected from CRₓ or N;

in Formula 1b, X₁ and X₄ to X₅ are, at each occurrence identically or differently, selected from CRₓ or N;

in Formula 1d and Formula 1e, X₁, X₂, and X₅ to X₅ are, at each occurrence identically or differently, selected from CRₓ or N;

the substituent Rₙ has a structure represented by Formula 2:

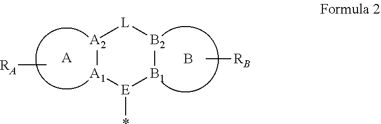

wherein in Formula 2,

the substituents R_{A} and R_{B} represent, at each occurrence identically or differently, mono-substitution, multiple substitutions or non-substitution;

the ring A and the ring B are identically or differently selected from a carbocyclic ring having 3 to 30 ring atoms or a heterocyclic ring having 3 to 30 ring atoms;

A₁, A₂, B₁, B₂ and E are, at each occurrence identically or differently, selected from C, N, B, P, CR′″, SiR′″ or GeR′″;

L is selected from a single bond, O, S, SO₂, Se, NR″, CR″R″, SiR″R″, GeR″R″, BR″, PR″, P(O)R″, R″C═CR″, substituted or unsubstituted alkylene having 1 to 20 carbon atoms, substituted or unsubstituted heteroalkylene having 1 to 20 carbon atoms, substituted or unsubstituted cycloalkylene having 3 to 20 carbon atoms, substituted or unsubstituted heterocyclylene having 3 to 20 ring atoms, substituted or unsubstituted arylene having 6 to 30 carbon atoms, substituted or unsubstituted heteroarylene having 3 to 30 carbon atoms or a combination thereof,

the substituents R′, R″, R′″, Rₓ, R_{y}, R_{A} and R_{B} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof,

“*” represents a position where Formula 2 is joined; and

adjacent substituents R′, Rₓ, R″, R′″, R_{A}, R_{B}, R_{y} can be optionally joined to form a ring.

According to an embodiment of the present disclosure, the metal complex has a general formula of M(Lₐ)ₘ(L_{b})ₙ(L_{c})_{q};

wherein

the metal M is selected from a metal with a relative atomic mass greater than 40; preferably, M is, at each occurrence identically or differently, selected from the group consisting of Cu, Ag, Au, Ru, Rh, Pd, Os, Ir and Pt; more preferably, M is, at each occurrence identically or differently, selected from Pt or Ir;

Lₐ, L_{b} and L_{c} are a first ligand, a second ligand and a third ligand coordinated to the metal M, respectively, and L_{c} is the same as or different from Lₐ or L_{b}; wherein Lₐ, L_{b} and L_{c} can be optionally joined to form a multidentate ligand; for example, any two of the ligands Lₐ, L_{b} and L_{c} are joined to form a tetradentate ligand, the ligands Lₐ, L_{b} and L_{c} are joined to form a hexadentate ligand, or none of the ligands Lₐ, L_{b} and L_{c} are joined to form a multidentate ligand;

m is selected from 1, 2 or 3, n is selected from 0, 1 or 2, q is selected from 0, 1 or 2, and m+n+q equals to the oxidation state of the metal M; when m is greater than or equal to 2, multiple Lₐ are the same or different; when n is equal to 2, two L_{b} are the same or different; when q is equal to 2, two L_{c} are the same or different;

L_{b} and L_{c} are, at each occurrence identically or differently, selected from a structure represented by any one of the group consisting of:

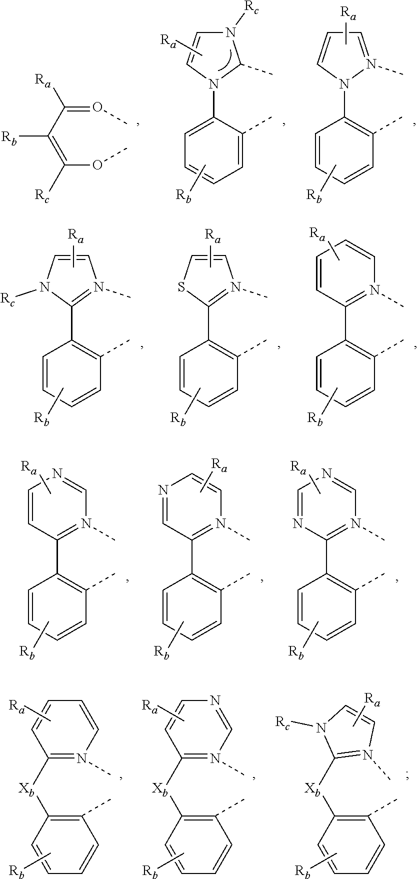

wherein

the substituents Rₐ and R_{b} represent, at each occurrence identically or differently, mono-substitution, multiple substitutions or non-substitution;

X_{b} is, at each occurrence identically or differently, selected from the group consisting of: O, S, Se, NR_{N1} and CR_{C1}R_{C2};

the substituents Rₐ, R_{b}, R_{c}, R_{N1}, R_{C1} and R_{C2} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof, and

adjacent substituents Rₐ, R_{b}, R_{c}, R_{N1}, R_{C1} and R_{C2} can be optionally joined to form a ring.

In the present disclosure, the expression that “adjacent substituents Rₐ, R_{b}, R_{c}, R_{N1}, R_{C1} and R_{C2} can be optionally joined to form a ring” is intended to mean that any one or more of groups of adjacent substituents, such as two substituents Rₐ, two substituents R_{b}, substituents Rₐ and R_{b}, substituents Rₐ and R_{c}, substituents R_{b} and R_{c}, substituents Rₐ and R_{N1}, substituents R_{b} and R_{N1}, substituents Rₐ and R_{C1}, substituents Rₐ and R_{C2}, substituents R_{b} and R_{C1}, substituents R_{b} and R_{C2} and substituents R_{C1} and R_{C2}, can be joined to form a ring. Obviously, it is also possible that none of these substituents are joined to form a ring.

According to an embodiment of the present disclosure, the metal complex has a general formula of Ir(Lₐ)ₘ(L_{b})₃₋ₘ and is represented by Formula 3:

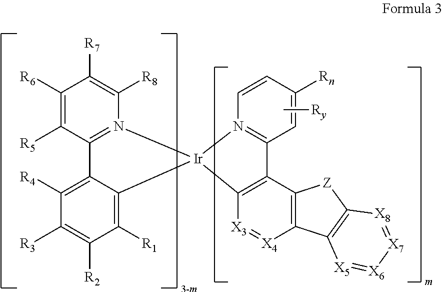

wherein

m is selected from 1, 2 or 3; when m is selected from 1, two L_{b} are the same or different; when m is selected from 2 or 3, multiple Lₐ are the same or different;

Z is selected from the group consisting of O, S, Se, NR′, CR′R′ and SiR′R′; when two R′ are present at the same time, the two R′ are the same or different;

the substituent R_{y} represents mono-substitution, multiple substitutions or non-substitution;

X₃ to X₅ are, at each occurrence identically or differently, selected from CRₓ or N;

the substituent Rₙ has a structure represented by Formula 2:

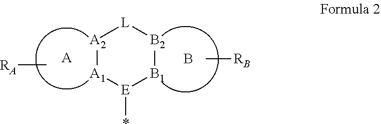

wherein in Formula 2,

the substituents R_{A} and R_{B} represent, at each occurrence identically or differently, mono-substitution, multiple substitutions or non-substitution;

the ring A and the ring B are identically or differently selected from a carbocyclic ring having 3 to 30 ring atoms or a heterocyclic ring having 3 to 30 ring atoms;

A₁, A₂, B₁, B₂ and E are, at each occurrence identically or differently, selected from C, N, B, P, CR′″, SiR′″ or GeR′″;

L is selected from a single bond, O, S, SO₂, Se, NR″, CR″R″, SiR″R″, GeR″R″, BR″, PR″, P(O)R″, R″C═CR″, substituted or unsubstituted alkylene having 1 to 20 carbon atoms, substituted or unsubstituted heteroalkylene having 1 to 20 carbon atoms, substituted or unsubstituted cycloalkylene having 3 to 20 carbon atoms, substituted or unsubstituted heterocyclylene having 3 to 20 ring atoms, substituted or unsubstituted arylene having 6 to 30 carbon atoms, substituted or unsubstituted heteroarylene having 3 to 30 carbon atoms or a combination thereof,

the substituents R₁ to R₈, R′, R″, R′″, Rₓ, R_{y}, R_{A} and R_{B} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof,

“*” represents a position where Formula 2 is joined;

adjacent substituents R′, Rₓ, R″, R′″, R_{A}, R_{B}, R_{y} can be optionally joined to form a ring; and

adjacent substituents R₁ to R₈ can be optionally joined to form a ring.

In this embodiment, the expression that “adjacent substituents R₁ to R₈ can be optionally joined to form a ring” is intended to mean that any one or more of groups of any two adjacent substituents of R₁ to R₈ can be joined to form a ring. Obviously, it is also possible that none of these substituents are joined to form a ring.

According to an embodiment of the present disclosure, Z is selected from 0 or S.

According to an embodiment of the present disclosure, Z is selected from 0.

According to an embodiment of the present disclosure, X₁ to X₅ are, at each occurrence identically or differently, selected from CRₓ.

According to an embodiment of the present disclosure, X₃ to X₅ are, at each occurrence identically or differently, selected from CRₓ.

According to an embodiment of the present disclosure, at least one of X₁ to X₅ is selected from N. For example, one of X₁ to X₅ is selected from N, or two of X₁ to X₅ are selected from N.

According to an embodiment of the present disclosure, at least one of X₃ to X₅ is selected from N. For example, one of X₃ to X₅ is selected from N, or two of X₃ to X₅ are selected from N.

According to an embodiment of the present disclosure, the substituent Rₓ is, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted alkylgermanyl having 3 to 20 carbon atoms, cyano and combinations thereof.

According to an embodiment of the present disclosure, the substituent Rₓ is, at each occurrence identically or differently, selected from the group consisting of: hydrogen, deuterium, fluorine, substituted or unsubstituted alkyl having 1 to 6 carbon atoms, substituted or unsubstituted cycloalkyl having 3 to 6 ring carbon atoms, substituted or unsubstituted aryl having 6 to 12 carbon atoms, substituted or unsubstituted heteroaryl having 3 to 12 carbon atoms, substituted or unsubstituted alkylsilyl having 3 to 6 carbon atoms, substituted or unsubstituted alkylgermanyl having 3 to 6 carbon atoms, cyano and combinations thereof.

According to an embodiment of the present disclosure, the substituent Rₓ is, at each occurrence identically or differently, selected from the group consisting of: hydrogen, deuterium, fluorine, cyano, methyl, ethyl, propyl, isopropyl, n-butyl, isobutyl, t-butyl, cyclopentyl, cyclohexyl, deuterated methyl, deuterated ethyl, deuterated propyl, deuterated isopropyl, deuterated n-butyl, deuterated isobutyl, deuterated t-butyl, deuterated cyclopentyl, deuterated cyclohexyl, phenyl, biphenyl, pyridyl, trimethylsilyl, trimethylgermanyl and combinations thereof, optionally, hydrogens in the above groups can be partially or fully deuterated.

According to an embodiment of the present disclosure, the substituent Rₙ has a structure represented by Formula 4:

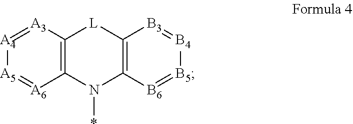

wherein

A₃ to A₆ are, at each occurrence identically or differently, selected from CR_{A} or N;

B₃ to B₆ are, at each occurrence identically or differently, selected from CR_{B} or N;

L is selected from a single bond, O, S, SO₂, Se, NR″, CR″R″, SiR″R″, GeR″R″, BR″, PR″, P(O)R″, R″C═CR″, alkylene having 1 to 20 carbon atoms, heteroalkylene having 1 to 20 carbon atoms, cycloalkylene having 3 to 20 carbon atoms, heterocyclylene having 3 to 20 ring atoms, arylene having 6 to 30 carbon atoms, heteroarylene having 3 to 30 carbon atoms or a combination thereof,

the substituents R_{A}, R_{B} and R″ are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof,

adjacent substituents R″, R_{A}, R_{B} can be optionally joined to form a ring; and

“*” represents a position where Formula 4 is joined.

In the present disclosure, the expression that “adjacent substituents R″, R_{A}, R_{B} can be optionally joined to form a ring” is intended to mean that any one or more of groups of adjacent substituents, such as two substituents R″, two substituents R_{A}, two substituents R_{B}, substituents R″ and R_{A} and substituents R″ and R_{B}, can be joined to form a ring. Obviously, it is also possible that none of these substituents are joined to form a ring.

According to an embodiment of the present disclosure, the ring A and the ring B are identically or differently selected from a carbocyclic ring having 6 ring atoms or a heterocyclic ring having 5 to 6 ring atoms.

According to an embodiment of the present disclosure, the ring A and the ring B are identically or differently selected from a benzene ring or a heteroaromatic ring having 5 to 6 ring atoms.

According to an embodiment of the present disclosure, A₃ to A₆ are, at each occurrence identically or differently, selected from CR_{A}, and the substituent R_{A} is, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted alkylgermanyl having 3 to 20 carbon atoms, cyano and combinations thereof.

According to an embodiment of the present disclosure, B₃ to B₆ are, at each occurrence identically or differently, selected from CR_{B}, and the substituent R_{B} is, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted alkylgermanyl having 3 to 20 carbon atoms, cyano and combinations thereof.

According to an embodiment of the present disclosure, the substituents R_{A} and R_{B} are, at each occurrence identically or differently, selected from the group consisting of: hydrogen, deuterium, fluorine, substituted or unsubstituted alkyl having 1 to 6 carbon atoms, substituted or unsubstituted cycloalkyl having 3 to 6 ring carbon atoms, substituted or unsubstituted aryl having 6 to 12 carbon atoms, substituted or unsubstituted heteroaryl having 3 to 12 carbon atoms, substituted or unsubstituted alkylsilyl having 3 to 6 carbon atoms, substituted or unsubstituted alkylgermanyl having 3 to 6 carbon atoms, cyano and combinations thereof.

According to an embodiment of the present disclosure, the substituents R_{A} and R_{B} are, at each occurrence identically or differently, selected from the group consisting of: hydrogen, deuterium, fluorine, substituted or unsubstituted alkyl having 1 to 6 carbon atoms, substituted or unsubstituted aryl having 6 to 12 carbon atoms, substituted or unsubstituted heteroaryl having 3 to 12 carbon atoms, substituted or unsubstituted alkylsilyl having 3 to 6 carbon atoms, substituted or unsubstituted alkylgermanyl having 3 to 6 carbon atoms, cyano and combinations thereof.

According to an embodiment of the present disclosure, the substituents R_{A} and R_{B} are, at each occurrence identically or differently, selected from the group consisting of: hydrogen, deuterium, fluorine, cyano, methyl, ethyl, propyl, isopropyl, n-butyl, isobutyl, t-butyl, neopentyl, cyclopentyl, cyclohexyl, deuterated methyl, deuterated ethyl, deuterated propyl, deuterated isopropyl, deuterated n-butyl, deuterated isobutyl, deuterated t-butyl, deuterated neopentyl, deuterated cyclopentyl, deuterated cyclohexyl, phenyl, pyridyl, trimethylsilyl, trimethylgermanyl and combinations thereof, optionally, hydrogens in the above groups can be partially or fully deuterated.

According to an embodiment of the present disclosure, L is selected from a single bond, O, S, Se, NR″, SiR″R″, GeR″R″, BR″, PR″, P(O)R″, R″C═CR″, substituted or unsubstituted alkylene having 1 to 10 carbon atoms, substituted or unsubstituted heteroalkylene having 1 to 10 carbon atoms, substituted or unsubstituted cycloalkylene having 3 to 10 carbon atoms, substituted or unsubstituted heterocyclylene having 3 to 10 ring atoms, substituted or unsubstituted arylene having 6 to 10 carbon atoms, substituted or unsubstituted heteroarylene having 3 to 10 carbon atoms or a combination thereof.

According to an embodiment of the present disclosure, L is selected from a single bond, O, S, Se, NR″, SiR″R″, GeR″R″, BR″, PR″, P(O)R″, substituted or unsubstituted alkylene having 1 to 10 carbon atoms, substituted or unsubstituted arylene having 6 to 10 carbon atoms, substituted or unsubstituted heteroarylene having 3 to 10 carbon atoms or a combination thereof.

According to an embodiment of the present disclosure, L is selected from a single bond, O, S, NR″, substituted or unsubstituted alkylene having 1 to 10 carbon atoms or substituted or unsubstituted phenylene.

According to an embodiment of the present disclosure, L is selected from a single bond, O, S, NR″ or phenylene.

According to an embodiment of the present disclosure, the substituents R′, R″ and R′″ are, at each occurrence identically or differently, selected from the group consisting of: hydrogen, deuterium, fluorine, substituted or unsubstituted alkyl having 1 to 6 carbon atoms, substituted or unsubstituted cycloalkyl having 3 to 6 ring carbon atoms, substituted or unsubstituted aryl having 6 to 12 carbon atoms, substituted or unsubstituted heteroaryl having 3 to 12 carbon atoms, substituted or unsubstituted alkylsilyl having 3 to 6 carbon atoms, substituted or unsubstituted alkylgermanyl having 3 to 6 carbon atoms, cyano and combinations thereof.

According to an embodiment of the present disclosure, the substituents R′, R″ and R′″ are, at each occurrence identically or differently, selected from the group consisting of: hydrogen, deuterium, fluorine, substituted or unsubstituted alkyl having 1 to 6 carbon atoms, substituted or unsubstituted aryl having 6 to 12 carbon atoms, substituted or unsubstituted heteroaryl having 3 to 12 carbon atoms, substituted or unsubstituted alkylsilyl having 3 to 6 carbon atoms, substituted or unsubstituted alkylgermanyl having 3 to 6 carbon atoms, cyano and combinations thereof.

According to an embodiment of the present disclosure, the substituent R′, R″ and R′″ are, at each occurrence identically or differently, selected from the group consisting of: hydrogen, deuterium, fluorine, cyano, methyl, ethyl, propyl, isopropyl, n-butyl, isobutyl, t-butyl, cyclopentyl, cyclohexyl, deuterated methyl, deuterated ethyl, deuterated propyl, deuterated isopropyl, deuterated n-butyl, deuterated isobutyl, deuterated t-butyl, deuterated cyclopentyl, deuterated cyclohexyl, phenyl, pyridyl, trimethylsilyl, trimethylgermanyl and combinations thereof, optionally, hydrogens in the above groups can be partially or fully deuterated.

According to an embodiment of the present disclosure, at least one of X₃ to X₅ is CRₓ, and the substituent Rₓ is selected from cyano or fluorine.

According to an embodiment of the present disclosure, at least one of X₅ to X₅ is CRₓ, and the substituent Rₓ is selected from cyano or fluorine.

According to an embodiment of the present disclosure, X₇ or X₅ is CRₓ, and Rₓ is selected from cyano.

According to an embodiment of the present disclosure, X₇ is CRₓ, and Rₓ is selected from fluorine.

According to an embodiment of the present disclosure, at least two of X₃ to X₅ are selected from CRₓ, wherein one substituent Rₓ is selected from cyano or fluorine, and another substituent Rₓ is selected from the group consisting of: deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, cyano, isocyano and combinations thereof.

According to an embodiment of the present disclosure, at least two of X₅ to X₅ are selected from CRₓ, wherein one substituent Rₓ is selected from cyano or fluorine, and another substituent Rₓ is selected from the group consisting of: deuterium, fluorine, substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, cyano, isocyano and combinations thereof.

According to an embodiment of the present disclosure, X₇ and X₅ are selected from CRₓ, wherein one substituent Rₓ is cyano or fluorine, and the other substituent Rₓ is selected from the group consisting of: deuterium, fluorine, substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, cyano, isocyano and combinations thereof.

According to an embodiment of the present disclosure, X₇ and X₅ are selected from CRₓ, wherein one substituent Rₓ is cyano or fluorine, and the other substituent Rₓ is selected from the group consisting of: deuterium, fluorine, substituted or unsubstituted alkyl having 1 to 20 carbon atoms, substituted or unsubstituted aryl having 6 to 30 carbon atoms, cyano, isocyano and combinations thereof.

According to an embodiment of the present disclosure, Rₙ is, at each occurrence identically or differently, selected from the group consisting of An₁ to An₉₆, wherein the specific structures of An₁ to An₉₆ are referred to claim 11.

According to an embodiment of the present disclosure, hydrogens in An₁ to An₅₂, An₅₄ to An₅₈ and An₆₁ to An₉₆ can be partially or fully deuterated.

According to an embodiment of the present disclosure, the substituent R_{y} is, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted arylalkyl having 7 to 30 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted amino having 6 to 20 carbon atoms and combinations thereof.

According to an embodiment of the present disclosure, the substituent R_{y} is, at each occurrence identically or differently, selected from the group consisting of: hydrogen, deuterium, halogen, substituted or unsubstituted alkyl having 1 to 6 carbon atoms, substituted or unsubstituted cycloalkyl having 3 to 6 ring carbon atoms, substituted or unsubstituted aryl having 6 to 12 carbon atoms, substituted or unsubstituted heteroaryl having 3 to 12 carbon atoms, substituted or unsubstituted alkylsilyl having 3 to 12 carbon atoms and combinations thereof.

According to an embodiment of the present disclosure, at least one substituent R_{y} is selected from the group consisting of: deuterium, halogen, substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms and combinations thereof.

According to an embodiment of the present disclosure, at least one substituent R_{y} is selected from the group consisting of: deuterium, fluorine, cyano, methyl, ethyl, propyl, isopropyl, n-butyl, isobutyl, t-butyl, cyclopentyl, cyclohexyl, deuterated methyl, deuterated ethyl, deuterated propyl, deuterated isopropyl, deuterated n-butyl, deuterated isobutyl, deuterated t-butyl, deuterated cyclopentyl, deuterated cyclohexyl, phenyl, pyridyl, trimethylsilyl, trimethylgermanyl and combinations thereof, optionally, hydrogens in the above groups can be partially or fully deuterated.

According to an embodiment of the present disclosure, at least one or at least two of the substituents R₁ to R₈ are selected from substituted or unsubstituted alkyl having 1 to 20 carbon atoms, substituted or unsubstituted cycloalkyl having 3 to 20 ring carbon atoms or a combination thereof, and the total number of carbon atoms in all of R₁ to R₄ and/or R₅ to R₈ is at least 4.

According to an embodiment of the present disclosure, at least one or at least two of the substituents R₁ to R₄ are selected from substituted or unsubstituted alkyl having 1 to 20 carbon atoms, substituted or unsubstituted cycloalkyl having 3 to 20 ring carbon atoms or a combination thereof, and the total number of carbon atoms in all of the substituents R₁ to R₄ is at least 4.

According to an embodiment of the present disclosure, at least one or at least two of the substituents R₅ to R₈ are selected from substituted or unsubstituted alkyl having 1 to 20 carbon atoms, substituted or unsubstituted cycloalkyl having 3 to 20 ring carbon atoms or a combination thereof, and the total number of carbon atoms in all of the substituents R₅ to R₈ is at least 4.

According to an embodiment of the present disclosure, at least one, at least two, at least three or all of the substituents R₂, R₃, R₆ and R₇ are selected from the group consisting of: deuterium, substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms and combinations thereof.

According to an embodiment of the present disclosure, at least one, at least two, at least three or all of the substituents R₂, R₃, R₆ and R₇ are selected from the group consisting of: deuterium, substituted or unsubstituted alkyl having 1 to 20 carbon atoms, substituted or unsubstituted cycloalkyl having 3 to 20 ring carbon atoms and combinations thereof.

According to an embodiment of the present disclosure, at least one, at least two, at least three or all of the substituents R₂, R₃, R₆ and R₇ are selected from the group consisting of: deuterium, methyl, ethyl, propyl, isopropyl, n-butyl, isobutyl, t-butyl, cyclopentyl, cyclohexyl, neopentyl, t-pentyl and combinations thereof, optionally, hydrogens in the above groups can be partially or fully deuterated.

According to an embodiment of the present disclosure, the ligand Lₐ is, at each occurrence identically or differently, selected from the group consisting of Lₐ₁ to Lₐ₈₂₁, wherein the specific structures of Lₐ₁ to Lₐ₈₂₁ are referred to claim 15.

According to an embodiment of the present disclosure, hydrogens in ligands Lₐ₁ to Lₐ₈₂₁ can be partially or fully deuterated.

According to an embodiment of the present disclosure, the ligand L_{b} is, at each occurrence identically or differently, selected from the group consisting of L_{b1} to L_{b334}, wherein the specific structures of L_{b1} to L_{b334} are referred to claim 16.

According to an embodiment of the present disclosure, hydrogens in ligands L_{b1} to L_{b334} can be partially or fully deuterated.

According to an embodiment of the present disclosure, the ligand L_{c} is, at each occurrence identically or differently, selected from the group consisting of L_{c1} to L_{c360}, wherein the specific structures of L_{c1} to L_{c360} are referred to claim 17.

According to an embodiment of the present disclosure, the metal complex has a general formula of Ir(Lₐ)₃, Ir(Lₐ)(L_{b})₂, Ir(Lₐ)₂(L_{b}), Ir(Lₐ)(L_{c})₂, Ir(Lₐ)₂(L_{c}) or Ir(Lₐ)(L_{b})(L_{c}), wherein Lₐ is, at each occurrence identically or differently, selected from the group consisting of Lₐ₁ to Lₐ₈₂₁, L_{b} is, at each occurrence identically or differently, selected from the group consisting of L_{b1} to L_{b334}, and the ligand L_{c} is, at each occurrence identically or differently, selected from the group consisting of L_{c1} to L_{c360}.

According to an embodiment of the present disclosure, the metal complex is selected from the group consisting of Metal Complex 1 to Metal Complex 432, wherein the specific structures of Metal Complex 1 to Metal Complex 432 are referred to claim 18.

According to an embodiment of the present disclosure, hydrogens in Metal Complex 1 to Metal Complex 432 can be partially or fully deuterated.

According to an embodiment of the present disclosure, the metal complex is selected from the group consisting of Metal Complex 1 to Metal Complex 435, wherein the specific structures of Metal Complex 1 to Metal Complex 435 are referred to claim 18.

According to an embodiment of the present disclosure, hydrogens in Metal Complex 1 to Metal Complex 435 can be partially or fully deuterated.

According to an embodiment of the present disclosure, disclosed is an organic electroluminescent device comprising an anode, a cathode and an organic layer disposed between the anode and the cathode, wherein at least one layer of the organic layer comprises the metal complex in any one of the preceding embodiments.

According to an embodiment of the present disclosure, the organic layer comprising the metal complex is a light-emitting layer.

According to an embodiment of the present disclosure, the organic electroluminescent device emits green light.

According to an embodiment of the present disclosure, the organic electroluminescent device emits yellow light.

According to an embodiment of the present disclosure, the light-emitting layer further comprises a first host compound.

According to an embodiment of the present disclosure, the light-emitting layer further comprises a second host compound.

According to an embodiment of the present disclosure, at least one of the host compound comprises at least one chemical group selected from the group consisting of: benzene, pyridine, pyrimidine, triazine, carbazole, azacarbazole, indolocarbazole, dibenzothiophene, aza-dibenzothiophene, dibenzofuran, azadibenzofuran, dibenzoselenophene, triphenylene, azatriphenylene, fluorene, silafluorene, naphthalene, quinoline, isoquinoline, quinazoline, quinoxaline, phenanthrene, azaphenanthrene and combinations thereof.

According to an embodiment of the present disclosure, the metal complex is doped in the first host compound and the second host compound, and the weight of the metal complex accounts for 1% to 30% of the total weight of the light-emitting layer.

According to an embodiment of the present disclosure, the metal complex is doped in the first host compound and the second host compound, and the weight of the metal complex accounts for 3% to 13% of the total weight of the light-emitting layer.

According to an embodiment of the present disclosure, disclosed is a compound composition comprising the metal complex in any one of the preceding embodiments.

Combination with Other Materials

The materials described in the present disclosure for a particular layer in an organic light-emitting device can be used in combination with various other materials present in the device. The combinations of these materials are described in more detail in U.S. Pat. App. No. 20160359122 at paragraphs 0132-0161, which is incorporated by reference herein in its entirety. The materials described or referred to the disclosure are non-limiting examples of materials that may be useful in combination with the compounds disclosed herein, and one of skill in the art can readily consult the literature to identify other materials that may be useful in combination.

The materials described herein as useful for a particular layer in an organic light-emitting device may be used in combination with a variety of other materials present in the device. For example, dopants disclosed herein may be used in combination with a wide variety of hosts, transport layers, blocking layers, injection layers, electrodes and other layers that may be present. The combination of these materials is described in detail in paragraphs 0080-0101 of U.S. Pat. App. No. 20150349273, which is incorporated by reference herein in its entirety. The materials described or referred to the disclosure are non-limiting examples of materials that may be useful in combination with the compounds disclosed herein, and one of skill in the art can readily consult the literature to identify other materials that may be useful in combination.

In the embodiments of material synthesis, all reactions were performed under nitrogen protection unless otherwise stated. All reaction solvents were anhydrous and used as received from commercial sources. Synthetic products were structurally confirmed and tested for properties using one or more conventional equipment in the art (including, but not limited to, nuclear magnetic resonance instrument produced by BRUKER, liquid chromatograph produced by SHIMADZU, liquid chromatograph-mass spectrometry produced by SHIMADZU, gas chromatograph-mass spectrometry produced by SHIMADZU, differential Scanning calorimeters produced by SHIMADZU, fluorescence spectrophotometer produced by SHANGHAI LENGGUANG TECH., electrochemical workstation produced by WUHAN CORRTEST, and sublimation apparatus produced by ANHUI BEQ, etc.) by methods well known to the persons skilled in the art. In the embodiments of the device, the characteristics of the device were also tested using conventional equipment in the art (including, but not limited to, evaporator produced by ANGSTROM ENGINEERING, optical testing system produced by SUZHOU FATAR, life testing system produced by SUZHOU FATAR, and ellipsometer produced by BEIJING ELLITOP, etc.) by methods well known to the persons skilled in the art. As the persons skilled in the art are aware of the above-mentioned equipment use, test methods and other related contents, the inherent data of the sample can be obtained with certainty and without influence, so the above related contents are not further described in this patent.

### Material Synthesis Example

The method for preparing a compound in the present disclosure is not limited herein. Typically, the following compounds are used as examples without limitation, and synthesis routes and preparation methods thereof are described below.

### Synthesis Example 1: Synthesis of Metal Complex 159

Step 1:

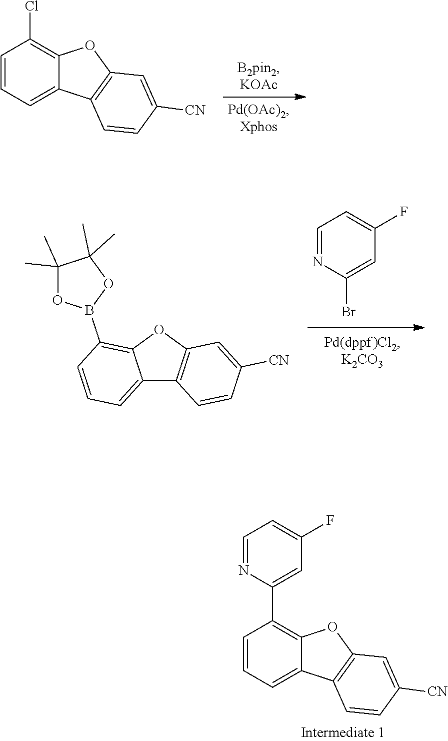 [SMILES: N#Cc1ccc2c(c1)oc1c(Cl)cccc12 ; CC1(C)OB(c2cccc3c2oc2cc(C#N)ccc23)OC1(C)C ; Fc1ccnc(Br)c1 ; N#Cc1ccc2c(c1)oc1c(-c3cc(F)ccn3)cccc12]

In a dry 250 mL round-bottom flask, 6-chloro-dibenzofuran-3-carbonitrile (3.4 g, 13.9 mmol), B₂pin₂ (4.1 g, 16.0 mmol), Pd(OAc)₂ (0.09 g, 0.4 mmol), Xphos (0.4 g, 0.8 mmol), KOAc (2.0 g, 21.0 mmol) and dioxane (90 mL) were added in sequence and heated to reflux for 12 h under N₂ protection.

The above-obtained reaction solution was cooled and added with 2-bromo-4-fluoro-pyridine (2.9 g, 16.7 mmol), Pd(dppf)Cl₂ (0.5 g, 0.7 mmol), K₂CO₃ (2.9 g, 16.7 mmol) and water (30 mL). The reaction solution was heated to reflux for 12 h under N₂ protection. The reaction solution was cooled, extracted with DCM, and subjected to column chromatography to obtain Intermediate 1 (3.3 g, 82.5%).

Step 2:

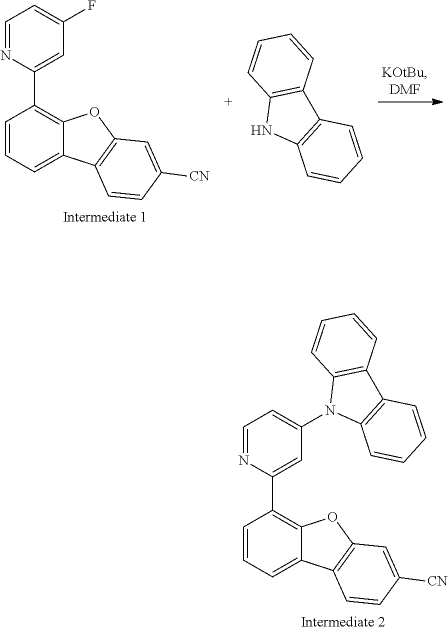 [SMILES: N#Cc1ccc2c(c1)oc1c(-c3cc(F)ccn3)cccc12 ; c1ccc2c(c1)[nH]c1ccccc12 ; N#Cc1ccc2c(c1)oc1c(-c3cc(-n4c5ccccc5c5ccccc54)ccn3)cccc12]

In a dry 250 mL round-bottom flask, Intermediate 1 (2.0 g, 6.9 mmol), carbazole (1.7 g, 10.4 mmol), potassium t-butoxide (1.4 g, 12.6 mmol) and DMF (50 mL) were added in sequence and heated to react for 12 h at 100° C. under N₂ protection. The reaction was cooled, added with water and extracted with dichloromethane, the organic layer was washed twice with saturated sodium chloride, and the organic phases were collected, dried over anhydrous sodium sulfate, concentrated under reduced pressure, and purified through column chromatography to obtain Intermediate 2 as a white solid (2.3 g, with a yield of 76.6%).

Step 3:

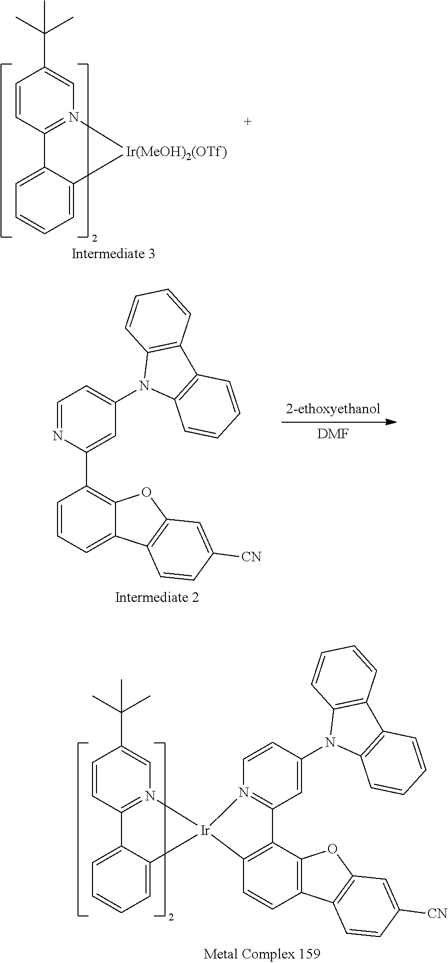

In a dry 250 mL round-bottom flask, Intermediate 2 (1.6 g, 3.6 mmol), Intermediate 3 (2.0 g, 2.4 mmol), 2-ethoxyethanol (30 mL) and DMF (30 mL) were added in sequence and heated to react for 144 h at 95° C. under N₂ protection. The reaction was cooled and filtered through Celite. The reaction was washed twice with methanol and washed twice with n-hexane. Yellow solids on the Celite were dissolved with dichloromethane. The organic phases were collected, concentrated under reduced pressure, and purified through column chromatography to obtain Metal Complex 159 as a yellow solid (0.84 g, with a yield of 33.5%). The product structure was confirmed as the target product with a molecular weight of 1047.3.

### Synthesis Example 2: Synthesis of Metal Complex 169

Step 1:

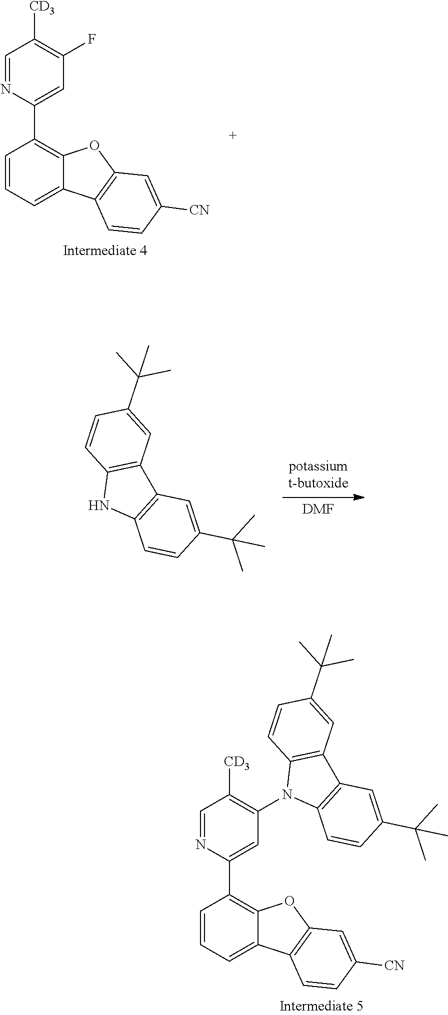

In a dry 250 mL round-bottom flask, Intermediate 4 (1.0 g, 3.3 mmol), 3,6-di-t-butylcarbazole (1.1 g, 3.9 mmol), potassium t-butoxide (0.5 g, 4.9 mmol) and DMF (50 mL) were added in sequence and heated to react for 12 h at 100° C. under N₂ protection. The reaction was cooled, added with water and extracted with dichloromethane, the organic layer was washed twice with saturated sodium chloride, and the organic phases were collected, dried over anhydrous sodium sulfate, concentrated under reduced pressure, and purified through column chromatography to obtain Intermediate 5 as a white solid (1.1 g, with a yield of 61.1%).

Step 2:

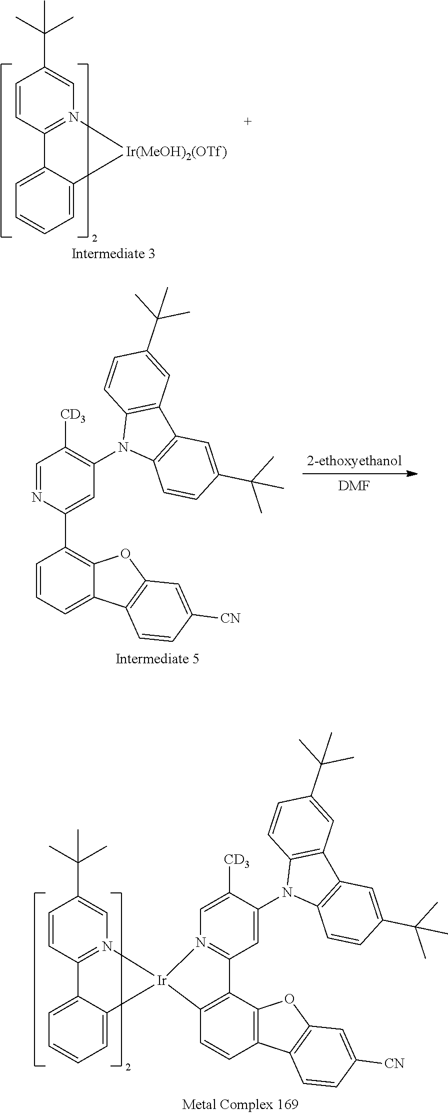

In a dry 250 mL round-bottom flask, Intermediate 5 (1.1 g, 1.9 mmol), Intermediate 3 (1.3 g, 1.6 mmol), 2-ethoxyethanol (30 mL) and DMF (30 mL) were added in sequence and heated to react for 144 h at 95° C. under N₂ protection. The reaction was cooled and filtered through Celite. The reaction was washed twice with methanol and washed twice with n-hexane. Yellow solids on the Celite were dissolved with dichloromethane. The organic phases were collected, concentrated under reduced pressure, and purified through column chromatography to obtain yellow Metal Complex 169 (0.45 g, with a yield of 23.9%). The product structure was confirmed as the target product with a molecular weight of 1176.5.

### Synthesis Example 3: Synthesis of Metal Complex 411

Step 1:

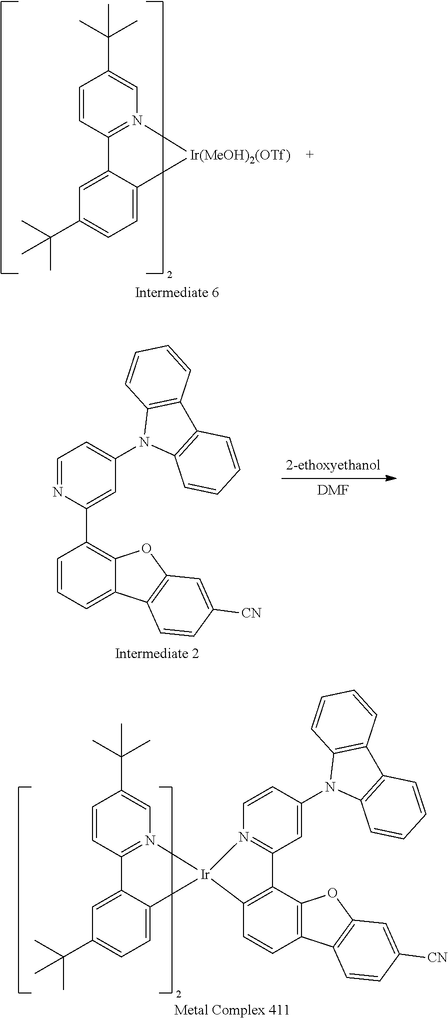

In a dry 250 mL round-bottom flask, Intermediate 2 (2.7 g, 6.2 mmol), Intermediate 6 (5.3 g, 5.7 mmol), 2-ethoxyethanol (50 mL) and DMF (50 mL) were added in sequence and heated to react for 144 h at 100° C. under N₂ protection. The reaction was cooled and filtered through Celite. The reaction was washed twice with methanol and washed twice with n-hexane. Yellow solids on the Celite were dissolved with dichloromethane. The organic phases were collected, concentrated under reduced pressure, and purified through column chromatography to obtain Metal Complex 411 as a yellow solid (2.4 g, with a yield of 36.4%). The product structure was confirmed as the target product with a molecular weight of 1159.5.

### Synthesis Example 4: Synthesis of Metal Complex 427

Step 1:

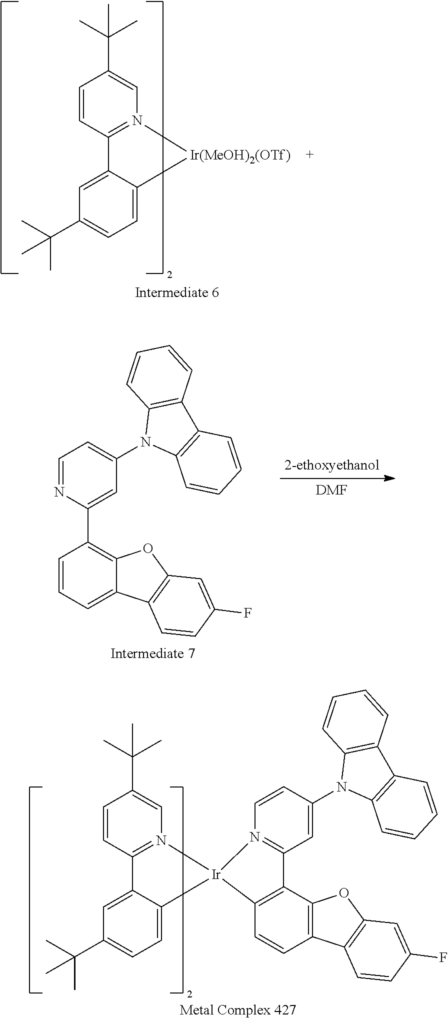

In a dry 250 mL round-bottom flask, Intermediate 7 (2.1 g, 4.9 mmol), Intermediate 6 (3.8 g, 4.1 mmol), 2-ethoxyethanol (50 mL) and DMF (50 mL) were added in sequence and heated to react for 144 h at 100° C. under N₂ protection. The reaction was cooled and filtered through Celite. The reaction was washed twice with methanol and washed twice with n-hexane. Yellow solids on the Celite were dissolved with dichloromethane. The organic phases were collected, concentrated under reduced pressure, and purified through column chromatography to obtain Metal Complex 427 as a yellow solid (2.8 g, with a yield of 59.0%). The product structure was confirmed as the target product with a molecular weight of 1152.5.

### Synthesis Example 5: Synthesis of Metal Complex 433

Step 1:

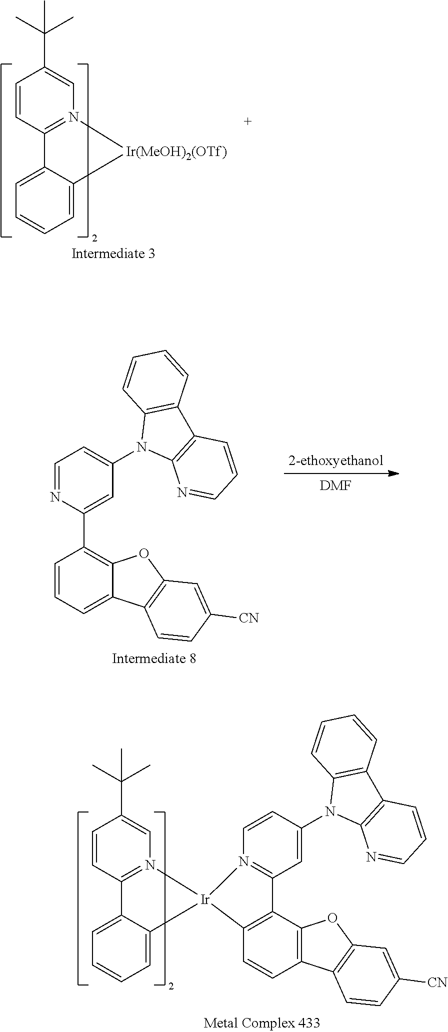

In a dry 250 mL round-bottom flask, Intermediate 8 (1.6 g, 3.6 mmol), Intermediate 3 (2.0 g, 2.4 mmol), 2-ethoxyethanol (30 mL) and DMF (30 mL) were added in sequence and heated to react for 144 h at 95° C. under N₂ protection. The reaction was cooled and filtered through Celite. The reaction was washed twice with methanol and washed twice with n-hexane. Yellow solids on the Celite were dissolved with dichloromethane. The organic phases were collected, concentrated under reduced pressure, and purified through column chromatography to obtain Metal Complex 433 as a yellow solid (0.84 g, with a yield of 33.5%). The product structure was confirmed as the target product with a molecular weight of 1048.3.

Those skilled in the art will appreciate that the above preparation methods are merely exemplary. Those skilled in the art can obtain other compound structures of the present disclosure through the modifications of the preparation methods.

### Device Example 1

Firstly, a glass substrate having an indium tin oxide (ITO) anode with a thickness of 80 nm was cleaned and then treated with oxygen plasma and UV ozone. After the treatment, the substrate was dried in a glovebox to remove moisture. Then, the substrate was mounted on a substrate holder and placed in a vacuum chamber. Organic layers specified below were sequentially deposited through vacuum thermal evaporation on the ITO anode at a rate of 0.2 to 2 Angstroms per second and a vacuum degree of about 10-8 torr. Compound HI was used as a hole injection layer (HIL). Compound HT was used as a hole transporting layer (HTL). Compound H1 was used as an electron blocking layer (EBL). Metal Complex 159 of the present disclosure, as a dopant, was co-deposited with Compound H1 and Compound H2 for use as an emissive layer (EML). On the EML, Compound H3 was used as a hole blocking layer (HBL). Compound ET and 8-hydroxyquinolinolato-lithium (Liq) were co-deposited for use as an electron transporting layer (ETL). Finally, 8-hydroxyquinolinolato-lithium (Liq) was deposited as an electron injection layer with a thickness of 1 nm and Al was deposited as a cathode with a thickness of 120 nm. The device was transferred back to the glovebox and encapsulated with a glass lid to complete the device.

### Device Example 2

The implementation mode in Device Example 2 was the same as that in Device Example 1, except that in the emissive layer (EML), Metal Complex 159 of the present disclosure was replaced with Metal Complex 411, and the weight ratio of Compound H1, Compound H2 and Metal Complex 411 was 56:38:6.

### Device Comparative Example 1

The implementation mode in Device Comparative Example 1 was the same as that in Device Example 1, except that in the emissive layer (EML), Metal Complex 159 of the present disclosure was replaced with Compound GD1.

### Device Comparative Example 2

The implementation mode in Device Comparative Example 2 was the same as that in Device Example 1, except that in the emissive layer (EML), Metal Complex 159 of the present disclosure was replaced with Compound GD2.

### Device Comparative Example 3

The implementation mode in Device Comparative Example 3 was the same as that in Device Example 1, except that in the emissive layer (EML), Metal Complex 159 of the present disclosure was replaced with Compound GD3.

Detailed structures and thicknesses of layers of the devices are shown in the following table. A layer using more than one material is obtained by doping different compounds at their weight ratio as recorded.

TABLE 1
Partial device structures of Device Examples 1 and 2 and Comparative Examples 1 to 3

| Device ID | HL | HTL | EBL | EML | HBL | ETL |
|---|---|---|---|---|---|---|
| Example 1 | Compound | Compound | Compound | Compound | Compound | Compound |
| | HI (100 Å) | HT (350 Å) | H1 (50 Å) | H1:Compound | H3 (50 Å) | ET:Liq |
| | | | | H2:Metal Complex | | (40:60) |
| | | | | 159 (47:47:6) | | (350 Å) |
| | | | | (400 Å) | | |
| Example 2 | Compound | Compound | Compound | Compound | Compound | Compound |
| | HI (100 Å) | HT (350 Å) | H1 (50 Å) | H1:Compound | H3 (50 Å) | ET:Liq |
| | | | | H2:Metal Complex | | (40:60) |
| | | | | 411 (56:38:6) | | (350 Å) |
| | | | | (400 Å) | | |
| Comparative | Compound | Compound | Compound | Compound | Compound | Compound |
| Example 1 | HI (100 Å) | HT (350 Å) | H1 (50 Å) | H1:Compound | H3 (50 Å) | ET:Liq |
| | | | | H2:Compound GD1 | | (40:60) |
| | | | | (47:47:6) | | (350 Å) |
| | | | | (400 Å) | | |
| Comparative | Compound | Compound | Compound | Compound | Compound | Compound |
| Example 2 | HI (100 Å) | HT (350 Å) | H1 (50 Å) | H1:Compound | H3 (50 Å) | ET:Liq |
| | | | | H2:Compound GD2 | | (40:60) |
| | | | | (47:47:6) | | (350 Å) |
| | | | | (400 Å) | | |
| Comparative | Compound | Compound | Compound | Compound | Compound | Compound |
| Example 3 | HI (100 Å) | HT (350 Å) | H1 (50 Å) | H1:Compound | H3 (50 Å) | ET:Liq |
| | | | | H2:Compound GD3 | | (40:60) |
| | | | | (47:47:6) | | (350 Å) |
| | | | | (400 Å) | | |

The materials used in the devices have the following structures:

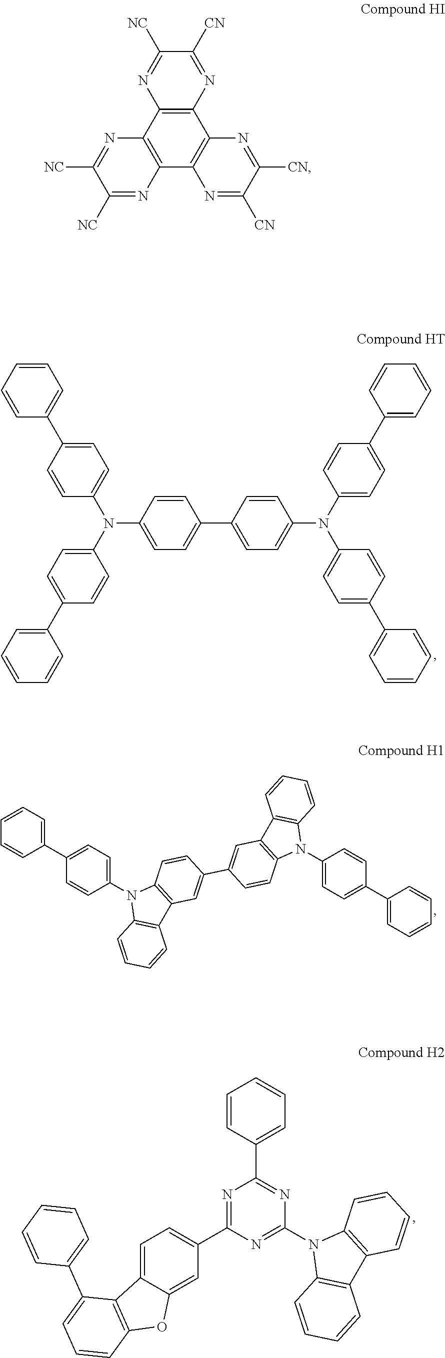 [SMILES: N#Cc1nc2c3nc(C#N)c(C#N)nc3c3nc(C#N)c(C#N)nc3c2nc1C#N ; c1ccc(-c2ccc(N(c3ccc(-c4ccccc4)cc3)c3ccc(-c4ccc(N(c5ccc(-c6ccccc6)cc5)c5ccc(-c6ccccc6)cc5)cc4)cc3)cc2)cc1 ; c1ccc(-c2ccc(-n3c4ccccc4c4cc(-c5ccc6c(c5)c5ccccc5n6-c5ccc(-c6ccccc6)cc5)ccc43)cc2)cc1 ; c1ccc(-c2nc(-c3ccc4c(c3)oc3cccc(-c5ccccc5)c34)nc(-n3c4ccccc4c4ccccc43)n2)cc1]

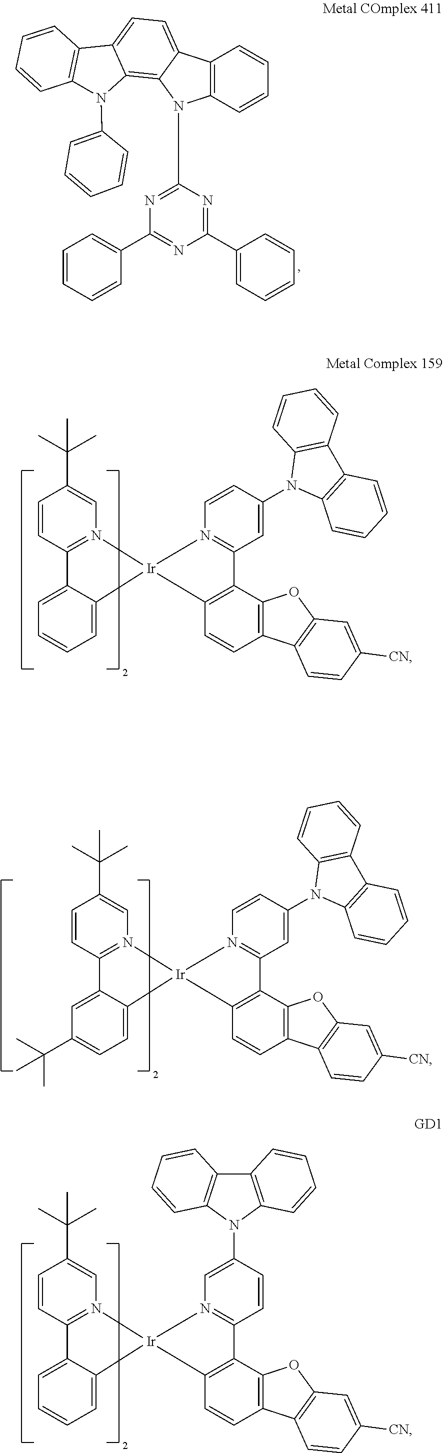

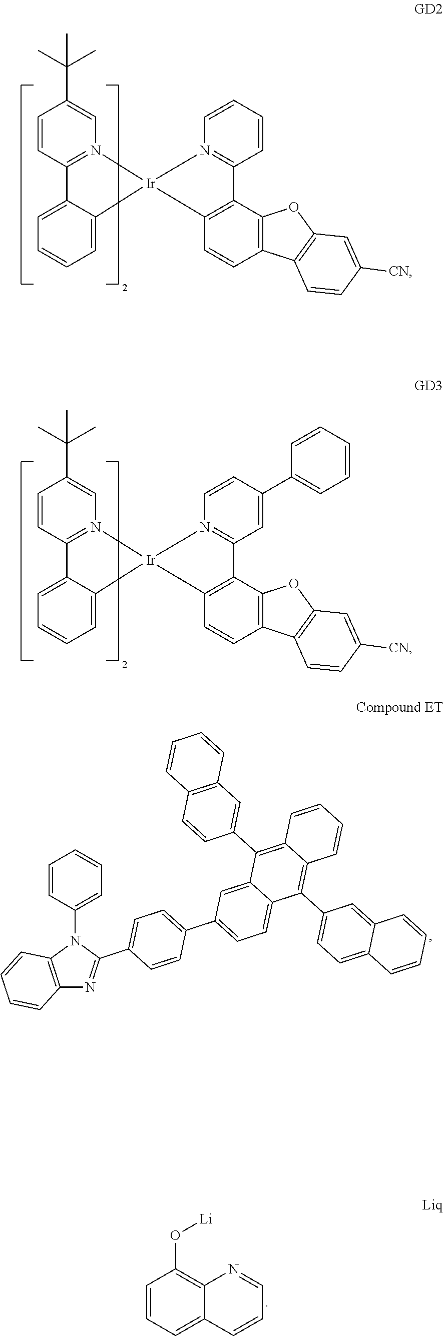

The current-voltage-luminance (IVL) characteristics of the devices were measured. Under 1000 cd/m², the CIE data, maximum emission wavelength (λₘₐₓ), full width at half maximum (FWHM), driving voltage (V), current efficiency (CE) and external quantum efficiency (EQE) of the devices were measured. Lifetime (LT97) data was tested at a constant current of 80 mA/cm². The data was recorded and shown in Table 2.

TABLE 2
Device data of Device Examples 1 and 2 and Comparative Examples 1 to 3

| | | λₘₐₓ | FWHM | Voltage | CE | EQE | LT 97 |
|---|---|---|---|---|---|---|---|
| Device ID | CIE (x, y) | (nm) | (nm) | (V) | (cd/A) | (%) | (h) |
| Example 1 | (0.406, 0.584) | 544 | 58.7 | 2.55 | 103 | 27.39 | 62.5 |
| Example 2 | (0.428, 0.564) | 547 | 62.7 | 2.69 | 98 | 26.60 | 67.2 |
| Comparative | (0.429, 0.564) | 546 | 53.7 | 2.56 | 90 | 24.57 | 59.0 |
| Example 1 | | | | | | | |
| Comparative | (0.351, 0.627) | 531 | 50.7 | 2.60 | 95 | 24.52 | 52.3 |
| Example 2 | | | | | | | |
| Comparative | (0.444, 0.549) | 550 | 70.6 | 2.57 | 88 | 25.29 | 51.3 |
| Example 3 | | | | | | | |

Discussion

Table 2 shows the device performance of the metal complexes of the present disclosure and the comparative compounds. Metal Complex 159 of the present disclosure differs from Comparative Compound GD1 only in that the carbazole substituent is located at different substitution positions of pyridine in the ligand Lₐ. Compared with Comparative Example 1, Example 1 has substantially the same driving voltage, the CE increased by 14.4%, the EQE increased by 11.4%, and the lifetime increased by 5.9%, indicating that the metal complex of the present application comprising a ligand Lₐ with the substituent Rₙ at the particular position can improve the device efficiency (CE and EQE) and the lifetime and significantly improve the overall performance of the device.

Metal Complex 159 of the present disclosure differs from Comparative Compound GD2 only in that a carbazole substitution exists at position 4 of pyridine in the ligand Lₐ. Compared with Comparative Example 2, Example 1 has the slightly reduced driving voltage, the CE increased by 8.4%, the EQE increased by 11.7%, and the lifetime increased by 19.5%, indicating that the metal complex of the present application comprising the ligand Lₐ with the substituent Rₙ at the particular position can improve the device efficiency (CE and EQE) and the lifetime and significantly improve the overall performance of the device.

Metal Complex 159 of the present disclosure differs from Comparative Compound GD3 only in that a carbazole substituent, rather than phenyl, exists at position 4 of pyridine in the ligand Lₐ. Compared with Comparative Example 3, Example 1 has substantially the same driving voltage, the CE increased by 17.0%, the EQE increased by 8.3%, and the lifetime increased by 21.8%, indicating that the metal complex of the present application comprising the ligand Lₐ with the substituent Rₙ at the particular position can improve the device efficiency (CE and EQE) and the lifetime and significantly improve the overall performance of the device.

In addition, the maximum emission wavelength of the device in Example 1 is in the region close to yellow light, and the device in Example 1 has achieved the device performance including a long lifetime and high efficiency, which has a huge application prospect in the aspects of white and low blue light sources.

In Example 2, Metal Complex 411 of the present disclosure is used as a light-emitting material in the emissive layer. The voltage, CE and EQE of Example 2 maintain excellent levels comparable to those of Example 1, and the lifetime of Example 2 is further improved. Meanwhile, the EQE and lifetime of Example 2 are significantly improved compared with those of Comparative Examples 1 to 3. Therefore, Example 2 has excellent light emission performance and an excellent device lifetime.

All the above results indicate that the metal complex of the present disclosure comprising the ligand Lₐ with the substituent Rₙ at the particular position, when applied to an organic electroluminescent device, can improve the device efficiency (CE and EQE) and the lifetime and achieve the beneficial effect of significantly improving the overall performance of the device.

### Device Example 3

The implementation mode in Device Example 3 was the same as that in Device Example 2, except that in the emissive layer (EML), Metal Complex 411 of the present disclosure was replaced with Metal Complex 427.

### Device Example 4

The implementation mode in Device Example 4 was the same as that in Device Example 2, except that in the emissive layer (EML), Metal Complex 411 of the present disclosure was replaced with Metal Complex 433.

Detailed structures and thicknesses of layers of the devices are shown in Table 3. A layer using more than one material is obtained by doping different compounds at their weight ratio as recorded.

TABLE 3
Device structures of Device Examples 3 and 4

| Device ID | HL | HTL | EBL | EML | HBL | ETL |
|---|---|---|---|---|---|---|
| Example 3 | Compound | Compound | Compound | Compound | Compound | Compound |
| | HI (100 Å) | HT (350 Å) | H1 (50 Å) | H1:Compound | H3 (50 Å) | ET:Liq |
| | | | | H2:Metal Complex | | (40:60) |
| | | | | 427 (56:38:6) | | (350 Å) |
| | | | | (400 Å) | | |
| Example 4 | Compound | Compound | Compound | Compound | Compound | Compound |
| | HI (100 Å) | HT (350 Å) | H1 (50 Å) | H1:Compound | H3 (50 Å) | ET:Liq |
| | | | | H2:Metal Complex | | (40:60) |
| | | | | 433 (56:38:6) | | (350 Å) |
| | | | | (400 Å) | | |

The new materials used in the devices have the following structures:

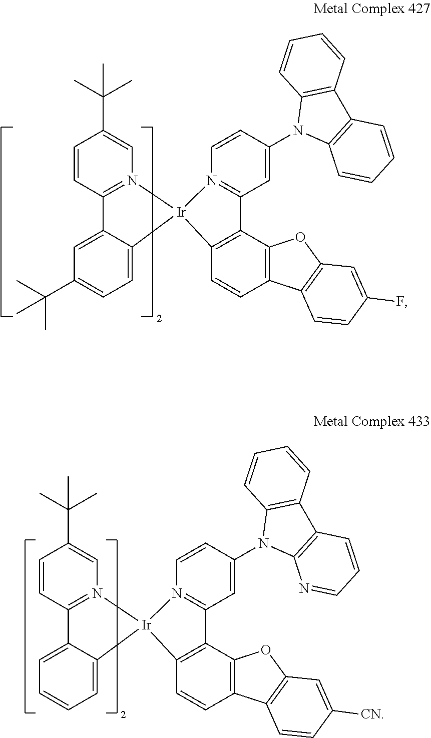

The IVL characteristics of the devices were measured. Under 1000 cd/m², the CIE data, maximum emission wavelength (λₘₐₓ), full width at half maximum (FWHM), driving voltage (V), current efficiency (CE) and external quantum efficiency (EQE) of the devices were measured. The data was recorded and shown in Table 4.

TABLE 4
Device data of Device Examples 3 and 4

| | | λₘₐₓ | FWHM | Voltage | CE | EQE |
|---|---|---|---|---|---|---|
| Device ID | CIE (x, y) | (nm) | (nm) | (V) | (cd/A) | (%) |
| Example 3 | (0.433, 0.559) | 550 | 66.6 | 2.83 | 96 | 26.40 |
| Example 4 | (0.373, 0.671) | 536 | 54.5 | 2.60 | 107 | 27.72 |

Discussion:

Table 4 further shows the device performance of the metal complexes of the present disclosure. In Example 3 and Example 4, Metal Complex 427 and Metal Complex 433 of the present disclosure comprising the ligand Lₐ with the substituent Rₙ at the particular position are used as the light-emitting material in the emissive layer, respectively. The voltages, CE and EQE of Example 3 and Example 4 remain comparable to those of Example 1. Meanwhile, the EQE of Example 3 and the EQE of Example 4 are significantly improved compared with those of Comparative Examples 1 to 3.

All the above results indicate that the metal complexes of the present disclosure comprising ligands Lₐ with different substituents Rₙ at a particular position and different ligands L_{b}, when applied to organic electroluminescent devices, can improve the device efficiency (CE and EQE) and/or the lifetime and achieve the beneficial effect of significantly improving the overall performance of the devices.

It is to be understood that various embodiments described herein are merely examples and not intended to limit the scope of the present disclosure. Therefore, it is apparent to the persons skilled in the art that the present disclosure as claimed may include variations of specific embodiments and preferred embodiments described herein. Many of materials and structures described herein may be substituted with other materials and structures without departing from the spirit of the present disclosure. It is to be understood that various theories as to why the present disclosure works are not intended to be limitative.

What is claimed is:

1. A metal complex, comprising a metal M and a ligand Lₐ coordinated to the metal M, wherein Lₐ has a structure represented by Formula 1: 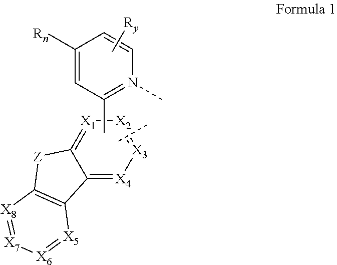
wherein
the metal M is selected from a metal with a relative atomic mass greater than 40;
Z is selected from the group consisting of O, S, Se, NR′, CR′R′ and SiR′R′; when two R′ are present at the same time, the two R′ are the same or different;
the substituent R_{y} represents mono-substitution, multiple substitutions or non-substitution;
X₁ to X₈ are, at each occurrence identically or differently, selected from C, CRₓ or N, and at least one of X₁ to X₄ is selected from C and joined to pyridine in Formula 1;
the substituent Rₙ has a structure represented by Formula 2: 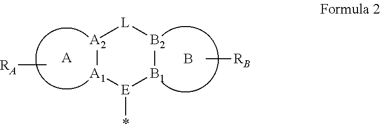
wherein in Formula 2,
the substituents R_{A} and R_{B} represent, at each occurrence identically or differently, mono-substitution, multiple substitutions or non-substitution;
the ring A and the ring B are identically or differently selected from a carbocyclic ring having 3 to 30 ring atoms or a heterocyclic ring having 3 to 30 ring atoms;
A₁, A₂, B₁, B₂ and E are, at each occurrence identically or differently, selected from C, N, B, P, CR′″, SiR′″ or GeR′″;
L is selected from a single bond, O, S, SO₂, Se, NR″, CR″R″, SiR″R″, GeR″R″, BR″, PR″, P(O)R″, R″C═CR″, substituted or unsubstituted alkylene having 1 to 20 carbon atoms, substituted or unsubstituted heteroalkylene having 1 to 20 carbon atoms, substituted or unsubstituted cycloalkylene having 3 to 20 carbon atoms, substituted or unsubstituted heterocyclylene having 3 to 20 ring atoms, substituted or unsubstituted arylene having 6 to 30 carbon atoms, substituted or unsubstituted heteroarylene having 3 to 30 carbon atoms or a combination thereof,
the substituents R′, R″, R′″, Rₓ, R_{y}, R_{A} and R_{B} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof,
“*” represents a position where Formula 2 is joined; and
adjacent substituents R′, Rₓ, R″, R′″, R_{A}, R_{B}, R_{y} can be optionally joined to form a ring.

2. The metal complex according to claim 1, wherein the metal complex has a general formula of M(Lₐ)ₘ(L_{b})ₙ(L_{c})_{q};
wherein
the metal M is selected from a metal with a relative atomic mass greater than 40; preferably, M is, at each occurrence identically or differently, selected from the group consisting of Cu, Ag, Au, Ru, Rh, Pd, Os, Ir and Pt; more preferably, M is, at each occurrence identically or differently, selected from Pt or Ir;
Lₐ, L_{b} and L_{c} are a first ligand, a second ligand and a third ligand coordinated to the metal M, respectively, and L_{c} is the same as or different from Lₐ or L_{b}; wherein Lₐ, L_{b} and L_{c} can be optionally joined to form a multidentate ligand;
m is selected from 1, 2 or 3, n is selected from 0, 1 or 2, q is selected from 0, 1 or 2, and m+n+q equals to the oxidation state of the metal M; when m is greater than or equal to 2, multiple Lₐ are the same or different; when n is equal to 2, two L_{b} are the same or different; when q is equal to 2, two L_{c} are the same or different;
L_{b} and L_{c} are, at each occurrence identically or differently, selected from a structure represented by any one of the group consisting of: 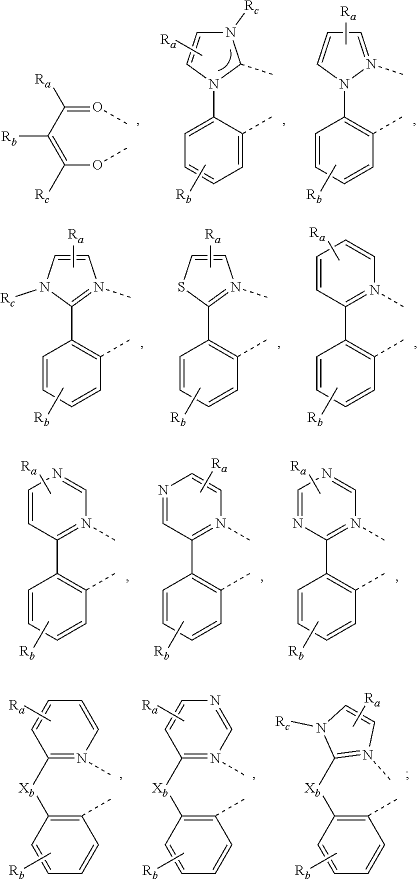
wherein
the substituents Rₐ and R_{b} represent, at each occurrence identically or differently, mono-substitution, multiple substitutions or non-substitution;
X_{b} is, at each occurrence identically or differently, selected from the group consisting of: O, S, Se, NR_{N1} and CR_{C1}R_{C2};
the substituents Rₐ, R_{b}, R_{c}, R_{N1}, R_{C1} and R_{C2} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof, and
adjacent substituents Rₐ, R_{b}, R_{c}, R_{N1}, R_{C1} and R_{C2} can be optionally joined to form a ring.

3. The metal complex according to claim 1, wherein the metal complex has a general formula of Ir(Lₐ)ₘ(L_{b})₃₋ₘ and is represented by Formula 3: 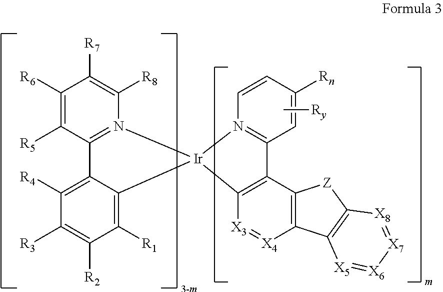
wherein
m is selected from 1, 2 or 3; when m is selected from 1, two L_{b} are the same or different; when m is selected from 2 or 3, multiple Lₐ are the same or different;
Z is selected from the group consisting of O, S, Se, NR′, CR′R′ and SiR′R′; when two R′ are present at the same time, the two R′ are the same or different;
the substituent R_{y} represents mono-substitution, multiple substitutions or non-substitution;
X₃ to X₈ are, at each occurrence identically or differently, selected from CRₓ or N;
the substituent Rₙ has a structure represented by Formula 2: 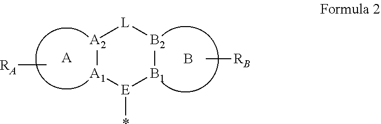
wherein in Formula 2,
the substituents R_{A} and R_{B} represent, at each occurrence identically or differently, mono-substitution, multiple substitutions or non-substitution;
the ring A and the ring B are identically or differently selected from a carbocyclic ring having 3 to 30 ring atoms or a heterocyclic ring having 3 to 30 ring atoms;
A₁, A₂, B₁, B₂ and E are, at each occurrence identically or differently, selected from C, N, B, P, CR′″, SiR′″ or GeR′″;
L is selected from a single bond, O, S, SO₂, Se, NR″, CR″R″, SiR″R″, GeR″R″, BR″, PR″, P(O)R″, R″C═CR″, substituted or unsubstituted alkylene having 1 to 20 carbon atoms, substituted or unsubstituted heteroalkylene having 1 to 20 carbon atoms, substituted or unsubstituted cycloalkylene having 3 to 20 carbon atoms, substituted or unsubstituted heterocyclylene having 3 to 20 ring atoms, substituted or unsubstituted arylene having 6 to 30 carbon atoms, substituted or unsubstituted heteroarylene having 3 to 30 carbon atoms or a combination thereof,
the substituents R₁ to R₈, R′, R″, R′″, Rₓ, R_{y}, R_{A} and R_{B} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof,
“*” represents a position where Formula 2 is joined;
adjacent substituents R′, Rₓ, R″, R′″, R_{A}, R_{B}, R_{y} can be optionally joined to form a ring; and
adjacent substituents R₁ to R₈ can be optionally joined to form a ring.

4. The metal complex according to claim 1, wherein Z is selected from O or S; preferably, Z is selected from O.

5. The metal complex according to claim 1, wherein X₁ to X₈ are, at each occurrence identically or differently, selected from CRₓ, and the substituent Rₓ is, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted alkylgermanyl having 3 to 20 carbon atoms, cyano and combinations thereof,
preferably, the substituent Rₓ is, at each occurrence identically or differently, selected from the group consisting of: hydrogen, deuterium, fluorine, cyano, methyl, ethyl, propyl, isopropyl, n-butyl, isobutyl, t-butyl, cyclopentyl, cyclohexyl, deuterated methyl, deuterated ethyl, deuterated propyl, deuterated isopropyl, deuterated n-butyl, deuterated isobutyl, deuterated t-butyl, deuterated cyclopentyl, deuterated cyclohexyl, phenyl, biphenyl, pyridyl, trimethylsilyl, trimethylgermanyl and combinations thereof.

6. The metal complex according to claim 1, wherein the substituent Rₙ has a structure represented by Formula 4: 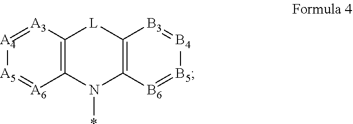
wherein
A₃ to A₆ are, at each occurrence identically or differently, selected from CR_{A} or N;
B₃ to B₆ are, at each occurrence identically or differently, selected from CR_{B} or N;
L is selected from a single bond, O, S, SO₂, Se, NR″, CR″R″, SiR″R″, GeR″R″, BR″, PR″, P(O)R″, R″C═CR″, alkylene having 1 to 20 carbon atoms, heteroalkylene having 1 to 20 carbon atoms, cycloalkylene having 3 to 20 carbon atoms, heterocyclylene having 3 to 20 ring atoms, arylene having 6 to 30 carbon atoms, heteroarylene having 3 to 30 carbon atoms or a combination thereof,
the substituents R_{A}, R_{B} and R″ are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof,
adjacent substituents R″, R_{A}, R_{B} can be optionally joined to form a ring; and
“*” represents a position where Formula 4 is joined.

7. The metal complex according to claim 6, wherein A₃ to A₆ are, at each occurrence identically or differently, selected from CR_{A} and/or B₃ to B₆ are, at each occurrence identically or differently, selected from CR_{B}; and the substituents R_{A} and R_{B} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted alkylgermanyl having 3 to 20 carbon atoms, cyano and combinations thereof,
preferably, the substituents R_{A} and R_{B} are, at each occurrence identically or differently, selected from the group consisting of: hydrogen, deuterium, fluorine, substituted or unsubstituted alkyl having 1 to 6 carbon atoms, substituted or unsubstituted cycloalkyl having 3 to 6 ring carbon atoms, substituted or unsubstituted aryl having 6 to 12 carbon atoms, substituted or unsubstituted heteroaryl having 3 to 12 carbon atoms, substituted or unsubstituted alkylsilyl having 3 to 6 carbon atoms, substituted or unsubstituted alkylgermanyl having 3 to 6 carbon atoms, cyano and combinations thereof,
more preferably, the substituents R_{A} and R_{B} are, at each occurrence identically or differently, selected from the group consisting of: hydrogen, deuterium, fluorine, cyano, methyl, ethyl, propyl, isopropyl, n-butyl, isobutyl, t-butyl, neopentyl, cyclopentyl, cyclohexyl, deuterated methyl, deuterated ethyl, deuterated propyl, deuterated isopropyl, deuterated n-butyl, deuterated isobutyl, deuterated t-butyl, deuterated neopentyl, deuterated cyclopentyl, deuterated cyclohexyl, phenyl, pyridyl, trimethylsilyl, trimethylgermanyl and combinations thereof.

8. The metal complex according to claim 1, wherein L is selected from a single bond, O, S, Se, NR″, SiR″R″, GeR″R″, BR″, PR″, P(O)R″, substituted or unsubstituted alkylene having 1 to 10 carbon atoms, substituted or unsubstituted arylene having 6 to 10 carbon atoms, substituted or unsubstituted heteroarylene having 3 to 10 carbon atoms or a combination thereof,
preferably, L is selected from a single bond, O, S, NR″, substituted or unsubstituted alkylene having 1 to 10 carbon atoms or phenylene;
more preferably, L is selected from a single bond.

9. The metal complex according to claim 3, wherein at least one of X₃ to X₈ is CRₓ, and the substituent Rₓ is selected from cyano or fluorine;
preferably, at least one of X₅ to X₈ is CRₓ, and the substituent Rₓ is selected from cyano or fluorine;
more preferably, X₇ or X₈ is CRₓ, and Rₓ is selected from cyano; or X₇ is CRₓ, and the substituent Rₓ is selected from fluorine.

10. The metal complex according to claim 3, wherein at least two of X₃ to X₅ are selected from CRₓ, wherein one substituent Rₓ is selected from cyano or fluorine, and another substituent Rₓ is selected from the group consisting of: deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, cyano, isocyano and combinations thereof,
preferably, at least two of X₅ to X₅ are selected from CRₓ, wherein one substituent Rₓ is selected from cyano or fluorine, and another substituent Rₓ is selected from the group consisting of: deuterium, fluorine, substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, cyano, isocyano and combinations thereof,
more preferably, X₇ and X₅ are selected from CRₓ, wherein one substituent Rₓ is cyano or fluorine, and another substituent Rₓ is selected from the group consisting of: deuterium, fluorine, substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, cyano, isocyano and combinations thereof.

11. The metal complex according to claim 1, wherein Rₙ is, at each occurrence identically or differently, selected from the group consisting of: 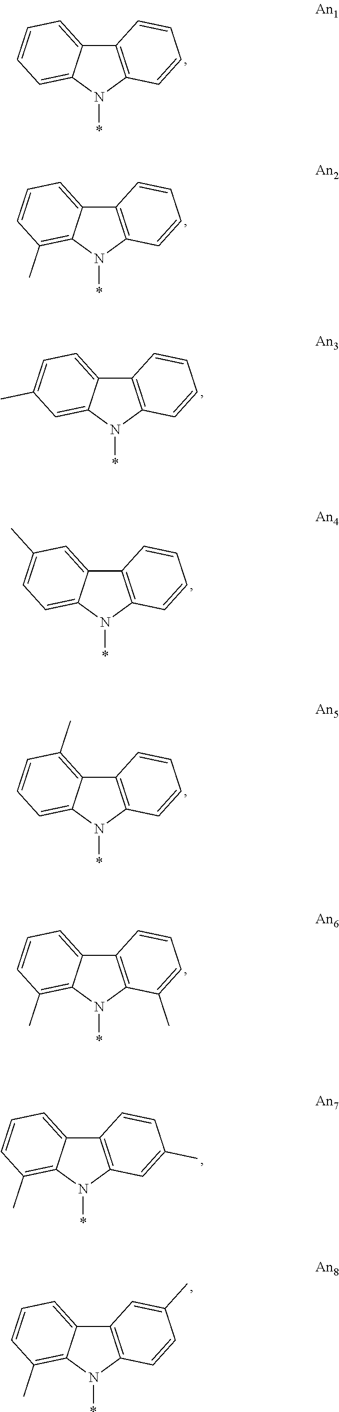 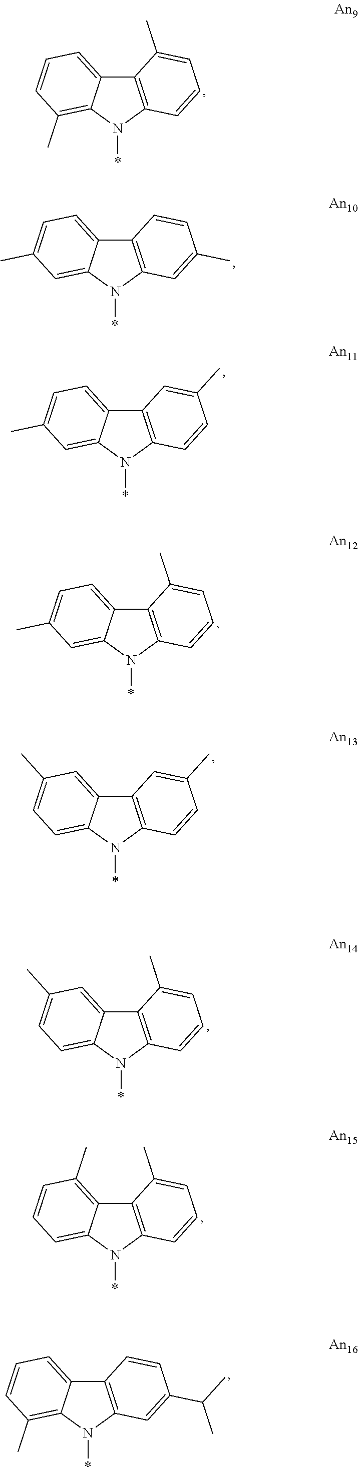 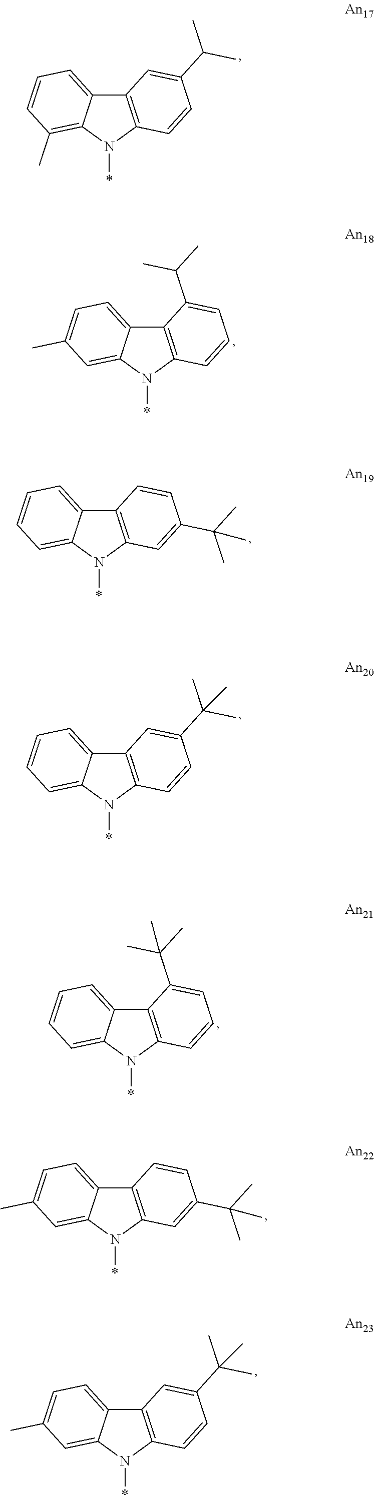 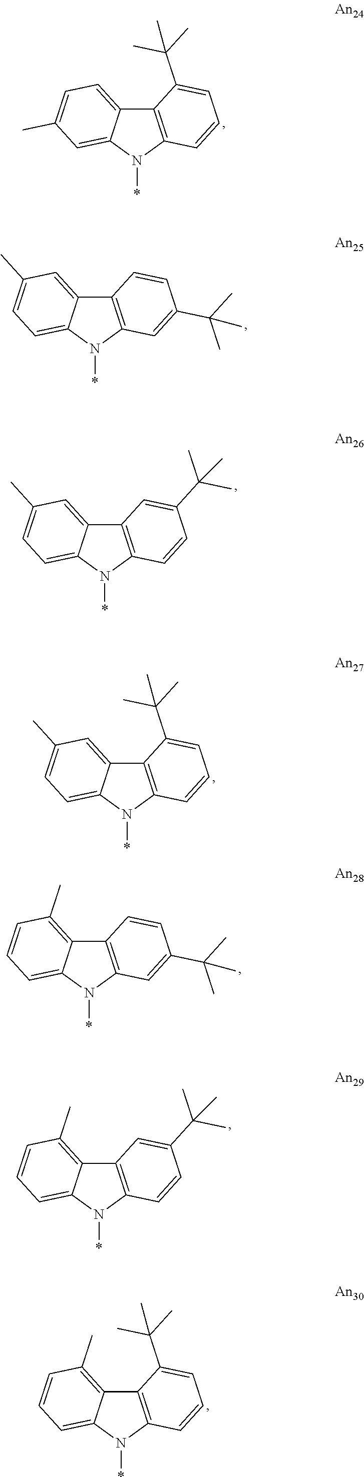 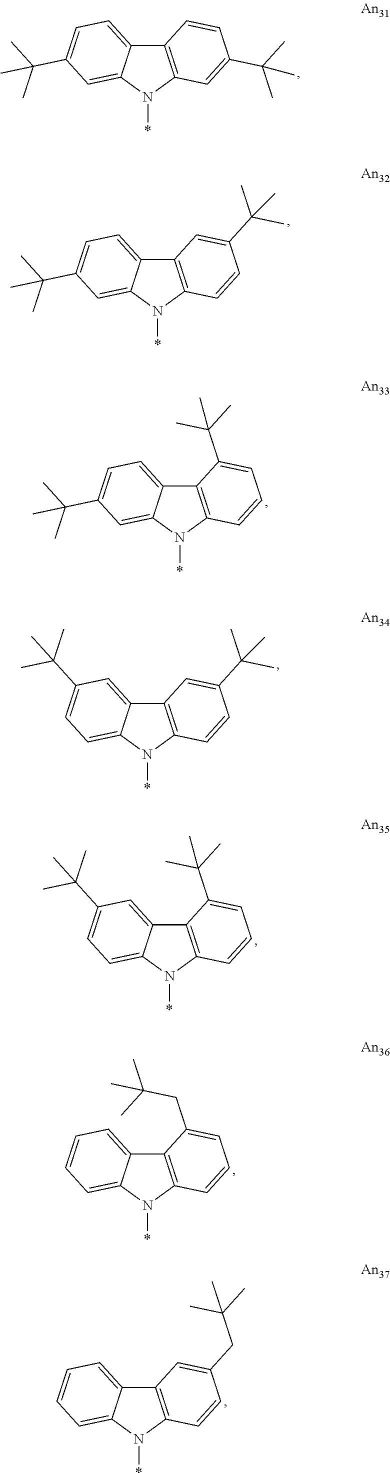 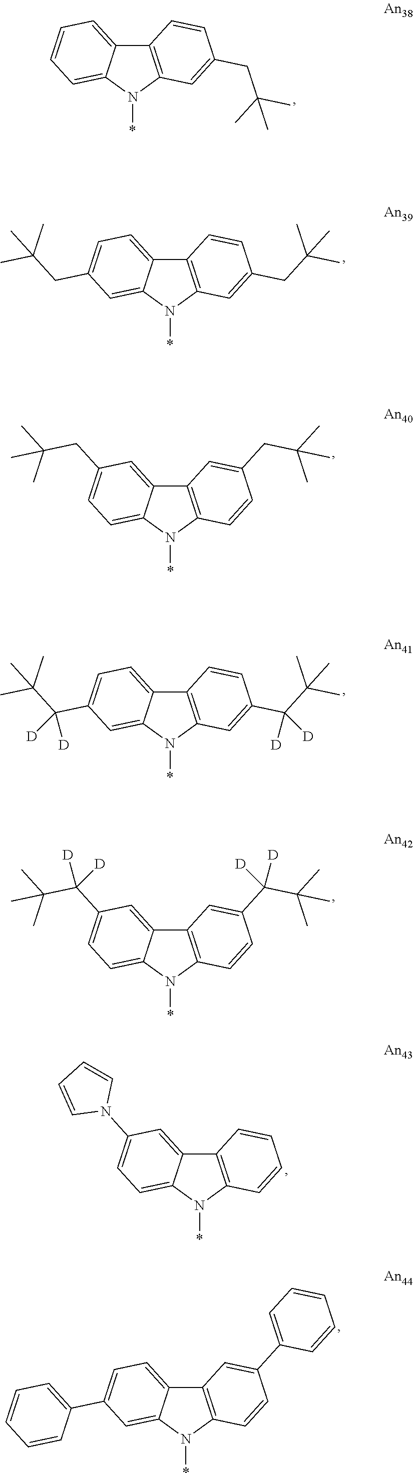 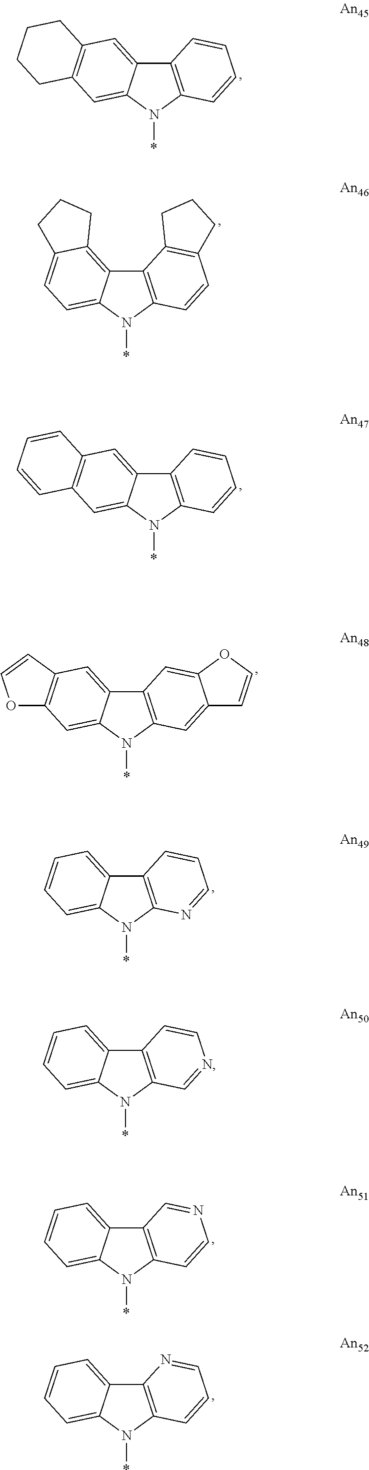 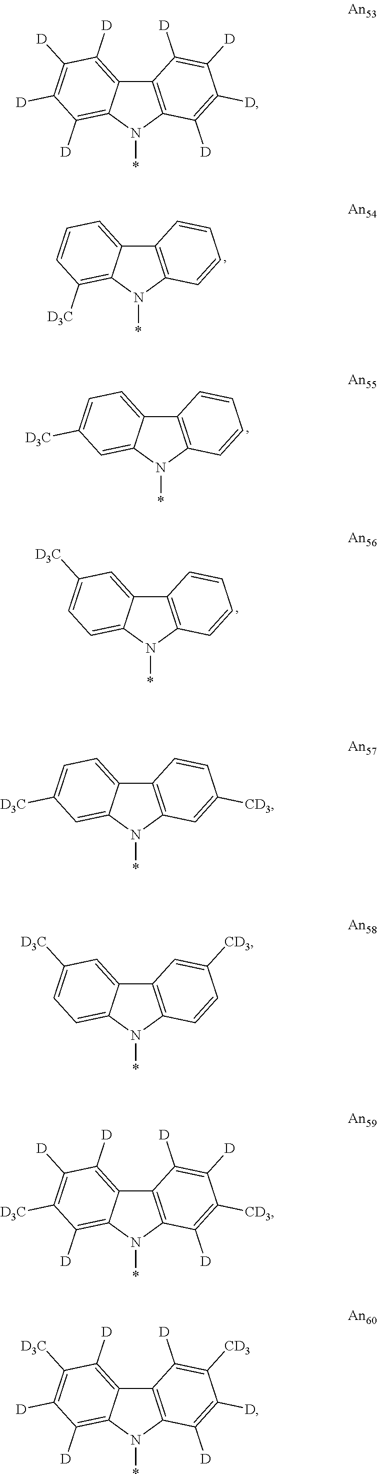 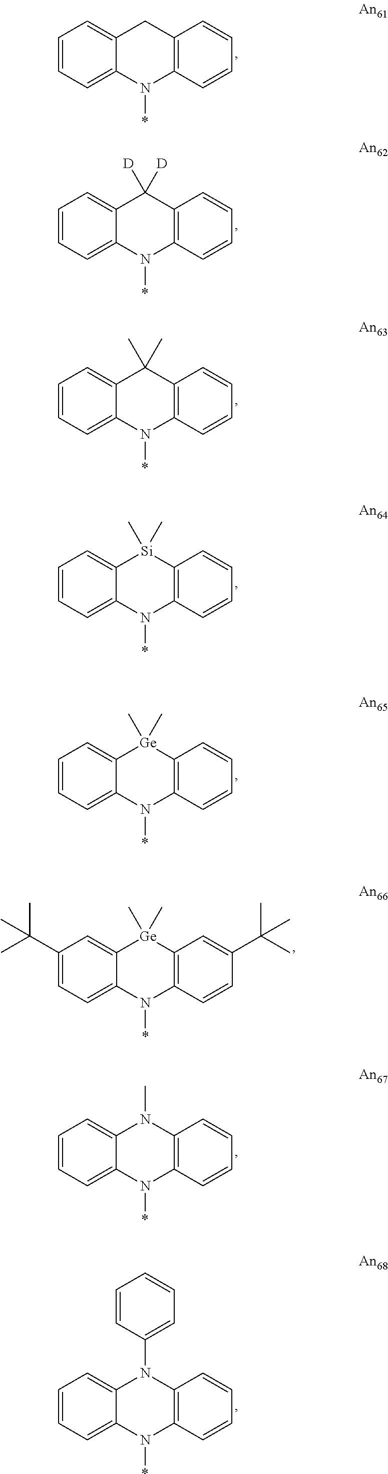 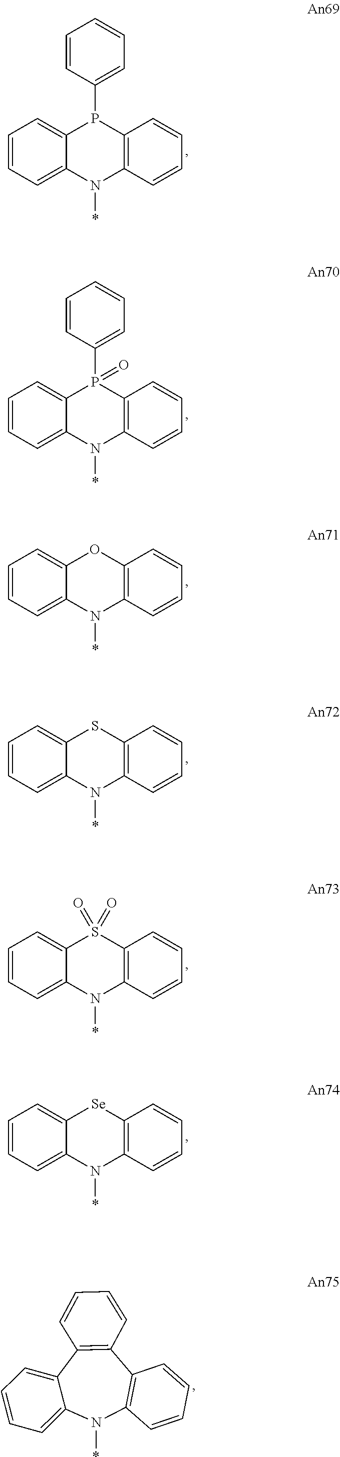 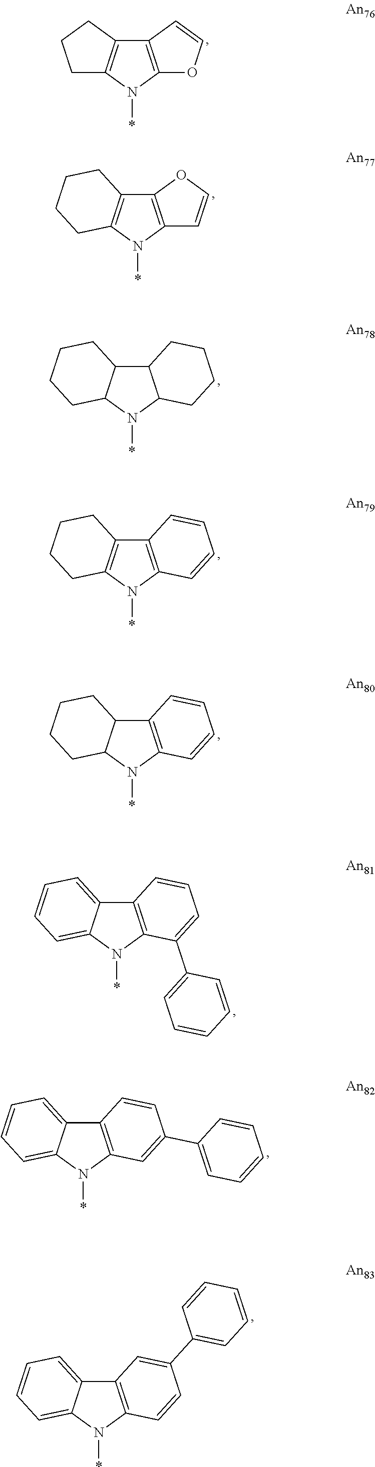 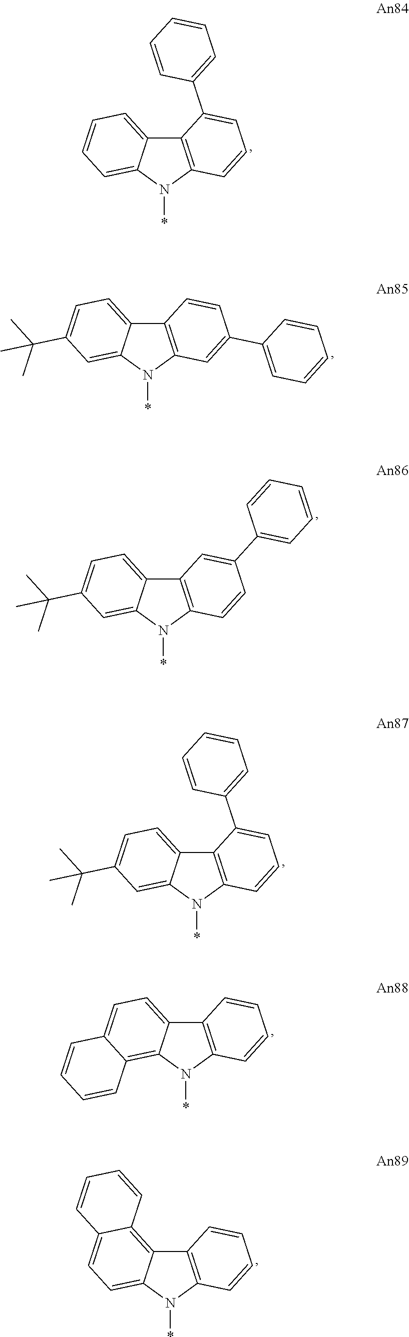 [SMILES: *n1c2ccccc2c2c(-c3ccccc3)cccc21 ; *n1c2cc(-c3ccccc3)ccc2c2ccc(C(C)(C)C)cc21 ; *n1c2ccc(-c3ccccc3)cc2c2ccc(C(C)(C)C)cc21 ; *n1c2cc(C(C)(C)C)ccc2c2c(-c3ccccc3)cccc21 ; *n1c2ccccc2c2ccc3ccccc3c21 ; *n1c2ccccc2c2c3ccccc3ccc21] 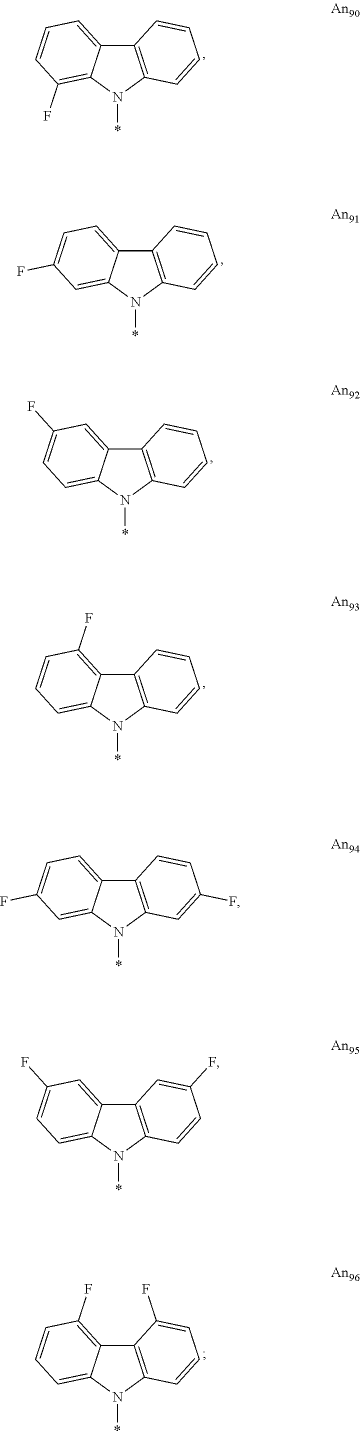
wherein optionally, hydrogens in An₁ to An₅₂, An₅₄ to An₅₈ and An₆₁ to An₉₆ can be partially or fully deuterated.

12. The metal complex according to claim 1, wherein the substituent R_{y} is, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted arylalkyl having 7 to 30 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted amino having 6 to 20 carbon atoms and combinations thereof, preferably, at least one substituent R_{y} is selected from the group consisting of: deuterium, halogen, substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms and combinations thereof.

13. The metal complex according to claim 3, wherein at least one or at least two of the substituents R₁ to R₈ are selected from substituted or unsubstituted alkyl having 1 to 20 carbon atoms, substituted or unsubstituted cycloalkyl having 3 to 20 ring carbon atoms or a combination thereof, and the total number of carbon atoms in all of the substituents R₁ to R₄ and/or the substituents R₅ to R₈ is at least 4; and
preferably, at least one or at least two of the substituents R₁ to R₄ are selected from substituted or unsubstituted alkyl having 1 to 20 carbon atoms, substituted or unsubstituted cycloalkyl having 3 to 20 ring carbon atoms or a combination thereof, and the total number of carbon atoms in all of the substituents R₁ to R₄ is at least 4; and/or at least one or at least two of the substituents R₅ to R₈ are selected from substituted or unsubstituted alkyl having 1 to 20 carbon atoms, substituted or unsubstituted cycloalkyl having 3 to 20 ring carbon atoms or a combination thereof, and the total number of carbon atoms in all of the substituents R₅ to R₈ is at least 4.

14. The metal complex according to claim 3, wherein at least one, at least two, at least three or all of the substituents R₂, R₃, R₆ and R₇ are selected from the group consisting of: deuterium, substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms and combinations thereof,
preferably, at least one, at least two, at least three or all of the substituents R₂, R₃, R₆ and R₇ are selected from the group consisting of: deuterium, substituted or unsubstituted alkyl having 1 to 20 carbon atoms, substituted or unsubstituted cycloalkyl having 3 to 20 ring carbon atoms and combinations thereof,
more preferably, at least one, at least two, at least three or all of the substituents R₂, R₃, R₆ and R₇ are selected from the group consisting of: deuterium, methyl, ethyl, propyl, isopropyl, n-butyl, isobutyl, t-butyl, cyclopentyl, cyclohexyl, neopentyl, t-pentyl and combinations thereof, optionally, hydrogens in the above groups can be partially or fully deuterated.

15. The metal complex according to claim 11, wherein Lₐ is, at each occurrence identically or differently, selected from the group consisting of Lₐ₁ to Lₐ₈₂₁, wherein Lₐ₁ to Lₐ₈₂₁ have the following specific structures:
Lₐ₁ to Lₐ₇₇₃ have the following general formula: 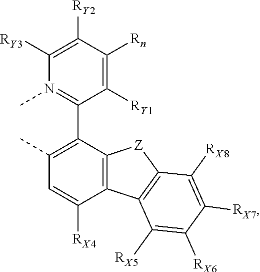
wherein Rₙ, R_{Y1} to R_{Y3}, R_{X4} to R_{X8} and Z are selected from atoms or groups in the following table:

| Ligand Lₐ | | | | | | | | | | |
|---|---|---|---|---|---|---|---|---|---|---|
| No. | Rₙ | R_{Y1} | R_{Y2} | R_{Y3} | R_{X4} | R_{X5} | R_{X6} | R_{X7} | R_{X8} | Z |
| Lₐ₁ | Aₙ₁ | H | H | H | H | H | H | H | H | O |
| Lₐ₂ | Aₙ₂ | H | H | H | H | H | H | H | H | O |
| Lₐ₃ | Aₙ₃ | H | H | H | H | H | H | H | H | O |
| Lₐ₄ | Aₙ₄ | H | H | H | H | H | H | H | H | O |
| Lₐ₅ | Aₙ₅ | H | H | H | H | H | H | H | H | O |
| Lₐ₆ | Aₙ₆ | H | H | H | H | H | H | H | H | O |
| Lₐ₇ | Aₙ₇ | H | H | H | H | H | H | H | H | O |
| Lₐ₈ | Aₙ₈ | H | H | H | H | H | H | H | H | O |
| Lₐ₉ | Aₙ₉ | H | H | H | H | H | H | H | H | O |
| Lₐ₁₀ | Aₙ₁₀ | H | H | H | H | H | H | H | H | O |
| Lₐ₁₁ | Aₙ₁₁ | H | H | H | H | H | H | H | H | O |
| Lₐ₁₂ | Aₙ₁₂ | H | H | H | H | H | H | H | H | O |
| Lₐ₁₃ | Aₙ₁₃ | H | H | H | H | H | H | H | H | O |
| Lₐ₁₄ | Aₙ₁₄ | H | H | H | H | H | H | H | H | O |
| Lₐ₁₅ | Aₙ₁₅ | H | H | H | H | H | H | H | H | O |
| Lₐ₁₆ | Aₙ₁₆ | H | H | H | H | H | H | H | H | O |
| Lₐ₁₇ | Aₙ₁₇ | H | H | H | H | H | H | H | H | O |
| Lₐ₁₈ | Aₙ₁₈ | H | H | H | H | H | H | H | H | O |
| Lₐ₁₉ | Aₙ₁₉ | H | H | H | H | H | H | H | H | O |
| Lₐ₂₀ | Aₙ₂₀ | H | H | H | H | H | H | H | H | O |
| Lₐ₂₁ | Aₙ₂₁ | H | H | H | H | H | H | H | H | O |
| Lₐ₂₂ | Aₙ₂₂ | H | H | H | H | H | H | H | H | O |
| Lₐ₂₃ | Aₙ₂₃ | H | H | H | H | H | H | H | H | O |
| Lₐ₂₄ | Aₙ₂₄ | H | H | H | H | H | H | H | H | O |
| Lₐ₂₅ | Aₙ₂₅ | H | H | H | H | H | H | H | H | O |
| Lₐ₂₆ | Aₙ₂₆ | H | H | H | H | H | H | H | H | O |
| Lₐ₂₇ | Aₙ₂₇ | H | H | H | H | H | H | H | H | O |
| Lₐ₂₈ | Aₙ₂₈ | H | H | H | H | H | H | H | H | O |
| Lₐ₂₉ | Aₙ₂₉ | H | H | H | H | H | H | H | H | O |
| Lₐ₃₀ | Aₙ₃₀ | H | H | H | H | H | H | H | H | O |
| Lₐ₃₁ | Aₙ₃₁ | H | H | H | H | H | H | H | H | O |
| Lₐ₃₂ | Aₙ₃₂ | H | H | H | H | H | H | H | H | O |
| Lₐ₃₃ | Aₙ₃₃ | H | H | H | H | H | H | H | H | O |
| Lₐ₃₄ | Aₙ₃₄ | H | H | H | H | H | H | H | H | O |
| Lₐ₃₅ | Aₙ₃₅ | H | H | H | H | H | H | H | H | O |
| Lₐ₃₆ | Aₙ₃₆ | H | H | H | H | H | H | H | H | O |
| Lₐ₃₇ | Aₙ₃₇ | H | H | H | H | H | H | H | H | O |
| Lₐ₃₈ | Aₙ₃₈ | H | H | H | H | H | H | H | H | O |
| Lₐ₃₉ | Aₙ₃₉ | H | H | H | H | H | H | H | H | O |
| Lₐ₄₀ | Aₙ₄₀ | H | H | H | H | H | H | H | H | O |
| Lₐ₄₁ | Aₙ₄₁ | H | H | H | H | H | H | H | H | O |
| Lₐ₄₂ | Aₙ₄₂ | H | H | H | H | H | H | H | H | O |
| Lₐ₄₃ | Aₙ₄₃ | H | H | H | H | H | H | H | H | O |
| Lₐ₄₄ | Aₙ₄₄ | H | H | H | H | H | H | H | H | O |
| Lₐ₄₅ | Aₙ₄₅ | H | H | H | H | H | H | H | H | O |
| Lₐ₄₆ | Aₙ₄₆ | H | H | H | H | H | H | H | H | O |
| Lₐ₄₇ | Aₙ₄₇ | H | H | H | H | H | H | H | H | O |
| Lₐ₄₈ | Aₙ₄₈ | H | H | H | H | H | H | H | H | O |
| Lₐ₄₉ | Aₙ₄₉ | H | H | H | H | H | H | H | H | O |
| Lₐ₅₀ | Aₙ₅₀ | H | H | H | H | H | H | H | H | O |
| Lₐ₅₁ | Aₙ₅₁ | H | H | H | H | H | H | H | H | O |
| Lₐ₅₂ | Aₙ₅₂ | H | H | H | H | H | H | H | H | O |
| Lₐ₅₃ | Aₙ₅₃ | H | H | H | H | H | H | H | H | O |
| Lₐ₅₄ | Aₙ₅₄ | H | H | H | H | H | H | H | H | O |
| Lₐ₅₅ | Aₙ₅₅ | H | H | H | H | H | H | H | H | O |
| Lₐ₅₆ | Aₙ₅₆ | H | H | H | H | H | H | H | H | O |
| Lₐ₅₇ | Aₙ₅₇ | H | H | H | H | H | H | H | H | O |
| Lₐ₅₈ | Aₙ₅₈ | H | H | H | H | H | H | H | H | O |
| Lₐ₅₉ | Aₙ₅₉ | H | H | H | H | H | H | H | H | O |
| Lₐ₆₀ | Aₙ₆₀ | H | H | H | H | H | H | H | H | O |
| Lₐ₆₁ | Aₙ₆₁ | H | H | H | H | H | H | H | H | O |
| Lₐ₆₂ | Aₙ₆₂ | H | H | H | H | H | H | H | H | O |
| Lₐ₆₃ | Aₙ₆₃ | H | H | H | H | H | H | H | H | O |
| Lₐ₆₄ | Aₙ₆₄ | H | H | H | H | H | H | H | H | O |
| Lₐ₆₅ | Aₙ₆₅ | H | H | H | H | H | H | H | H | O |
| Lₐ₆₆ | Aₙ₆₆ | H | H | H | H | H | H | H | H | O |
| Lₐ₆₇ | Aₙ₆₇ | H | H | H | H | H | H | H | H | O |
| Lₐ₆₈ | Aₙ₆₈ | H | H | H | H | H | H | H | H | O |
| Lₐ₆₉ | Aₙ₆₉ | H | H | H | H | H | H | H | H | O |
| Lₐ₇₀ | Aₙ₇₀ | H | H | H | H | H | H | H | H | O |
| Lₐ₇₁ | Aₙ₇₁ | H | H | H | H | H | H | H | H | O |
| Lₐ₇₂ | Aₙ₇₂ | H | H | H | H | H | H | H | H | O |
| Lₐ₇₃ | Aₙ₇₃ | H | H | H | H | H | H | H | H | O |
| Lₐ₇₄ | Aₙ₇₄ | H | H | H | H | H | H | H | H | O |
| Lₐ₇₅ | Aₙ₇₅ | H | H | H | H | H | H | H | H | O |
| Lₐ₇₆ | Aₙ₇₆ | H | H | H | H | H | H | H | H | O |
| Lₐ₇₇ | Aₙ₇₇ | H | H | H | H | H | H | H | H | O |
| Lₐ₇₈ | Aₙ₇₈ | H | H | H | H | H | H | H | H | O |
| Lₐ₇₉ | Aₙ₇₉ | H | H | H | H | H | H | H | H | O |
| Lₐ₈₀ | Aₙ₈₀ | H | H | H | H | H | H | H | H | O |
| Lₐ₈₁ | Aₙ₈₁ | H | H | H | H | H | H | H | H | O |
| Lₐ₈₂ | Aₙ₈₂ | H | H | H | H | H | H | H | H | O |
| Lₐ₈₃ | Aₙ₈₃ | H | H | H | H | H | H | H | H | O |
| Lₐ₈₄ | Aₙ₈₄ | H | H | H | H | H | H | H | H | O |
| Lₐ₈₅ | Aₙ₈₅ | H | H | H | H | H | H | H | H | O |
| Lₐ₈₆ | Aₙ₈₆ | H | H | H | H | H | H | H | H | O |
| Lₐ₈₇ | Aₙ₈₇ | H | H | H | H | H | H | H | H | O |
| Lₐ₈₈ | Aₙ₈₈ | H | H | H | H | H | H | H | H | O |
| Lₐ₈₉ | Aₙ₈₉ | H | H | H | H | H | H | H | H | O |
| Lₐ₉₀ | Aₙ₉₀ | H | H | H | H | H | H | H | H | O |
| Lₐ₉₁ | Aₙ₉₁ | H | H | H | H | H | H | H | H | O |
| Lₐ₉₂ | Aₙ₉₂ | H | H | H | H | H | H | H | H | O |
| Lₐ₉₃ | Aₙ₉₃ | H | H | H | H | H | H | H | H | O |
| Lₐ₉₄ | Aₙ₉₄ | H | H | H | H | H | H | H | H | O |
| Lₐ₉₅ | Aₙ₉₅ | H | H | H | H | H | H | H | H | O |
| Lₐ₉₆ | Aₙ₉₆ | H | H | H | H | H | H | H | H | O |
| Lₐ₉₇ | Aₙ₁ | H | CD₃ | H | H | H | H | H | H | O |
| Lₐ₉₈ | Aₙ₁₀ | H | CD₃ | H | H | H | H | H | H | O |
| Lₐ₉₉ | Aₙ₁₃ | H | CD₃ | H | H | H | H | H | H | O |
| Lₐ₁₀₀ | Aₙ₃₁ | H | CD₃ | H | H | H | H | H | H | O |
| Lₐ₁₀₁ | Aₙ₃₄ | H | CD₃ | H | H | H | H | H | H | O |
| Lₐ₁₀₂ | Aₙ₅₃ | H | CD₃ | H | H | H | H | H | H | O |
| Lₐ₁₀₃ | Aₙ₅₇ | H | CD₃ | H | H | H | H | H | H | O |
| Lₐ₁₀₄ | Aₙ₅₈ | H | CD₃ | H | H | H | H | H | H | O |
| Lₐ₁₀₅ | Aₙ₅₉ | H | CD₃ | H | H | H | H | H | H | O |
| Lₐ₁₀₆ | Aₙ₆₀ | H | CD₃ | H | H | H | H | H | H | O |
| Lₐ₁₀₇ | Aₙ₈₄ | H | CD₃ | H | H | H | H | H | H | O |
| Lₐ₁₀₈ | Aₙ₉₁ | H | CD₃ | H | H | H | H | H | H | O |
| Lₐ₁₀₉ | Aₙ₉₃ | H | CD₃ | H | H | H | H | H | H | O |
| Lₐ₁₁₀ | Aₙ₉₄ | H | CD₃ | H | H | H | H | H | H | O |
| Lₐ₁₁₁ | Aₙ₉₆ | H | CD₃ | H | H | H | H | H | H | O |
| Lₐ₁₁₂ | Aₙ₁ | H | Rₛ₁ | H | H | H | H | H | H | O |
| Lₐ₁₁₃ | Aₙ₁₀ | H | Rₛ₁ | H | H | H | H | H | H | O |
| Lₐ₁₁₄ | Aₙ₁₃ | H | Rₛ₁ | H | H | H | H | H | H | O |
| Lₐ₁₁₅ | Aₙ₃₁ | H | Rₛ₁ | H | H | H | H | H | H | O |
| Lₐ₁₁₆ | Aₙ₃₄ | H | Rₛ₁ | H | H | H | H | H | H | O |
| Lₐ₁₁₇ | Aₙ₅₃ | H | Rₛ₁ | H | H | H | H | H | H | O |
| Lₐ₁₁₈ | Aₙ₅₇ | H | Rₛ₁ | H | H | H | H | H | H | O |
| Lₐ₁₁₉ | Aₙ₅₈ | H | Rₛ₁ | H | H | H | H | H | H | O |
| Lₐ₁₂₀ | Aₙ₅₉ | H | Rₛ₁ | H | H | H | H | H | H | O |
| Lₐ₁₂₁ | Aₙ₆₀ | H | Rₛ₁ | H | H | H | H | H | H | O |
| Lₐ₁₂₂ | Aₙ₈₄ | H | Rₛ₁ | H | H | H | H | H | H | O |
| Lₐ₁₂₃ | Aₙ₉₁ | H | Rₛ₁ | H | H | H | H | H | H | O |
| Lₐ₁₂₄ | Aₙ₉₃ | H | Rₛ₁ | H | H | H | H | H | H | O |
| Lₐ₁₂₅ | Aₙ₉₄ | H | Rₛ₁ | H | H | H | H | H | H | O |
| Lₐ₁₂₆ | Aₙ₉₆ | H | Rₛ₁ | H | H | H | H | H | H | O |
| Lₐ₁₂₇ | Aₙ₁ | H | Rₛ₂ | H | H | H | H | H | H | O |
| Lₐ₁₂₈ | Aₙ₁₀ | H | Rₛ₂ | H | H | H | H | H | H | O |
| Lₐ₁₂₉ | Aₙ₁₃ | H | Rₛ₂ | H | H | H | H | H | H | O |
| Lₐ₁₃₀ | Aₙ₃₁ | H | Rₛ₂ | H | H | H | H | H | H | O |
| Lₐ₁₃₁ | Aₙ₃₄ | H | Rₛ₂ | H | H | H | H | H | H | O |
| Lₐ₁₃₂ | Aₙ₅₃ | H | Rₛ₂ | H | H | H | H | H | H | O |
| Lₐ₁₃₃ | Aₙ₅₇ | H | Rₛ₂ | H | H | H | H | H | H | O |
| Lₐ₁₃₄ | Aₙ₅₈ | H | Rₛ₂ | H | H | H | H | H | H | O |
| Lₐ₁₃₅ | Aₙ₅₉ | H | Rₛ₂ | H | H | H | H | H | H | O |
| Lₐ₁₃₆ | Aₙ₆₀ | H | Rₛ₂ | H | H | H | H | H | H | O |
| Lₐ₁₃₇ | Aₙ₈₄ | H | Rₛ₂ | H | H | H | H | H | H | O |
| Lₐ₁₃₈ | Aₙ₉₁ | H | Rₛ₂ | H | H | H | H | H | H | O |
| Lₐ₁₃₉ | Aₙ₉₃ | H | Rₛ₂ | H | H | H | H | H | H | O |
| Lₐ₁₄₀ | Aₙ₉₄ | H | Rₛ₂ | H | H | H | H | H | H | O |
| Lₐ₁₄₁ | Aₙ₉₆ | H | Rₛ₂ | H | H | H | H | H | H | O |
| Lₐ₁₄₂ | Aₙ₁ | H | Rₛ₃ | H | H | H | H | H | H | O |
| Lₐ₁₄₃ | Aₙ₁₀ | H | Rₛ₃ | H | H | H | H | H | H | O |
| Lₐ₁₄₄ | Aₙ₁₃ | H | Rₛ₃ | H | H | H | H | H | H | O |
| Lₐ₁₄₅ | Aₙ₃₁ | H | Rₛ₃ | H | H | H | H | H | H | O |
| Lₐ₁₄₆ | Aₙ₃₄ | H | Rₛ₃ | H | H | H | H | H | H | O |
| Lₐ₁₄₇ | Aₙ₅₃ | H | Rₛ₃ | H | H | H | H | H | H | O |
| Lₐ₁₄₈ | Aₙ₅₇ | H | Rₛ₃ | H | H | H | H | H | H | O |
| Lₐ₁₄₉ | Aₙ₅₈ | H | Rₛ₃ | H | H | H | H | H | H | O |
| Lₐ₁₅₀ | Aₙ₅₉ | H | Rₛ₃ | H | H | H | H | H | H | O |
| Lₐ₁₅₁ | Aₙ₆₀ | H | Rₛ₃ | H | H | H | H | H | H | O |
| Lₐ₁₅₂ | Aₙ₈₄ | H | Rₛ₃ | H | H | H | H | H | H | O |
| Lₐ₁₅₃ | Aₙ₉₁ | H | Rₛ₃ | H | H | H | H | H | H | O |
| Lₐ₁₅₄ | Aₙ₉₃ | H | Rₛ₃ | H | H | H | H | H | H | O |
| Lₐ₁₅₅ | Aₙ₉₄ | H | Rₛ₃ | H | H | H | H | H | H | O |
| Lₐ₁₅₆ | Aₙ₉₆ | H | Rₛ₃ | H | H | H | H | H | H | O |
| Lₐ₁₅₇ | Aₙ₁ | H | Rₛ₄ | H | H | H | H | H | H | O |
| Lₐ₁₅₈ | Aₙ₁₀ | H | Rₛ₄ | H | H | H | H | H | H | O |
| Lₐ₁₅₉ | Aₙ₁₃ | H | Rₛ₄ | H | H | H | H | H | H | O |
| Lₐ₁₆₀ | Aₙ₃₁ | H | Rₛ₄ | H | H | H | H | H | H | O |
| Lₐ₁₆₁ | Aₙ₃₄ | H | Rₛ₄ | H | H | H | H | H | H | O |
| Lₐ₁₆₂ | Aₙ₅₃ | H | Rₛ₄ | H | H | H | H | H | H | O |
| Lₐ₁₆₃ | Aₙ₅₇ | H | Rₛ₄ | H | H | H | H | H | H | O |
| Lₐ₁₆₄ | Aₙ₅₈ | H | Rₛ₄ | H | H | H | H | H | H | O |
| Lₐ₁₆₅ | Aₙ₅₉ | H | Rₛ₄ | H | H | H | H | H | H | O |
| Lₐ₁₆₆ | Aₙ₆₀ | H | Rₛ₄ | H | H | H | H | H | H | O |
| Lₐ₁₆₇ | Aₙ₈₄ | H | Rₛ₄ | H | H | H | H | H | H | O |
| Lₐ₁₆₈ | Aₙ₉₁ | H | Rₛ₄ | H | H | H | H | H | H | O |
| Lₐ₁₆₉ | Aₙ₉₃ | H | Rₛ₄ | H | H | H | H | H | H | O |
| Lₐ₁₇₀ | Aₙ₉₄ | H | Rₛ₄ | H | H | H | H | H | H | O |
| Lₐ₁₇₁ | Aₙ₉₆ | H | Rₛ₄ | H | H | H | H | H | H | O |
| Lₐ₁₇₂ | Aₙ₁ | H | Rₛ₅ | H | H | H | H | H | H | O |
| Lₐ₁₇₃ | Aₙ₁₀ | H | Rₛ₅ | H | H | H | H | H | H | O |
| Lₐ₁₇₄ | Aₙ₁₃ | H | Rₛ₅ | H | H | H | H | H | H | O |
| Lₐ₁₇₅ | Aₙ₃₁ | H | Rₛ₅ | H | H | H | H | H | H | O |
| Lₐ₁₇₆ | Aₙ₃₄ | H | Rₛ₅ | H | H | H | H | H | H | O |
| Lₐ₁₇₇ | Aₙ₅₃ | H | Rₛ₅ | H | H | H | H | H | H | O |
| Lₐ₁₇₈ | Aₙ₅₇ | H | Rₛ₅ | H | H | H | H | H | H | O |
| Lₐ₁₇₉ | Aₙ₅₈ | H | Rₛ₅ | H | H | H | H | H | H | O |
| Lₐ₁₈₀ | Aₙ₅₉ | H | Rₛ₅ | H | H | H | H | H | H | O |
| Lₐ₁₈₁ | Aₙ₆₀ | H | Rₛ₅ | H | H | H | H | H | H | O |
| Lₐ₁₈₂ | Aₙ₈₄ | H | Rₛ₅ | H | H | H | H | H | H | O |
| Lₐ₁₈₃ | Aₙ₉₁ | H | Rₛ₅ | H | H | H | H | H | H | O |
| Lₐ₁₈₄ | Aₙ₉₃ | H | Rₛ₅ | H | H | H | H | H | H | O |
| Lₐ₁₈₅ | Aₙ₉₄ | H | Rₛ₅ | H | H | H | H | H | H | O |
| Lₐ₁₈₆ | Aₙ₉₆ | H | Rₛ₅ | H | H | H | H | H | H | O |
| Lₐ₁₈₇ | Aₙ₁ | H | Rₛ₆ | H | H | H | H | H | H | O |
| Lₐ₁₈₈ | Aₙ₁₀ | H | Rₛ₆ | H | H | H | H | H | H | O |
| Lₐ₁₈₉ | Aₙ₁₃ | H | Rₛ₆ | H | H | H | H | H | H | O |
| Lₐ₁₉₀ | Aₙ₃₁ | H | Rₛ₆ | H | H | H | H | H | H | O |
| Lₐ₁₉₁ | Aₙ₃₄ | H | Rₛ₆ | H | H | H | H | H | H | O |
| Lₐ₁₉₂ | Aₙ₅₃ | H | Rₛ₆ | H | H | H | H | H | H | O |
| Lₐ₁₉₃ | Aₙ₅₇ | H | Rₛ₆ | H | H | H | H | H | H | O |
| Lₐ₁₉₄ | Aₙ₅₈ | H | Rₛ₆ | H | H | H | H | H | H | O |
| Lₐ₁₉₅ | Aₙ₅₉ | H | Rₛ₆ | H | H | H | H | H | H | O |
| Lₐ₁₉₆ | Aₙ₆₀ | H | Rₛ₆ | H | H | H | H | H | H | O |
| Lₐ₁₉₇ | Aₙ₈₄ | H | Rₛ₆ | H | H | H | H | H | H | O |
| Lₐ₁₉₈ | Aₙ₉₁ | H | Rₛ₆ | H | H | H | H | H | H | O |
| Lₐ₁₉₉ | Aₙ₉₃ | H | Rₛ₆ | H | H | H | H | H | H | O |
| Lₐ₂₀₀ | Aₙ₉₄ | H | Rₛ₆ | H | H | H | H | H | H | O |
| Lₐ₂₀₁ | Aₙ₉₆ | H | Rₛ₆ | H | H | H | H | H | H | O |
| Lₐ₂₀₂ | Aₙ₁ | H | H | H | H | H | H | H | CN | O |
| Lₐ₂₀₃ | Aₙ₂ | H | H | H | H | H | H | H | CN | O |
| Lₐ₂₀₄ | Aₙ₃ | H | H | H | H | H | H | H | CN | O |
| Lₐ₂₀₅ | Aₙ₄ | H | H | H | H | H | H | H | CN | O |
| Lₐ₂₀₆ | Aₙ₅ | H | H | H | H | H | H | H | CN | O |
| Lₐ₂₀₇ | Aₙ₆ | H | H | H | H | H | H | H | CN | O |
| Lₐ₂₀₈ | Aₙ₇ | H | H | H | H | H | H | H | CN | O |
| Lₐ₂₀₉ | Aₙ₈ | H | H | H | H | H | H | H | CN | O |
| Lₐ₂₁₀ | Aₙ₉ | H | H | H | H | H | H | H | CN | O |
| Lₐ₂₁₁ | Aₙ₁₀ | H | H | H | H | H | H | H | CN | O |
| Lₐ₂₁₂ | Aₙ₁₁ | H | H | H | H | H | H | H | CN | O |
| Lₐ₂₁₃ | Aₙ₁₂ | H | H | H | H | H | H | H | CN | O |
| Lₐ₂₁₄ | Aₙ₁₃ | H | H | H | H | H | H | H | CN | O |
| Lₐ₂₁₅ | Aₙ₁₄ | H | H | H | H | H | H | H | CN | O |
| Lₐ₂₁₆ | Aₙ₁₅ | H | H | H | H | H | H | H | CN | O |
| Lₐ₂₁₇ | Aₙ₁₆ | H | H | H | H | H | H | H | CN | O |
| Lₐ₂₁₈ | Aₙ₁₇ | H | H | H | H | H | H | H | CN | O |
| Lₐ₂₁₉ | Aₙ₁₈ | H | H | H | H | H | H | H | CN | O |
| Lₐ₂₂₀ | Aₙ₁₉ | H | H | H | H | H | H | H | CN | O |
| Lₐ₂₂₁ | Aₙ₂₀ | H | H | H | H | H | H | H | CN | O |
| Lₐ₂₂₂ | Aₙ₂₁ | H | H | H | H | H | H | H | CN | O |
| Lₐ₂₂₃ | Aₙ₂₂ | H | H | H | H | H | H | H | CN | O |
| Lₐ₂₂₄ | Aₙ₂₃ | H | H | H | H | H | H | H | CN | O |
| Lₐ₂₂₅ | Aₙ₂₄ | H | H | H | H | H | H | H | CN | O |
| Lₐ₂₂₆ | Aₙ₂₅ | H | H | H | H | H | H | H | CN | O |
| Lₐ₂₂₇ | Aₙ₂₆ | H | H | H | H | H | H | H | CN | O |
| Lₐ₂₂₈ | Aₙ₂₇ | H | H | H | H | H | H | H | CN | O |
| Lₐ₂₂₉ | Aₙ₂₈ | H | H | H | H | H | H | H | CN | O |
| Lₐ₂₃₀ | Aₙ₂₉ | H | H | H | H | H | H | H | CN | O |
| Lₐ₂₃₁ | Aₙ₃₀ | H | H | H | H | H | H | H | CN | O |
| Lₐ₂₃₂ | Aₙ₃₁ | H | H | H | H | H | H | H | CN | O |
| Lₐ₂₃₃ | Aₙ₃₂ | H | H | H | H | H | H | H | CN | O |
| Lₐ₂₃₄ | Aₙ₃₃ | H | H | H | H | H | H | H | CN | O |
| Lₐ₂₃₅ | Aₙ₃₄ | H | H | H | H | H | H | H | CN | O |
| Lₐ₂₃₆ | Aₙ₃₅ | H | H | H | H | H | H | H | CN | O |
| Lₐ₂₃₇ | Aₙ₃₆ | H | H | H | H | H | H | H | CN | O |
| Lₐ₂₃₈ | Aₙ₃₇ | H | H | H | H | H | H | H | CN | O |
| Lₐ₂₃₉ | Aₙ₃₈ | H | H | H | H | H | H | H | CN | O |
| Lₐ₂₄₀ | Aₙ₃₉ | H | H | H | H | H | H | H | CN | O |
| Lₐ₂₄₁ | Aₙ₄₀ | H | H | H | H | H | H | H | CN | O |
| Lₐ₂₄₂ | Aₙ₄₁ | H | H | H | H | H | H | H | CN | O |
| Lₐ₂₄₃ | Aₙ₄₂ | H | H | H | H | H | H | H | CN | O |
| Lₐ₂₄₄ | Aₙ₄₃ | H | H | H | H | H | H | H | CN | O |
| Lₐ₂₄₅ | Aₙ₄₄ | H | H | H | H | H | H | H | CN | O |
| Lₐ₂₄₆ | Aₙ₄₅ | H | H | H | H | H | H | H | CN | O |
| Lₐ₂₄₇ | Aₙ₄₆ | H | H | H | H | H | H | H | CN | O |
| Lₐ₂₄₈ | Aₙ₄₇ | H | H | H | H | H | H | H | CN | O |
| Lₐ₂₄₉ | Aₙ₄₈ | H | H | H | H | H | H | H | CN | O |
| Lₐ₂₅₀ | Aₙ₄₉ | H | H | H | H | H | H | H | CN | O |
| Lₐ₂₅₁ | Aₙ₅₀ | H | H | H | H | H | H | H | CN | O |
| Lₐ₂₅₂ | Aₙ₅₁ | H | H | H | H | H | H | H | CN | O |
| Lₐ₂₅₃ | Aₙ₅₂ | H | H | H | H | H | H | H | CN | O |
| Lₐ₂₅₄ | Aₙ₅₃ | H | H | H | H | H | H | H | CN | O |
| Lₐ₂₅₅ | Aₙ₅₄ | H | H | H | H | H | H | H | CN | O |
| Lₐ₂₅₆ | Aₙ₅₅ | H | H | H | H | H | H | H | CN | O |
| Lₐ₂₅₇ | Aₙ₅₆ | H | H | H | H | H | H | H | CN | O |
| Lₐ₂₅₈ | Aₙ₅₇ | H | H | H | H | H | H | H | CN | O |
| Lₐ₂₅₉ | Aₙ₅₈ | H | H | H | H | H | H | H | CN | O |
| Lₐ₂₆₀ | Aₙ₅₉ | H | H | H | H | H | H | H | CN | O |
| Lₐ₂₆₁ | Aₙ₆₀ | H | H | H | H | H | H | H | CN | O |
| Lₐ₂₆₂ | Aₙ₆₁ | H | H | H | H | H | H | H | CN | O |
| Lₐ₂₆₃ | Aₙ₆₂ | H | H | H | H | H | H | H | CN | O |
| Lₐ₂₆₄ | Aₙ₆₃ | H | H | H | H | H | H | H | CN | O |
| Lₐ₂₆₅ | Aₙ₆₄ | H | H | H | H | H | H | H | CN | O |
| Lₐ₂₆₆ | Aₙ₆₅ | H | H | H | H | H | H | H | CN | O |
| Lₐ₂₆₇ | Aₙ₆₆ | H | H | H | H | H | H | H | CN | O |
| Lₐ₂₆₈ | Aₙ₆₇ | H | H | H | H | H | H | H | CN | O |
| Lₐ₂₆₉ | Aₙ₆₈ | H | H | H | H | H | H | H | CN | O |
| Lₐ₂₇₀ | Aₙ₆₉ | H | H | H | H | H | H | H | CN | O |
| Lₐ₂₇₁ | Aₙ₇₀ | H | H | H | H | H | H | H | CN | O |
| Lₐ₂₇₂ | Aₙ₇₁ | H | H | H | H | H | H | H | CN | O |
| Lₐ₂₇₃ | Aₙ₇₂ | H | H | H | H | H | H | H | CN | O |
| Lₐ₂₇₄ | Aₙ₇₃ | H | H | H | H | H | H | H | CN | O |
| Lₐ₂₇₅ | Aₙ₇₄ | H | H | H | H | H | H | H | CN | O |
| Lₐ₂₇₆ | Aₙ₇₅ | H | H | H | H | H | H | H | CN | O |
| Lₐ₂₇₇ | Aₙ₇₆ | H | H | H | H | H | H | H | CN | O |
| Lₐ₂₇₈ | Aₙ₇₇ | H | H | H | H | H | H | H | CN | O |
| Lₐ₂₇₉ | Aₙ₇₈ | H | H | H | H | H | H | H | CN | O |
| Lₐ₂₈₀ | Aₙ₇₉ | H | H | H | H | H | H | H | CN | O |
| Lₐ₂₈₁ | Aₙ₈₀ | H | H | H | H | H | H | H | CN | O |
| Lₐ₂₈₂ | Aₙ₈₁ | H | H | H | H | H | H | H | CN | O |
| Lₐ₂₈₃ | Aₙ₈₂ | H | H | H | H | H | H | H | CN | O |
| Lₐ₂₈₄ | Aₙ₈₃ | H | H | H | H | H | H | H | CN | O |
| Lₐ₂₈₅ | Aₙ₈₄ | H | H | H | H | H | H | H | CN | O |
| Lₐ₂₈₆ | Aₙ₈₅ | H | H | H | H | H | H | H | CN | O |
| Lₐ₂₈₇ | Aₙ₈₆ | H | H | H | H | H | H | H | CN | O |
| Lₐ₂₈₈ | Aₙ₈₇ | H | H | H | H | H | H | H | CN | O |
| Lₐ₂₈₉ | Aₙ₈₈ | H | H | H | H | H | H | H | CN | O |
| Lₐ₂₉₀ | Aₙ₈₉ | H | H | H | H | H | H | H | CN | O |
| Lₐ₂₉₁ | Aₙ₉₀ | H | H | H | H | H | H | H | CN | O |
| Lₐ₂₉₂ | Aₙ₉₁ | H | H | H | H | H | H | H | CN | O |
| Lₐ₂₉₃ | Aₙ₉₂ | H | H | H | H | H | H | H | CN | O |
| Lₐ₂₉₄ | Aₙ₉₃ | H | H | H | H | H | H | H | CN | O |
| Lₐ₂₉₅ | Aₙ₉₄ | H | H | H | H | H | H | H | CN | O |
| Lₐ₂₉₆ | Aₙ₉₅ | H | H | H | H | H | H | H | CN | O |
| Lₐ₂₉₇ | Aₙ₉₆ | H | H | H | H | H | H | H | CN | O |
| Lₐ₂₉₈ | Aₙ₁ | H | CD₃ | H | H | H | H | H | CN | O |
| Lₐ₂₉₉ | Aₙ₁₀ | H | CD₃ | H | H | H | H | H | CN | O |
| Lₐ₃₀₀ | Aₙ₁₃ | H | CD₃ | H | H | H | H | H | CN | O |
| Lₐ₃₀₁ | Aₙ₃₁ | H | CD₃ | H | H | H | H | H | CN | O |
| Lₐ₃₀₂ | Aₙ₃₄ | H | CD₃ | H | H | H | H | H | CN | O |
| Lₐ₃₀₃ | Aₙ₅₃ | H | CD₃ | H | H | H | H | H | CN | O |
| Lₐ₃₀₄ | Aₙ₅₇ | H | CD₃ | H | H | H | H | H | CN | O |
| Lₐ₃₀₅ | Aₙ₅₈ | H | CD₃ | H | H | H | H | H | CN | O |
| Lₐ₃₀₆ | Aₙ₅₉ | H | CD₃ | H | H | H | H | H | CN | O |
| Lₐ₃₀₇ | Aₙ₆₀ | H | CD₃ | H | H | H | H | H | CN | O |
| Lₐ₃₀₈ | Aₙ₈₄ | H | CD₃ | H | H | H | H | H | CN | O |
| Lₛ₃₀₉ | Aₙ₉₁ | H | CD₃ | H | H | H | H | H | CN | O |
| Lₐ₃₁₀ | Aₙ₉₃ | H | CD₃ | H | H | H | H | H | CN | O |
| Lₐ₃₁₁ | Aₙ₉₄ | H | CD₃ | H | H | H | H | H | CN | O |
| Lₐ₃₁₂ | Aₙ₉₆ | H | CD₃ | H | H | H | H | H | CN | O |
| Lₐ₃₁₃ | Aₙ₁ | H | Rₛ₁ | H | H | H | H | H | CN | O |
| Lₐ₃₁₄ | Aₙ₁₀ | H | Rₛ₁ | H | H | H | H | H | CN | O |
| Lₐ₃₁₅ | Aₙ₁₃ | H | Rₛ₁ | H | H | H | H | H | CN | O |
| Lₐ₃₁₆ | Aₙ₃₁ | H | Rₛ₁ | H | H | H | H | H | CN | O |
| Lₐ₃₁₇ | Aₙ₃₄ | H | Rₛ₁ | H | H | H | H | H | CN | O |
| Lₐ₃₁₈ | Aₙ₅₃ | H | Rₛ₁ | H | H | H | H | H | CN | O |
| Lₐ₃₁₉ | Aₙ₅₇ | H | Rₛ₁ | H | H | H | H | H | CN | O |
| Lₐ₃₂₀ | Aₙ₅₈ | H | Rₛ₁ | H | H | H | H | H | CN | O |
| Lₐ₃₂₁ | Aₙ₅₉ | H | Rₛ₁ | H | H | H | H | H | CN | O |
| Lₐ₃₂₂ | Aₙ₆₀ | H | Rₛ₁ | H | H | H | H | H | CN | O |
| Lₐ₃₂₃ | Aₙ₈₄ | H | Rₛ₁ | H | H | H | H | H | CN | O |
| Lₐ₃₂₄ | Aₙ₉₁ | H | Rₛ₁ | H | H | H | H | H | CN | O |
| Lₐ₃₂₅ | Aₙ₉₃ | H | Rₛ₁ | H | H | H | H | H | CN | O |
| Lₐ₃₂₆ | Aₙ₉₄ | H | Rₛ₁ | H | H | H | H | H | CN | O |
| Lₐ₃₂₇ | Aₙ₉₆ | H | Rₛ₁ | H | H | H | H | H | CN | O |
| Lₐ₃₂₈ | Aₙ₁ | H | Rₛ₂ | H | H | H | H | H | CN | O |
| Lₐ₃₂₉ | Aₙ₁₀ | H | Rₛ₂ | H | H | H | H | H | CN | O |
| Lₐ₃₃₀ | Aₙ₁₃ | H | Rₛ₂ | H | H | H | H | H | CN | O |
| Lₐ₃₃₁ | Aₙ₃₁ | H | Rₛ₂ | H | H | H | H | H | CN | O |
| Lₐ₃₃₂ | Aₙ₃₄ | H | Rₛ₂ | H | H | H | H | H | CN | O |
| Lₐ₃₃₃ | Aₙ₅₃ | H | Rₛ₂ | H | H | H | H | H | CN | O |
| Lₐ₃₃₄ | Aₙ₅₇ | H | Rₛ₂ | H | H | H | H | H | CN | O |
| Lₐ₃₃₅ | Aₙ₅₈ | H | Rₛ₂ | H | H | H | H | H | CN | O |
| Lₐ₃₃₆ | Aₙ₅₉ | H | Rₛ₂ | H | H | H | H | H | CN | O |
| Lₐ₃₃₇ | Aₙ₆₀ | H | Rₛ₂ | H | H | H | H | H | CN | O |
| Lₐ₃₃₈ | Aₙ₈₄ | H | Rₛ₂ | H | H | H | H | H | CN | O |
| Lₐ₃₃₉ | Aₙ₉₁ | H | Rₛ₂ | H | H | H | H | H | CN | O |
| Lₐ₃₄₀ | Aₙ₉₃ | H | Rₛ₂ | H | H | H | H | H | CN | O |
| Lₐ₃₄₁ | Aₙ₉₄ | H | Rₛ₂ | H | H | H | H | H | CN | O |
| Lₐ₃₄₂ | Aₙ₉₆ | H | Rₛ₂ | H | H | H | H | H | CN | O |
| Lₐ₃₄₃ | Aₙ₁ | H | Rₛ₃ | H | H | H | H | H | CN | O |
| Lₐ₃₄₄ | Aₙ₁₀ | H | Rₛ₃ | H | H | H | H | H | CN | O |
| Lₐ₃₄₅ | Aₙ₁₃ | H | Rₛ₃ | H | H | H | H | H | CN | O |
| Lₐ₃₄₆ | Aₙ₃₁ | H | Rₛ₃ | H | H | H | H | H | CN | O |
| Lₐ₃₄₇ | Aₙ₃₄ | H | Rₛ₃ | H | H | H | H | H | CN | O |
| Lₐ₃₄₈ | Aₙ₅₃ | H | Rₛ₃ | H | H | H | H | H | CN | O |
| Lₐ₃₄₉ | Aₙ₅₇ | H | Rₛ₃ | H | H | H | H | H | CN | O |
| Lₐ₃₅₀ | Aₙ₅₈ | H | Rₛ₃ | H | H | H | H | H | CN | O |
| Lₐ₃₅₁ | Aₙ₅₉ | H | Rₛ₃ | H | H | H | H | H | CN | O |
| Lₐ₃₅₂ | Aₙ₆₀ | H | Rₛ₃ | H | H | H | H | H | CN | O |
| Lₐ₃₅₃ | Aₙ₈₄ | H | Rₛ₃ | H | H | H | H | H | CN | O |
| Lₐ₃₅₄ | Aₙ₉₁ | H | Rₛ₃ | H | H | H | H | H | CN | O |
| Lₐ₃₅₅ | Aₙ₉₃ | H | Rₛ₃ | H | H | H | H | H | CN | O |
| Lₐ₃₅₆ | Aₙ₉₄ | H | Rₛ₃ | H | H | H | H | H | CN | O |
| Lₐ₃₅₇ | Aₙ₉₆ | H | Rₛ₃ | H | H | H | H | H | CN | O |
| Lₐ₃₅₈ | Aₙ₁ | H | Rₛ₄ | H | H | H | H | H | CN | O |
| Lₐ₃₅₉ | Aₙ₁₀ | H | Rₛ₄ | H | H | H | H | H | CN | O |
| Lₐ₃₆₀ | Aₙ₁₃ | H | Rₛ₄ | H | H | H | H | H | CN | O |
| Lₐ₃₆₁ | Aₙ₃₁ | H | Rₛ₄ | H | H | H | H | H | CN | O |
| Lₐ₃₆₂ | Aₙ₃₃ | H | Rₛ₄ | H | H | H | H | H | CN | O |
| Lₐ₃₆₃ | Aₙ₃₄ | H | Rₛ₄ | H | H | H | H | H | CN | O |
| Lₐ₃₆₄ | Aₙ₅₃ | H | Rₛ₄ | H | H | H | H | H | CN | O |
| Lₐ₃₆₅ | Aₙ₅₇ | H | Rₛ₄ | H | H | H | H | H | CN | O |
| Lₐ₃₆₆ | Aₙ₅₈ | H | Rₛ₄ | H | H | H | H | H | CN | O |
| Lₐ₃₆₇ | Aₙ₅₉ | H | Rₛ₄ | H | H | H | H | H | CN | O |
| Lₐ₃₆₈ | Aₙ₆₀ | H | Rₛ₄ | H | H | H | H | H | CN | O |
| Lₐ₃₆₉ | Aₙ₈₄ | H | Rₛ₄ | H | H | H | H | H | CN | O |
| Lₐ₃₇₀ | Aₙ₉₁ | H | Rₛ₄ | H | H | H | H | H | CN | O |
| Lₐ₃₇₁ | Aₙ₉₃ | H | Rₛ₄ | H | H | H | H | H | CN | O |
| Lₐ₃₇₂ | Aₙ₉₄ | H | Rₛ₄ | H | H | H | H | H | CN | O |
| Lₐ₃₇₃ | Aₙ₉₆ | H | Rₛ₄ | H | H | H | H | H | CN | O |
| Lₐ₃₇₄ | Aₙ₁ | H | H | H | H | H | H | CN | H | O |
| Lₐ₃₇₅ | Aₙ₂ | H | H | H | H | H | H | CN | H | O |
| Lₐ₃₇₆ | Aₙ₃ | H | H | H | H | H | H | CN | H | O |
| Lₐ₃₇₇ | Aₙ₄ | H | H | H | H | H | H | CN | H | O |
| Lₐ₃₇₈ | Aₙ₅ | H | H | H | H | H | H | CN | H | O |
| Lₐ₃₇₉ | Aₙ₆ | H | H | H | H | H | H | CN | H | O |
| Lₐ₃₈₀ | Aₙ₇ | H | H | H | H | H | H | CN | H | O |
| Lₐ₃₈₁ | Aₙ₈ | H | H | H | H | H | H | CN | H | O |
| Lₐ₃₈₂ | Aₙ₉ | H | H | H | H | H | H | CN | H | O |
| Lₐ₃₈₃ | Aₙ₁₀ | H | H | H | H | H | H | CN | H | O |
| Lₐ₃₈₄ | Aₙ₁₁ | H | H | H | H | H | H | CN | H | O |
| Lₐ₃₈₅ | Aₙ₁₂ | H | H | H | H | H | H | CN | H | O |
| Lₐ₃₈₆ | Aₙ₁₃ | H | H | H | H | H | H | CN | H | O |
| Lₐ₃₈₇ | Aₙ₁₄ | H | H | H | H | H | H | CN | H | O |
| Lₐ₃₈₈ | Aₙ₁₅ | H | H | H | H | H | H | CN | H | O |
| Lₐ₃₈₉ | Aₙ₁₆ | H | H | H | H | H | H | CN | H | O |
| Lₐ₃₉₀ | Aₙ₁₇ | H | H | H | H | H | H | CN | H | O |
| Lₐ₃₉₁ | Aₙ₁₈ | H | H | H | H | H | H | CN | H | O |
| Lₐ₃₉₂ | Aₙ₁₉ | H | H | H | H | H | H | CN | H | O |
| Lₐ₃₉₃ | Aₙ₂₀ | H | H | H | H | H | H | CN | H | O |
| Lₐ₃₉₄ | Aₙ₂₁ | H | H | H | H | H | H | CN | H | O |
| Lₐ₃₉₅ | Aₙ₂₂ | H | H | H | H | H | H | CN | H | O |
| Lₐ₃₉₆ | Aₙ₂₃ | H | H | H | H | H | H | CN | H | O |
| Lₐ₃₉₇ | Aₙ₂₄ | H | H | H | H | H | H | CN | H | O |
| Lₐ₃₉₈ | Aₙ₂₅ | H | H | H | H | H | H | CN | H | O |
| Lₐ₃₉₉ | Aₙ₂₆ | H | H | H | H | H | H | CN | H | O |
| Lₐ₄₀₀ | Aₙ₂₇ | H | H | H | H | H | H | CN | H | O |
| Lₐ₄₀₁ | Aₙ₂₈ | H | H | H | H | H | H | CN | H | O |
| Lₐ₄₀₂ | Aₙ₂₉ | H | H | H | H | H | H | CN | H | O |
| Lₐ₄₀₃ | Aₙ₃₀ | H | H | H | H | H | H | CN | H | O |
| Lₐ₄₀₄ | Aₙ₃₁ | H | H | H | H | H | H | CN | H | O |
| Lₐ₄₀₅ | Aₙ₃₂ | H | H | H | H | H | H | CN | H | O |
| Lₐ₄₀₆ | Aₙ₃₃ | H | H | H | H | H | H | CN | H | O |
| Lₐ₄₀₇ | Aₙ₃₄ | H | H | H | H | H | H | CN | H | O |
| Lₐ₄₀₈ | Aₙ₃₅ | H | H | H | H | H | H | CN | H | O |
| Lₐ₄₀₉ | Aₙ₃₆ | H | H | H | H | H | H | CN | H | O |
| Lₐ₄₁₀ | Aₙ₃₇ | H | H | H | H | H | H | CN | H | O |
| Lₐ₄₁₁ | Aₙ₃₈ | H | H | H | H | H | H | CN | H | O |
| Lₐ₄₁₂ | Aₙ₃₉ | H | H | H | H | H | H | CN | H | O |
| Lₐ₄₁₃ | Aₙ₄₀ | H | H | H | H | H | H | CN | H | O |
| Lₐ₄₁₄ | Aₙ₄₁ | H | H | H | H | H | H | CN | H | O |
| Lₐ₄₁₅ | Aₙ₄₂ | H | H | H | H | H | H | CN | H | O |
| Lₐ₄₁₆ | Aₙ₄₃ | H | H | H | H | H | H | CN | H | O |
| Lₐ₄₁₇ | Aₙ₄₄ | H | H | H | H | H | H | CN | H | O |
| Lₐ₄₁₈ | Aₙ₄₅ | H | H | H | H | H | H | CN | H | O |
| Lₐ₄₁₉ | Aₙ₄₆ | H | H | H | H | H | H | CN | H | O |
| Lₐ₄₂₀ | Aₙ₄₇ | H | H | H | H | H | H | CN | H | O |
| Lₐ₄₂₁ | Aₙ₄₈ | H | H | H | H | H | H | CN | H | O |
| Lₐ₄₂₂ | Aₙ₄₉ | H | H | H | H | H | H | CN | H | O |
| Lₐ₄₂₃ | Aₙ₅₀ | H | H | H | H | H | H | CN | H | O |
| Lₐ₄₂₄ | Aₙ₅₁ | H | H | H | H | H | H | CN | H | O |
| Lₐ₄₂₅ | Aₙ₅₂ | H | H | H | H | H | H | CN | H | O |
| Lₐ₄₂₆ | Aₙ₅₃ | H | H | H | H | H | H | CN | H | O |
| Lₐ₄₂₇ | Aₙ₅₄ | H | H | H | H | H | H | CN | H | O |
| Lₐ₄₂₈ | Aₙ₅₅ | H | H | H | H | H | H | CN | H | O |
| Lₐ₄₂₉ | Aₙ₅₆ | H | H | H | H | H | H | CN | H | O |
| Lₐ₄₃₀ | Aₙ₅₇ | H | H | H | H | H | H | CN | H | O |
| Lₐ₄₃₁ | Aₙ₅₈ | H | H | H | H | H | H | CN | H | O |
| Lₐ₄₃₂ | Aₙ₅₉ | H | H | H | H | H | H | CN | H | O |
| Lₐ₄₃₃ | Aₙ₆₀ | H | H | H | H | H | H | CN | H | O |
| Lₐ₄₃₄ | Aₙ₆₁ | H | H | H | H | H | H | CN | H | O |
| Lₐ₄₃₅ | Aₙ₆₂ | H | H | H | H | H | H | CN | H | O |
| Lₐ₄₃₆ | Aₙ₆₃ | H | H | H | H | H | H | CN | H | O |
| Lₐ₄₃₇ | Aₙ₆₄ | H | H | H | H | H | H | CN | H | O |
| Lₐ₄₃₈ | Aₙ₆₅ | H | H | H | H | H | H | CN | H | O |
| Lₐ₄₃₉ | Aₙ₆₆ | H | H | H | H | H | H | CN | H | O |
| Lₐ₄₄₀ | Aₙ₆₇ | H | H | H | H | H | H | CN | H | O |
| Lₐ₄₄₁ | Aₙ₆₈ | H | H | H | H | H | H | CN | H | O |
| Lₐ₄₄₂ | Aₙ₆₉ | H | H | H | H | H | H | CN | H | O |
| Lₐ₄₄₃ | Aₙ₇₀ | H | H | H | H | H | H | CN | H | O |
| Lₐ₄₄₄ | Aₙ₇₁ | H | H | H | H | H | H | CN | H | O |
| Lₐ₄₄₅ | Aₙ₇₂ | H | H | H | H | H | H | CN | H | O |
| Lₐ₄₄₆ | Aₙ₇₃ | H | H | H | H | H | H | CN | H | O |
| Lₐ₄₄₇ | Aₙ₇₄ | H | H | H | H | H | H | CN | H | O |
| Lₐ₄₄₈ | Aₙ₇₅ | H | H | H | H | H | H | CN | H | O |
| Lₐ₄₄₉ | Aₙ₇₆ | H | H | H | H | H | H | CN | H | O |
| Lₐ₄₅₀ | Aₙ₇₇ | H | H | H | H | H | H | CN | H | O |
| Lₐ₄₅₁ | Aₙ₇₈ | H | H | H | H | H | H | CN | H | O |
| Lₐ₄₅₂ | Aₙ₇₉ | H | H | H | H | H | H | CN | H | O |
| Lₐ₄₅₃ | Aₙ₈₀ | H | H | H | H | H | H | CN | H | O |
| Lₐ₄₅₄ | Aₙ₈₁ | H | H | H | H | H | H | CN | H | O |
| Lₐ₄₅₅ | Aₙ₈₂ | H | H | H | H | H | H | CN | H | O |
| Lₐ₄₅₆ | Aₙ₈₃ | H | H | H | H | H | H | CN | H | O |
| Lₐ₄₅₇ | Aₙ₈₄ | H | H | H | H | H | H | CN | H | O |
| Lₐ₄₅₈ | Aₙ₈₅ | H | H | H | H | H | H | CN | H | O |
| Lₐ₄₅₉ | Aₙ₈₆ | H | H | H | H | H | H | CN | H | O |
| Lₐ₄₆₀ | Aₙ₈₇ | H | H | H | H | H | H | CN | H | O |
| Lₐ₄₆₁ | Aₙ₈₈ | H | H | H | H | H | H | CN | H | O |
| Lₐ₄₆₂ | Aₙ₈₉ | H | H | H | H | H | H | CN | H | O |
| Lₐ₄₆₃ | Aₙ₉₀ | H | H | H | H | H | H | CN | H | O |
| Lₐ₄₆₄ | Aₙ₉₁ | H | H | H | H | H | H | CN | H | O |
| Lₐ₄₆₅ | Aₙ₉₂ | H | H | H | H | H | H | CN | H | O |
| Lₐ₄₆₆ | Aₙ₉₃ | H | H | H | H | H | H | CN | H | O |
| Lₐ₄₆₇ | Aₙ₉₄ | H | H | H | H | H | H | CN | H | O |
| Lₐ₄₆₈ | Aₙ₉₅ | H | H | H | H | H | H | CN | H | O |
| Lₐ₄₆₉ | Aₙ₉₆ | H | H | H | H | H | H | CN | H | O |
| Lₐ₄₇₀ | Aₙ₁ | H | CD₃ | H | H | H | H | CN | H | O |
| Lₐ₄₇₁ | Aₙ₁₀ | H | CD₃ | H | H | H | H | CN | H | O |
| Lₐ₄₇₂ | Aₙ₁₃ | H | CD₃ | H | H | H | H | CN | H | O |
| Lₐ₄₇₃ | Aₙ₃₁ | H | CD₃ | H | H | H | H | CN | H | O |
| Lₐ₄₇₄ | Aₙ₃₄ | H | CD₃ | H | H | H | H | CN | H | O |
| Lₐ₄₇₅ | Aₙ₅₃ | H | CD₃ | H | H | H | H | CN | H | O |
| Lₐ₄₇₆ | Aₙ₅₇ | H | CD₃ | H | H | H | H | CN | H | O |
| Lₐ₄₇₇ | Aₙ₅₈ | H | CD₃ | H | H | H | H | CN | H | O |
| Lₐ₄₇₈ | Aₙ₅₉ | H | CD₃ | H | H | H | H | CN | H | O |
| Lₐ₄₇₉ | Aₙ₆₀ | H | CD₃ | H | H | H | H | CN | H | O |
| Lₐ₄₈₀ | Aₙ₈₄ | H | CD₃ | H | H | H | H | CN | H | O |
| Lₐ₄₈₁ | Aₙ₉₁ | H | CD₃ | H | H | H | H | CN | H | O |
| Lₐ₄₈₂ | Aₙ₉₃ | H | CD₃ | H | H | H | H | CN | H | O |
| Lₐ₄₈₃ | Aₙ₉₄ | H | CD₃ | H | H | H | H | CN | H | O |
| Lₐ₄₈₄ | Aₙ₉₆ | H | CD₃ | H | H | H | H | CN | H | O |
| Lₐ₄₈₅ | Aₙ₁ | H | Rₛ₂ | H | H | H | H | CN | H | O |
| Lₐ₄₈₆ | Aₙ₁₀ | H | Rₛ₂ | H | H | H | H | CN | H | O |
| Lₐ₄₈₇ | Aₙ₁₃ | H | Rₛ₂ | H | H | H | H | CN | H | O |
| Lₐ₄₈₈ | Aₙ₃₁ | H | Rₛ₂ | H | H | H | H | CN | H | O |
| Lₐ₄₈₉ | Aₙ₃₄ | H | Rₛ₂ | H | H | H | H | CN | H | O |
| Lₐ₄₉₀ | Aₙ₅₃ | H | Rₛ₂ | H | H | H | H | CN | H | O |
| Lₐ₄₉₁ | Aₙ₅₇ | H | Rₛ₂ | H | H | H | H | CN | H | O |
| Lₐ₄₉₂ | Aₙ₅₈ | H | Rₛ₂ | H | H | H | H | CN | H | O |
| Lₐ₄₉₃ | Aₙ₅₉ | H | Rₛ₂ | H | H | H | H | CN | H | O |
| Lₐ₄₉₄ | Aₙ₆₀ | H | Rₛ₂ | H | H | H | H | CN | H | O |
| Lₐ₄₉₅ | Aₙ₈₄ | H | Rₛ₂ | H | H | H | H | CN | H | O |
| Lₐ₄₉₆ | Aₙ₉₁ | H | Rₛ₂ | H | H | H | H | CN | H | O |
| Lₐ₄₉₇ | Aₙ₉₃ | H | Rₛ₂ | H | H | H | H | CN | H | O |
| Lₐ₄₉₈ | Aₙ₉₄ | H | Rₛ₂ | H | H | H | H | CN | H | O |
| Lₐ₄₉₉ | Aₙ₉₆ | H | Rₛ₂ | H | H | H | H | CN | H | O |
| Lₐ₅₀₀ | Aₙ₁ | H | Rₛ₃ | H | H | H | H | CN | H | O |
| Lₐ₅₀₁ | Aₙ₁₀ | H | Rₛ₃ | H | H | H | H | CN | H | O |
| Lₐ₅₀₂ | Aₙ₁₃ | H | Rₛ₃ | H | H | H | H | CN | H | O |
| Lₐ₅₀₃ | Aₙ₃₁ | H | Rₛ₃ | H | H | H | H | CN | H | O |
| Lₐ₅₀₄ | Aₙ₃₄ | H | Rₛ₃ | H | H | H | H | CN | H | O |
| Lₐ₅₀₅ | Aₙ₅₃ | H | Rₛ₃ | H | H | H | H | CN | H | O |
| Lₐ₅₀₆ | Aₙ₅₇ | H | Rₛ₃ | H | H | H | H | CN | H | O |
| Lₐ₅₀₇ | Aₙ₅₈ | H | Rₛ₃ | H | H | H | H | CN | H | O |
| Lₐ₅₀₈ | Aₙ₅₉ | H | Rₛ₃ | H | H | H | H | CN | H | O |
| Lₐ₅₀₉ | Aₙ₆₀ | H | Rₛ₃ | H | H | H | H | CN | H | O |
| Lₐ₅₁₀ | Aₙ₈₄ | H | Rₛ₃ | H | H | H | H | CN | H | O |
| Lₐ₅₁₁ | Aₙ₉₁ | H | Rₛ₃ | H | H | H | H | CN | H | O |
| Lₐ₅₁₂ | Aₙ₉₃ | H | Rₛ₃ | H | H | H | H | CN | H | O |
| Lₐ₅₁₃ | Aₙ₉₄ | H | Rₛ₃ | H | H | H | H | CN | H | O |
| Lₐ₅₁₄ | Aₙ₉₆ | H | Rₛ₃ | H | H | H | H | CN | H | O |
| Lₐ₅₁₅ | Aₙ₁ | H | Rₛ₄ | H | H | H | H | CN | H | O |
| Lₐ₅₁₆ | Aₙ₁₀ | H | Rₛ₄ | H | H | H | H | CN | H | O |
| Lₐ₅₁₇ | Aₙ₁₃ | H | Rₛ₄ | H | H | H | H | CN | H | O |
| Lₐ₅₁₈ | Aₙ₃₁ | H | Rₛ₄ | H | H | H | H | CN | H | O |
| Lₐ₅₁₉ | Aₙ₃₄ | H | Rₛ₄ | H | H | H | H | CN | H | O |
| Lₐ₅₂₀ | Aₙ₅₃ | H | Rₛ₄ | H | H | H | H | CN | H | O |
| Lₐ₅₂₁ | Aₙ₅₇ | H | Rₛ₄ | H | H | H | H | CN | H | O |
| Lₐ₅₂₂ | Aₙ₅₈ | H | Rₛ₄ | H | H | H | H | CN | H | O |
| Lₐ₅₂₃ | Aₙ₅₉ | H | Rₛ₄ | H | H | H | H | CN | H | O |
| Lₐ₅₂₄ | Aₙ₆₀ | H | Rₛ₄ | H | H | H | H | CN | H | O |
| Lₐ₅₂₅ | Aₙ₈₄ | H | Rₛ₄ | H | H | H | H | CN | H | O |
| Lₐ₅₂₆ | Aₙ₉₁ | H | Rₛ₄ | H | H | H | H | CN | H | O |
| Lₐ₅₂₇ | Aₙ₉₃ | H | Rₛ₄ | H | H | H | H | CN | H | O |
| Lₐ₅₂₈ | Aₙ₉₄ | H | Rₛ₄ | H | H | H | H | CN | H | O |
| Lₐ₅₂₉ | Aₙ₉₆ | H | Rₛ₄ | H | H | H | H | CN | H | O |
| Lₐ₅₃₀ | Aₙ₁ | H | H | H | H | H | H | CN | D | O |
| Lₐ₅₃₁ | Aₙ₁ | H | H | H | H | H | H | CN | Rₛ₇ | O |
| Lₐ₅₃₂ | Aₙ₁ | H | H | H | H | H | H | CN | Rₛ₈ | O |
| Lₐ₅₃₃ | Aₙ₁ | H | H | H | H | H | H | CN | Rₛ₉ | O |
| Lₐ₅₃₄ | Aₙ₁ | H | H | H | H | H | H | CN | Rₛ₁₀ | O |
| Lₐ₅₃₅ | Aₙ₁ | H | H | H | H | H | H | CN | Rₛ₁₁ | O |
| Lₐ₅₃₆ | Aₙ₁ | H | H | H | H | H | H | CN | Rₛ₁₂ | O |
| Lₐ₅₃₇ | Aₙ₁ | H | H | H | H | H | H | CN | Rₛ₁₃ | O |
| Lₐ₅₃₈ | Aₙ₁ | H | H | H | H | H | H | CN | Rₛ₁₄ | O |
| Lₐ₅₃₉ | Aₙ₁ | H | H | H | H | H | H | CN | Rₛ₁₅ | O |
| Lₐ₅₄₀ | Aₙ₁ | H | H | H | H | H | H | CN | Rₛ₁₆ | O |
| Lₐ₅₄₁ | Aₙ₁ | H | H | H | H | H | H | CN | Rₛ₁₇ | O |
| Lₐ₅₄₂ | Aₙ₃₄ | H | H | H | H | H | H | CN | D | O |
| Lₐ₅₄₃ | Aₙ₃₄ | H | H | H | H | H | H | CN | Rₛ₇ | O |
| Lₐ₅₄₄ | Aₙ₃₄ | H | H | H | H | H | H | CN | Rₛ₈ | O |
| Lₐ₅₄₅ | Aₙ₃₄ | H | H | H | H | H | H | CN | Rₛ₉ | O |
| Lₐ₅₄₆ | Aₙ₃₄ | H | H | H | H | H | H | CN | Rₛ₁₀ | O |
| Lₐ₅₄₇ | Aₙ₃₄ | H | H | H | H | H | H | CN | Rₛ₁₁ | O |
| Lₐ₅₄₈ | Aₙ₃₄ | H | H | H | H | H | H | CN | Rₛ₁₂ | O |
| Lₐ₅₄₉ | Aₙ₃₄ | H | H | H | H | H | H | CN | Rₛ₁₃ | O |
| Lₐ₅₅₀ | Aₙ₃₄ | H | H | H | H | H | H | CN | Rₛ₁₄ | O |
| Lₐ₅₅₁ | Aₙ₃₄ | H | H | H | H | H | H | CN | Rₛ₁₅ | O |
| Lₐ₅₅₂ | Aₙ₃₄ | H | H | H | H | H | H | CN | Rₛ₁₆ | O |
| Lₐ₅₅₃ | Aₙ₃₄ | H | H | H | H | H | H | CN | Rₛ₁₇ | O |
| Lₐ₅₅₄ | Aₙ₁ | H | H | H | H | H | CN | H | H | O |
| Lₐ₅₅₅ | Aₙ₁₀ | H | H | H | H | H | CN | H | H | O |
| Lₐ₅₅₆ | Aₙ₁₃ | H | H | H | H | H | CN | H | H | O |
| Lₐ₅₅₇ | Aₙ₃₁ | H | H | H | H | H | CN | H | H | O |
| Lₐ₅₅₈ | Aₙ₃₄ | H | H | H | H | H | CN | H | H | O |
| Lₐ₅₅₉ | Aₙ₅₃ | H | H | H | H | H | CN | H | H | O |
| Lₐ₅₆₀ | Aₙ₅₇ | H | H | H | H | H | CN | H | H | O |
| Lₐ₅₆₁ | Aₙ₅₈ | H | H | H | H | H | CN | H | H | O |
| Lₐ₅₆₂ | Aₙ₅₉ | H | H | H | H | H | CN | H | H | O |
| Lₐ₅₆₃ | Aₙ₆₀ | H | H | H | H | H | CN | H | H | O |
| Lₐ₅₆₄ | Aₙ₈₄ | H | H | H | H | H | CN | H | H | O |
| Lₐ₅₆₅ | Aₙ₉₁ | H | H | H | H | H | CN | H | H | O |
| Lₐ₅₆₆ | Aₙ₉₃ | H | H | H | H | H | CN | H | H | O |
| Lₐ₅₆₇ | Aₙ₉₄ | H | H | H | H | H | CN | H | H | O |
| Lₐ₅₆₈ | Aₙ₁ | H | H | H | H | CN | H | H | H | O |
| Lₐ₅₆₉ | Aₙ₁₀ | H | H | H | H | CN | H | H | H | O |
| Lₐ₅₇₀ | Aₙ₁₃ | H | H | H | H | CN | H | H | H | O |
| Lₐ₅₇₁ | Aₙ₃₁ | H | H | H | H | CN | H | H | H | O |
| Lₐ₅₇₂ | Aₙ₃₄ | H | H | H | H | CN | H | H | H | O |
| Lₐ₅₇₃ | Aₙ₅₃ | H | H | H | H | CN | H | H | H | O |
| Lₐ₅₇₄ | Aₙ₅₇ | H | H | H | H | CN | H | H | H | O |
| Lₐ₅₇₅ | Aₙ₅₈ | H | H | H | H | CN | H | H | H | O |
| Lₐ₅₇₆ | Aₙ₅₉ | H | H | H | H | CN | H | H | H | O |
| Lₐ₅₇₇ | Aₙ₆₀ | H | H | H | H | CN | H | H | H | O |
| Lₐ₅₇₈ | Aₙ₈₄ | H | H | H | H | CN | H | H | H | O |
| Lₐ₅₇₉ | Aₙ₉₁ | H | H | H | H | CN | H | H | H | O |
| Lₐ₅₈₀ | Aₙ₉₃ | H | H | H | H | CN | H | H | H | O |
| Lₐ₅₈₁ | Aₙ₉₄ | H | H | H | H | CN | H | H | H | O |
| Lₐ₅₈₂ | Aₙ₁ | H | H | H | H | H | H | F | H | O |
| Lₐ₅₈₃ | Aₙ₂ | H | H | H | H | H | H | F | H | O |
| Lₐ₅₈₄ | Aₙ₃ | H | H | H | H | H | H | F | H | O |
| Lₐ₅₈₅ | Aₙ₄ | H | H | H | H | H | H | F | H | O |
| Lₐ₅₈₆ | Aₙ₅ | H | H | H | H | H | H | F | H | O |
| Lₐ₅₈₇ | Aₙ₆ | H | H | H | H | H | H | F | H | O |
| Lₐ₅₈₈ | Aₙ₇ | H | H | H | H | H | H | F | H | O |
| Lₐ₅₈₉ | Aₙ₈ | H | H | H | H | H | H | F | H | O |
| Lₐ₅₉₀ | Aₙ₉ | H | H | H | H | H | H | F | H | O |
| Lₐ₅₉₁ | Aₙ₁₀ | H | H | H | H | H | H | F | H | O |
| Lₐ₅₉₂ | Aₙ₁₁ | H | H | H | H | H | H | F | H | O |
| Lₐ₅₉₃ | Aₙ₁₂ | H | H | H | H | H | H | F | H | O |
| Lₐ₅₉₄ | Aₙ₁₃ | H | H | H | H | H | H | F | H | O |
| Lₐ₅₉₅ | Aₙ₁₄ | H | H | H | H | H | H | F | H | O |
| Lₐ₅₉₆ | Aₙ₁₅ | H | H | H | H | H | H | F | H | O |
| Lₐ₅₉₇ | Aₙ₁₆ | H | H | H | H | H | H | F | H | O |
| Lₐ₅₉₈ | Aₙ₁₇ | H | H | H | H | H | H | F | H | O |
| Lₐ₅₉₉ | Aₙ₁₈ | H | H | H | H | H | H | F | H | O |
| Lₐ₆₀₀ | Aₙ₁₉ | H | H | H | H | H | H | F | H | O |
| Lₐ₆₀₁ | Aₙ₂₀ | H | H | H | H | H | H | F | H | O |
| Lₐ₆₀₂ | Aₙ₂₁ | H | H | H | H | H | H | F | H | O |
| Lₐ₆₀₃ | Aₙ₂₂ | H | H | H | H | H | H | F | H | O |
| Lₐ₆₀₄ | Aₙ₂₃ | H | H | H | H | H | H | F | H | O |
| Lₐ₆₀₅ | Aₙ₂₄ | H | H | H | H | H | H | F | H | O |
| Lₐ₆₀₆ | Aₙ₂₅ | H | H | H | H | H | H | F | H | O |
| Lₐ₆₀₇ | Aₙ₂₆ | H | H | H | H | H | H | F | H | O |
| Lₐ₆₀₈ | Aₙ₂₇ | H | H | H | H | H | H | F | H | O |
| Lₐ₆₀₉ | Aₙ₂₈ | H | H | H | H | H | H | F | H | O |
| Lₐ₆₁₀ | Aₙ₂₉ | H | H | H | H | H | H | F | H | O |
| Lₐ₆₁₁ | Aₙ₃₀ | H | H | H | H | H | H | F | H | O |
| Lₐ₆₁₂ | Aₙ₃₁ | H | H | H | H | H | H | F | H | O |
| Lₐ₆₁₃ | Aₙ₃₂ | H | H | H | H | H | H | F | H | O |
| Lₐ₆₁₄ | Aₙ₃₃ | H | H | H | H | H | H | F | H | O |
| Lₐ₆₁₅ | Aₙ₃₄ | H | H | H | H | H | H | F | H | O |
| Lₐ₆₁₆ | Aₙ₃₅ | H | H | H | H | H | H | F | H | O |
| Lₐ₆₁₇ | Aₙ₃₆ | H | H | H | H | H | H | F | H | O |
| Lₐ₆₁₈ | Aₙ₃₇ | H | H | H | H | H | H | F | H | O |
| Lₐ₆₁₉ | Aₙ₃₈ | H | H | H | H | H | H | F | H | O |
| Lₐ₆₂₀ | Aₙ₃₉ | H | H | H | H | H | H | F | H | O |
| Lₐ₆₂₁ | Aₙ₄₀ | H | H | H | H | H | H | F | H | O |
| Lₐ₆₂₂ | Aₙ₄₁ | H | H | H | H | H | H | F | H | O |
| Lₐ₆₂₃ | Aₙ₄₂ | H | H | H | H | H | H | F | H | O |
| Lₐ₆₂₄ | Aₙ₄₃ | H | H | H | H | H | H | F | H | O |
| Lₐ₆₂₅ | Aₙ₄₄ | H | H | H | H | H | H | F | H | O |
| Lₐ₆₂₆ | Aₙ₄₅ | H | H | H | H | H | H | F | H | O |
| Lₐ₆₂₇ | Aₙ₄₆ | H | H | H | H | H | H | F | H | O |
| Lₐ₆₂₈ | Aₙ₄₇ | H | H | H | H | H | H | F | H | O |
| Lₐ₆₂₉ | Aₙ₄₈ | H | H | H | H | H | H | F | H | O |
| Lₐ₆₃₀ | Aₙ₄₉ | H | H | H | H | H | H | F | H | O |
| Lₐ₆₃₁ | Aₙ₅₀ | H | H | H | H | H | H | F | H | O |
| Lₐ₆₃₂ | Aₙ₅₁ | H | H | H | H | H | H | F | H | O |
| Lₐ₆₃₃ | Aₙ₅₂ | H | H | H | H | H | H | F | H | O |
| Lₐ₆₃₄ | Aₙ₅₃ | H | H | H | H | H | H | F | H | O |
| Lₐ₆₃₅ | Aₙ₅₄ | H | H | H | H | H | H | F | H | O |
| Lₐ₆₃₆ | Aₙ₅₅ | H | H | H | H | H | H | F | H | O |
| Lₐ₆₃₇ | Aₙ₅₆ | H | H | H | H | H | H | F | H | O |
| Lₐ₆₃₈ | Aₙ₅₇ | H | H | H | H | H | H | F | H | O |
| Lₐ₆₃₉ | Aₙ₅₈ | H | H | H | H | H | H | F | H | O |
| Lₐ₆₄₀ | Aₙ₅₉ | H | H | H | H | H | H | F | H | O |
| Lₐ₆₄₁ | Aₙ₆₀ | H | H | H | H | H | H | F | H | O |
| Lₐ₆₄₂ | Aₙ₆₁ | H | H | H | H | H | H | F | H | O |
| Lₐ₆₄₃ | Aₙ₆₂ | H | H | H | H | H | H | F | H | O |
| Lₐ₆₄₄ | Aₙ₆₃ | H | H | H | H | H | H | F | H | O |
| Lₐ₆₄₅ | Aₙ₆₄ | H | H | H | H | H | H | F | H | O |
| Lₐ₆₄₆ | Aₙ₆₅ | H | H | H | H | H | H | F | H | O |
| Lₐ₆₄₇ | Aₙ₆₆ | H | H | H | H | H | H | F | H | O |
| Lₐ₆₄₈ | Aₙ₆₇ | H | H | H | H | H | H | F | H | O |
| Lₐ₆₄₉ | Aₙ₆₈ | H | H | H | H | H | H | F | H | O |
| Lₐ₆₅₀ | Aₙ₆₉ | H | H | H | H | H | H | F | H | O |
| Lₐ₆₅₁ | Aₙ₇₀ | H | H | H | H | H | H | F | H | O |
| Lₐ₆₅₂ | Aₙ₇₁ | H | H | H | H | H | H | F | H | O |
| Lₐ₆₅₃ | Aₙ₇₂ | H | H | H | H | H | H | F | H | O |
| Lₐ₆₅₄ | Aₙ₇₃ | H | H | H | H | H | H | F | H | O |
| Lₐ₆₅₅ | Aₙ₇₄ | H | H | H | H | H | H | F | H | O |
| Lₐ₆₅₆ | Aₙ₇₅ | H | H | H | H | H | H | F | H | O |
| Lₐ₆₅₇ | Aₙ₇₆ | H | H | H | H | H | H | F | H | O |
| Lₐ₆₅₈ | Aₙ₇₇ | H | H | H | H | H | H | F | H | O |
| Lₐ₆₅₉ | Aₙ₇₈ | H | H | H | H | H | H | F | H | O |
| Lₐ₆₆₀ | Aₙ₇₉ | H | H | H | H | H | H | F | H | O |
| Lₐ₆₆₁ | Aₙ₈₀ | H | H | H | H | H | H | F | H | O |
| Lₐ₆₆₂ | Aₙ₈₁ | H | H | H | H | H | H | F | H | O |
| Lₐ₆₆₃ | Aₙ₈₂ | H | H | H | H | H | H | F | H | O |
| Lₐ₆₆₄ | Aₙ₈₃ | H | H | H | H | H | H | F | H | O |
| Lₐ₆₆₅ | Aₙ₈₄ | H | H | H | H | H | H | F | H | O |
| Lₐ₆₆₆ | Aₙ₈₅ | H | H | H | H | H | H | F | H | O |
| Lₐ₆₆₇ | Aₙ₈₆ | H | H | H | H | H | H | F | H | O |
| Lₐ₆₆₈ | Aₙ₈₇ | H | H | H | H | H | H | F | H | O |
| Lₐ₆₆₉ | Aₙ₈₈ | H | H | H | H | H | H | F | H | O |
| Lₐ₆₇₀ | Aₙ₈₉ | H | H | H | H | H | H | F | H | O |
| Lₐ₆₇₁ | Aₙ₉₀ | H | H | H | H | H | H | F | H | O |
| Lₐ₆₇₂ | Aₙ₉₁ | H | H | H | H | H | H | F | H | O |
| Lₐ₆₇₃ | Aₙ₉₂ | H | H | H | H | H | H | F | H | O |
| Lₐ₆₇₄ | Aₙ₉₃ | H | H | H | H | H | H | F | H | O |
| Lₐ₆₇₅ | Aₙ₉₄ | H | H | H | H | H | H | F | H | O |
| Lₐ₆₇₆ | Aₙ₉₅ | H | H | H | H | H | H | F | H | O |
| Lₐ₆₇₇ | Aₙ₉₆ | H | H | H | H | H | H | F | H | O |
| Lₐ₆₇₈ | Aₙ₁ | H | H | H | H | H | H | F | D | O |
| Lₐ₆₇₉ | Aₙ₁ | H | H | H | H | H | H | F | Rₛ₇ | O |
| Lₐ₆₈₀ | Aₙ₁ | H | H | H | H | H | H | F | Rₛ₈ | O |
| Lₐ₆₈₁ | Aₙ₁ | H | H | H | H | H | H | F | Rₛ₉ | O |
| Lₐ₆₈₂ | Aₙ₁ | H | H | H | H | H | H | F | Rₛ₁₀ | O |
| Lₐ₆₈₃ | Aₙ₁ | H | H | H | H | H | H | F | Rₛ₁₁ | O |
| Lₐ₈₃₄ | Aₙ₁ | H | H | H | H | H | H | F | Rₛ₁₂ | O |
| Lₐ₆₈₅ | Aₙ₁ | H | H | H | H | H | H | F | Rₛ₁₃ | O |
| Lₐ₆₈₆ | Aₙ₁ | H | H | H | H | H | H | F | Rₛ₁₄ | O |
| Lₐ₆₈₇ | Aₙ₁ | H | H | H | H | H | H | F | Rₛ₁₅ | O |
| Lₐ₆₈₈ | Aₙ₁ | H | H | H | H | H | H | F | Rₛ₁₆ | O |
| Lₐ₆₈₉ | Aₙ₁ | H | H | H | H | H | H | F | Rₛ₁₇ | O |
| Lₐ₆₉₀ | Aₙ₃₄ | H | H | H | H | H | H | F | D | O |
| Lₐ₆₉₁ | Aₙ₃₄ | H | H | H | H | H | H | F | Rₛ₇ | O |
| Lₐ₆₉₂ | Aₙ₃₄ | H | H | H | H | H | H | F | Rₛ₈ | O |
| Lₐ₆₉₃ | Aₙ₃₄ | H | H | H | H | H | H | F | Rₛ₉ | O |
| Lₐ₆₉₄ | Aₙ₃₄ | H | H | H | H | H | H | F | Rₛ₁₀ | O |
| Lₐ₆₉₅ | Aₙ₃₄ | H | H | H | H | H | H | F | Rₛ₁₁ | O |
| Lₐ₆₉₆ | Aₙ₃₄ | H | H | H | H | H | H | F | Rₛ₁₂ | O |
| Lₐ₆₉₇ | Aₙ₃₄ | H | H | H | H | H | H | F | Rₛ₁₃ | O |
| Lₐ₆₉₈ | Aₙ₃₄ | H | H | H | H | H | H | F | Rₛ₁₄ | O |
| Lₐ₆₉₉ | Aₙ₃₄ | H | H | H | H | H | H | F | Rₛ₁₅ | O |
| Lₐ₇₀₀ | Aₙ₃₄ | H | H | H | H | H | H | F | Rₛ₁₆ | O |
| Lₐ₇₀₁ | Aₙ₃₄ | H | H | H | H | H | H | F | Rₛ₁₇ | O |
| Lₐ₇₀₂ | Aₙ₁ | H | H | H | H | H | H | H | H | S |
| Lₐ₇₀₃ | Aₙ₁₀ | H | H | H | H | H | H | H | H | S |
| Lₐ₇₀₄ | Aₙ₁₃ | H | H | H | H | H | H | H | H | S |
| Lₐ₇₀₅ | Aₙ₃₁ | H | H | H | H | H | H | H | H | S |
| Lₐ₇₀₆ | Aₙ₃₄ | H | H | H | H | H | H | H | H | S |
| Lₐ₇₀₇ | Aₙ₅₃ | H | H | H | H | H | H | H | H | S |
| Lₐ₇₀₈ | Aₙ₅₇ | H | H | H | H | H | H | H | H | S |
| Lₐ₇₀₉ | Aₙ₅₈ | H | H | H | H | H | H | H | H | S |
| Lₐ₇₁₀ | Aₙ₅₉ | H | H | H | H | H | H | H | H | S |
| Lₐ₇₁₁ | Aₙ₆₀ | H | H | H | H | H | H | H | H | S |
| Lₐ₇₁₂ | Aₙ₈₄ | H | H | H | H | H | H | H | H | S |
| Lₐ₇₁₃ | Aₙ₉₁ | H | H | H | H | H | H | H | H | S |
| Lₐ₇₁₄ | Aₙ₉₃ | H | H | H | H | H | H | H | H | S |
| Lₐ₇₁₅ | Aₙ₉₄ | H | H | H | H | H | H | H | H | S |
| Lₐ₇₁₆ | Aₙ₉₆ | H | H | H | H | H | H | H | H | S |
| Lₐ₇₁₇ | Aₙ₁ | H | H | H | H | H | H | H | CN | S |
| Lₐ₇₁₈ | Aₙ₁₀ | H | H | H | H | H | H | H | CN | S |
| Lₐ₇₁₉ | Aₙ₁₃ | H | H | H | H | H | H | H | CN | S |
| Lₐ₇₂₀ | Aₙ₃₁ | H | H | H | H | H | H | H | CN | S |
| Lₐ₇₂₁ | Aₙ₃₄ | H | H | H | H | H | H | H | CN | S |
| Lₐ₇₂₂ | Aₙ₅₃ | H | H | H | H | H | H | H | CN | S |
| Lₐ₇₂₃ | Aₙ₅₇ | H | H | H | H | H | H | H | CN | S |
| Lₐ₇₂₄ | Aₙ₅₈ | H | H | H | H | H | H | H | CN | S |
| Lₐ₇₂₅ | Aₙ₅₉ | H | H | H | H | H | H | H | CN | S |
| Lₐ₇₂₆ | Aₙ₆₀ | H | H | H | H | H | H | H | CN | S |
| Lₐ₇₂₇ | Aₙ₈₄ | H | H | H | H | H | H | H | CN | S |
| Lₐ₇₂₈ | Aₙ₉₁ | H | H | H | H | H | H | H | CN | S |
| Lₐ₇₂₉ | Aₙ₉₃ | H | H | H | H | H | H | H | CN | S |
| Lₐ₇₃₀ | Aₙ₉₄ | H | H | H | H | H | H | H | CN | S |
| Lₐ₇₃₁ | Aₙ₉₆ | H | H | H | H | H | H | H | CN | S |
| Lₐ₇₃₂ | Aₙ₁ | H | H | H | H | H | H | CN | H | S |
| Lₐ₇₃₃ | Aₙ₁₀ | H | H | H | H | H | H | CN | H | S |
| Lₐ₇₃₄ | Aₙ₁₃ | H | H | H | H | H | H | CN | H | S |
| Lₐ₇₃₅ | Aₙ₃₁ | H | H | H | H | H | H | CN | H | S |
| Lₐ₇₃₆ | Aₙ₃₄ | H | H | H | H | H | H | CN | H | S |
| Lₐ₇₃₇ | Aₙ₅₃ | H | H | H | H | H | H | CN | H | S |
| Lₐ₇₃₈ | Aₙ₅₇ | H | H | H | H | H | H | CN | H | S |
| Lₐ₇₃₉ | Aₙ₅₈ | H | H | H | H | H | H | CN | H | S |
| Lₐ₇₄₀ | Aₙ₅₉ | H | H | H | H | H | H | CN | H | S |
| Lₐ₇₄₁ | Aₙ₆₀ | H | H | H | H | H | H | CN | H | S |
| Lₐ₇₄₂ | Aₙ₈₄ | H | H | H | H | H | H | CN | H | S |
| Lₐ₇₄₃ | Aₙ₉₁ | H | H | H | H | H | H | CN | H | S |
| Lₐ₇₄₄ | Aₙ₉₃ | H | H | H | H | H | H | CN | H | S |
| Lₐ₇₄₅ | Aₙ₉₄ | H | H | H | H | H | H | CN | H | S |
| Lₐ₇₄₆ | Aₙ₉₆ | H | H | H | H | H | H | CN | H | S |
| Lₐ₇₄₇ | Aₙ₁ | H | H | H | H | H | H | F | H | S |
| Lₐ₇₄₈ | Aₙ₁₀ | H | H | H | H | H | H | F | H | S |
| Lₐ₇₄₉ | Aₙ₁₃ | H | H | H | H | H | H | F | H | S |
| Lₐ₇₅₀ | Aₙ₃₁ | H | H | H | H | H | H | F | H | S |
| Lₐ₇₅₁ | Aₙ₃₄ | H | H | H | H | H | H | F | H | S |
| Lₐ₇₅₂ | Aₙ₅₃ | H | H | H | H | H | H | F | H | S |
| Lₐ₇₅₃ | Aₙ₅₇ | H | H | H | H | H | H | F | H | S |
| Lₐ₇₅₄ | Aₙ₅₈ | H | H | H | H | H | H | F | H | S |
| Lₐ₇₅₅ | Aₙ₅₉ | H | H | H | H | H | H | F | H | S |
| Lₐ₇₅₆ | Aₙ₆₀ | H | H | H | H | H | H | F | H | S |
| Lₐ₇₅₇ | Aₙ₈₄ | H | H | H | H | H | H | F | H | S |
| Lₐ₇₅₈ | Aₙ₉₁ | H | H | H | H | H | H | F | H | S |
| Lₐ₇₅₉ | Aₙ₉₃ | H | H | H | H | H | H | F | H | S |
| Lₐ₇₆₀ | Aₙ₉₄ | H | H | H | H | H | H | F | H | S |
| Lₐ₇₆₁ | Aₙ₉₆ | H | H | H | H | H | H | F | H | S |
| Lₐ₇₆₂ | Aₙ₁ | H | H | H | H | H | H | H | H | Se |
| Lₐ₇₆₃ | Aₙ₁ | H | H | H | H | H | H | H | CN | Se |
| Lₐ₇₆₄ | Aₙ₁ | H | H | H | H | H | H | CN | H | Se |
| Lₐ₇₆₅ | Aₙ₁ | H | H | H | H | H | H | F | H | Se |
| Lₐ₇₆₆ | Aₙ₁ | H | H | H | H | H | H | H | H | Si(CH₃)₂ |
| Lₐ₇₆₇ | Aₙ₁ | H | H | H | H | H | H | H | CN | Si(CH₃)₂ |
| Lₐ₇₆₈ | Aₙ₁ | H | H | H | H | H | H | CN | H | Si(CH₃)₂ |
| Lₐ₇₆₉ | Aₙ₁ | H | H | H | H | H | H | F | H | Si(CH₃)₂ |
| Lₐ₇₇₀ | Aₙ₁ | H | H | H | H | H | H | H | H | NPh |
| Lₐ₇₇₁ | Aₙ₁ | H | H | H | H | H | H | H | CN | NPh |
| Lₐ₇₇₂ | Aₙ₁ | H | H | H | H | H | H | CN | H | NPh |
| Lₐ₇₇₃ | Aₙ₁ | H | H | H | H | H | H | F | H | NPh |

Lₐ₇₇₄ to Lₐ₇₈₉ have the following general formula: 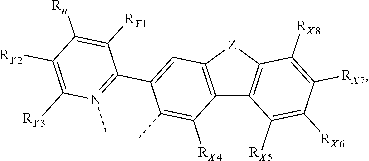
wherein Rₙ, R_{Y1} to R_{Y3}, R_{X4} to R_{X8} and Z are selected from atoms or groups in the following table:

| Ligand Lₐ No. | Rₙ | R_{Y1} | R_{Y2} | R_{Y3} | R_{X4} | R_{X5} | R_{X6} | R_{X7} | R_{X8} | Z |
|---|---|---|---|---|---|---|---|---|---|---|
| Lₐ₇₇₄ | Aₙ₁ | H | H | H | H | H | H | H | H | O |
| Lₐ₇₇₅ | Aₙ₁ | H | H | H | H | H | H | H | CN | O |
| Lₐ₇₇₆ | Aₙ₁ | H | H | H | H | H | H | CN | H | O |
| Lₐ₇₇₇ | Aₙ₁ | H | H | H | H | H | H | F | H | O |
| Lₐ₇₇₈ | Aₙ₃₁ | H | H | H | H | H | H | H | H | O |
| Lₐ₇₇₉ | Aₙ₃₁ | H | H | H | H | H | H | H | CN | O |
| Lₐ₇₈₀ | Aₙ₃₁ | H | H | H | H | H | H | CN | H | O |
| Lₐ₇₈₁ | Aₙ₃₁ | H | H | H | H | H | H | F | H | O |
| Lₐ₇₈₂ | Aₙ₃₄ | H | H | H | H | H | H | H | H | O |
| Lₐ₇₈₃ | Aₙ₃₄ | H | H | H | H | H | H | H | CN | O |
| Lₐ₇₈₄ | Aₙ₃₄ | H | H | H | H | H | H | CN | H | O |
| Lₐ₇₈₅ | Aₙ₃₄ | H | H | H | H | H | H | F | H | O |
| Lₐ₇₈₆ | Aₙ₅₃ | H | H | H | H | H | H | H | H | O |
| Lₐ₇₈₇ | Aₙ₅₃ | H | H | H | H | H | H | H | CN | O |
| Lₐ₇₈₈ | Aₙ₅₃ | H | H | H | H | H | H | CN | H | O |
| Lₐ₇₈₉ | Aₙ₅₃ | H | H | H | H | H | H | F | H | O |

Lₐ₇₉₀ to Lₐ₈₀₅ have the following general formula: 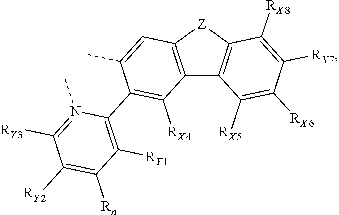
wherein Rₙ, R_{Y1} to R_{Y3}, R_{X4} to R_{X5} and Z are selected from atoms or groups in the following table:

| Ligand Lₐ No. | Rₙ | R_{Y1} | R_{Y2} | R_{Y3} | R_{X4} | R_{X5} | R_{X6} | R_{X7} | R_{X8} | Z |
|---|---|---|---|---|---|---|---|---|---|---|
| Lₐ₇₉₀ | Aₙ₁ | H | H | H | H | H | H | H | H | O |
| Lₐ₇₉₁ | Aₙ₁ | H | H | H | H | H | H | H | CN | O |
| Lₐ₇₉₂ | Aₙ₁ | H | H | H | H | H | H | CN | H | O |
| Lₐ₇₉₃ | Aₙ₁ | H | H | H | H | H | H | F | H | O |
| Lₐ₇₉₄ | Aₙ₃₁ | H | H | H | H | H | H | H | H | O |
| Lₐ₇₉₅ | Aₙ₃₁ | H | H | H | H | H | H | H | CN | O |
| Lₐ₇₉₆ | Aₙ₃₁ | H | H | H | H | H | H | CN | H | O |
| Lₐ₇₉₇ | Aₙ₃₁ | H | H | H | H | H | H | F | H | O |
| Lₐ₇₉₈ | Aₙ₃₄ | H | H | H | H | H | H | H | H | O |
| Lₐ₇₉₉ | Aₙ₃₄ | H | H | H | H | H | H | H | CN | O |
| Lₐ₈₀₀ | Aₙ₃₄ | H | H | H | H | H | H | CN | H | O |
| Lₐ₈₀₁ | Aₙ₃₄ | H | H | H | H | H | H | F | H | O |
| Lₐ₈₀₂ | Aₙ₅₃ | H | H | H | H | H | H | H | H | O |
| Lₐ₈₀₃ | Aₙ₅₃ | H | H | H | H | H | H | H | CN | O |
| Lₐ₈₀₄ | Aₙ₅₃ | H | H | H | H | H | H | CN | H | O |
| Lₐ₈₀₅ | Aₙ₅₃ | H | H | H | H | H | H | F | H | O |

Lₐ₈₀₆ to Lₐ₈₂₁ have the following general formula: 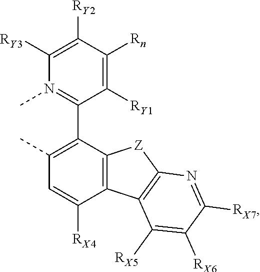
wherein Rₙ, R_{Y1} to R_{Y3}, R_{X4} to R_{X7} and Z are selected from atoms or groups in the following table:

| Ligand Lₐ No. | Rₙ | R_{Y1} | R_{Y2} | R_{Y3} | R_{X4} | R_{X5} | R_{X6} | R_{X7} | Z |
|---|---|---|---|---|---|---|---|---|---|
| Lₐ₈₀₆ | Aₙ₁ | H | H | H | H | H | H | H | O |
| Lₐ₈₀₇ | Aₙ₃₁ | H | H | H | H | H | H | H | O |
| Lₐ₈₀₈ | Aₙ₃₄ | H | H | H | H | H | H | H | O |
| Lₐ₈₀₉ | Aₙ₅₃ | H | H | H | H | H | H | H | O |
| Lₐ₈₁₀ | Aₙ₁ | H | H | H | H | H | H | CN | O |
| Lₐ₈₁₁ | Aₙ₃₁ | H | H | H | H | H | H | CN | O |
| Lₐ₈₁₂ | Aₙ₃₄ | H | H | H | H | H | H | CN | O |
| Lₐ₈₁₃ | Aₙ₅₃ | H | H | H | H | H | H | CN | O |
| Lₐ₈₁₄ | Aₙ₁ | H | H | H | H | H | H | F | O |
| Lₐ₈₁₅ | Aₙ₃₁ | H | H | H | H | H | H | F | O |
| Lₐ₈₁₆ | Aₙ₃₄ | H | H | H | H | H | H | F | O |
| Lₐ₈₁₇ | Aₙ₅₃ | H | H | H | H | H | H | F | O |
| Lₐ₈₁₈ | Aₙ₁ | H | H | H | H | H | H | Aₙ₁ | O |
| Lₐ₈₁₉ | Aₙ₃₁ | H | H | H | H | H | H | Aₙ₁ | O |
| Lₐ₈₂₀ | Aₙ₃₄ | H | H | H | H | H | H | Aₙ₁ | O |
| Lₐ₈₂₁ | Aₙ₅₃ | H | H | H | H | H | H | Aₙ₁ | O |

wherein 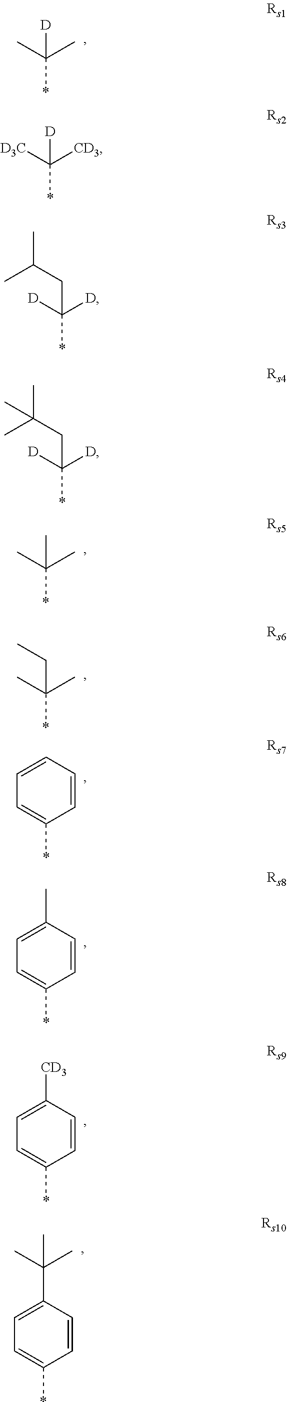 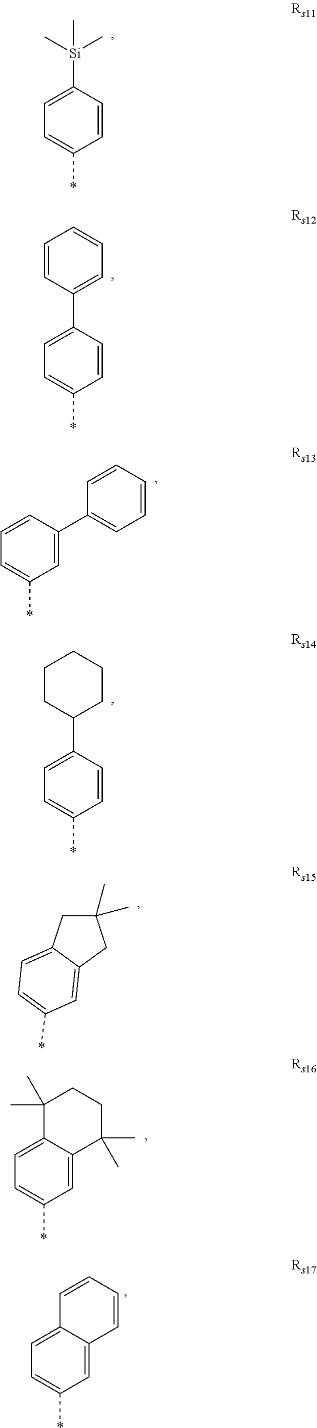
wherein “*” represents a position where Rₛ₁ to Rₛ₁₇ are each joined;
optionally, hydrogens in Lₐ₁ to Lₐ₈₂₁ can be partially or fully deuterated.

16. The metal complex according to claim 15, wherein L_{b} is, at each occurrence identically or differently, selected from the group consisting of: 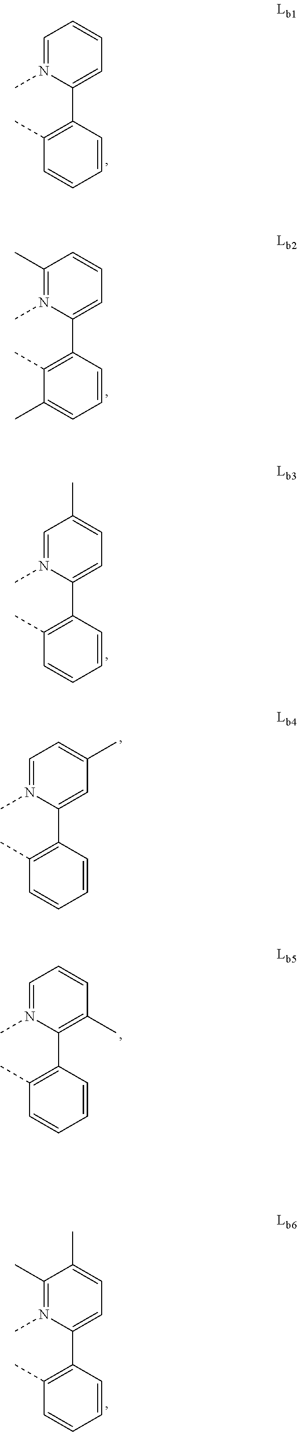 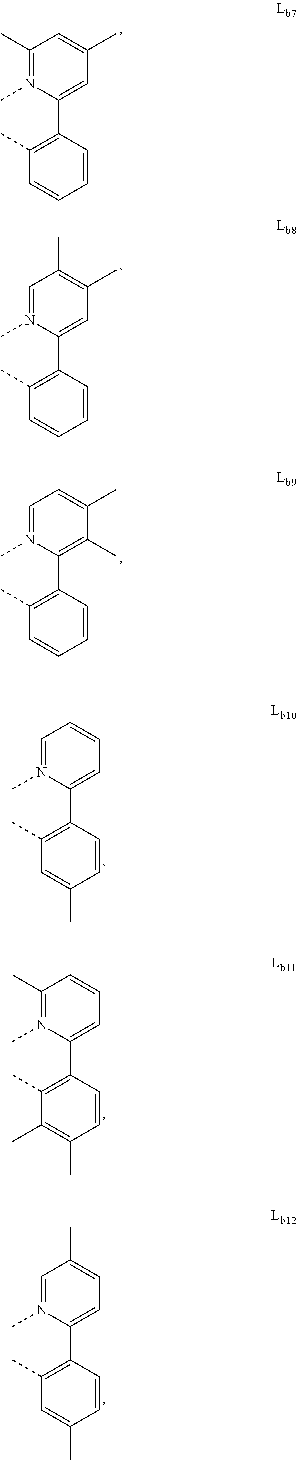 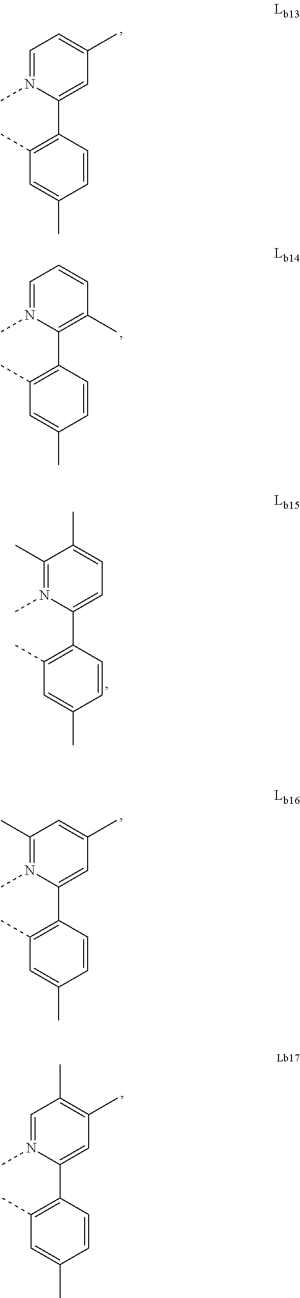 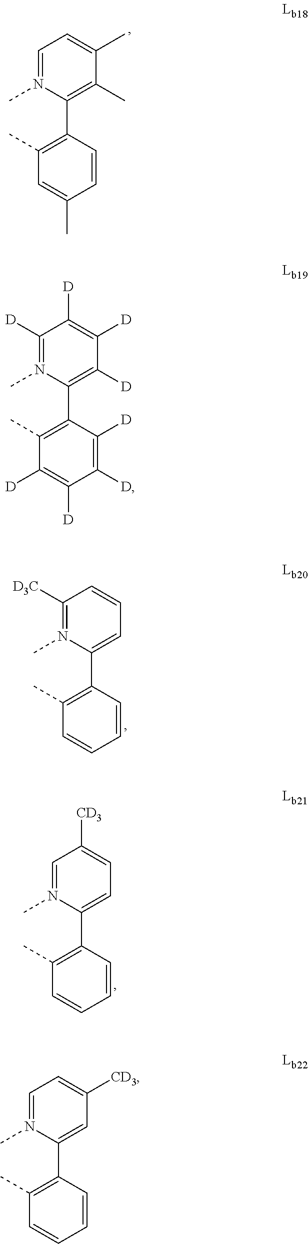 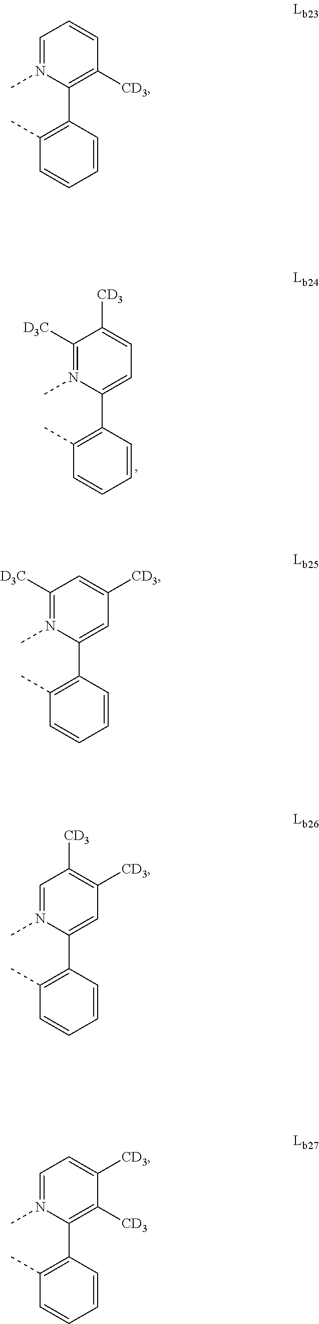 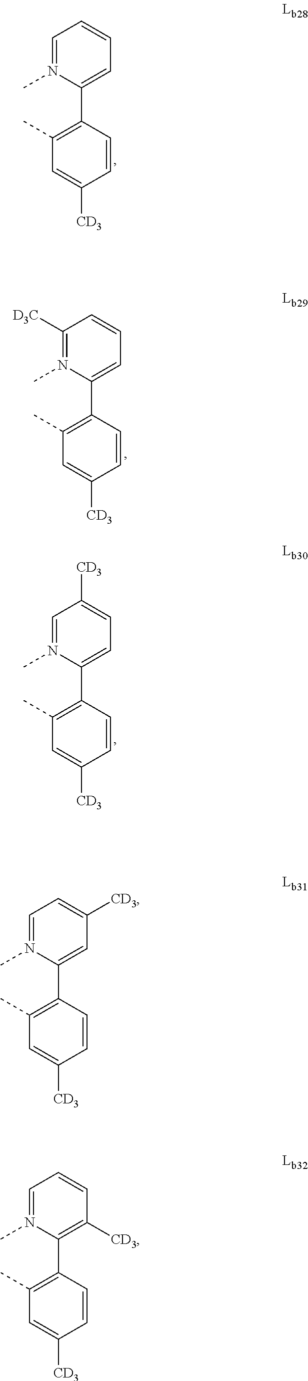 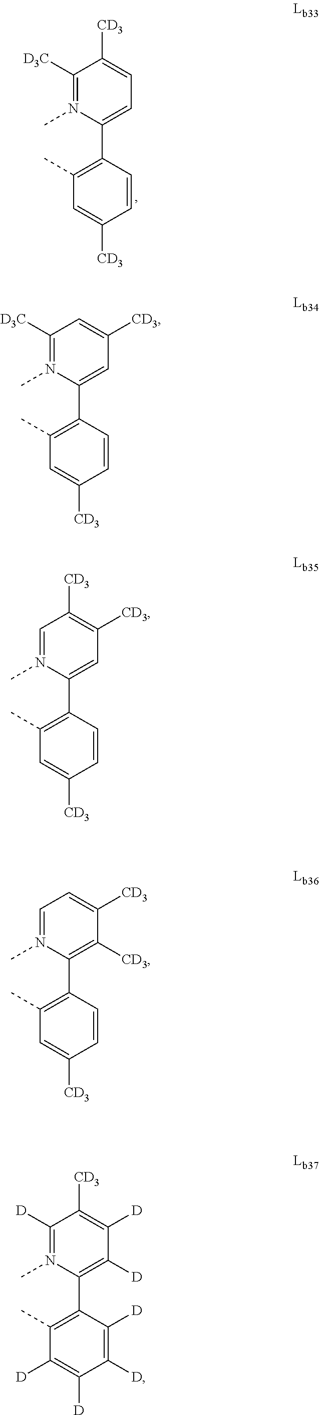 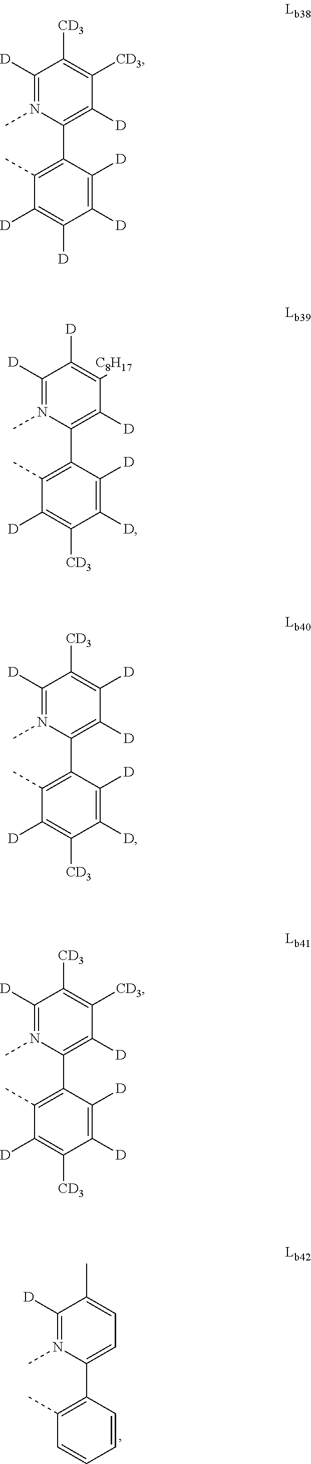 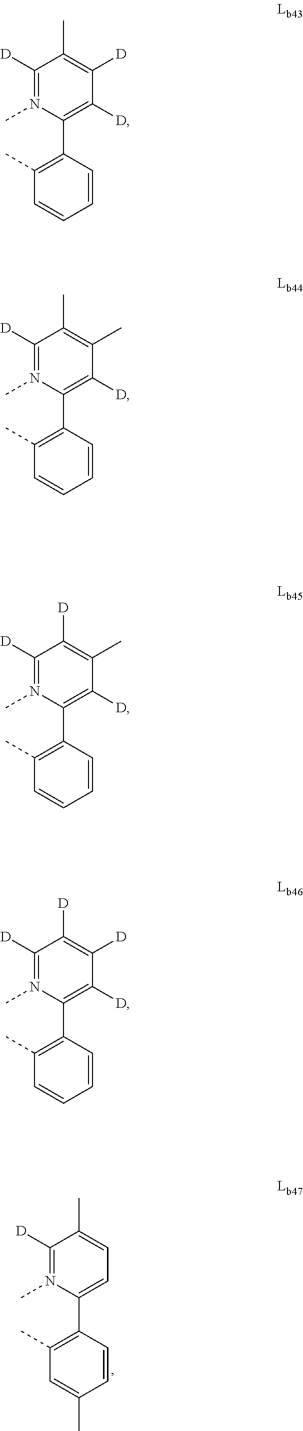 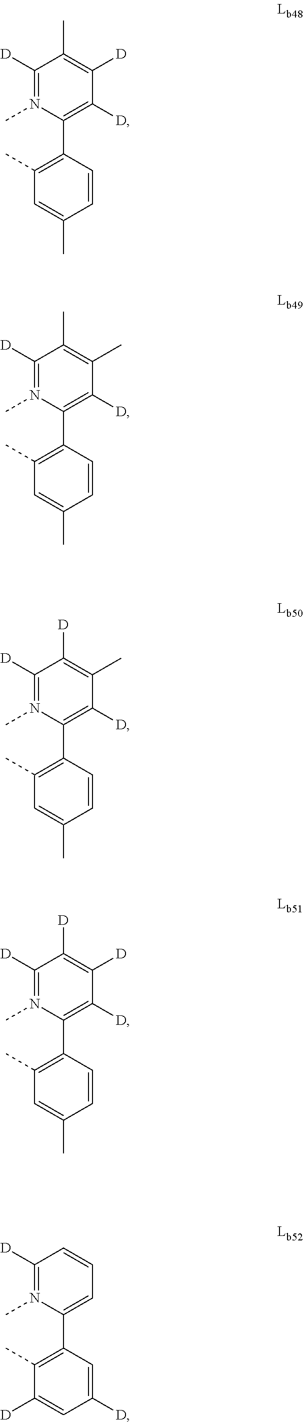 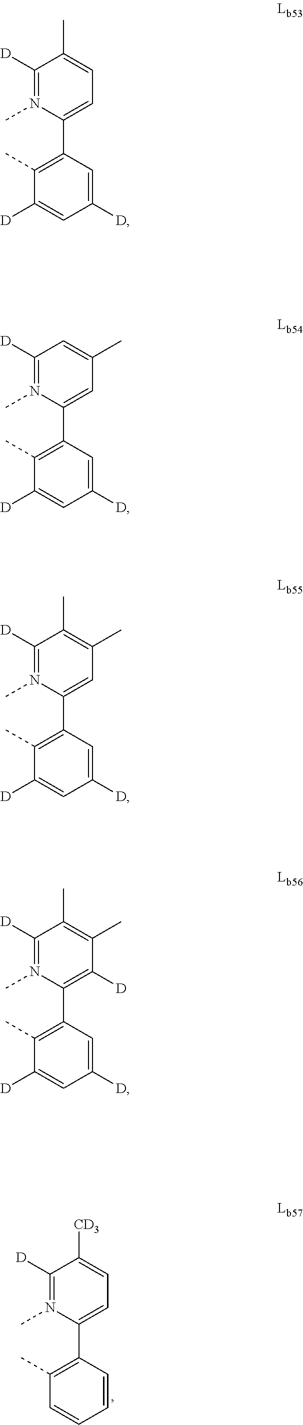 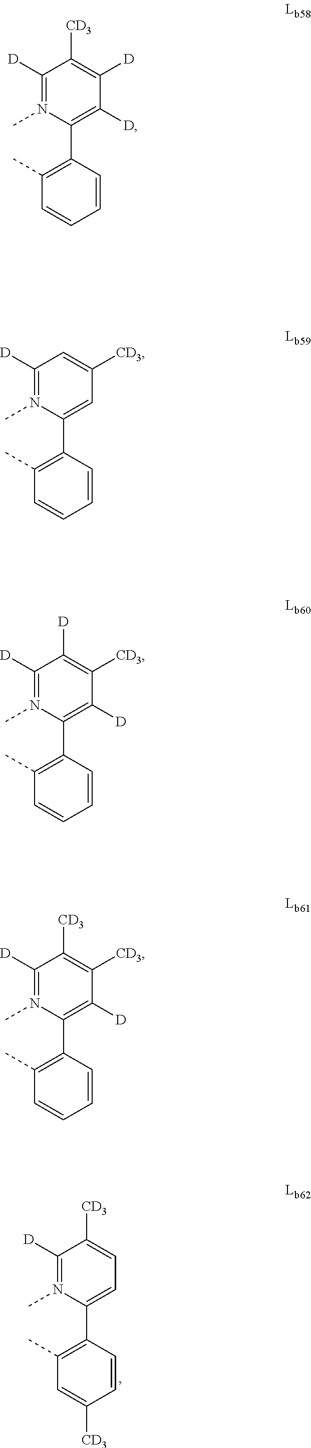 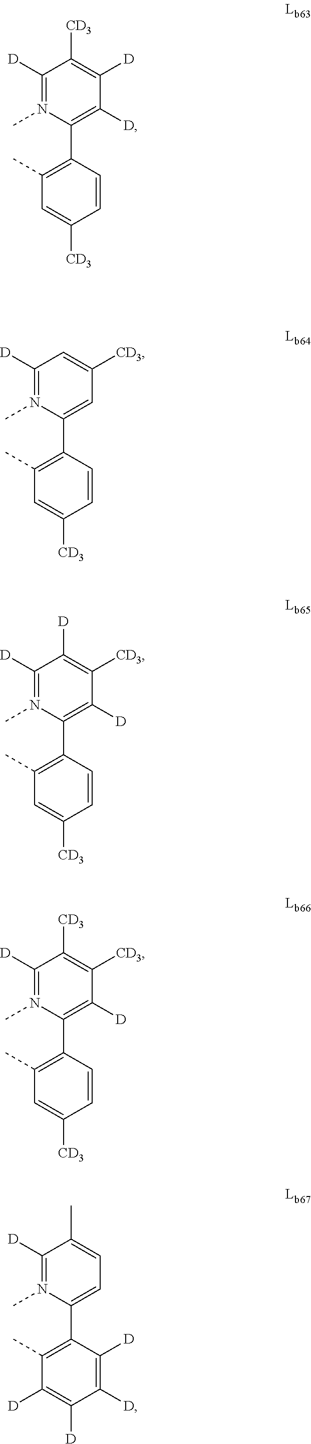 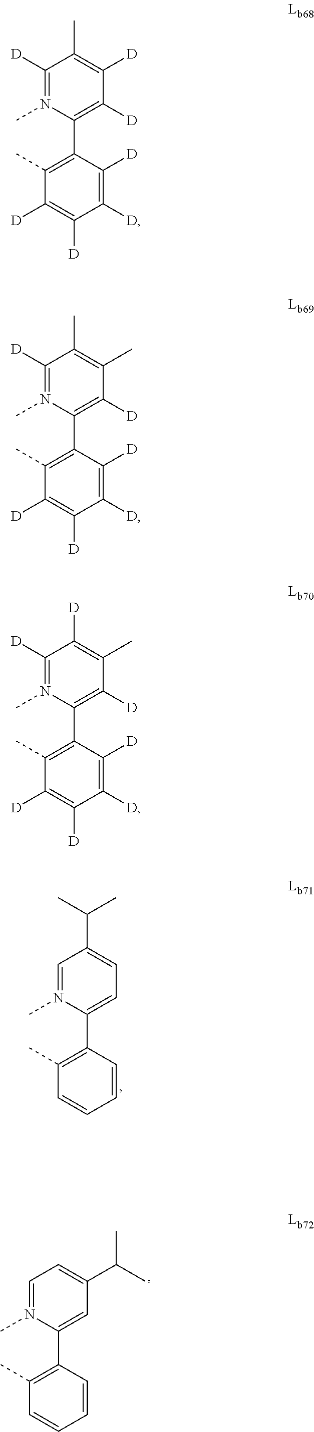 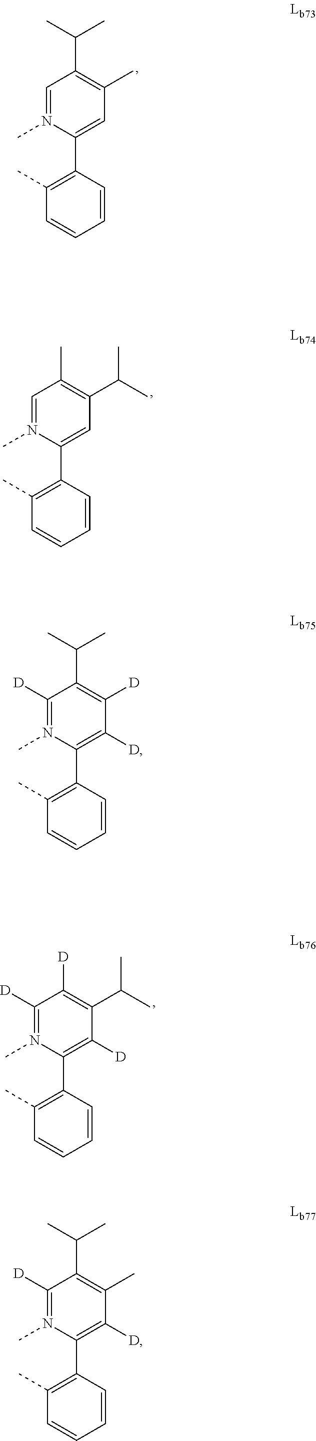 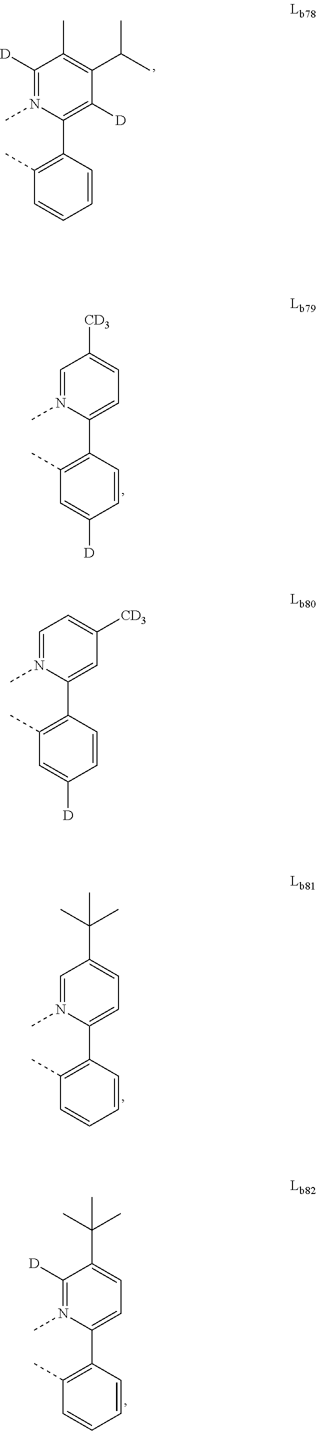 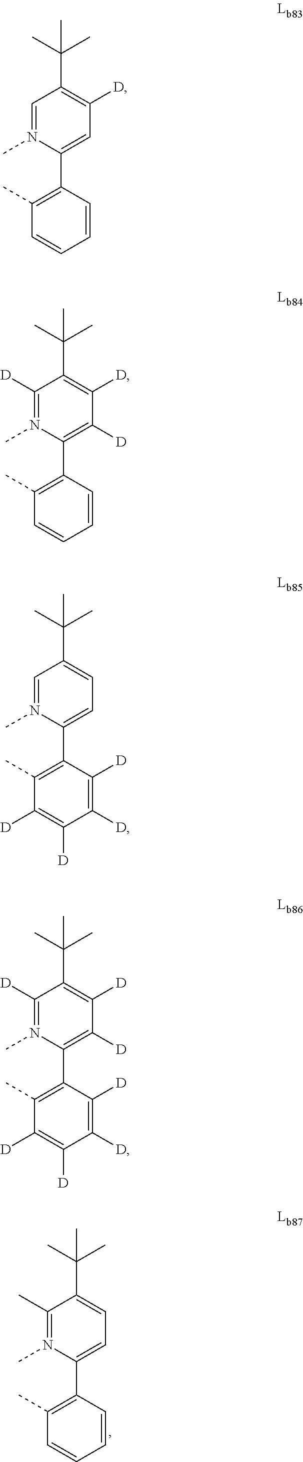 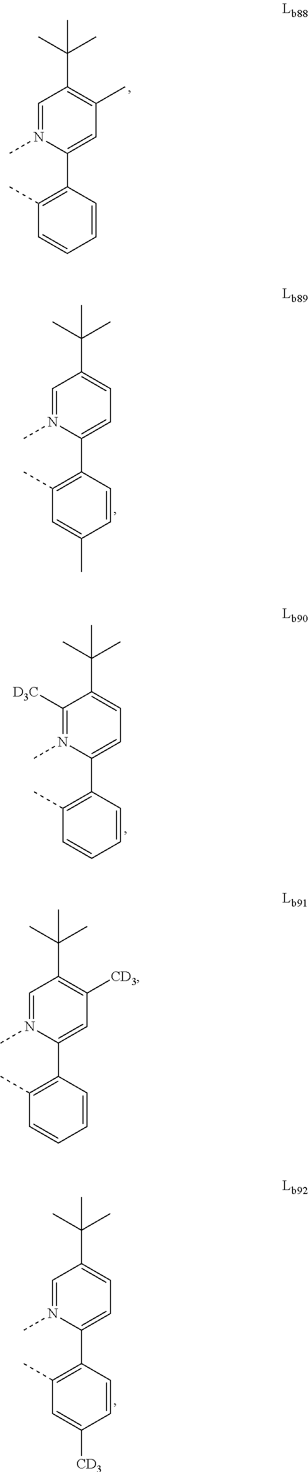 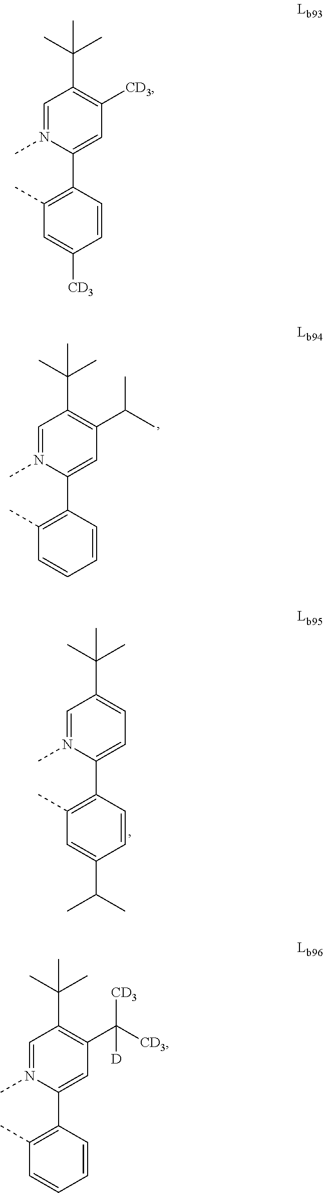 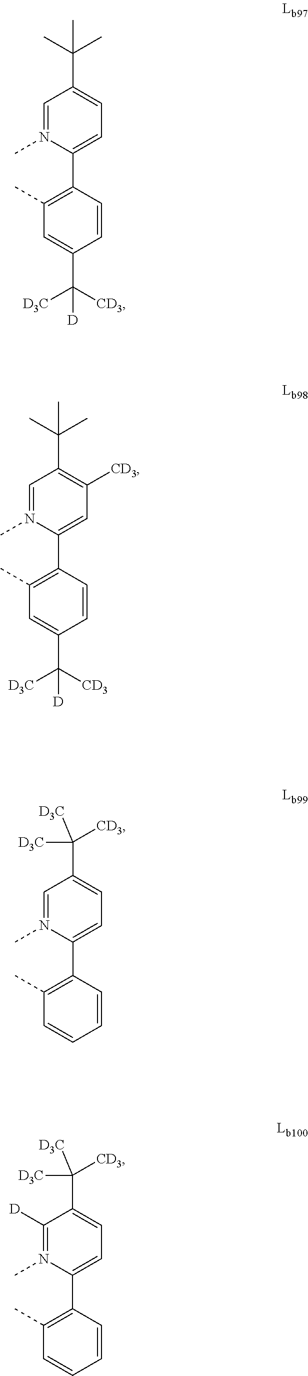 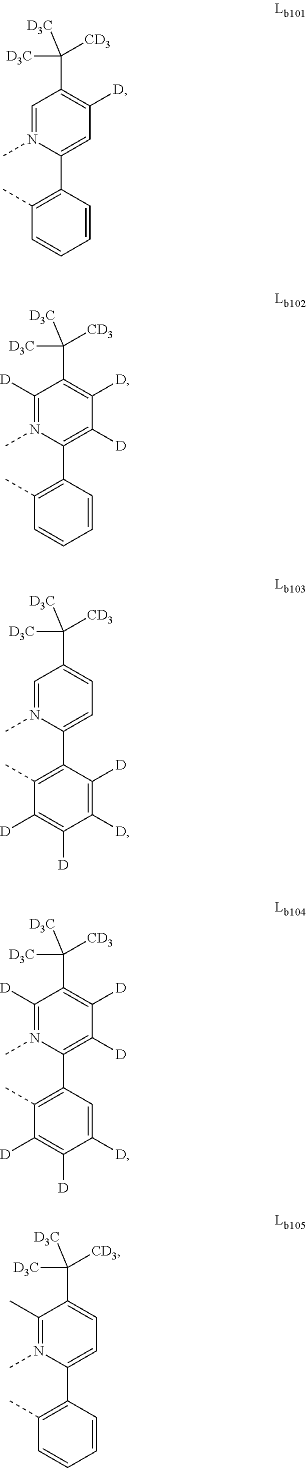 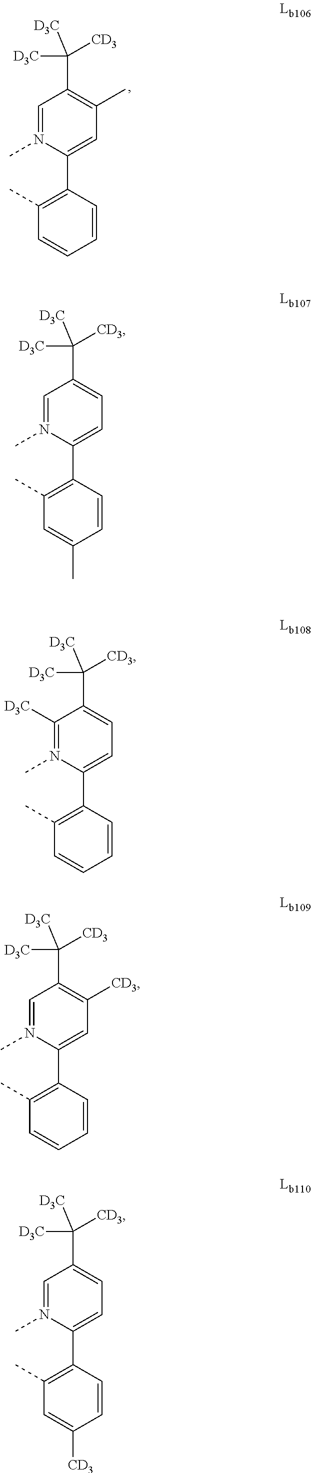 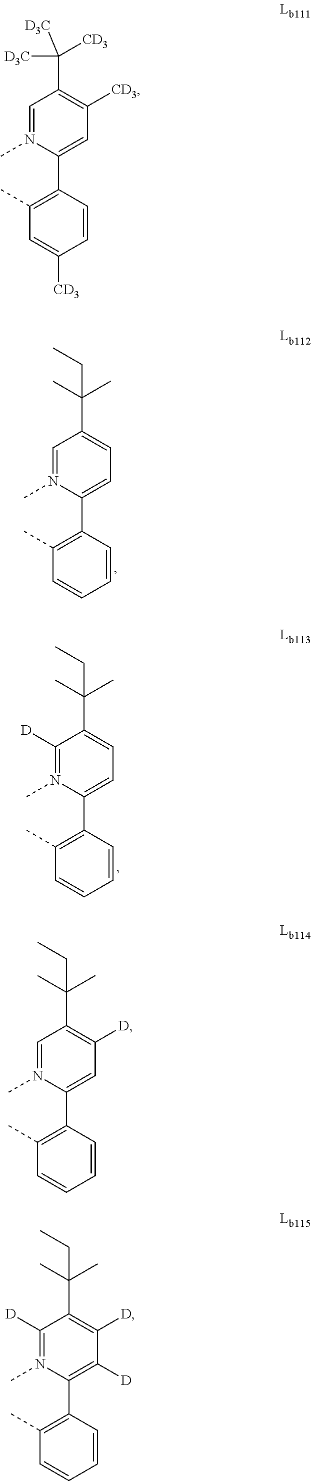 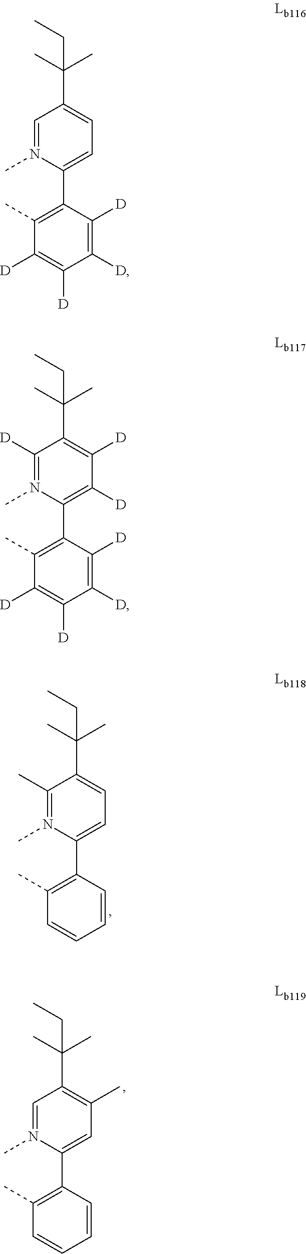 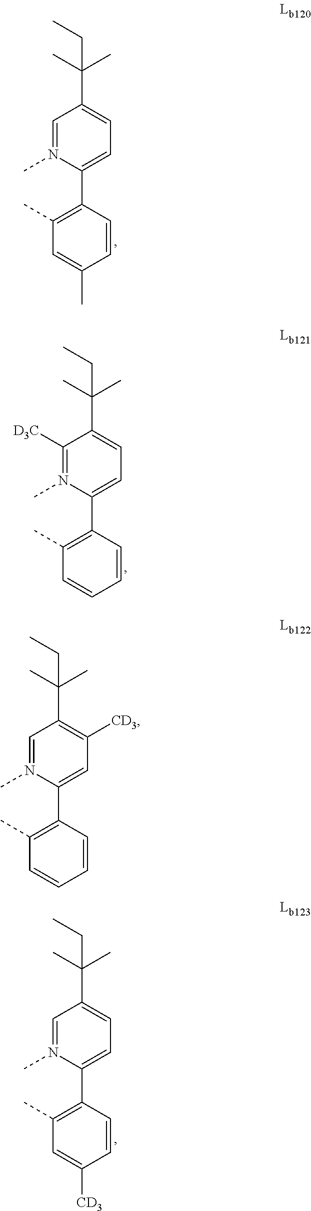 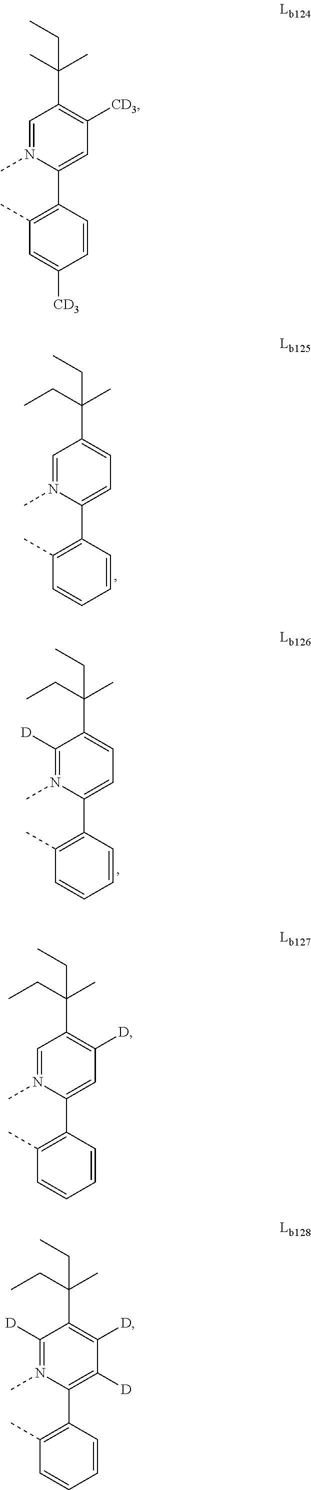 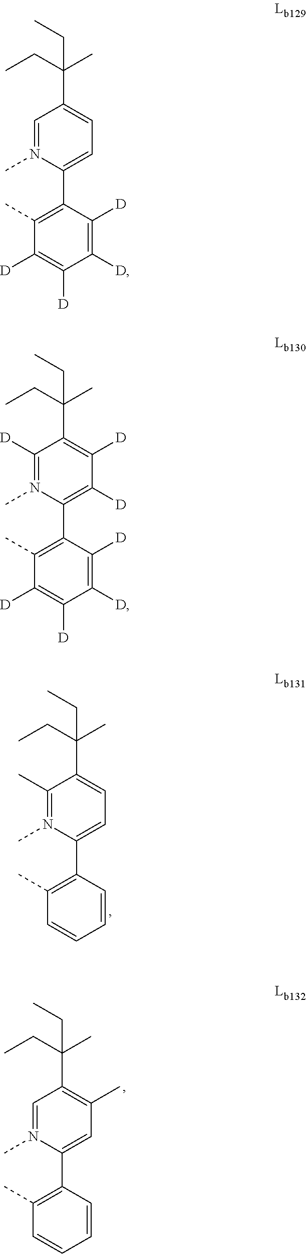 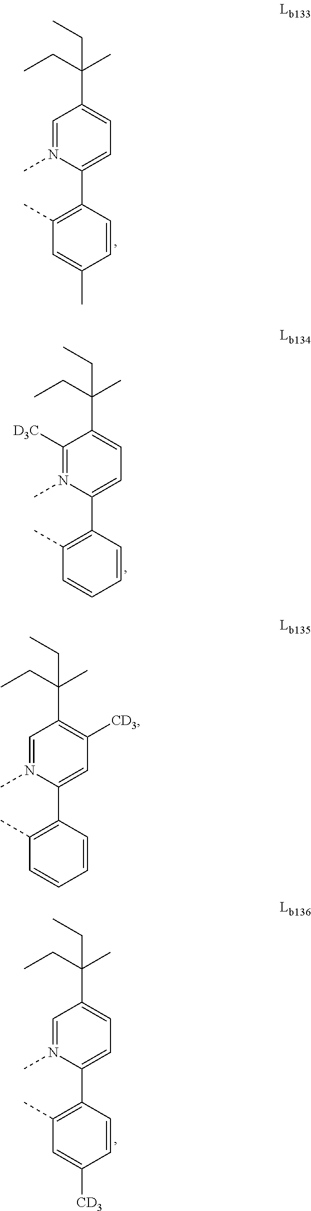 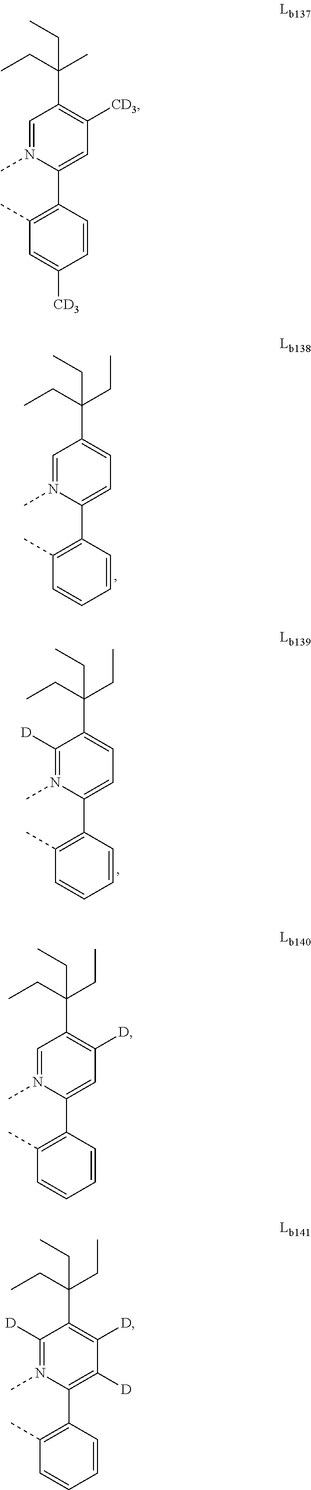 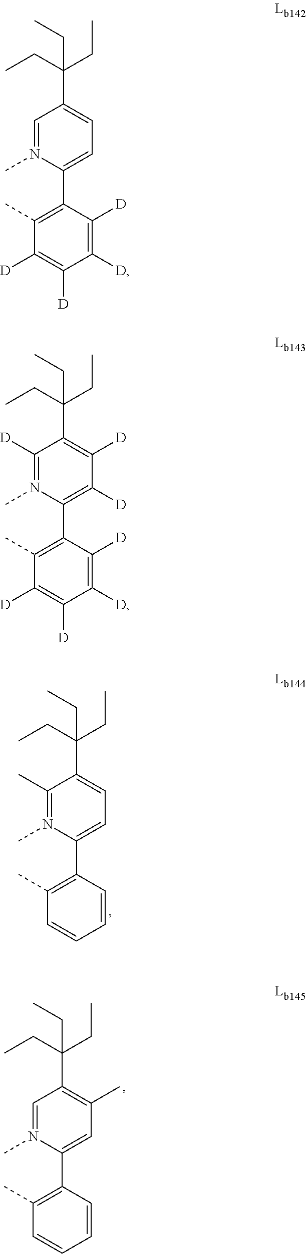 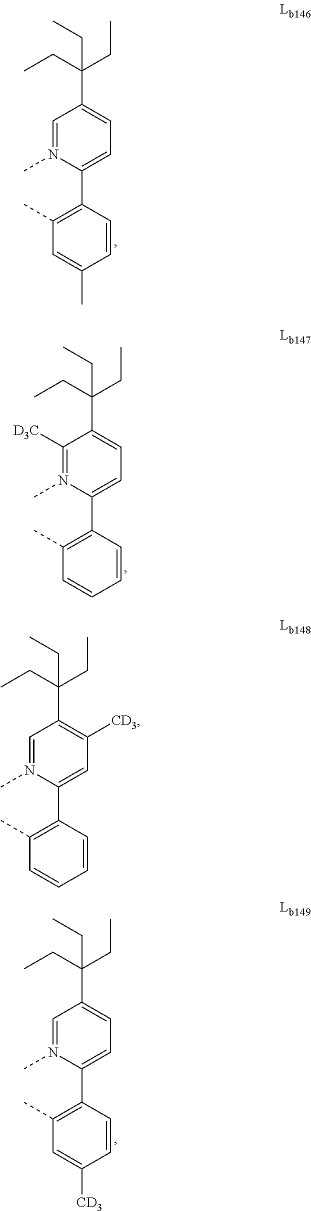 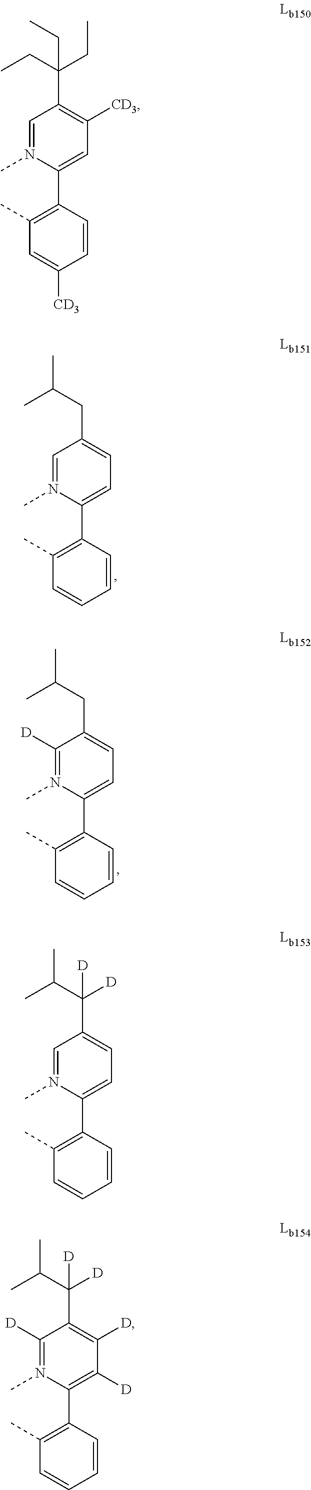 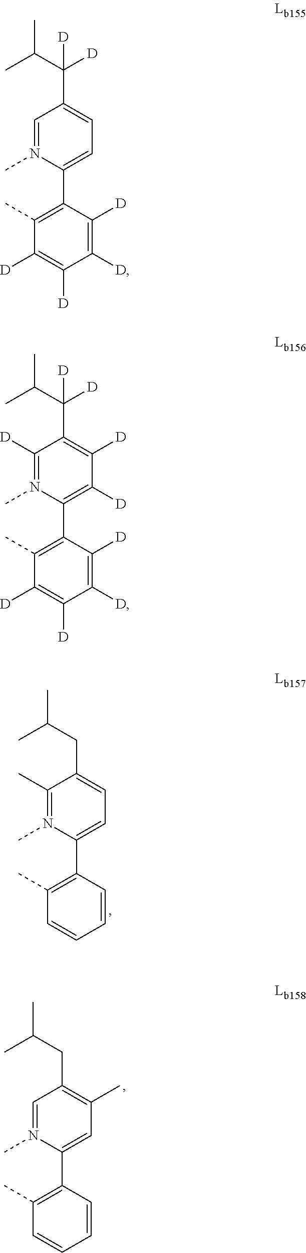 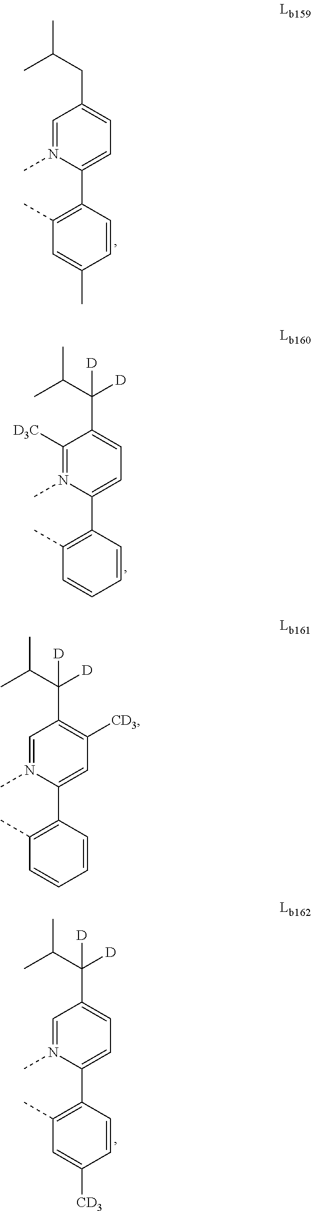 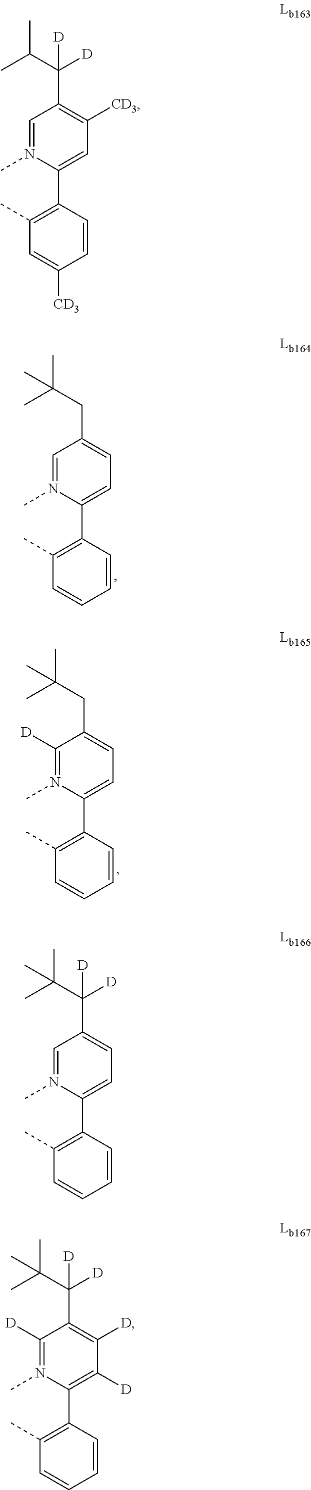 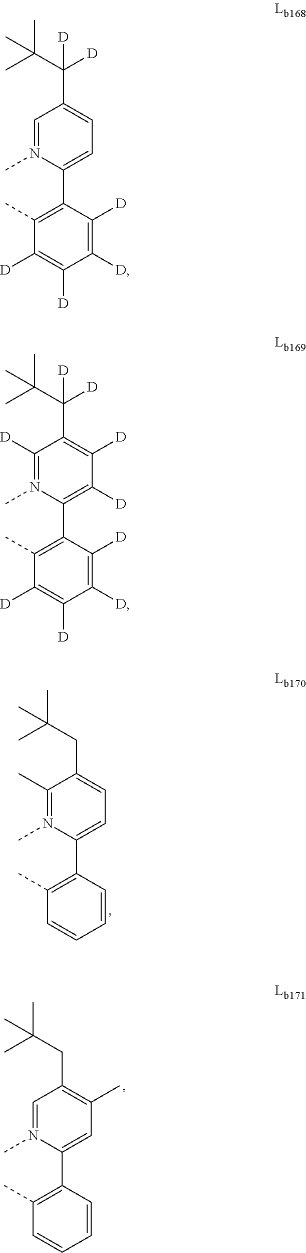 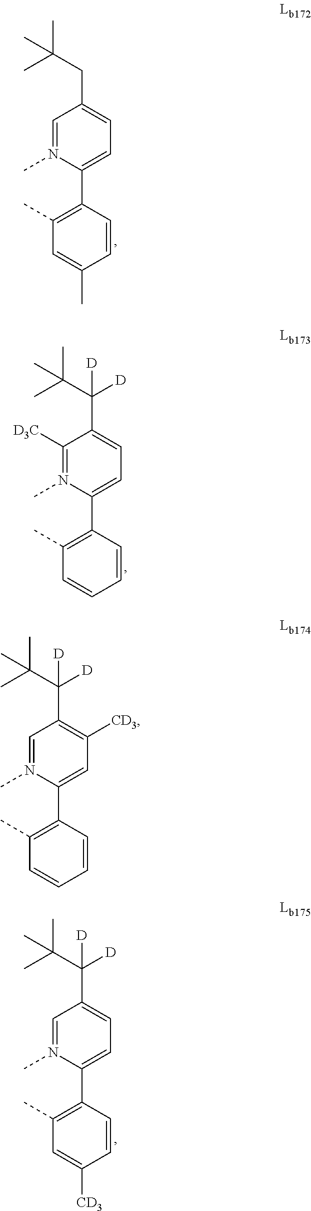 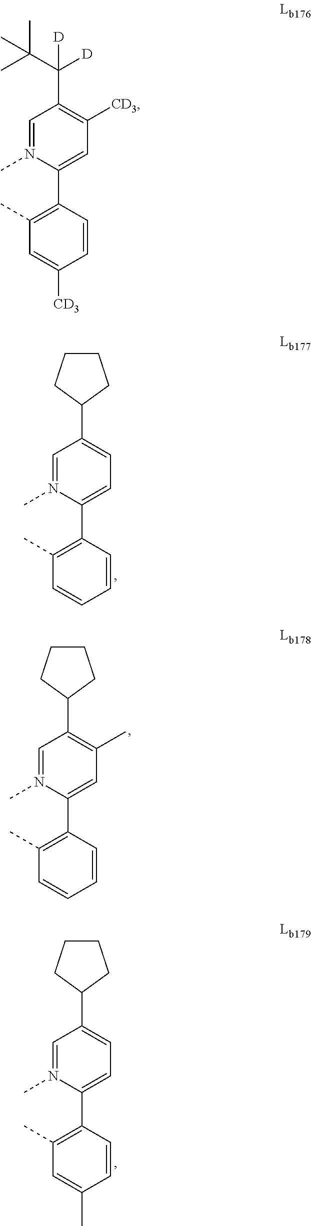 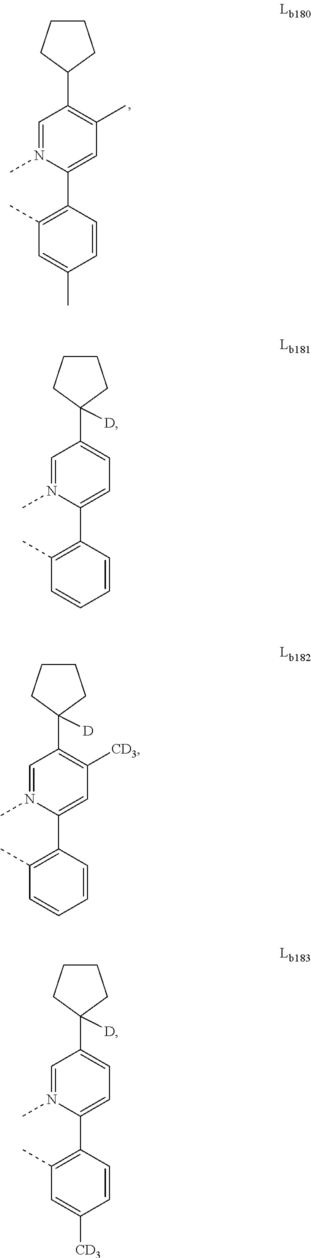 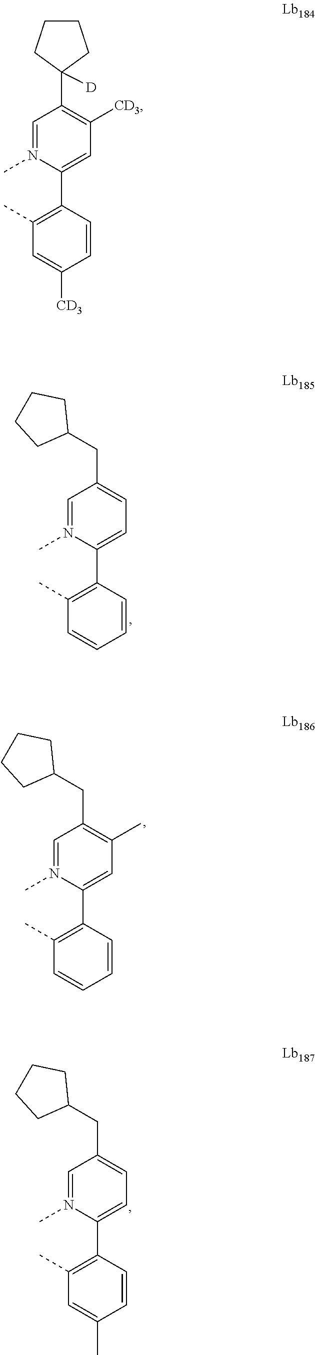 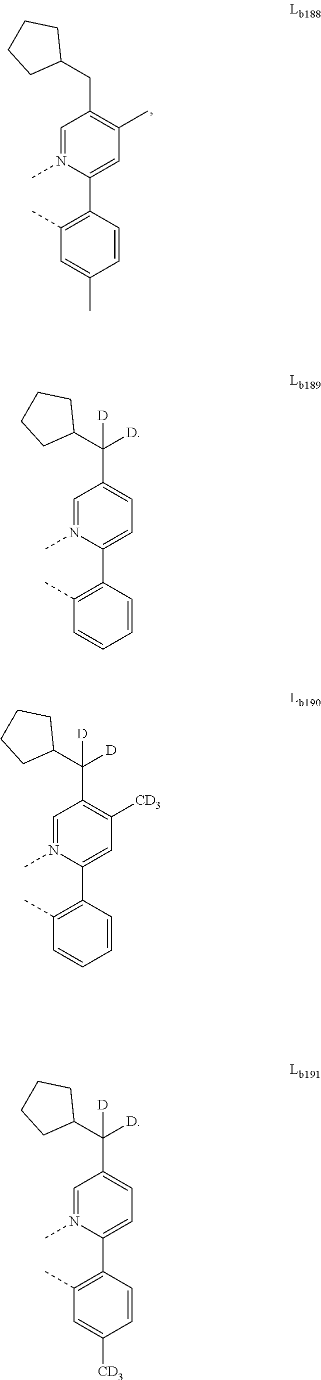 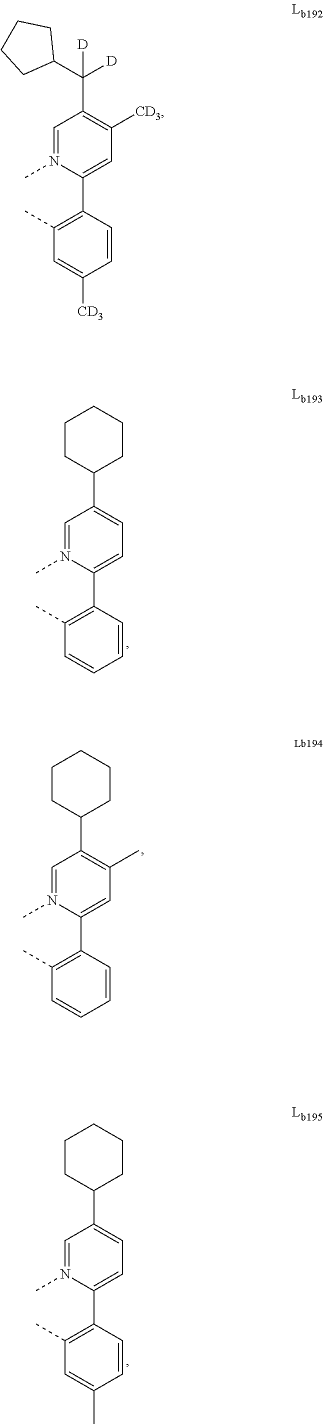 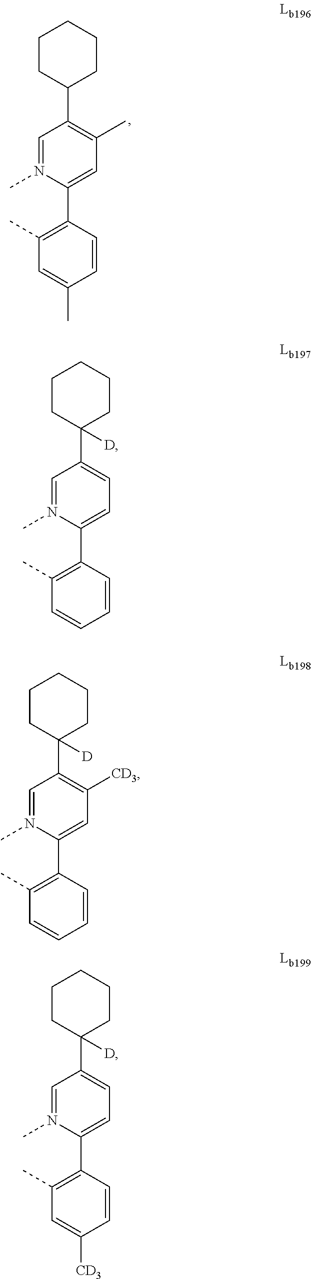 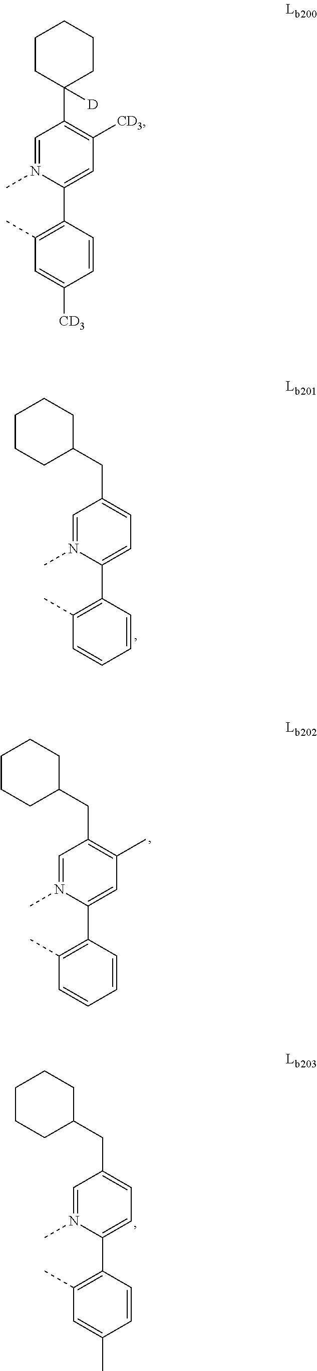 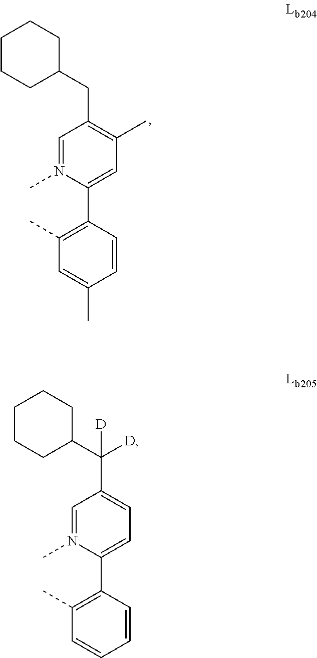 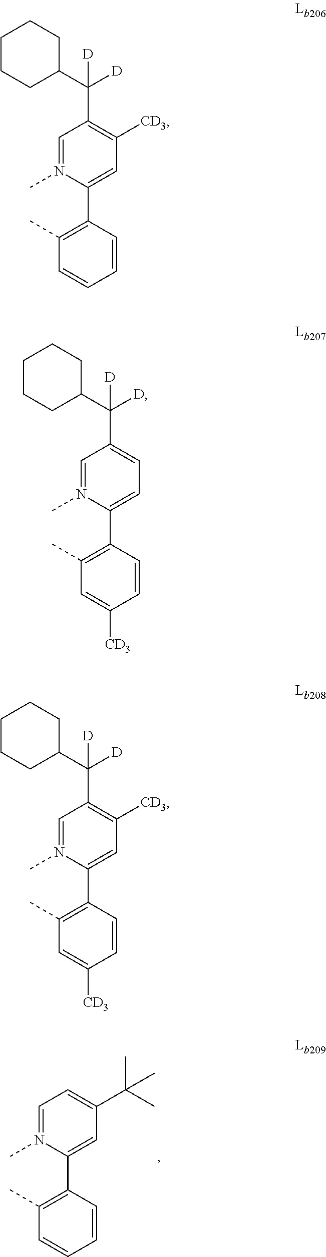 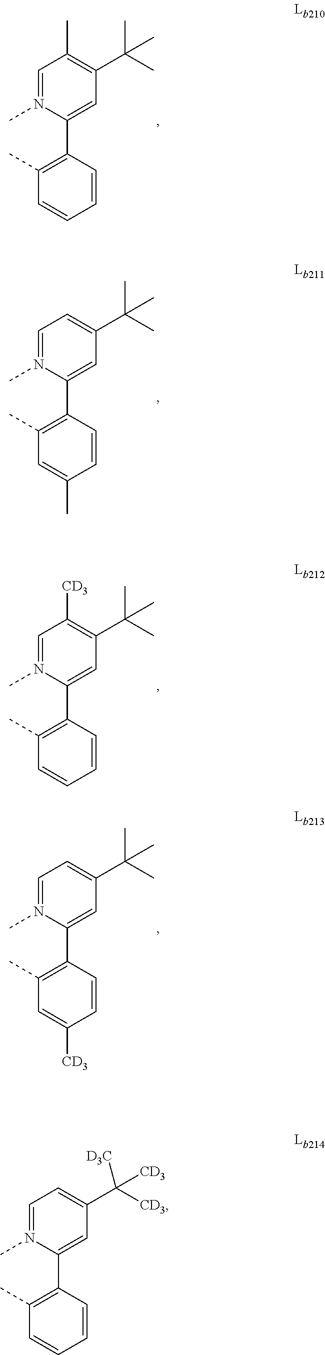 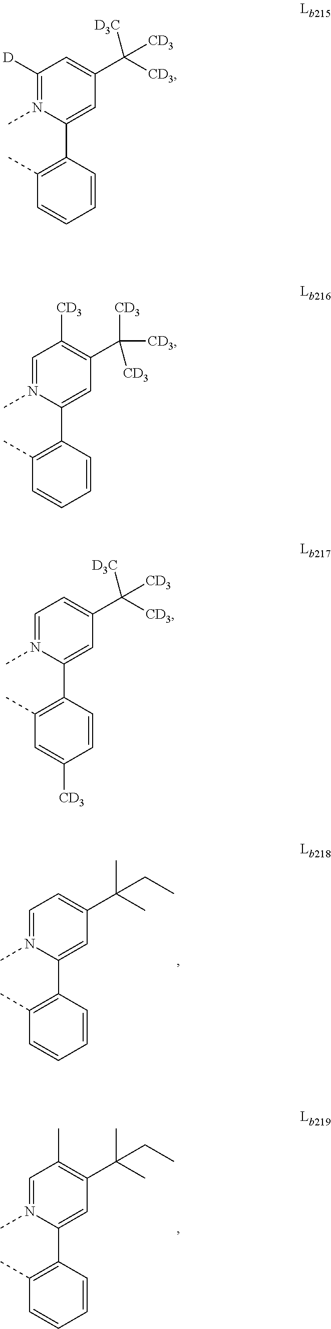 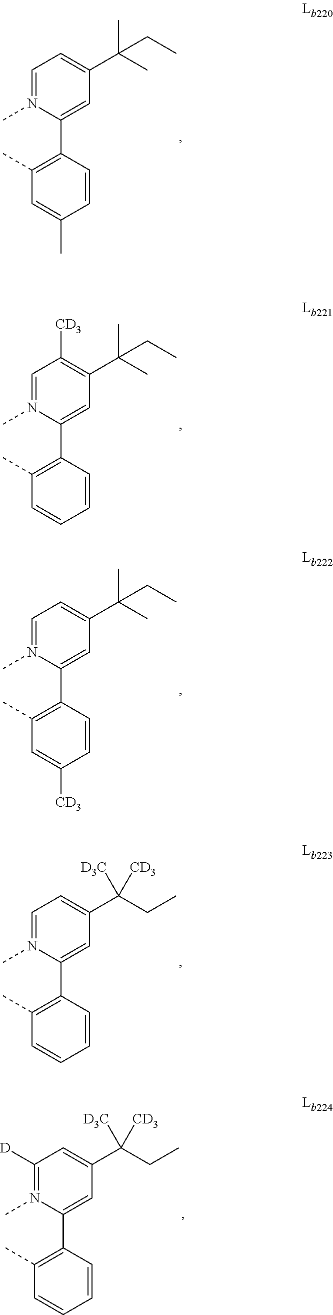 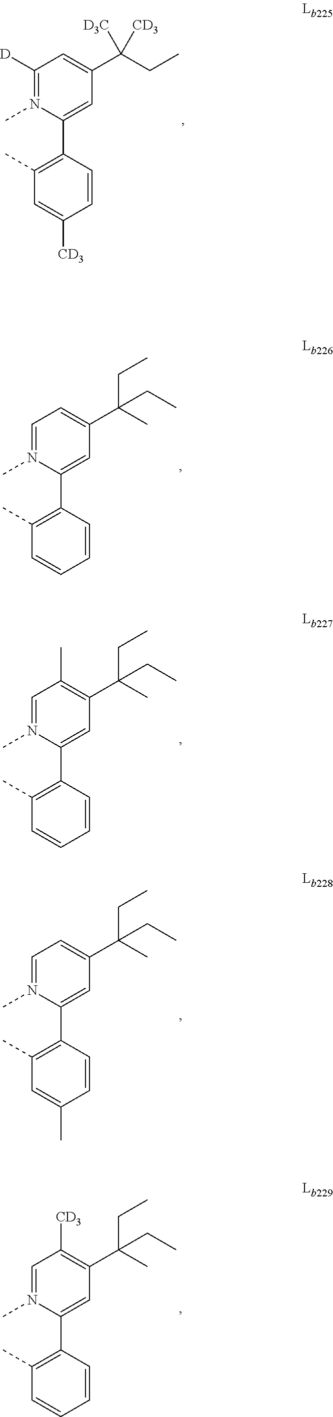 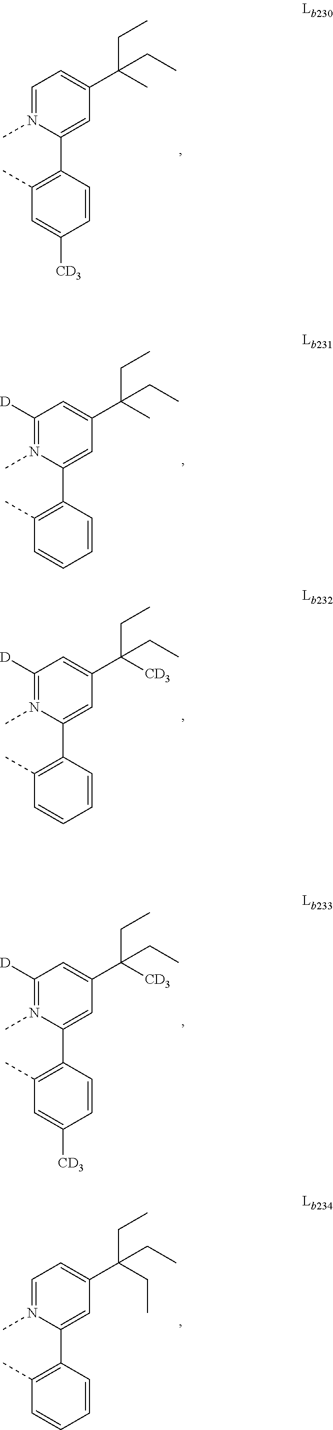 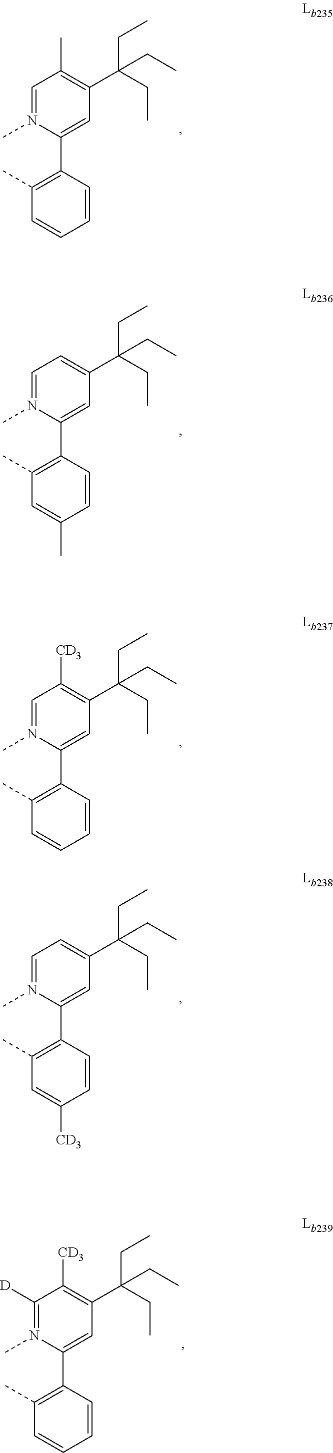 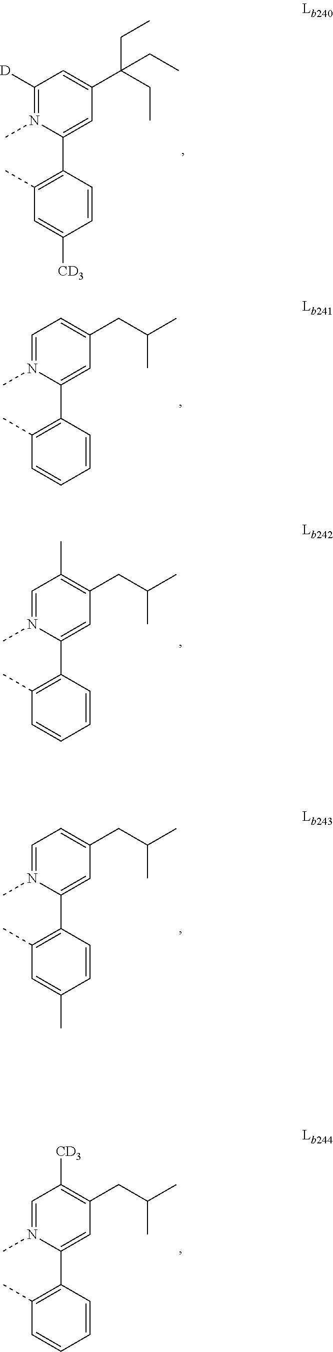 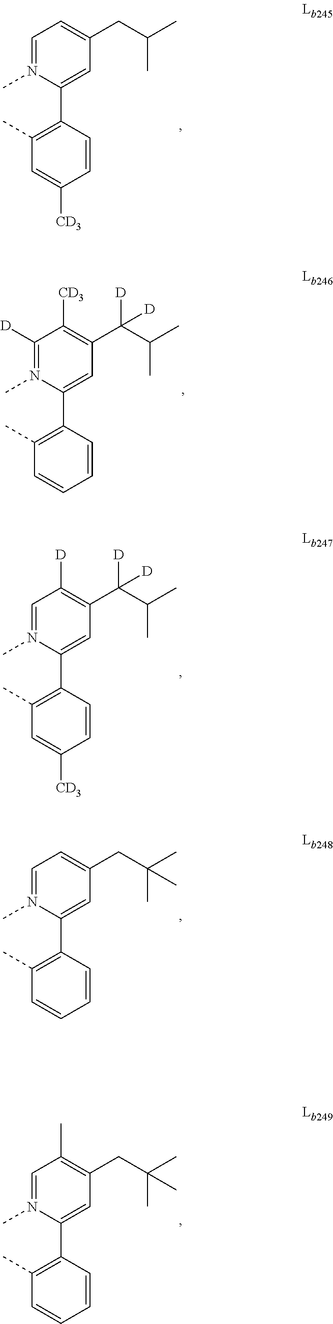 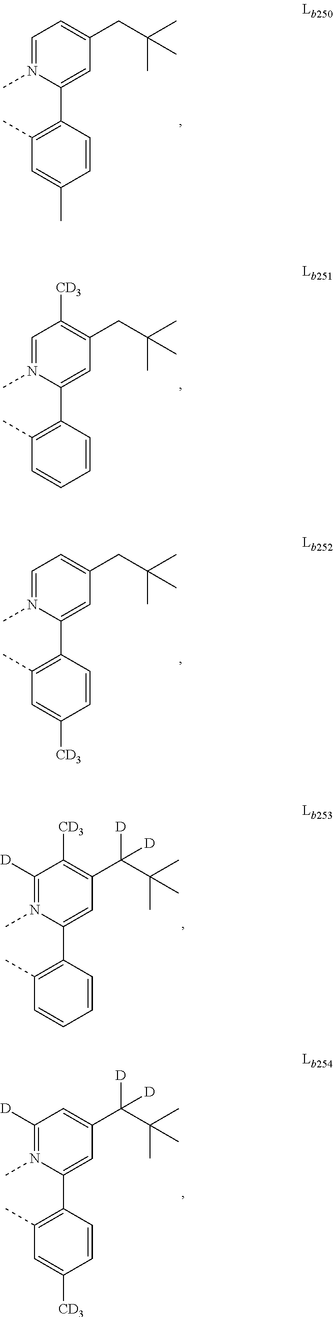 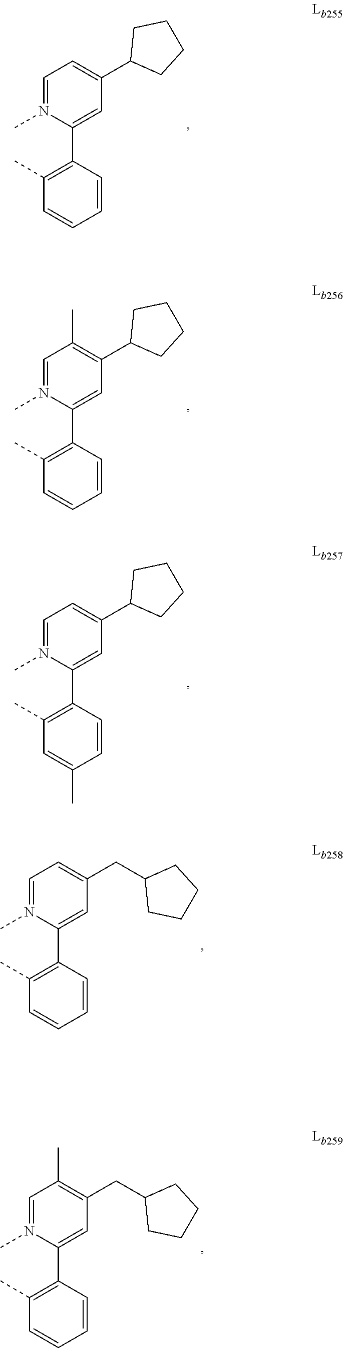 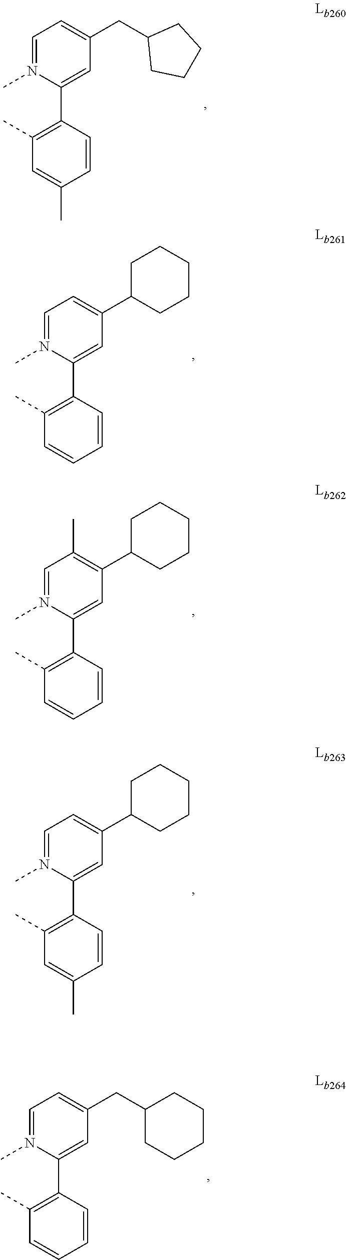 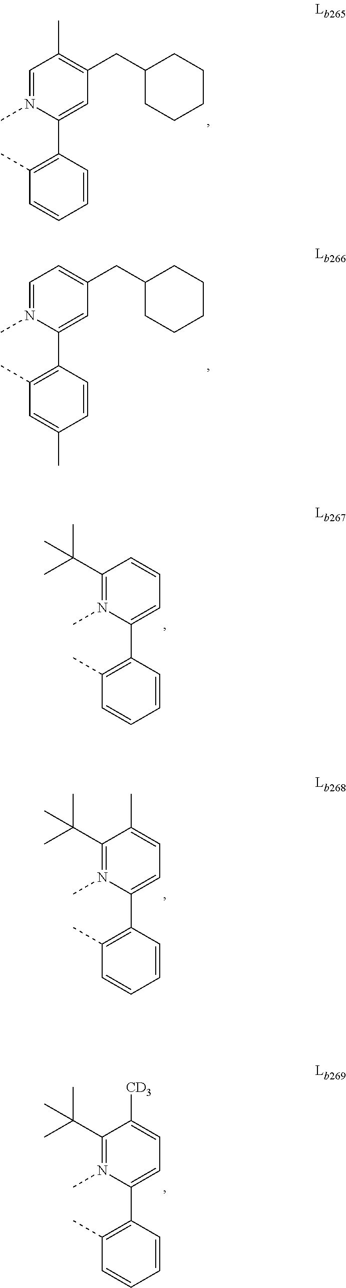 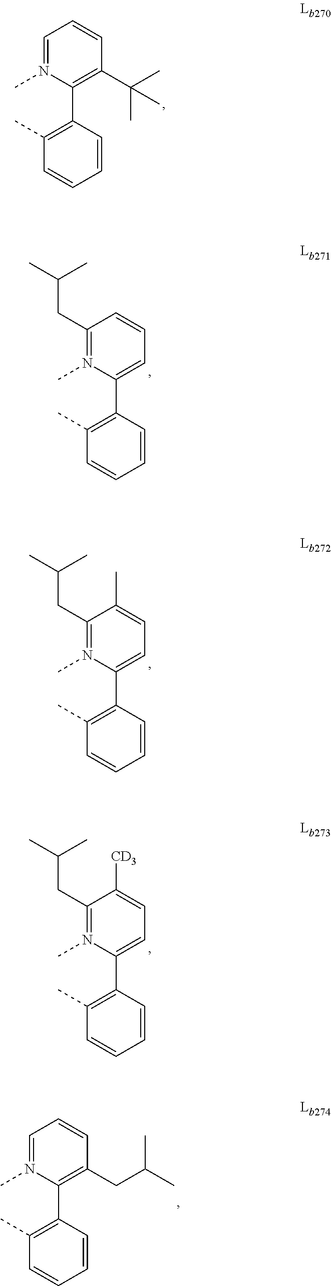 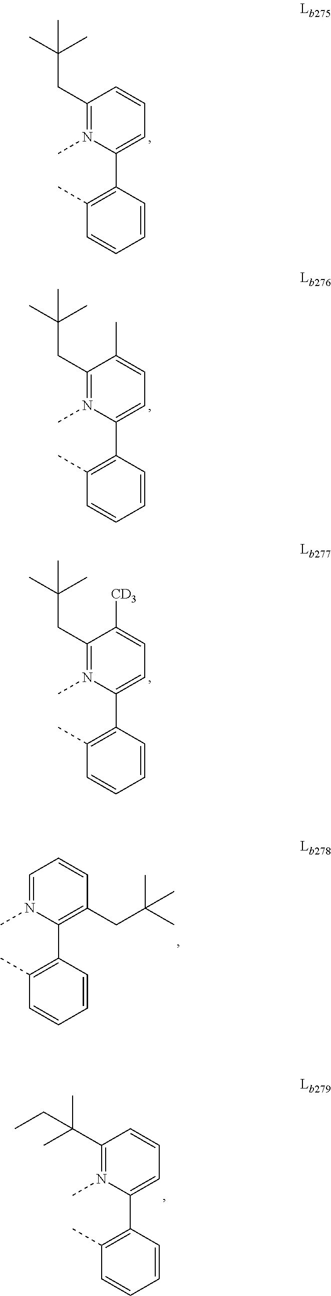 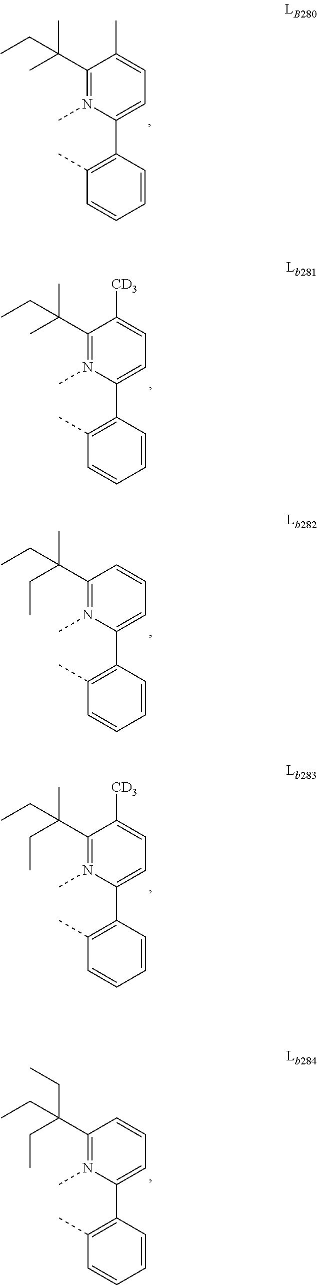 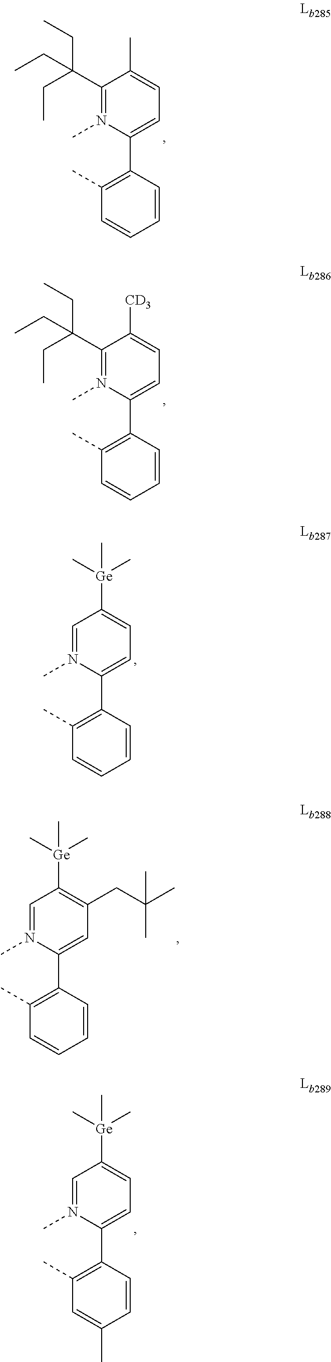 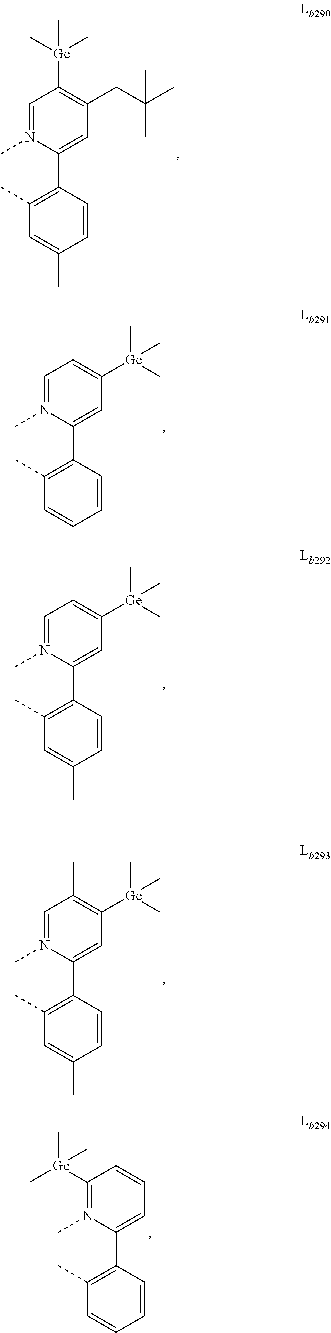 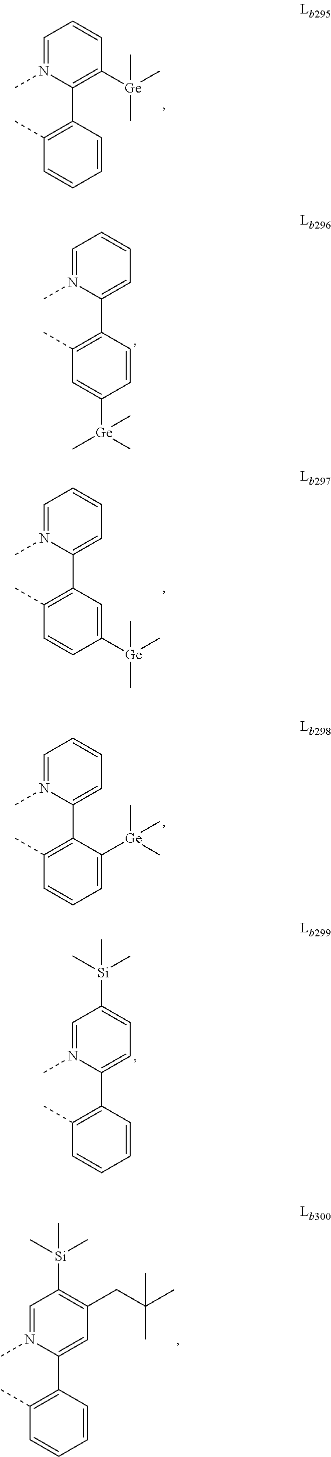 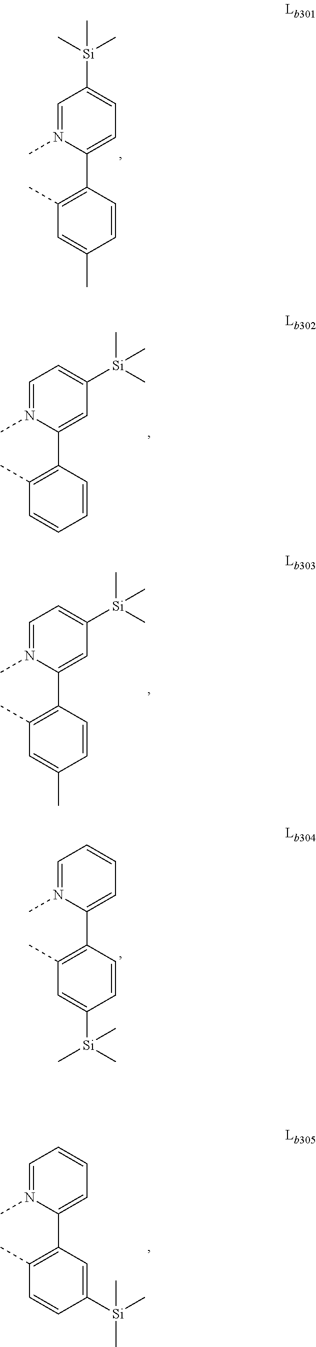 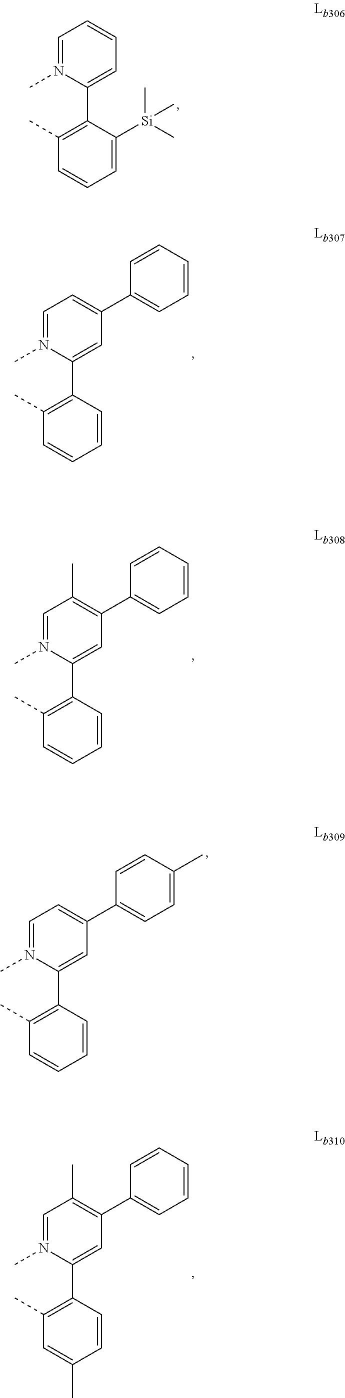 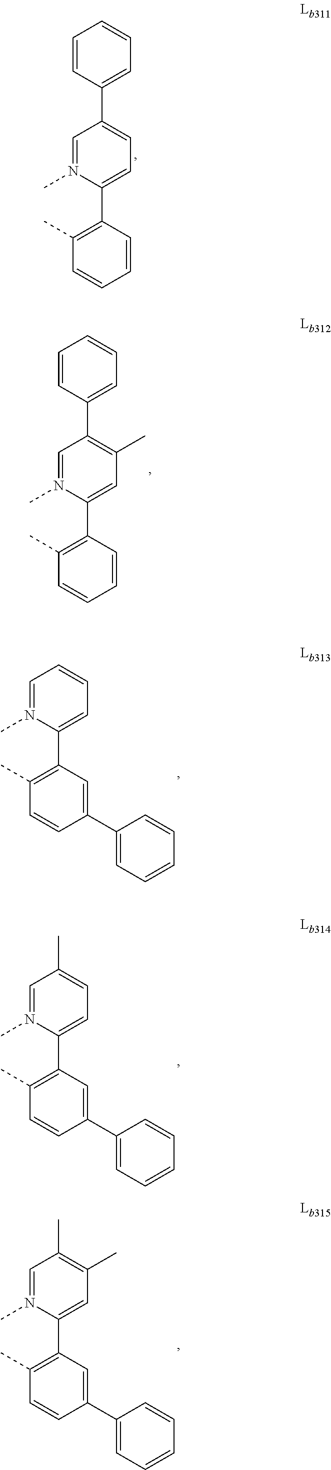 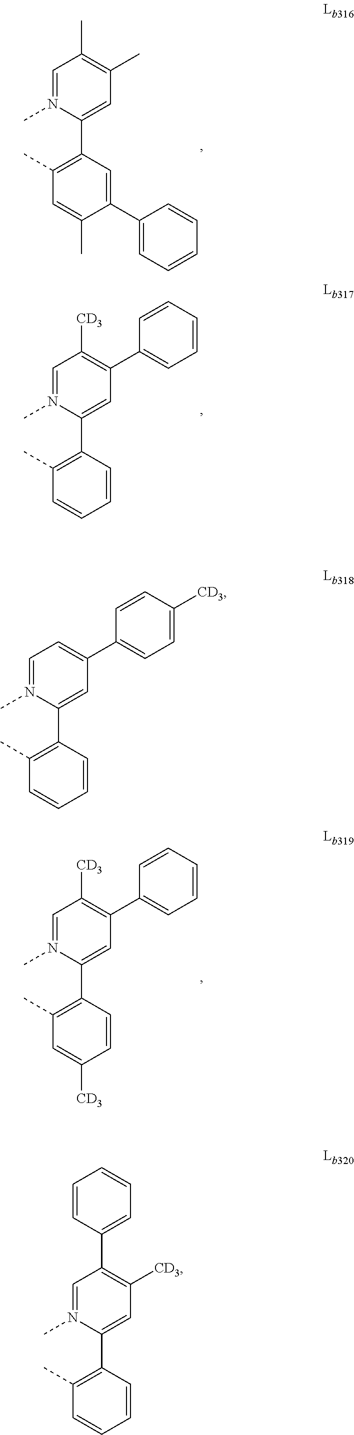 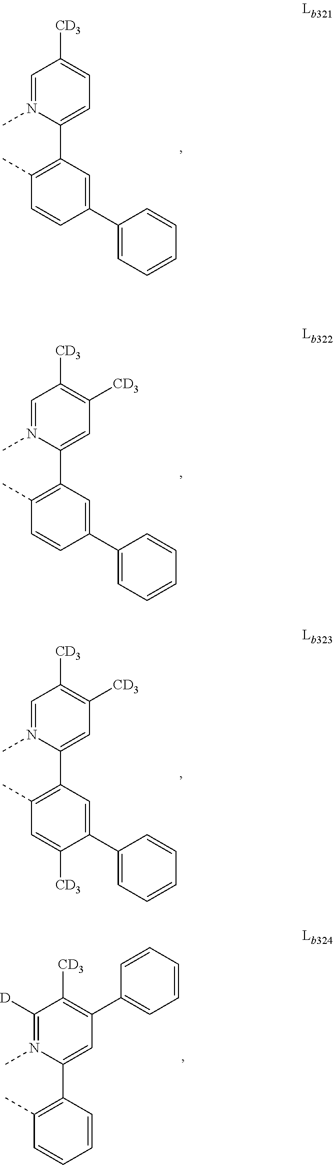 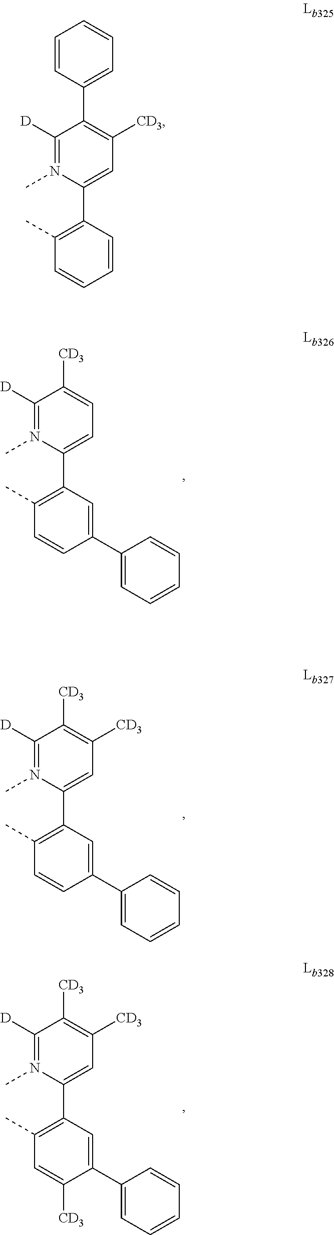 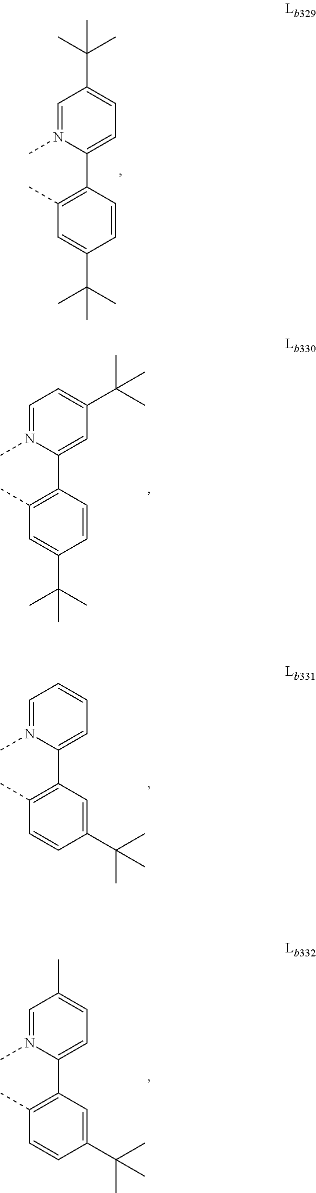 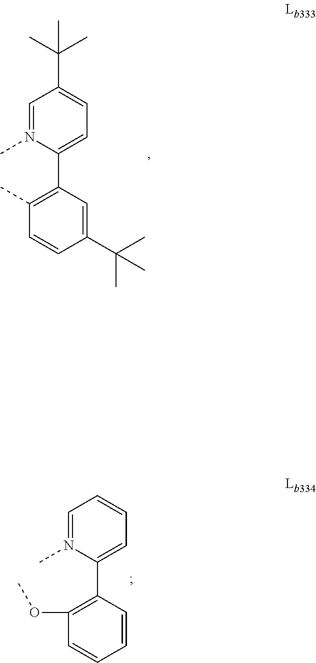
wherein optionally, hydrogen atoms in L_{b1} to L_{b334} can be partially or fully deuterated.

17. The metal complex according to claim 2, wherein L_{c} is, at each occurrence identically or differently, selected from the group consisting of:

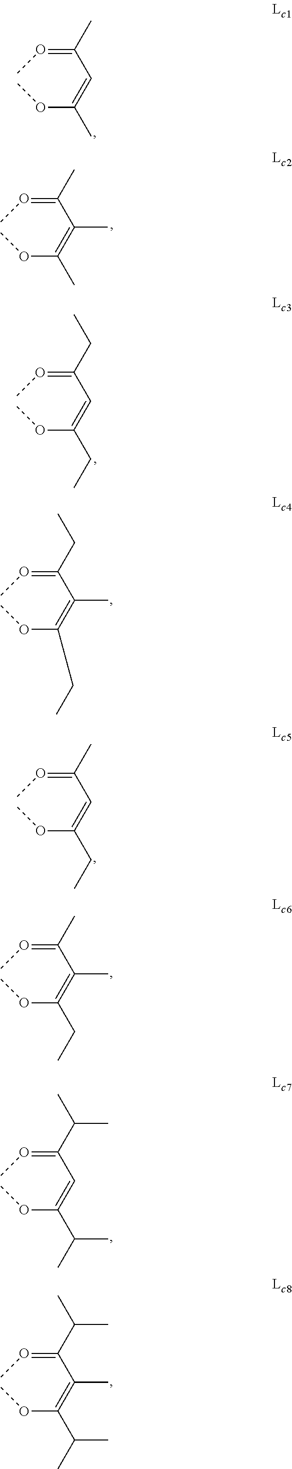

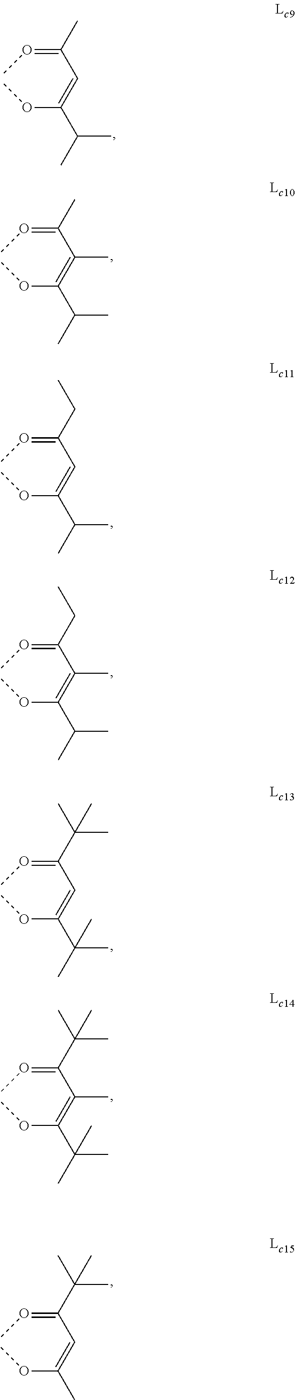

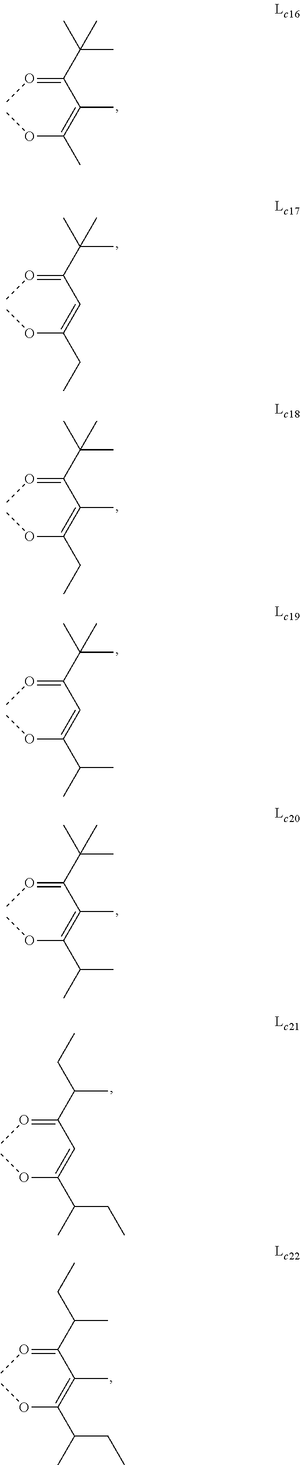

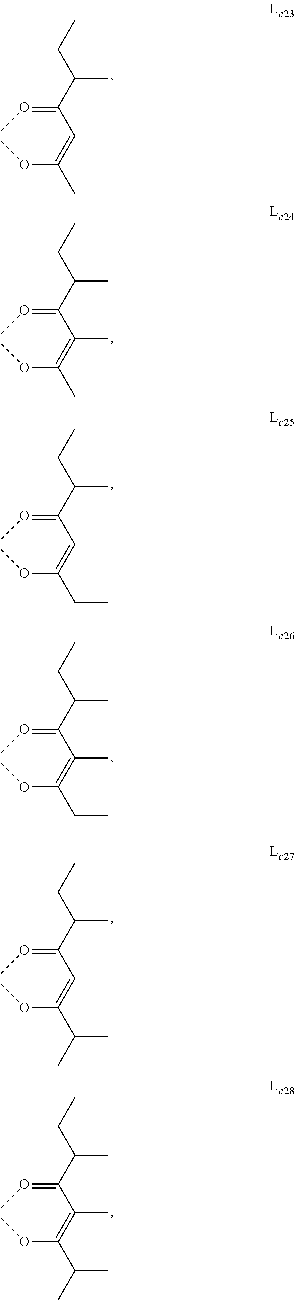

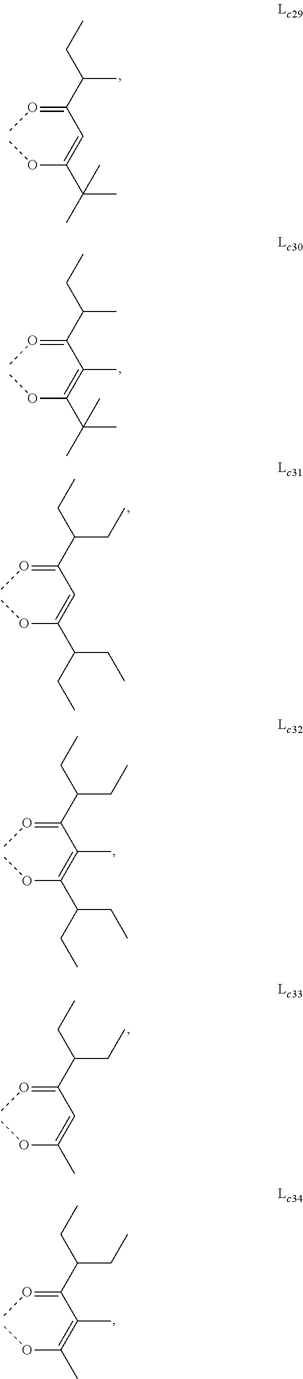

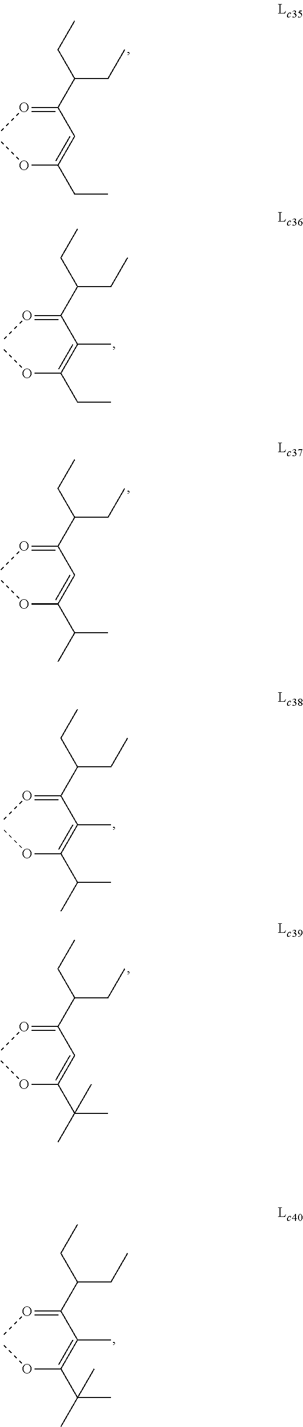

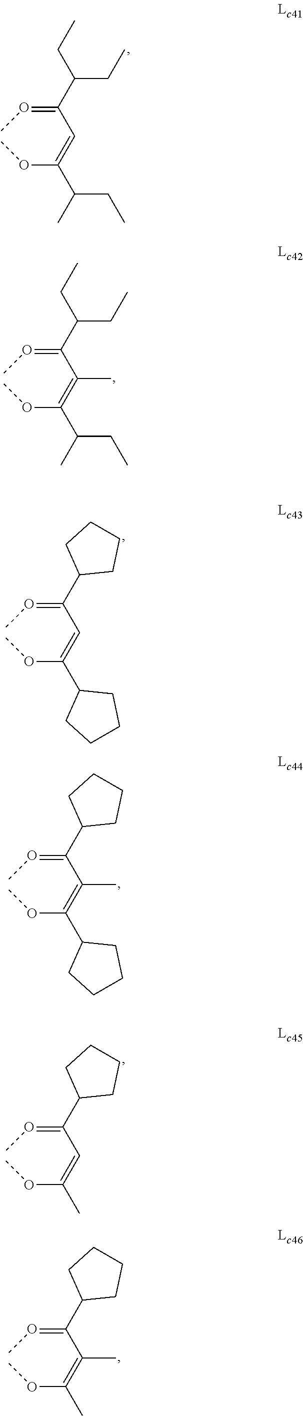

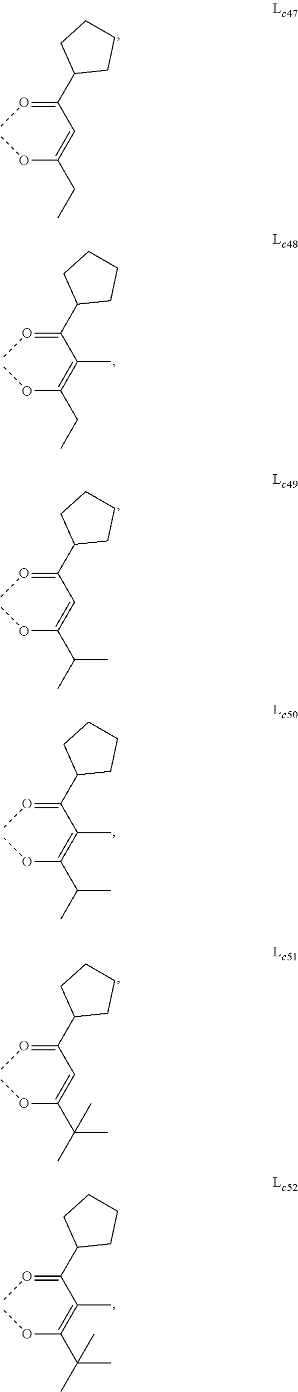

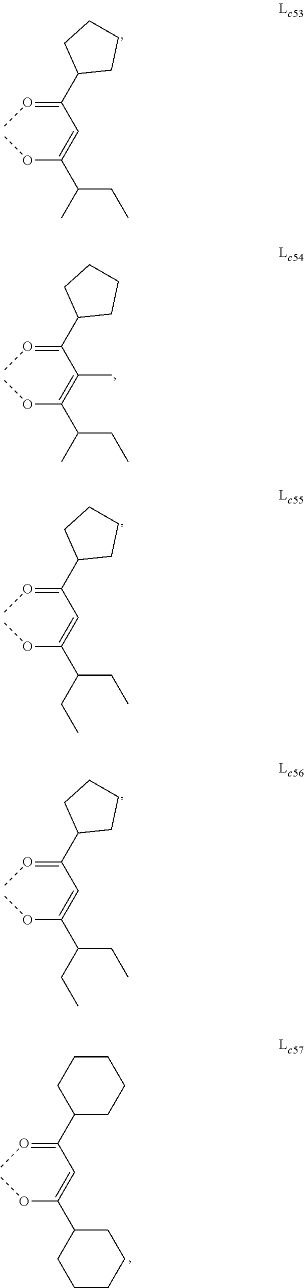

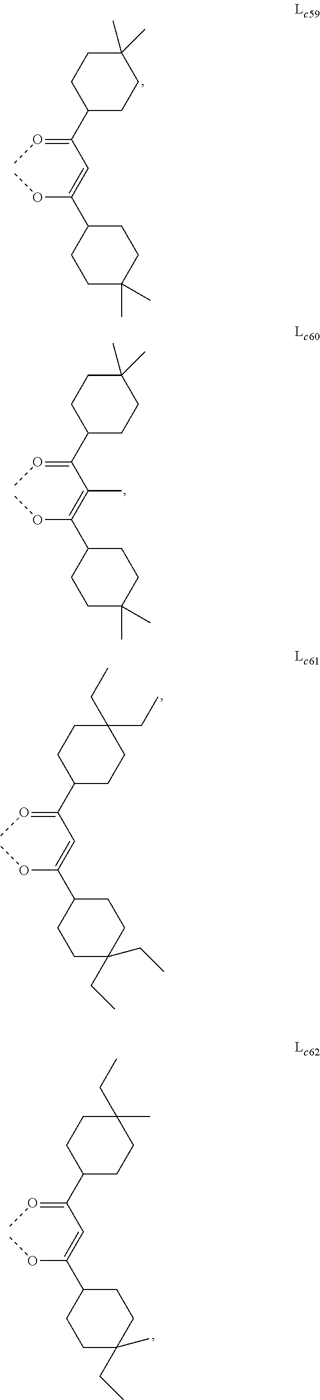

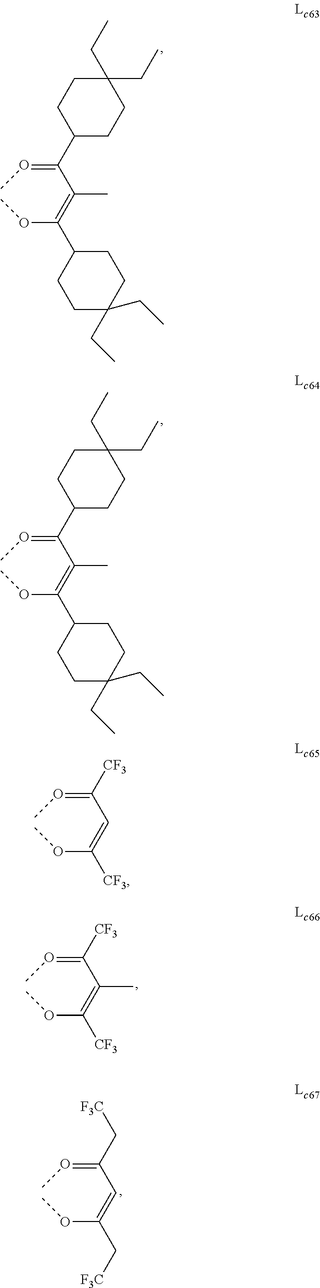

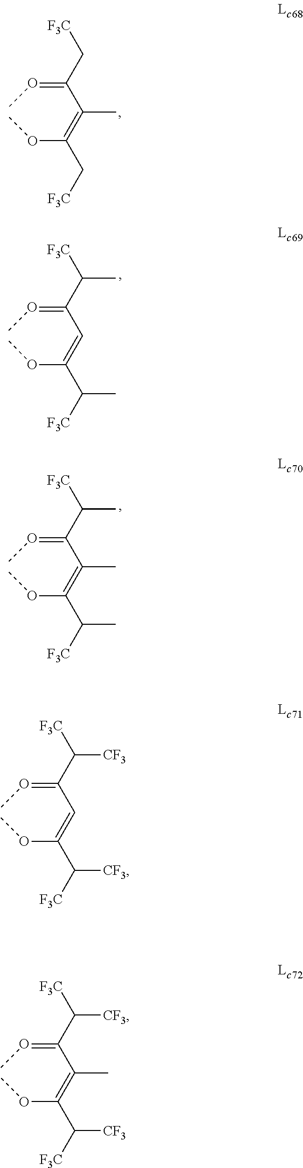

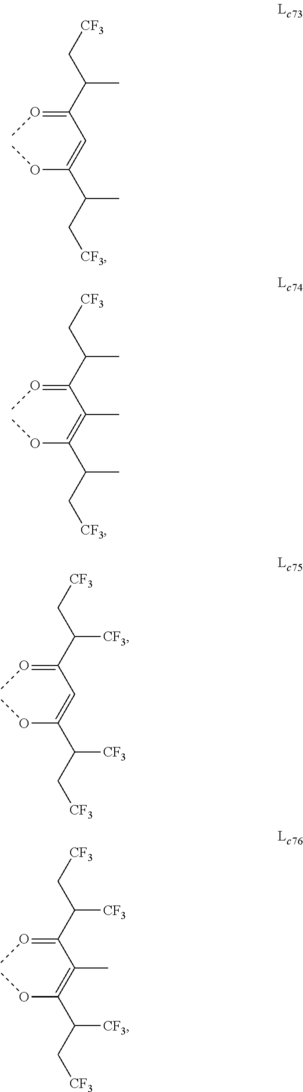

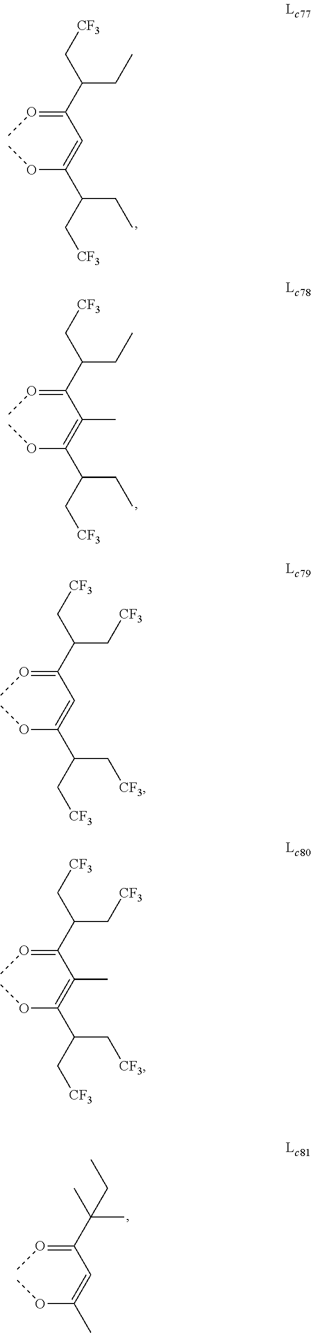

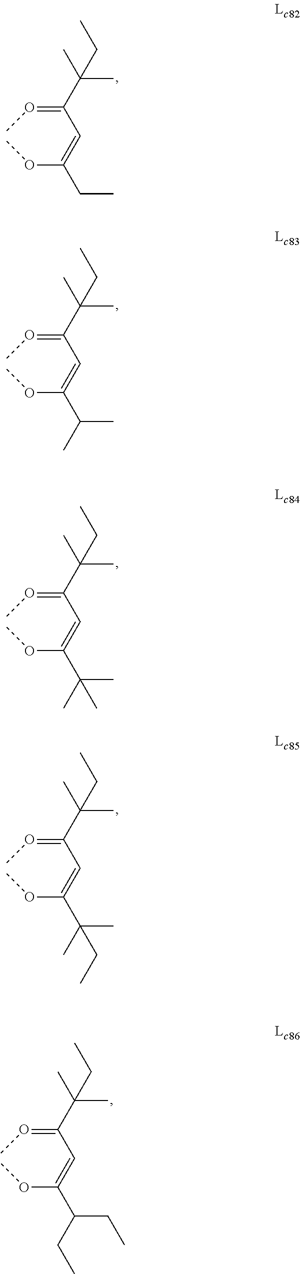

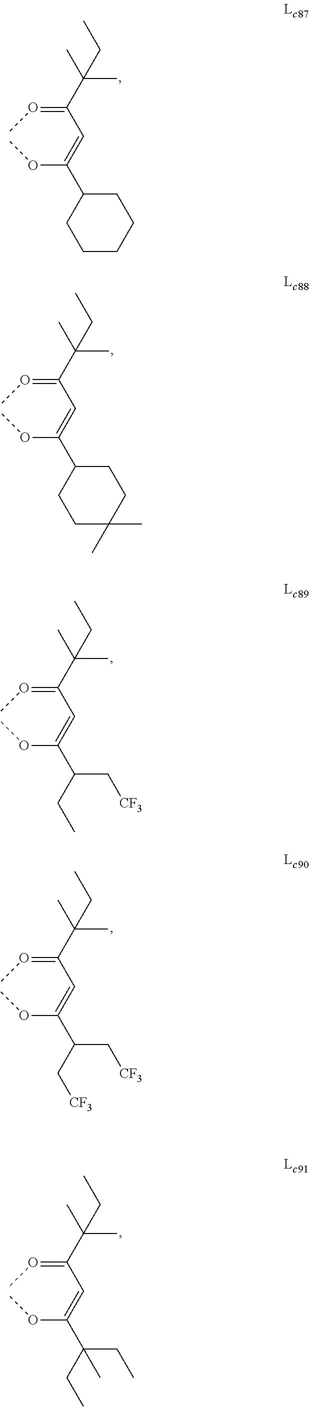

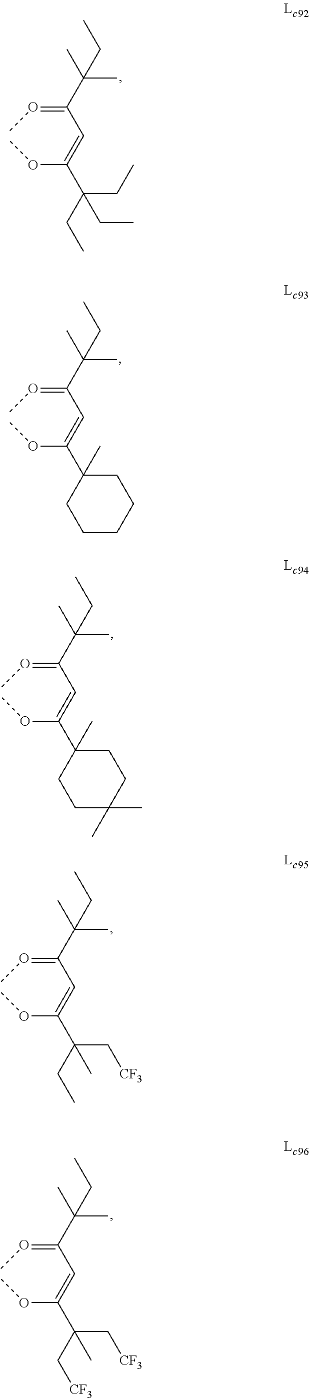

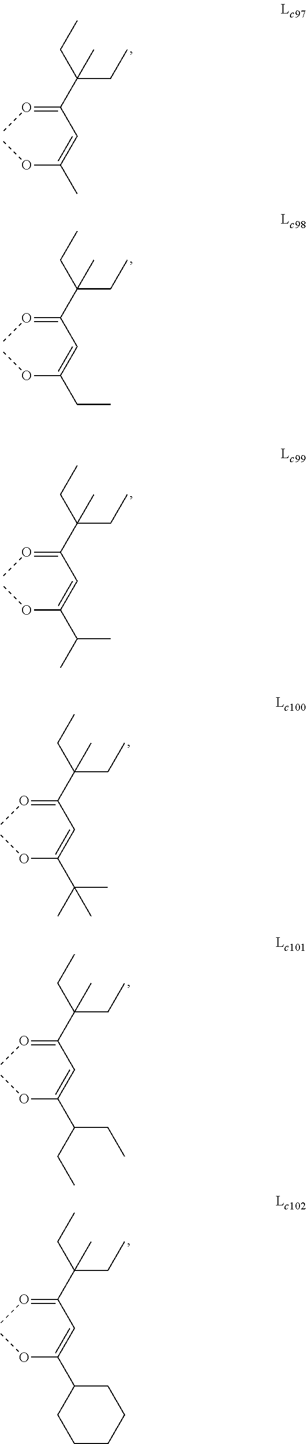

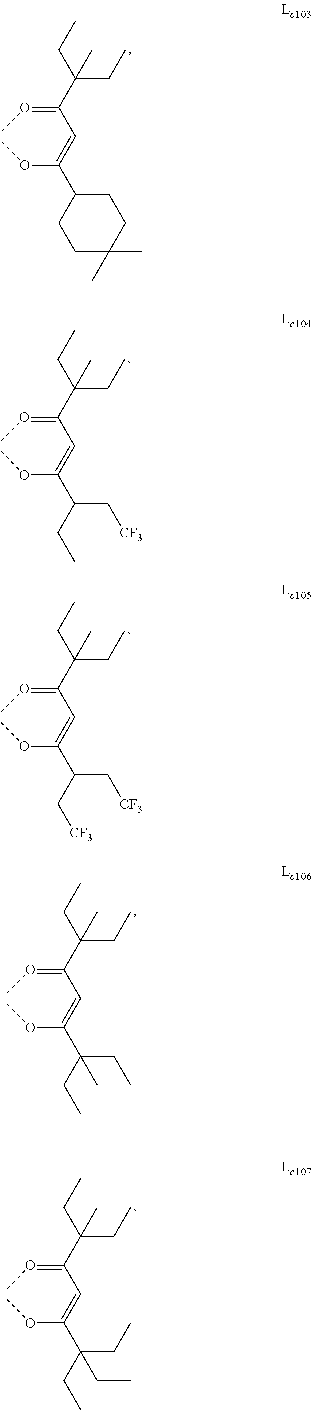

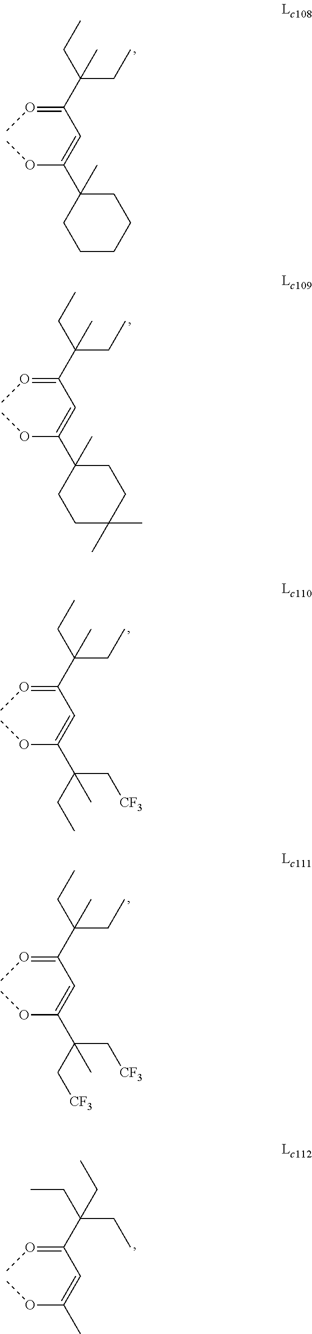

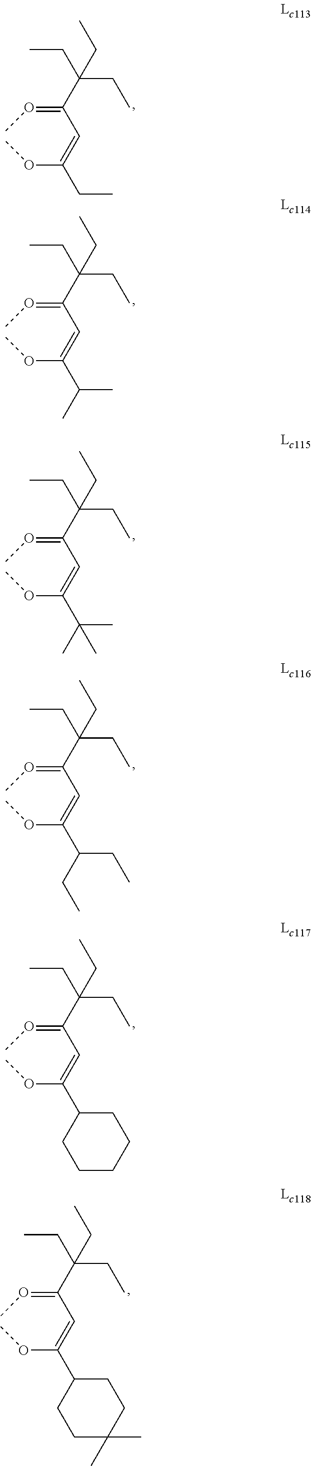

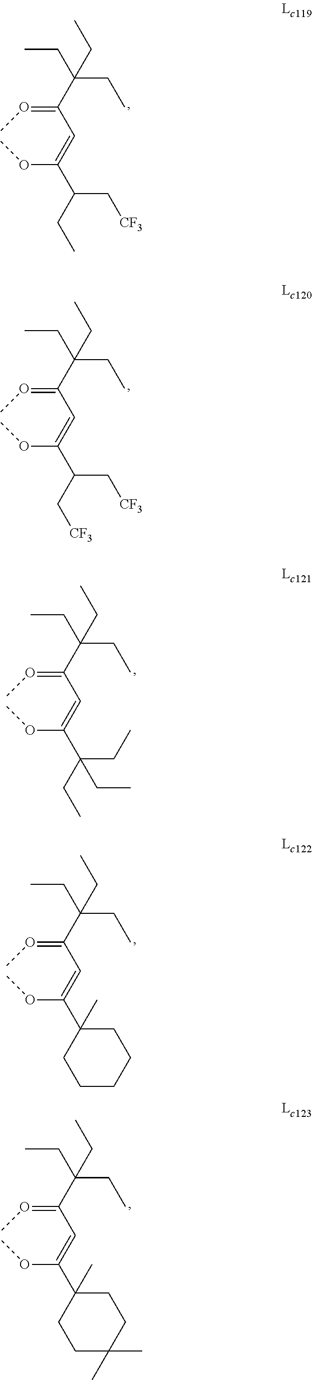

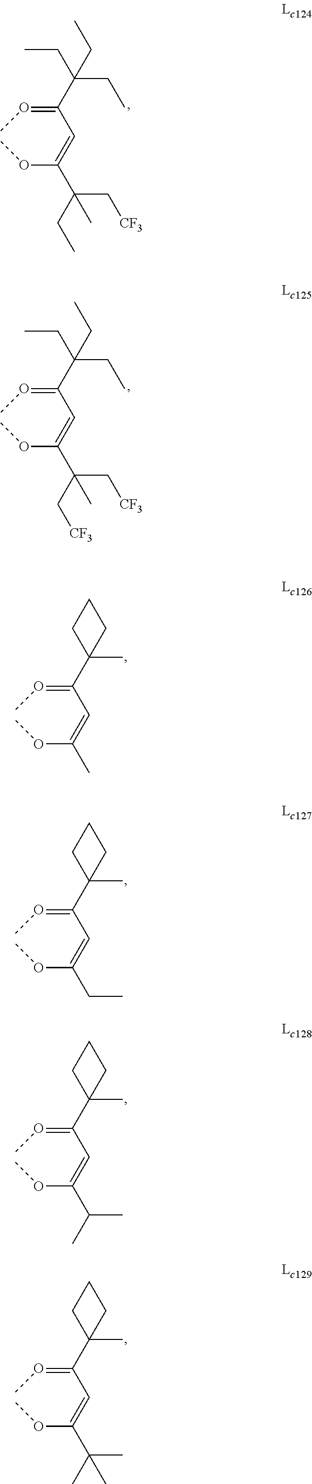

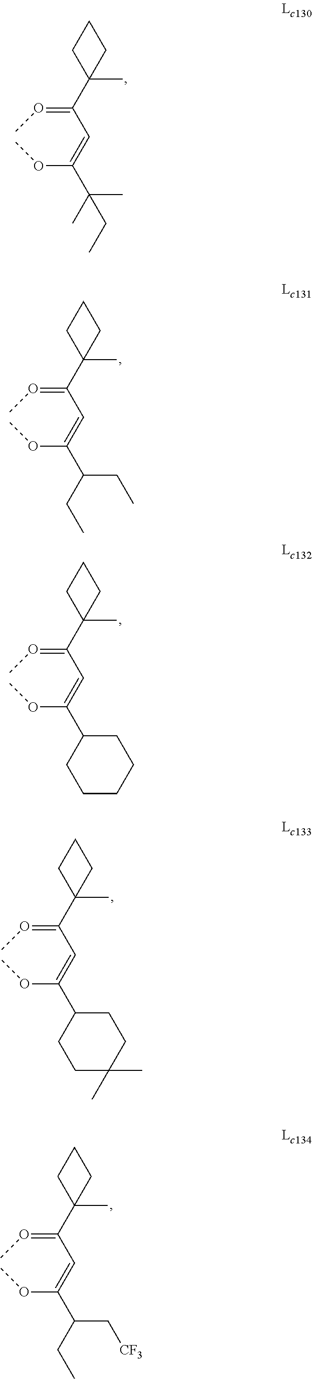

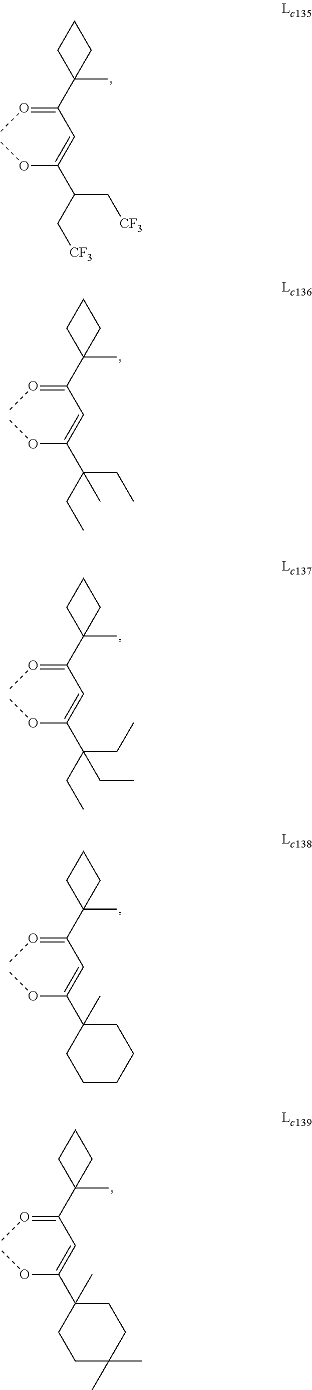

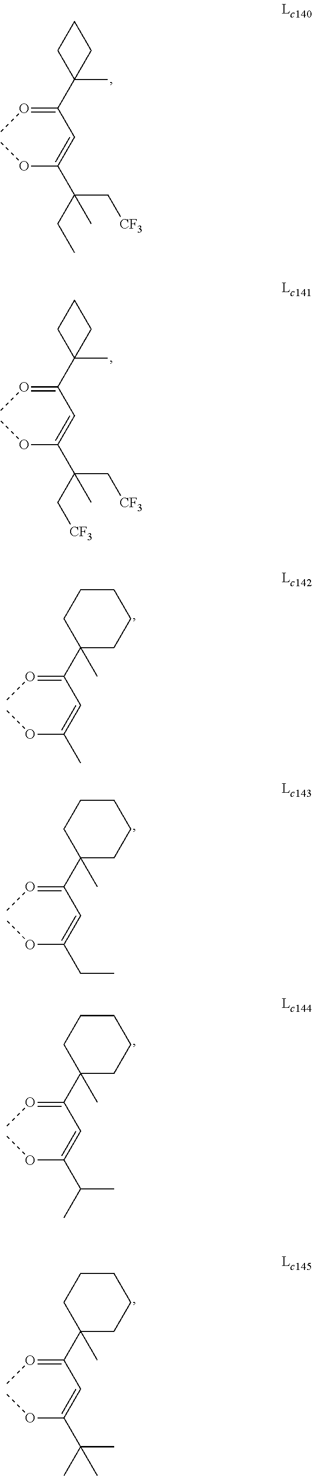

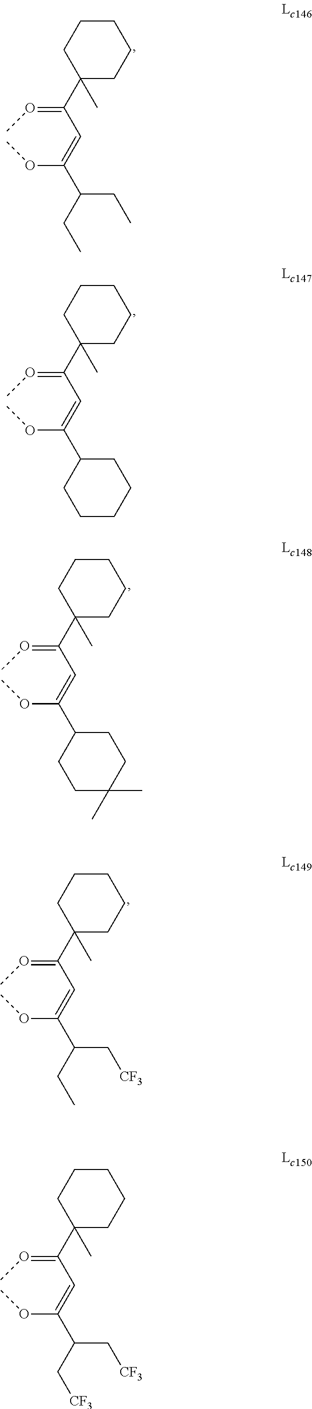

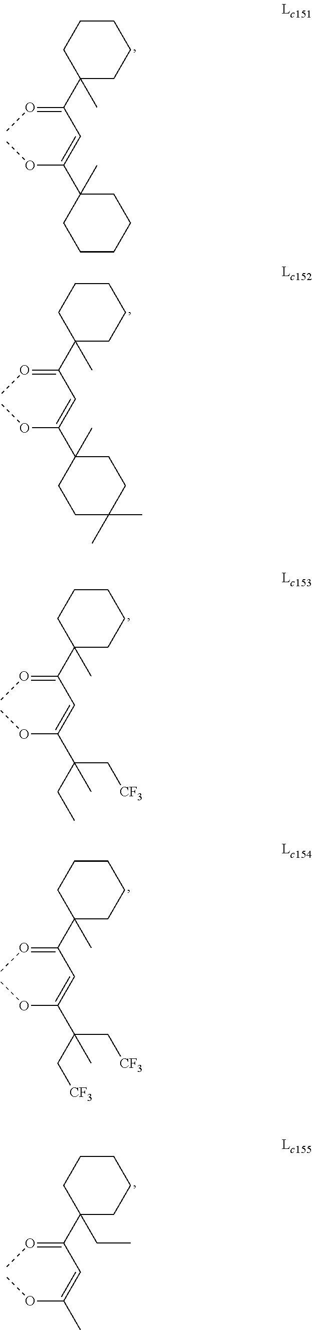

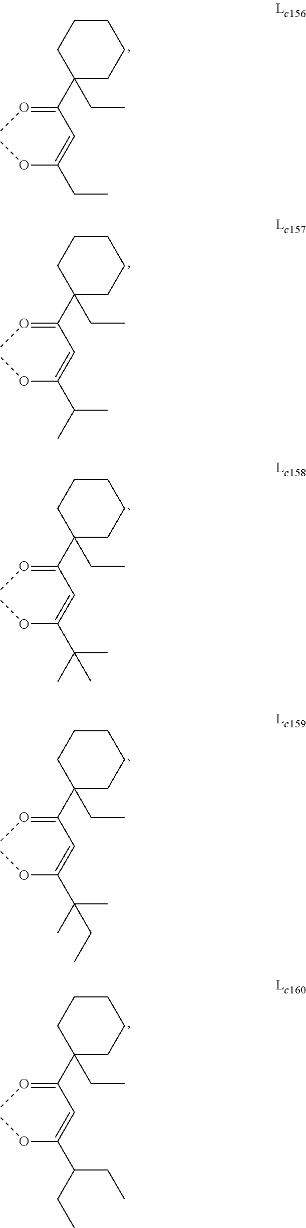

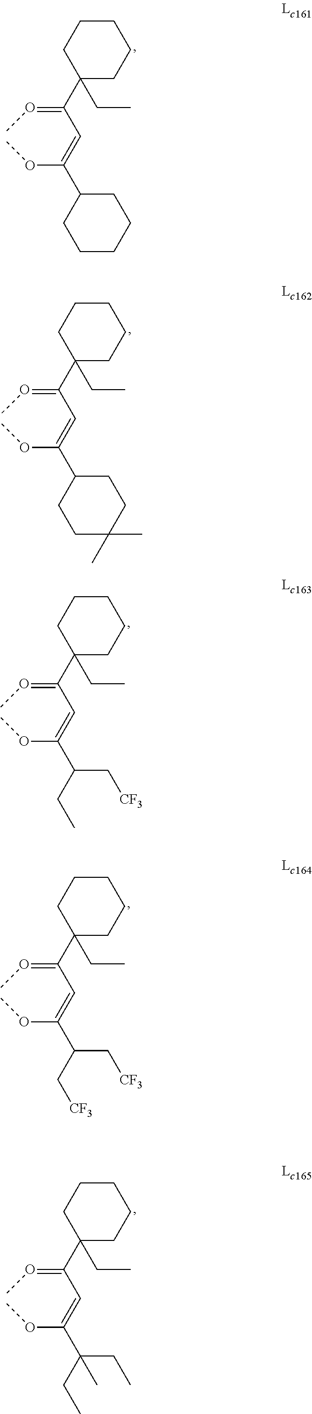

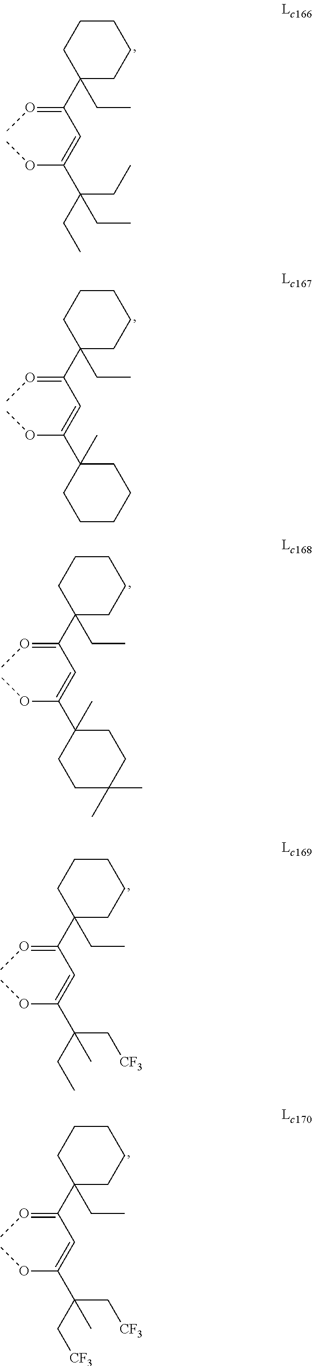

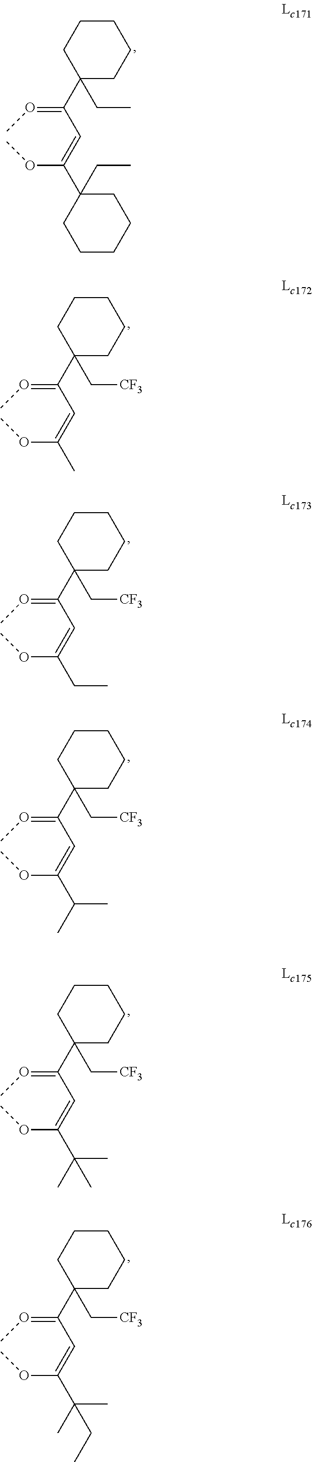

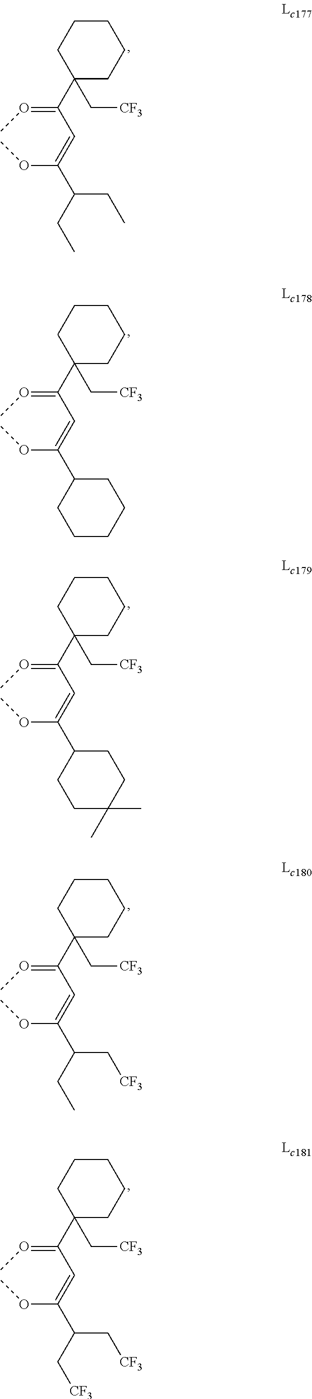

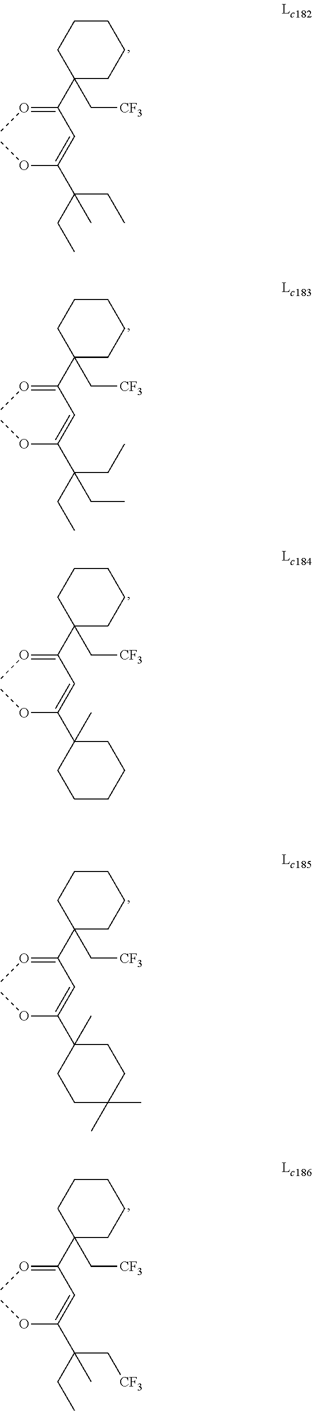

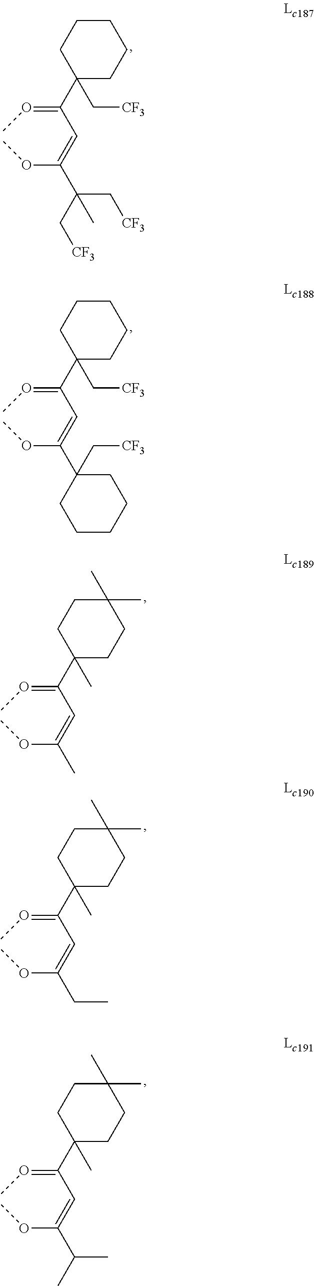

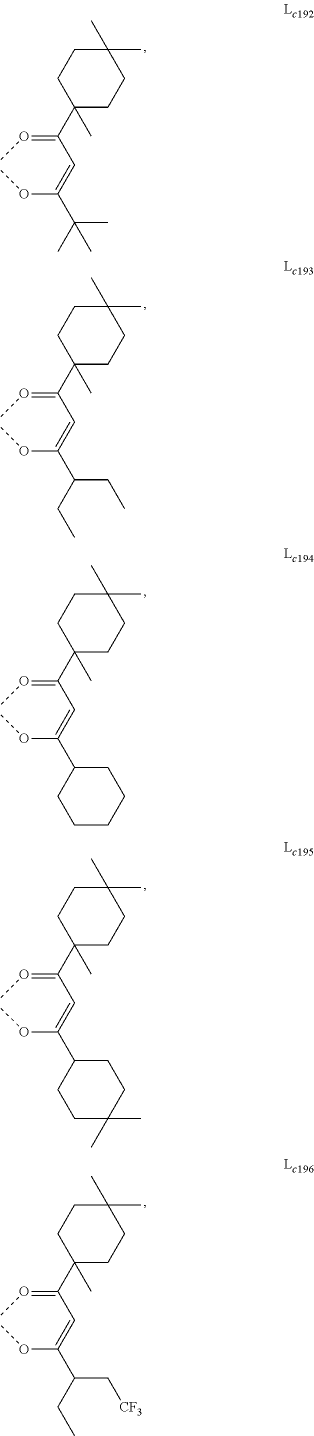

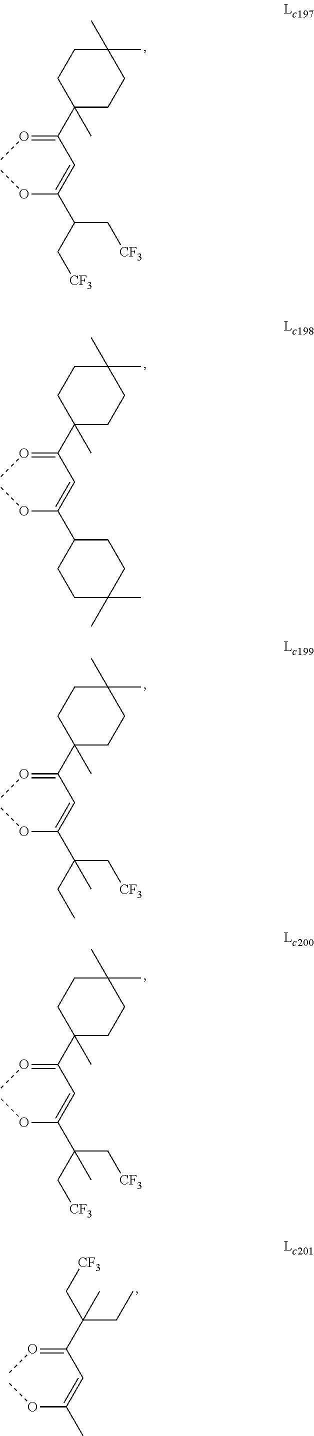

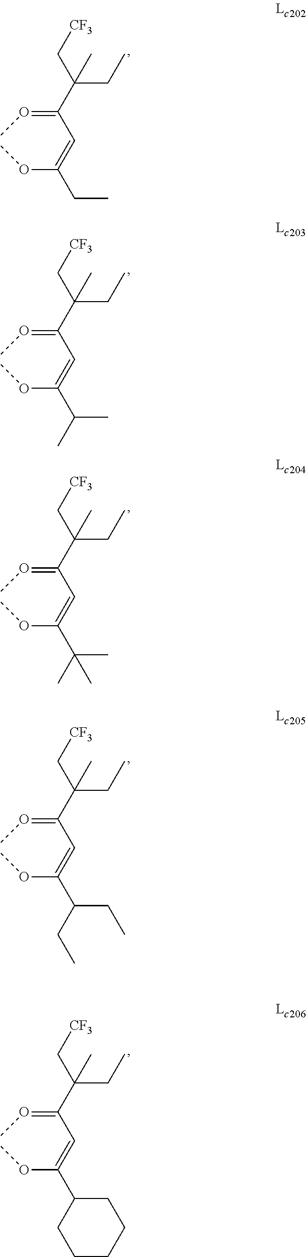

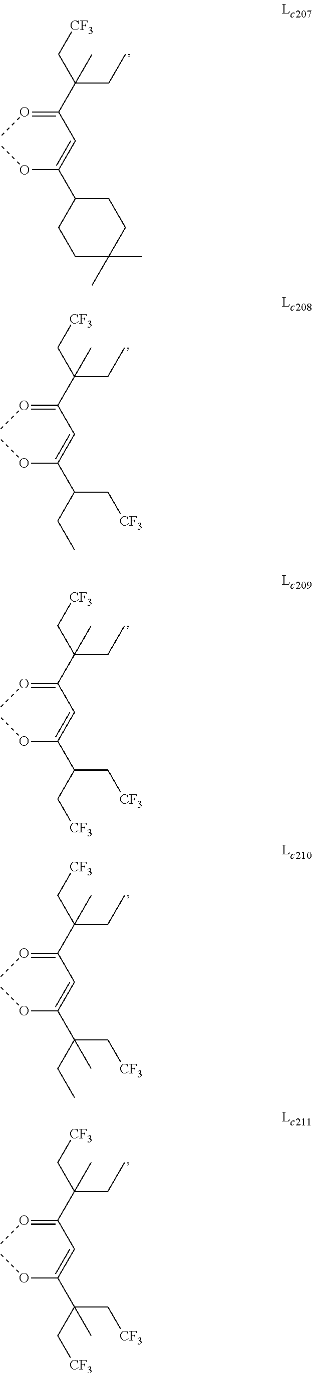

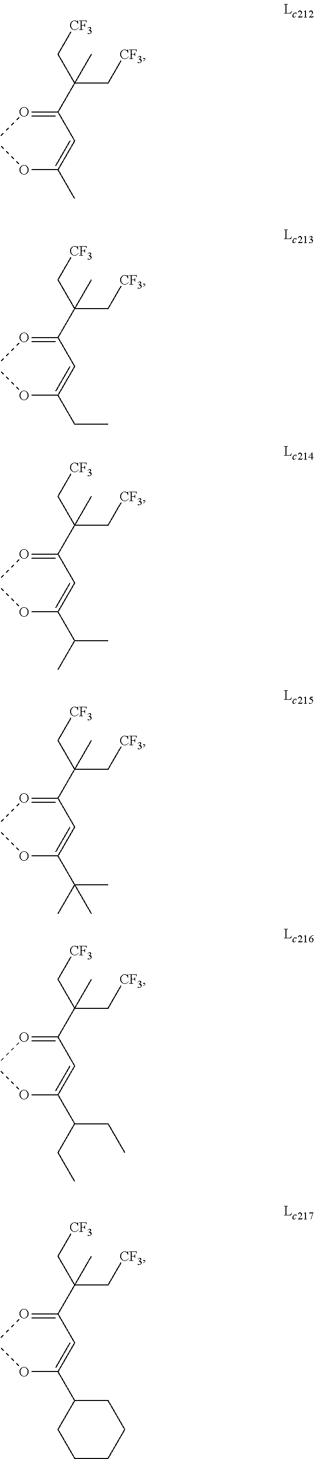

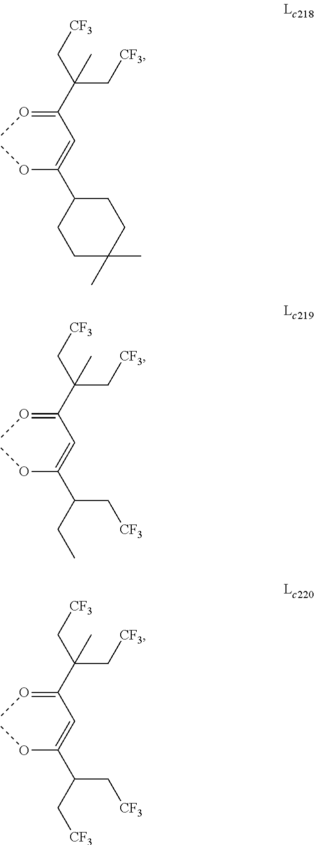

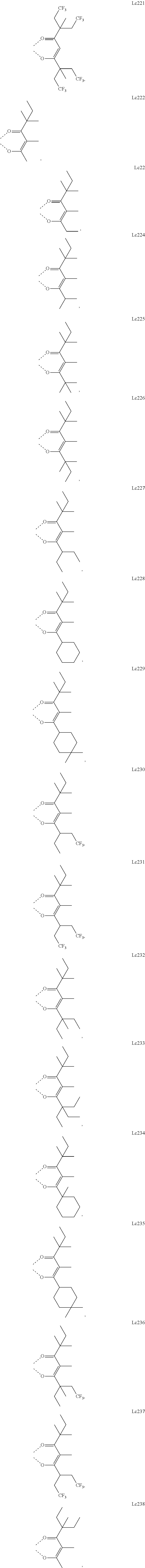

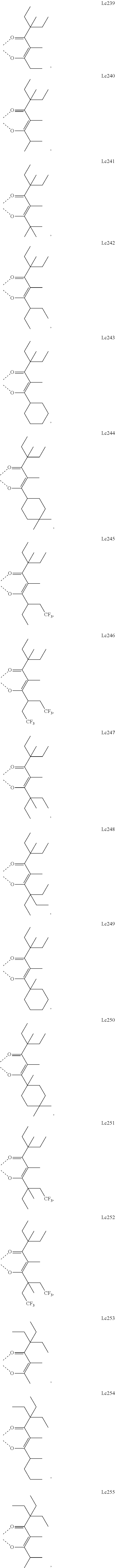

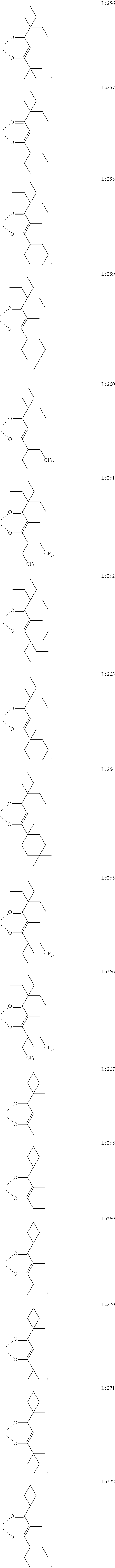

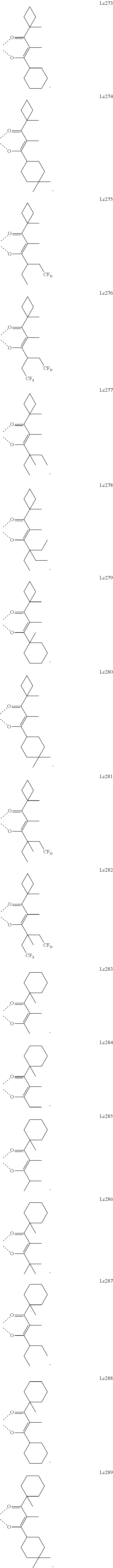

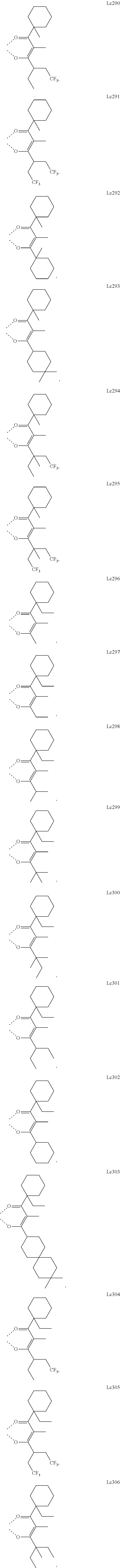

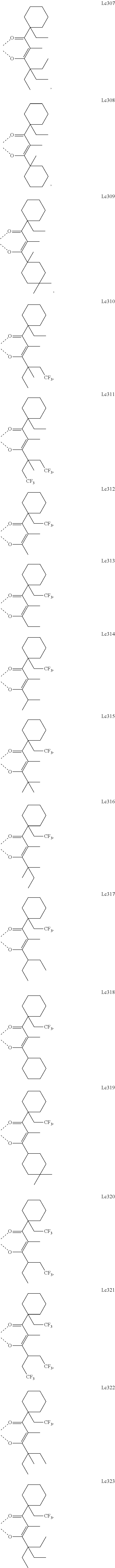

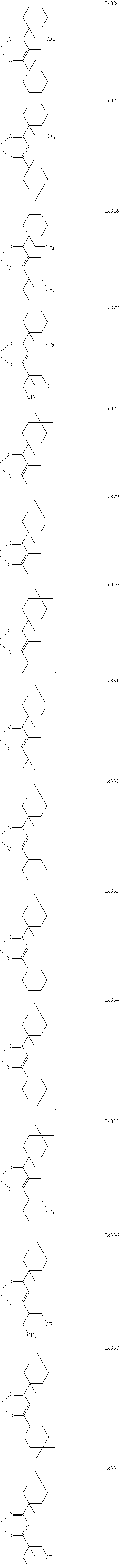

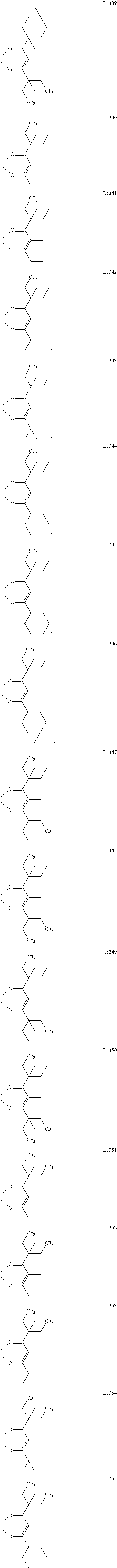

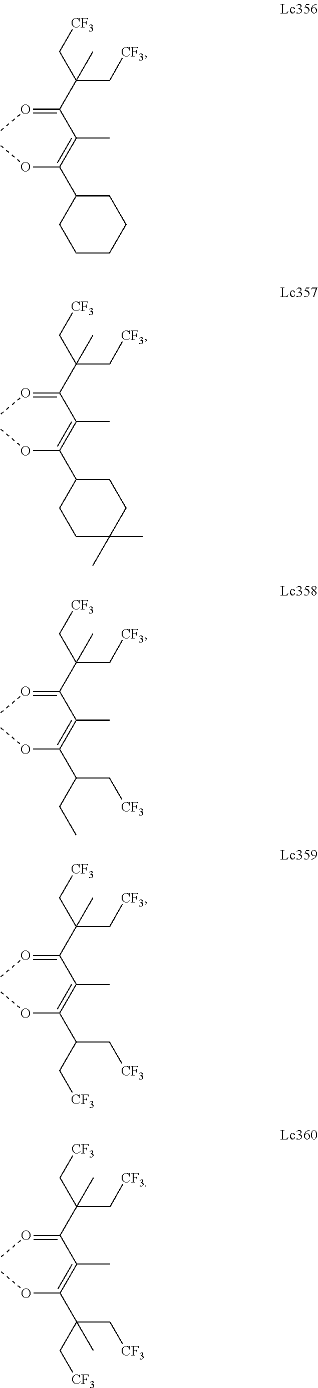

18. The metal complex according to claim 16, wherein the metal complex is selected from the group consisting of Metal Complex 1 to Metal Complex 435, wherein Metal Complex 1 to Metal Complex 435 have the structure of IrLₐ(L_{b})₂, wherein the two L_{b} are the same and Lₐ and L_{b} correspond to structures shown in the following table, respectively:

| Metal | | | Metal | | | Metal | | |
|---|---|---|---|---|---|---|---|---|
| Complex | Lₐ | L_{b} | Complex | Lₐ | L_{b} | Complex | Lₐ | L_{b} |
| 1 | Lₐ₁ | L_{b1} | 2 | Lₐ₃₁ | L_{b1} | 3 | Lₐ₃₄ | L_{b1} |
| 4 | Lₐ₅₃ | L_{b1} | 5 | Lₐ₉₁ | L_{b1} | 6 | Lₐ₉₃ | L_{b1} |
| 7 | Lₐ₉₄ | L_{b1} | 8 | Lₐ₉₆ | L_{b1} | 9 | Lₐ₉₇ | L_{b1} |
| 10 | Lₐ₂₀₂ | L_{b1} | 11 | Lₐ₂₃₂ | L_{b1} | 12 | Lₐ₂₃₅ | L_{b1} |
| 13 | Lₐ₂₅₄ | L_{b1} | 14 | Lₐ₂₉₈ | L_{b1} | 15 | Lₐ₃₇₄ | L_{b1} |
| 16 | Lₐ₄₀₄ | L_{b1} | 17 | Lₐ₄₀₇ | L_{b1} | 18 | Lₐ₄₂₆ | L_{b1} |
| 19 | Lₐ₄₆₄ | L_{b1} | 20 | Lₐ₄₆₆ | L_{b1} | 21 | Lₐ₄₆₇ | L_{b1} |
| 22 | Lₐ₄₆₉ | L_{b1} | 23 | Lₐ₄₇₀ | L_{b1} | 24 | Lₐ₄₇₃ | L_{b1} |
| 25 | Lₐ₄₇₄ | L_{b1} | 26 | Lₐ₄₇₅ | L_{b1} | 27 | Lₐ₄₈₁ | L_{b1} |
| 28 | Lₐ₄₈₂ | L_{b1} | 29 | Lₐ₄₈₃ | L_{b1} | 30 | Lₐ₄₈₄ | L_{b1} |
| 31 | Lₐ₅₈₂ | L_{b1} | 32 | Lₐ₆₁₂ | L_{b1} | 33 | Lₐ₆₁₅ | L_{b1} |
| 34 | Lₐ₆₃₄ | L_{b1} | 35 | Lₐ₇₃₂ | L_{b1} | 36 | Lₐ₈₁₀ | L_{b1} |
| 37 | Lₐ₁ | L_{b3} | 38 | Lₐ₃₁ | L_{b3} | 39 | Lₐ₃₄ | L_{b3} |
| 40 | Lₐ₅₃ | L_{b3} | 41 | Lₐ₉₁ | L_{b3} | 42 | Lₐ₉₃ | L_{b3} |
| 43 | Lₐ₉₄ | L_{b3} | 44 | Lₐ₉₆ | L_{b3} | 45 | Lₐ₉₇ | L_{b3} |
| 46 | Lₐ₂₀₂ | L_{b3} | 47 | Lₐ₂₃₂ | L_{b3} | 48 | Lₐ₂₃₅ | L_{b3} |
| 49 | Lₐ₂₅₄ | L_{b3} | 50 | Lₐ₂₉₈ | L_{b3} | 51 | Lₐ₃₇₄ | L_{b3} |
| 52 | Lₐ₄₀₄ | L_{b3} | 53 | Lₐ₄₀₇ | L_{b3} | 54 | Lₐ₄₂₆ | L_{b3} |
| 55 | Lₐ₄₆₄ | L_{b3} | 56 | Lₐ₄₆₆ | L_{b3} | 57 | Lₐ₄₆₇ | L_{b3} |
| 58 | Lₐ₄₆₉ | L_{b3} | 59 | Lₐ₄₇₀ | L_{b3} | 60 | Lₐ₄₇₃ | L_{b3} |
| 61 | Lₐ₄₇₄ | L_{b3} | 62 | Lₐ₄₇₅ | L_{b3} | 63 | Lₐ₄₈₁ | L_{b3} |
| 64 | Lₐ₄₈₂ | L_{b3} | 65 | Lₐ₄₈₃ | L_{b3} | 66 | Lₐ₄₈₄ | L_{b3} |
| 67 | Lₐ₅₈₂ | L_{b3} | 68 | Lₐ₆₁₂ | L_{b3} | 69 | Lₐ₆₁₅ | L_{b3} |
| 70 | Lₐ₆₃₄ | L_{b3} | 71 | Lₐ₇₃₂ | L_{b3} | 72 | Lₐ₈₁₀ | L_{b3} |
| 73 | Lₐ₁ | L_{b8} | 74 | Lₐ₃₁ | L_{b8} | 75 | Lₐ₃₄ | L_{b3} |
| 76 | Lₐ₅₃ | L_{b8} | 77 | Lₐ₉₁ | L_{b8} | 78 | Lₐ₉₃ | L_{b8} |
| 79 | Lₐ₉₄ | L_{b8} | 80 | Lₐ₉₆ | L_{b8} | 81 | Lₐ₉₇ | L_{b8} |
| 82 | Lₐ₂₀₂ | L_{b8} | 83 | Lₐ₂₃₂ | L_{b8} | 84 | Lₐ₂₃₅ | L_{b8} |
| 85 | Lₐ₂₅₄ | L_{b8} | 86 | Lₐ₂₉₈ | L_{b8} | 87 | Lₐ₃₇₄ | L_{b8} |
| 88 | Lₐ₄₀₄ | L_{b8} | 89 | Lₐ₄₀₇ | L_{b8} | 90 | Lₐ₄₂₆ | L_{b8} |
| 91 | Lₐ₄₆₄ | L_{b8} | 92 | Lₐ₄₆₆ | L_{b8} | 93 | Lₐ₄₆₇ | L_{b8} |
| 94 | Lₐ₄₆₉ | L_{b8} | 95 | Lₐ₄₇₀ | L_{b8} | 96 | Lₐ₄₇₃ | L_{b8} |
| 97 | Lₐ₄₇₄ | L_{b8} | 98 | Lₐ₄₇₅ | L_{b8} | 99 | Lₐ₄₈₁ | L_{b8} |
| 100 | Lₐ₄₈₂ | L_{b8} | 101 | Lₐ₄₈₃ | L_{b8} | 102 | Lₐ₄₈₄ | L_{b8} |
| 103 | Lₐ₅₈₂ | L_{b8} | 104 | Lₐ₆₁₂ | L_{b8} | 105 | Lₐ₆₁₅ | L_{b8} |
| 106 | Lₐ₆₃₄ | L_{b8} | 107 | Lₐ₇₃₂ | L_{b8} | 108 | Lₐ₈₁₀ | L_{b8} |
| 109 | Lₐ₁ | L_{b73} | 110 | Lₐ₃₁ | L_{b73} | 111 | Lₐ₃₄ | L_{b73} |
| 112 | Lₐ₅₃ | L_{b73} | 113 | Lₐ₉₁ | L_{b73} | 114 | Lₐ₉₃ | L_{b73} |
| 115 | Lₐ₉₄ | L_{b73} | 116 | Lₐ₉₆ | L_{b73} | 117 | Lₐ₉₇ | L_{b73} |
| 118 | Lₐ₂₀₂ | L_{b73} | 119 | Lₐ₂₃₂ | L_{b73} | 120 | Lₐ₂₃₅ | L_{b73} |
| 121 | Lₐ₂₅₄ | L_{b73} | 122 | Lₐ₂₉₈ | L_{b73} | 123 | Lₐ₃₇₄ | L_{b73} |
| 124 | Lₐ₄₀₄ | L_{b73} | 125 | Lₐ₄₀₇ | L_{b73} | 126 | Lₐ₄₂₆ | L_{b73} |
| 127 | Lₐ₄₆₄ | L_{b73} | 128 | Lₐ₄₆₆ | L_{b73} | 129 | Lₐ₄₆₇ | L_{b73} |
| 130 | Lₐ₄₆₉ | L_{b73} | 131 | Lₐ₄₇₀ | L_{b73} | 132 | Lₐ₄₇₃ | L_{b73} |
| 133 | Lₐ₄₇₄ | L_{b73} | 134 | Lₐ₄₇₅ | L_{b73} | 135 | Lₐ₄₈₁ | L_{b73} |
| 136 | Lₐ₄₈₂ | L_{b73} | 137 | Lₐ₄₈₃ | L_{b73} | 138 | Lₐ₄₈₄ | L_{b73} |
| 139 | Lₐ₅₈₂ | L_{b73} | 140 | Lₐ₆₁₂ | L_{b73} | 141 | Lₐ₆₁₅ | L_{b73} |
| 142 | Lₐ₆₃₄ | L_{b73} | 143 | Lₐ₇₃₂ | L_{b73} | 144 | Lₐ₈₁₀ | L_{b73} |
| 145 | Lₐ₁ | L_{b81} | 146 | Lₐ₃₁ | L_{b81} | 147 | Lₐ₃₄ | L_{b81} |
| 148 | Lₐ₅₃ | L_{b81} | 149 | Lₐ₉₁ | L_{b81} | 150 | Lₐ₉₃ | L_{b81} |
| 151 | Lₐ₉₄ | L_{b81} | 152 | Lₐ₉₆ | L_{b81} | 153 | Lₐ₉₇ | L_{b81} |
| 154 | Lₐ₂₀₂ | L_{b81} | 155 | Lₐ₂₃₂ | L_{b81} | 156 | Lₐ₂₃₅ | L_{b81} |
| 157 | Lₐ₂₅₄ | L_{b81} | 158 | Lₐ₂₉₈ | L_{b81} | 159 | Lₐ₃₇₄ | L_{b81} |
| 160 | Lₐ₄₀₄ | L_{b81} | 161 | Lₐ₄₀₇ | L_{b81} | 162 | Lₐ₄₂₆ | L_{b81} |
| 163 | Lₐ₄₆₄ | L_{b81} | 164 | Lₐ₄₆₆ | L_{b81} | 165 | Lₐ₄₆₇ | L_{b81} |
| 166 | Lₐ₄₆₉ | L_{b81} | 167 | Lₐ₄₇₀ | L_{b81} | 168 | Lₐ₄₇₃ | L_{b81} |
| 169 | Lₐ₄₇₄ | L_{b81} | 170 | Lₐ₄₇₅ | L_{b81} | 171 | Lₐ₄₈₁ | L_{b81} |
| 172 | Lₐ₄₈₂ | L_{b81} | 173 | Lₐ₄₈₃ | L_{b81} | 174 | Lₐ₄₈₄ | L_{b81} |
| 175 | Lₐ₅₈₂ | L_{b81} | 176 | Lₐ₆₁₂ | L_{b81} | 177 | Lₐ₆₁₅ | L_{b81} |
| 178 | Lₐ₆₃₄ | L_{b81} | 179 | Lₐ₇₃₂ | L_{b81} | 180 | Lₐ₈₁₀ | L_{b81} |
| 181 | Lₐ₁ | L_{b84} | 182 | Lₐ₃₁ | L_{b84} | 183 | Lₐ₃₄ | L_{b84} |
| 184 | Lₐ₅₃ | L_{b84} | 185 | Lₐ₉₁ | L_{b84} | 186 | Lₐ₉₃ | L_{b84} |
| 187 | Lₐ₉₄ | L_{b84} | 188 | Lₐ₉₆ | L_{b84} | 189 | Lₐ₉₇ | L_{b84} |
| 190 | Lₐ₂₀₂ | L_{b84} | 191 | Lₐ₂₃₂ | L_{b84} | 192 | Lₐ₂₃₅ | L_{b84} |
| 193 | Lₐ₂₅₄ | L_{b84} | 194 | Lₐ₂₉₈ | L_{b84} | 195 | Lₐ₃₇₄ | L_{b84} |
| 196 | Lₐ₄₀₄ | L_{b84} | 197 | Lₐ₄₀₇ | L_{b84} | 198 | Lₐ₄₂₆ | L_{b84} |
| 199 | Lₐ₄₆₄ | L_{b84} | 200 | Lₐ₄₆₆ | L_{b84} | 201 | Lₐ₄₆₇ | L_{b84} |
| 202 | Lₐ₄₆₉ | L_{b84} | 203 | Lₐ₄₇₀ | L_{b84} | 204 | Lₐ₄₇₃ | L_{b84} |
| 205 | Lₐ₄₇₄ | L_{b84} | 206 | Lₐ₄₇₅ | L_{b84} | 207 | Lₐ₄₈₁ | L_{b84} |
| 208 | Lₐ₄₈₂ | L_{b84} | 209 | Lₐ₄₈₃ | L_{b84} | 210 | Lₐ₄₈₄ | L_{b84} |
| 211 | Lₐ₅₈₂ | L_{b84} | 212 | Lₐ₆₁₂ | L_{b84} | 213 | Lₐ₄₈₁ | L_{b84} |
| 214 | Lₐ₆₃₄ | L_{b84} | 215 | Lₐ₇₃₂ | L_{b84} | 216 | Lₐ₄₈₄ | L_{b84} |
| 217 | Lₐ₁ | L_{b88} | 218 | Lₐ₃₁ | L_{b88} | 219 | Lₐ₃₄ | L_{b88} |
| 220 | Lₐ₅₃ | L_{b88} | 221 | Lₐ₉₁ | L_{b88} | 222 | Lₐ₉₃ | L_{b88} |
| 223 | Lₐ₉₄ | L_{b88} | 224 | Lₐ₉₆ | L_{b88} | 225 | Lₐ₉₇ | L_{b88} |
| 226 | Lₐ₂₀₂ | L_{b88} | 227 | Lₐ₂₃₂ | L_{b88} | 228 | Lₐ₂₃₅ | L_{b88} |
| 229 | Lₐ₂₅₄ | L_{b88} | 230 | Lₐ₂₉₈ | L_{b88} | 231 | Lₐ₃₇₄ | L_{b88} |
| 232 | Lₐ₄₀₄ | L_{b88} | 233 | Lₐ₄₀₇ | L_{b88} | 234 | Lₐ₄₂₆ | L_{b88} |
| 235 | Lₐ₄₆₄ | L_{b88} | 236 | Lₐ₄₆₆ | L_{b88} | 237 | Lₐ₄₆₇ | L_{b88} |
| 238 | Lₐ₄₆₉ | L_{b88} | 239 | Lₐ₄₇₀ | L_{b88} | 240 | Lₐ₄₇₃ | L_{b88} |
| 241 | Lₐ₄₇₄ | L_{b88} | 242 | Lₐ₄₇₅ | L_{b88} | 243 | Lₐ₄₈₁ | L_{b88} |
| 244 | Lₐ₄₈₂ | L_{b88} | 245 | Lₐ₄₈₃ | L_{b88} | 246 | Lₐ₄₈₄ | L_{b88} |
| 247 | Lₐ₅₈₂ | L_{b88} | 248 | Lₐ₆₁₂ | L_{b88} | 249 | Lₐ₆₁₅ | L_{b88} |
| 250 | Lₐ₆₃₄ | L_{b88} | 251 | Lₐ₇₃₂ | L_{b88} | 252 | Lₐ₈₁₀ | L_{b88} |
| 253 | Lₐ₁ | L_{b112} | 254 | Lₐ₃₁ | L_{b112} | 255 | Lₐ₃₄ | L_{b112} |
| 256 | Lₐ₅₃ | L_{b112} | 257 | Lₐ₉₁ | L_{b112} | 258 | Lₐ₉₃ | L_{b112} |
| 259 | Lₐ₉₄ | L_{b112} | 260 | Lₐ₉₆ | L_{b112} | 261 | Lₐ₉₇ | L_{b112} |
| 262 | Lₐ₂₀₂ | L_{b112} | 263 | Lₐ₂₃₂ | L_{b112} | 264 | Lₐ₂₃₅ | L_{b112} |
| 265 | Lₐ₂₅₄ | L_{b112} | 266 | Lₐ₂₉₈ | L_{b112} | 267 | Lₐ₃₇₄ | L_{b112} |
| 268 | Lₐ₄₀₄ | L_{b112} | 269 | Lₐ₄₀₇ | L_{b112} | 270 | Lₐ₄₂₆ | L_{b112} |
| 271 | Lₐ₄₆₄ | L_{b112} | 272 | Lₐ₄₆₆ | L_{b112} | 273 | Lₐ₄₆₇ | L_{b112} |
| 274 | Lₐ₄₆₉ | L_{b112} | 275 | Lₐ₄₇₀ | L_{b112} | 276 | Lₐ₄₇₃ | L_{b112} |
| 277 | Lₐ₄₇₄ | L_{b112} | 278 | Lₐ₄₇₅ | L_{b112} | 279 | Lₐ₄₈₁ | L_{b112} |
| 280 | Lₐ₄₈₂ | L_{b112} | 281 | Lₐ₄₈₃ | L_{b112} | 282 | Lₐ₄₈₄ | L_{b112} |
| 283 | Lₐ₅₈₂ | L_{b112} | 284 | Lₐ₆₁₂ | L_{b112} | 285 | Lₐ₆₁₅ | L_{b112} |
| 286 | Lₐ₆₃₄ | L_{b112} | 287 | Lₐ₇₃₂ | L_{b112} | 288 | Lₐ₈₁₀ | L_{b112} |
| 289 | Lₐ₁ | L_{b164} | 290 | Lₐ₃₁ | L_{b164} | 291 | Lₐ₃₄ | L_{b164} |
| 292 | Lₐ₅₃ | L_{b164} | 293 | Lₐ₉₁ | L_{b164} | 294 | Lₐ₉₃ | L_{b164} |
| 295 | Lₐ₉₄ | L_{b164} | 296 | Lₐ₉₆ | L_{b164} | 297 | Lₐ₉₇ | L_{b164} |
| 298 | Lₐ₂₀₂ | L_{b164} | 299 | Lₐ₂₃₂ | L_{b164} | 300 | Lₐ₂₃₅ | L_{b164} |
| 301 | Lₐ₂₅₄ | L_{b164} | 302 | Lₐ₂₉₈ | L_{b164} | 303 | Lₐ₃₇₄ | L_{b164} |
| 304 | Lₐ₄₀₄ | L_{b164} | 305 | Lₐ₄₀₇ | L_{b164} | 306 | Lₐ₄₂₆ | L_{b164} |
| 307 | Lₐ₄₆₄ | L_{b164} | 308 | Lₐ₄₆₆ | L_{b164} | 309 | Lₐ₄₆₇ | L_{b164} |
| 310 | Lₐ₄₆₉ | L_{b164} | 311 | Lₐ₄₇₀ | L_{b164} | 312 | Lₐ₄₇₃ | L_{b164} |
| 313 | Lₐ₄₇₄ | L_{b164} | 314 | Lₐ₄₇₅ | L_{b164} | 315 | Lₐ₄₈₁ | L_{b164} |
| 316 | Lₐ₄₈₂ | L_{b164} | 317 | Lₐ₄₈₃ | L_{b164} | 318 | Lₐ₄₈₄ | L_{b164} |
| 319 | Lₐ₅₈₂ | L_{b164} | 320 | Lₐ₆₁₂ | L_{b164} | 321 | Lₐ₆₁₅ | L_{b164} |
| 322 | Lₐ₆₃₄ | L_{b164} | 323 | Lₐ₇₃₂ | L_{b164} | 324 | Lₐ₈₁₀ | L_{b164} |
| 325 | Lₐ₁ | L_{b209} | 326 | Lₐ₃₁ | L_{b209} | 327 | Lₐ₃₄ | L_{b209} |
| 328 | Lₐ₅₃ | L_{b209} | 329 | Lₐ₉₁ | L_{b209} | 330 | Lₐ₉₃ | L_{b209} |
| 331 | Lₐ₉₄ | L_{b209} | 332 | Lₐ₉₆ | L_{b209} | 333 | Lₐ₉₇ | L_{b209} |
| 334 | Lₐ₂₀₂ | L_{b209} | 335 | Lₐ₂₃₂ | L_{b209} | 336 | Lₐ₂₃₅ | L_{b209} |
| 337 | Lₐ₂₅₄ | L_{b209} | 338 | Lₐ₂₉₈ | L_{b209} | 339 | Lₐ₃₇₄ | L_{b209} |
| 340 | Lₐ₄₀₄ | L_{b209} | 341 | Lₐ₄₀₇ | L_{b209} | 342 | Lₐ₄₂₆ | L_{b209} |
| 343 | Lₐ₄₆₄ | L_{b209} | 344 | Lₐ₄₆₆ | L_{b209} | 345 | Lₐ₄₆₇ | L_{b209} |
| 346 | Lₐ₄₆₉ | L_{b209} | 347 | Lₐ₄₇₀ | L_{b209} | 348 | Lₐ₄₇₃ | L_{b209} |
| 349 | Lₐ₄₇₄ | L_{b209} | 350 | Lₐ₄₇₅ | L_{b209} | 351 | Lₐ₄₈₁ | L_{b209} |
| 352 | Lₐ₄₈₂ | L_{b209} | 353 | Lₐ₄₈₃ | L_{b209} | 354 | Lₐ₄₈₄ | L_{b209} |
| 355 | Lₐ₅₈₂ | L_{b209} | 356 | Lₐ₆₁₂ | L_{b209} | 357 | Lₐ₆₁₅ | L_{b209} |
| 358 | Lₐ₆₃₄ | L_{b209} | 359 | Lₐ₇₃₂ | L_{b209} | 360 | Lₐ₈₁₀ | L_{b209} |
| 362 | Lₐ₁ | L_{b329} | 362 | Lₐ₃₁ | L_{b329} | 363 | Lₐ₃₄ | L_{b329} |
| 364 | Lₐ₅₃ | L_{b329} | 365 | Lₐ₉₁ | L_{b329} | 366 | Lₐ₉₃ | L_{b329} |
| 367 | Lₐ₉₄ | L_{b329} | 368 | Lₐ₉₆ | L_{b329} | 369 | Lₐ₉₇ | L_{b329} |
| 370 | Lₐ₂₀₂ | L_{b329} | 371 | Lₐ₂₃₂ | L_{b329} | 372 | Lₐ₂₃₅ | L_{b329} |
| 373 | Lₐ₂₅₄ | L_{b329} | 374 | Lₐ₂₉₈ | L_{b329} | 375 | Lₐ₃₇₄ | L_{b329} |
| 376 | Lₐ₄₀₄ | L_{b329} | 377 | Lₐ₄₀₇ | L_{b329} | 378 | Lₐ₄₂₆ | L_{b329} |
| 379 | Lₐ₄₆₄ | L_{b329} | 380 | Lₐ₄₆₆ | L_{b329} | 381 | Lₐ₄₆₇ | L_{b329} |
| 382 | Lₐ₄₆₉ | L_{b329} | 383 | Lₐ₄₇₀ | L_{b329} | 384 | Lₐ₄₇₃ | L_{b329} |
| 385 | Lₐ₄₇₄ | L_{b329} | 386 | Lₐ₄₇₅ | L_{b329} | 387 | Lₐ₄₈₁ | L_{b329} |
| 388 | Lₐ₄₈₂ | L_{b329} | 389 | Lₐ₄₈₃ | L_{b329} | 390 | Lₐ₄₈₄ | L_{b329} |
| 391 | Lₐ₅₈₂ | L_{b329} | 392 | Lₐ₆₁₂ | L_{b329} | 393 | Lₐ₆₁₅ | L_{b329} |
| 394 | Lₐ₆₃₄ | L_{b329} | 395 | Lₐ₇₃₂ | L_{b329} | 396 | Lₐ₈₁₀ | L_{b329} |
| 397 | Lₐ₁ | L_{b333} | 398 | Lₐ₃₁ | L_{b333} | 399 | Lₐ₃₄ | L_{b333} |
| 400 | Lₐ₅₃ | L_{b333} | 401 | Lₐ₉₁ | L_{b333} | 402 | Lₐ₉₃ | L_{b333} |
| 403 | Lₐ₉₄ | L_{b333} | 404 | Lₐ₉₆ | L_{b333} | 405 | Lₐ₉₇ | L_{b333} |
| 406 | Lₐ₂₀₂ | L_{b333} | 407 | Lₐ₂₃₂ | L_{b333} | 408 | Lₐ₂₃₅ | L_{b333} |
| 409 | Lₐ₂₅₄ | L_{b333} | 410 | Lₐ₂₉₈ | L_{b333} | 411 | Lₐ₃₇₄ | L_{b333} |
| 412 | Lₐ₄₀₄ | L_{b333} | 413 | Lₐ₄₀₇ | L_{b333} | 414 | Lₐ₄₂₆ | L_{b333} |
| 415 | Lₐ₄₆₄ | L_{b333} | 416 | Lₐ₄₆₆ | L_{b333} | 417 | Lₐ₄₆₇ | L_{b333} |
| 418 | Lₐ₄₆₉ | L_{b333} | 419 | Lₐ₄₇₀ | L_{b333} | 420 | Lₐ₄₇₃ | L_{b333} |
| 421 | Lₐ₄₇₄ | L_{b333} | 422 | Lₐ₄₇₅ | L_{b333} | 423 | Lₐ₄₈₁ | L_{b333} |
| 424 | Lₐ₄₈₂ | L_{b333} | 425 | Lₐ₄₈₃ | L_{b333} | 426 | Lₐ₄₈₄ | L_{b333} |
| 427 | Lₐ₅₈₂ | L_{b333} | 428 | Lₐ₆₁₂ | L_{b333} | 429 | Lₐ₆₁₅ | L_{b333} |
| 430 | Lₐ₆₃₄ | L_{b333} | 431 | Lₐ₇₃₂ | L_{b333} | 432 | Lₐ₈₁₀ | L_{b333} |
| 433 | Lₐ₄₂₂ | L_{b81} | 434 | Lₐ₄₂₂ | L_{b332} | 435 | Lₐ₄₂₂ | L_{b333} |

19. An organic electroluminescent device, comprising:
an anode,
a cathode and
an organic layer disposed between the anode and the cathode, wherein at least one layer of the organic layer comprises the metal complex according to claim 1.

20. The organic electroluminescent device according to claim 19, wherein the organic layer comprising the metal complex is a light-emitting layer.

21. The organic electroluminescent device according to claim 20, wherein the light-emitting layer further comprises a first host compound;
preferably, the light-emitting layer further comprises a second host compound;
more preferably, at least one of the host compound comprises at least one chemical group selected from the group consisting of: benzene, pyridine, pyrimidine, triazine, carbazole, azacarbazole, indolocarbazole, dibenzothiophene, aza-dibenzothiophene, dibenzofuran, azadibenzofuran, dibenzoselenophene, triphenylene, azatriphenylene, fluorene, silafluorene, naphthalene, quinoline, isoquinoline, quinazoline, quinoxaline, phenanthrene, azaphenanthrene and combinations thereof.

22. The organic electroluminescent device according to claim 21, wherein the metal complex is doped in the first host compound and the second host compound, and the weight of the metal complex accounts for 1% to 30% of the total weight of the light-emitting layer;
preferably, the weight of the metal complex accounts for 3% to 13% of the total weight of the light-emitting layer.

23. A compound composition, comprising the metal complex according to claim 1.
